(19) United States
(12) Patent Application Publication
(10) Pub. No.: US 2024/0268221 A1
(43) Pub. Date: Aug. 8, 2024

(54) LIGHT-EMITTING DEVICE AND ELECTRONIC APPARATUS INCLUDING THE SAME

(71) Applicant: Samsung Display Co., Ltd., Yongin-si (KR)

(72) Inventors: Namsu Kang, Yongin-si (KR); Jinwoo Park, Yongin-si (KR); Yongmun Choi, Yongin-si (KR); Sangbaek Woo, Yongin-si (KR); Daeyong Yoon, Yongin-si (KR); Younghee Lee, Yongin-si (KR)

(73) Assignee: Samsung Display Co., Ltd., Yongin-si (KR)

(21) Appl. No.: 18/360,026

(22) Filed: Jul. 27, 2023

(30) Foreign Application Priority Data
Dec. 27, 2022 (KR) 10-2022-0186377

(51) Int. Cl. H10K 85/60

(52) U.S. Cl. CPC H10K 85/654; H10K 85/615; H10K 85/626; H10K 85/6572; H10K 50/166

(57) ABSTRACT

Embodiments provide a light-emitting device and an electronic apparatus including the light-emitting device. The light-emitting device includes a first electrode, a second electrode facing the first electrode, m emitting units between the first electrode and the second electrode, and m−1 charge generation layers between adjacent ones of the m emitting units, and each including an n-type charge generation layer and a p-type charge generation layer, wherein m is an integer of 2 or more, and at least one emitting unit of the m emitting units includes a first emission layer, a second emission layer, a first electron transport layer, a second electron transport layer, and a third electron transport layer.

### CROSS-REFERENCE TO RELATED APPLICATION(S)

This application claims priority to and benefits of Korean Patent Application No. 10-2022-0186377 under 35 U.S.C. § 119, filed on Dec. 27, 2022, in the Korean Intellectual Property Office, the entire contents of which are incorporated herein by reference.

### BACKGROUND

### 1. Technical Field

Embodiments relate to a light-emitting device and an electronic apparatus including the same.

### 2. Description of the Related Art

Light-emitting devices are self-emissive devices that, as compared with devices of the related art, have wide viewing angles, high contrast ratios, short response times, and excellent characteristics in terms of luminance, driving voltage, and response speed.

Light-emitting devices may include a first electrode on a substrate, and a hole transport region, an emission layer, an electron transport region, and a second electrode sequentially stacked on the first electrode. Holes provided from the first electrode may move toward the emission layer through the hole transport region, and electrons provided from the second electrode may move toward the emission layer through the electron transport region. Carriers, such as holes and electrons, recombine in the emission layer to produce light.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments include a device with improved efficiency and lifespan compared to devices of the related art.

Additional aspects will be set forth in part in the description which follows and, in part, will be apparent from the description, or may be learned by practice of the embodiments of the disclosure.

According to embodiments, a light-emitting device may include:
a first electrode,
a second electrode facing the first electrode,
m emitting units between the first electrode and the second electrode, and
m−1 charge generation layers between adjacent ones of the m emitting units, and each including an n-type charge generation layer and a p-type charge generation layer, wherein m may be an integer of 2 or more,
at least one emitting unit of the m emitting units may include a first emission layer, a second emission layer, a first electron transport layer, a second electron transport layer, and a third electron transport layer,
the first emission layer may include a first host compound and a first dopant compound,
the second emission layer may include a second host compound and a second dopant compound,
the first electron transport layer may include a first compound,
the third electron transport layer may include a second compound and a third compound,
the second electron transport layer may include the first compound, the second compound, and the third compound,
the second compound and/or the third compound may each independently include a phosphine oxide-based compound and/or a phenanthroline-based compound,
the first electron transport layer and the second emission layer may contact each other,
the second electron transport layer may be between the first electron transport layer and the third electron transport layer,
the third electron transport layer and an n-type charge generation layer of the m−1 charge generation layers may contact each other, and
each of the first electron transport layer, the second electron transport layer, and the third electron transport layer may not include a metal complex.

In an embodiment, the second electron transport layer may contact the first electron transport layer and the third electron transport layer.

In an embodiment, the first emission layer and the second emission layer may each emit blue light.

In an embodiment, a difference between an absolute value of a highest occupied molecular orbital (HOMO) energy of the second host compound and an absolute value of a HOMO energy of the first compound may be in a range of about 0.5 eV to about 1.2 eV.

In an embodiment, a difference between an absolute value of a lowest unoccupied molecular orbital (LUMO) energy of the second compound and an absolute value of a LUMO energy of the first compound may be less than or equal to about 0.15 eV; and a difference between an absolute value of a LUMO energy of the third compound and an absolute value of the LUMO energy of the first compound may be less than or equal to about 0.15 eV.

In an embodiment, a difference between an absolute value of a highest occupied molecular orbital (HOMO) energy of the second compound and an absolute value of a HOMO energy of the second host compound is less than or equal to about 0.2 eV; and a difference between an absolute value of a HOMO energy of the third compound and an absolute value of the HOMO energy of the second host compound is less than or equal to about 0.2 eV.

In an embodiment, the n-type charge generation layer contacting the third electron transport layer may include: a phosphine oxide-based compound and/or a phenanthroline-based compound; and a metal.

In an embodiment, the metal may include Yb, Li, Cu, Ag, Au, Al, Mg, or any combination thereof.

In an embodiment, a weight ratio of the phosphine oxide-based compound and/or the phenanthroline-based compound, to the metal may be in a range of about 9:0.1 to about 0.1:9.

In an embodiment, a difference between a smaller value among an absolute value of a lowest unoccupied molecular orbital (LUMO) energy of the phosphine oxide-based compound of the n-type charge generation layer and an absolute value of a LUMO energy of the phenanthroline-based compound of the n-type charge generation layer, and an absolute value of a LUMO energy of the second compound, may be less than or equal to about 0.20 eV; or

a difference between a smaller value among an absolute value of a LUMO energy of the phosphine oxide-based compound of the n-type charge generation layer and an absolute value of a LUMO energy of the phenanthroline-based compound of the n-type charge generation layer, and an absolute value of a LUMO energy of the third compound, may be less than or equal to about 0.20 eV.

In an embodiment, in the second electron transport layer, the second compound and the third compound may be different from each other, and a weight ratio of the second compound to the third compound may be in a range of about 1:15 to about 15:1.

In an embodiment, in the third electron transport layer, a weight ratio of the second compound to the third compound may be in a range of about 1:15 to about 15:1.

In an embodiment, a weight ratio of the second compound to the third compound in the second electron transport layer and a weight ratio of the second compound to the third compound in the third electron transport layer may be equal to each other.

In an embodiment, in the second electron transport layer, a weight ratio of the first compound to a total weight of the second compound and the third compound may be in a range of about 19:10 to about 0.5:10.

In an embodiment, the first compound may be represented by Formula 1, which is explained below.

In an embodiment, in Formula 1, four or more of Ar₁ to Ar₅ may each independently be a C₆-C₆₀ aryl group that is unsubstituted or substituted with at least one R₁₀ₐ or a C₁-C₆₀ heteroaryl group that is unsubstituted or substituted with at least one R₁₀ₐ.

According to embodiments, an electronic apparatus may include the light-emitting device.

In an embodiment, the m emitting units may include one to seven blue emitting units.

It is to be understood that the embodiments above are described in a generic and explanatory sense only and not for the purpose of limitation, and the disclosure is not limited to the embodiments described above.

### BRIEF DESCRIPTION OF THE DRAWINGS

The above and other aspects and features of the disclosure will be more apparent by describing in detail embodiments thereof with reference to the accompanying drawings, in which:

FIGS. 1 and 2 are each a schematic cross-sectional view of a structure of a light-emitting device according to an embodiment;

FIG. 3 is a schematic cross-sectional view of an electronic apparatus according to an embodiment;

FIG. 4 is a schematic cross-sectional view of an electronic apparatus according to another embodiment;

FIG. 5 is a schematic perspective view of an exterior of a vehicle as an electronic device including a light-emitting device, according to an embodiment; and

FIGS. 6A to 6C are each a schematic diagram of an interior of a vehicle, according to embodiments.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within +20%, +10%, or +5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the case of a light-emitting device including an emission layer of the related art, a metal complex, for example, 8-hydroxyquinolinate, has been used to suppress holes from an electron transport layer to the emission layer. However, the metal complex has a function of absorbing excitons, which may reduce efficiency.

In a device structure having two emission layers in the related art, an emission region is pushed toward a first emission layer, and thus, device lifespan and efficiency are at a disadvantage.

According to embodiments, a light-emitting device may include:
a first electrode;
a second electrode facing the first electrode;
m emitting units between the first electrode and the second electrode; and
m−1 charge generation layers between adjacent ones of the m emitting units, and each including an n-type charge generation layer and a p-type charge generation layer, wherein m may be an integer of 2 or more,
at least one emitting unit of the m emitting units may include a first emission layer, a second emission layer, a first electron transport layer, a second electron transport layer, and a third electron transport layer,
the first emission layer may include a first host compound and a first dopant compound,
the second emission layer may include a second host compound and a second dopant compound, the first electron transport layer may include a first compound,
the third electron transport layer may include a second compound and a third compound,
the second electron transport layer may include the first compound, the second compound, and the third compound,
the second compound and/or the third compound may each independently include a phosphine oxide-based compound and/or a phenanthroline-based compound,
the first electron transport layer and the second emission layer may contact each other,
the second electron transport layer may be between the first electron transport layer and the third electron transport layer,
the third electron transport layer and an n-type charge generation layer of the m−1 charge generation layers may contact each other, and
each of the first electron transport layer, the second electron transport layer, and the third electron transport layer may not include a metal complex.

In the light-emitting device according to an embodiment, since an electron transport layer has the above-described structure, an emission region pushed toward a first emission layer may be brought toward a second emission layer by adjusting electron injection, and efficiency and lifespan may be improved and driving voltage may be reduced by not using a metal complex in the electron transport layer.

For example, the first electron transport layer may consist of the first compound, the third electron transport layer may consist of the second compound and the third compound, and the second electron transport layer may consist of the first compound, the second compound, and the third compound.

In an embodiment, the second electron transport layer may contact the first electron transport layer and the third electron transport layer.

In an embodiment, the first emission layer and the second emission layer may each emit blue light. In an embodiment, the first emission layer and the second emission layer may contact (for example, directly contact) each other. The first host compound and the first dopant compound, included in the first emission layer, and the second host compound and the second dopant compound, included in the second emission layer, may each independently be the same as described in connection with a host and a dopant, as described below.

In an embodiment, a difference between an absolute value of a highest occupied molecular orbital (HOMO) energy of the second host compound of the second emission layer and an absolute value of a HOMO energy of the first compound of the first electron transport layer may be in a range of about 0.5 eV to about 1.2 eV. When the energy relationship of the first electron transport layer contacting the second emission layer is as described above, the first electron transport layer has a hole blocking function.

In an embodiment, a difference between an absolute value of a lowest unoccupied molecular orbital (LUMO) energy of the second compound and an absolute value of a LUMO energy of the first compound may be less than or equal to about 0.15 eV, and a difference between an absolute value of a LUMO energy of the third compound and an absolute value of LUMO energy of the first compound may be less than or equal to about 0.15 eV.

In an embodiment, a difference between an absolute value of a HOMO energy of the second compound and an absolute value of a HOMO energy of the second host compound may be less than or equal to about 0.2 eV, and a difference between an absolute value of a HOMO energy of the third compound and an absolute value of HOMO energy of the second host compound may be less than or equal to about 0.2 eV.

When the energy relationship of the second host compound, the first compound, the second compound, and the third compound is as described above, charge injection and charge transfer may be facilitated.

In an embodiment, the n-type charge generation layer contacting the third electron transport layer may include: a phosphine oxide-based compound and/or a phenanthroline-based compound; and a metal.

The phosphine oxide-based compound and/or the phenanthroline-based compound, included in the n-type charge generation layer contacting the third electron transport layer, may be identical to or different from the phosphine oxide-based compound and/or the phenanthroline-based compound, included in the second compound and/or the third compound.

In an embodiment, the metal may include Yb, Li, Cu, Ag, Au, Al, Mg, or any combination thereof.

In an embodiment, a weight ratio of the phosphine oxide-based compound and/or the phenanthroline-based compound, to the metal may be in a range of about 9:0.1 to about 0.1:9. For example, a weight ratio of the phosphine oxide-based compound and/or the phenanthroline-based compound, to the metal may be in a range of about 9:0.1 to about 9:2.

In an embodiment, a difference between a smaller value among an absolute value of a LUMO energy of the phosphine oxide-based compound of the n-type charge generation layer and an absolute value of a LUMO energy of the phenanthroline-based compound of the n-type charge generation layer, and an absolute value of a LUMO energy of the second compound, may be less than or equal to about 0.20 eV; or

a difference between a smaller value among an absolute value of a LUMO energy of the phosphine oxide-based compound of the n-type charge generation layer and an absolute value of a LUMO energy of the phenanthroline-based compound of the n-type charge generation layer, and an absolute value of a LUMO energy of the third compound, may be less than or equal to about 0.20 eV.

When the energy relationship of the compounds is as described above, electron injection may be facilitated.

In an embodiment, in the second electron transport layer, the second compound and the third compound may be different from each other, and a weight ratio of the second compound to the third compound may be in a range of about 1:15 to about 15:1. For example, a weight ratio of the second compound to the third compound may be in a range of about 1:10 to about 10:1.

In an embodiment, in the third electron transport layer, a weight ratio of the second compound to the third compound may be in a range of about 1:15 to about 15:1. For example, a weight ratio of the second compound to the third compound may be in a range of about 1:10 to about 10:1.

When a weight ratio of the second compound to the third compound is within the above-described range, the device has low driving voltage, excellent efficiency, and excellent lifespan.

In an embodiment, a weight ratio of the second compound to the third compound in the second electron transport layer and a weight ratio of the second compound to the third compound in the third electron transport layer may be equal to each other.

In an embodiment, in the second electron transport layer, a weight ratio of the first compound to a total weight of the second compound and the third compound may be in a range of about 19:10 to about 0.5:10. For example, a weight ratio of the first compound to a total weight of the second compound and the third compound may be in a range of about 19:10 to about 1.1:10.

When a weight ratio of the first compound, the second compound, and the third compound is within the above-described range, the device has low driving voltage, excellent efficiency, and excellent lifespan.

In an embodiment, the first compound may be represented by Formula 1:

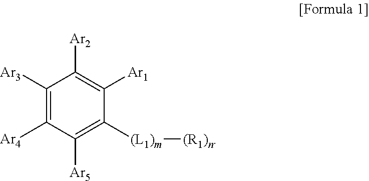

In Formula 1,
Ar₁ to Ar₅ and R₁ may each independently be hydrogen, deuterium, a C₆-C₆₀ aryl group that is unsubstituted or substituted with at least one R₁₀ₐ, or a C₁-C₆₀ heteroaryl group that is unsubstituted or substituted with at least one R₁₀ₐ,
L₁ may be a C₆-C₆₀ arylene group that is unsubstituted or substituted with at least one R₁₀ₐ or a C₁-C₆₀ heteroarylene group that is unsubstituted or substituted with at least one R₁₀ₐ,
m and n may each independently be an integer from 1 to 4,
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁) (Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, four or more of Ar₁ to Ar₅ may each independently be a C₆-C₆₀ aryl group that is unsubstituted or substituted with at least one R₁₀ₐ or a C₁-C₆₀ heteroaryl group that is unsubstituted or substituted with at least one R₁₀ₐ.

In an embodiment, the first compound may be selected from the compounds below:

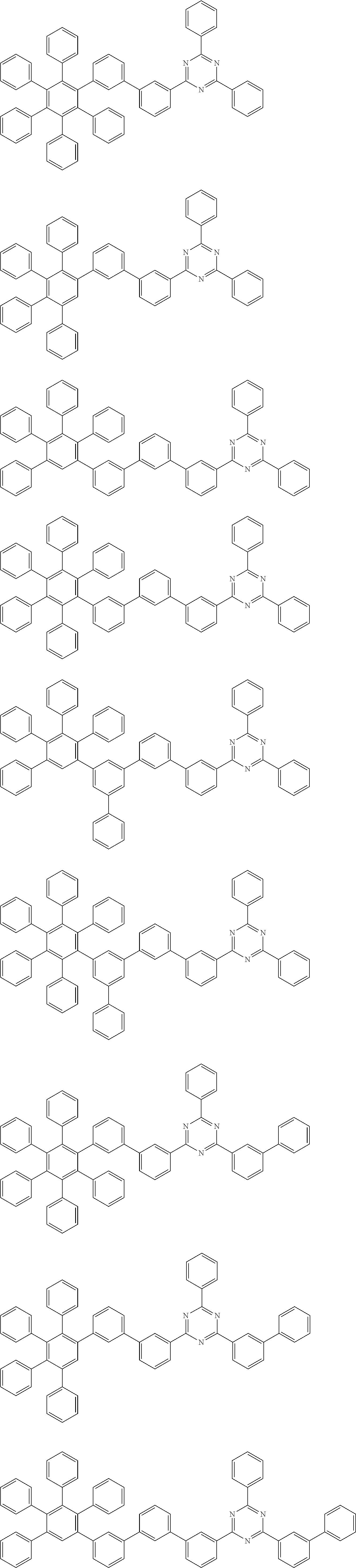

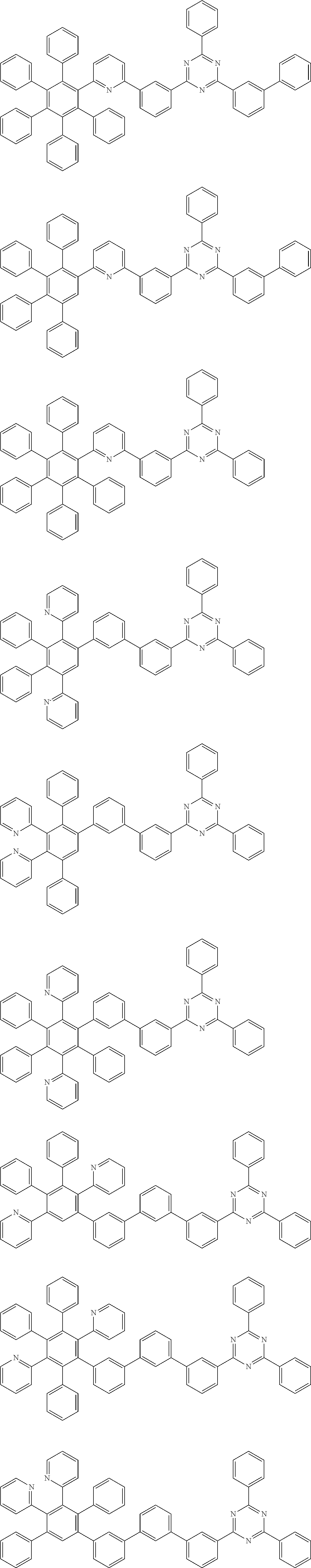

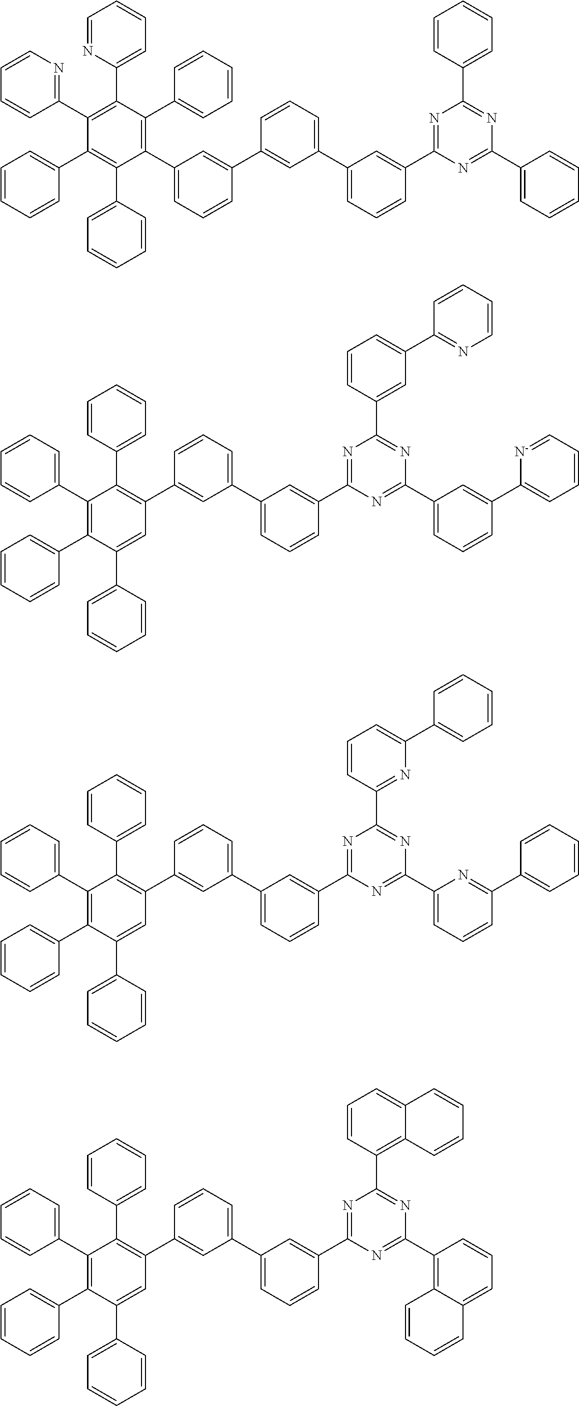

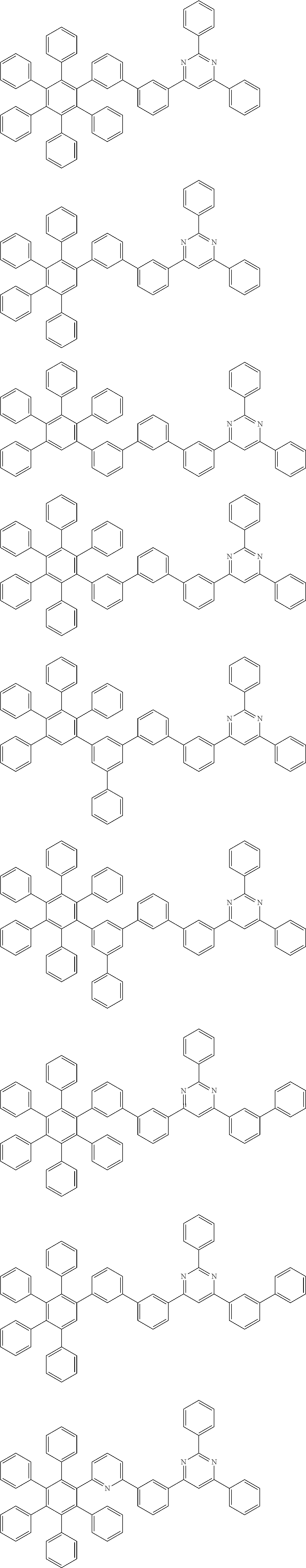

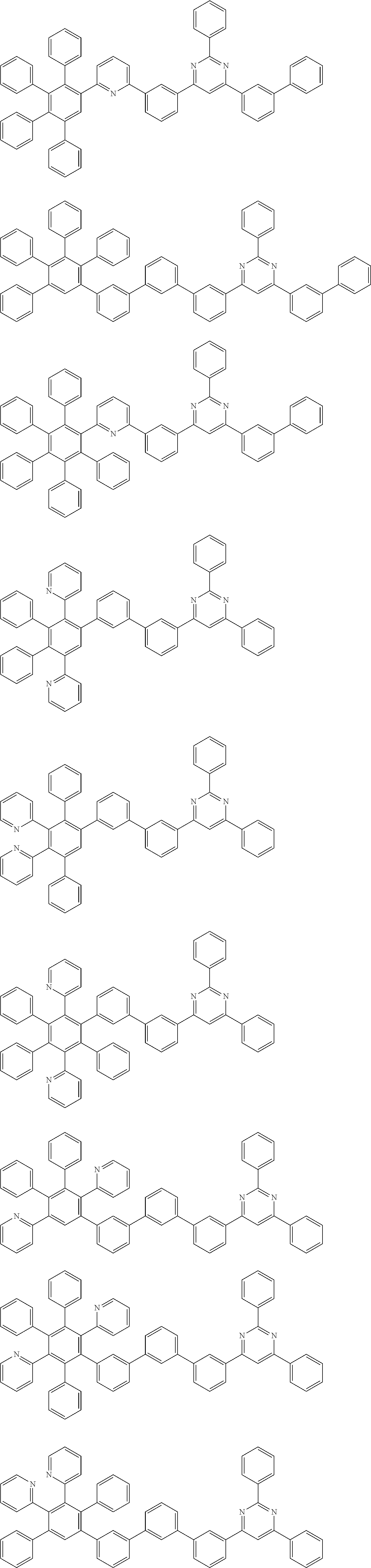

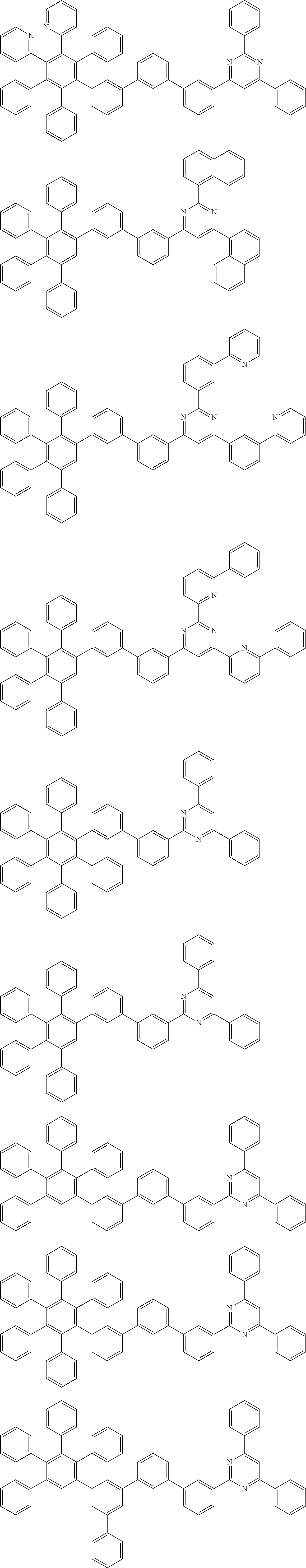

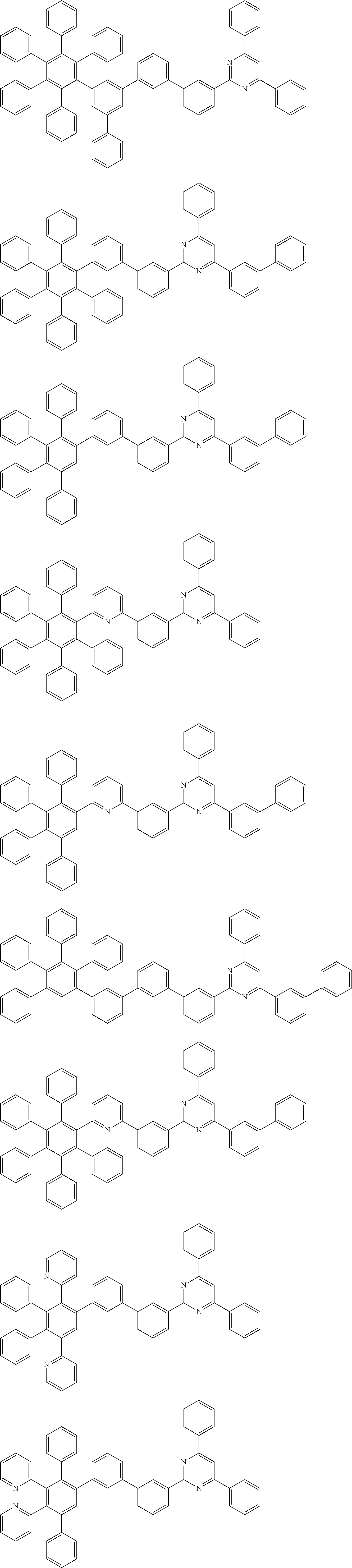

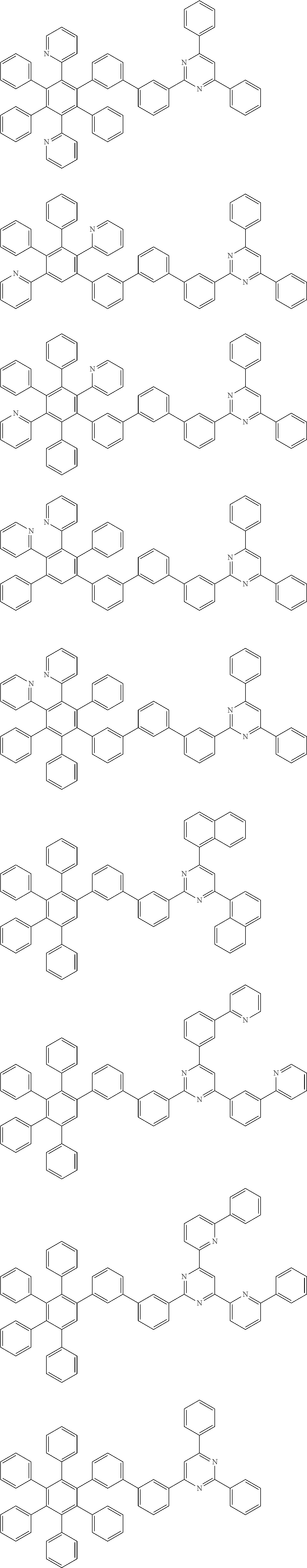

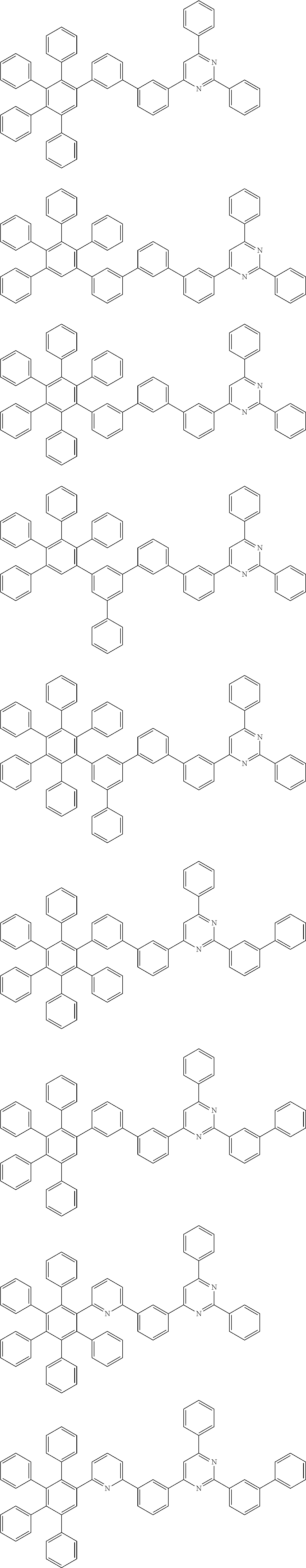

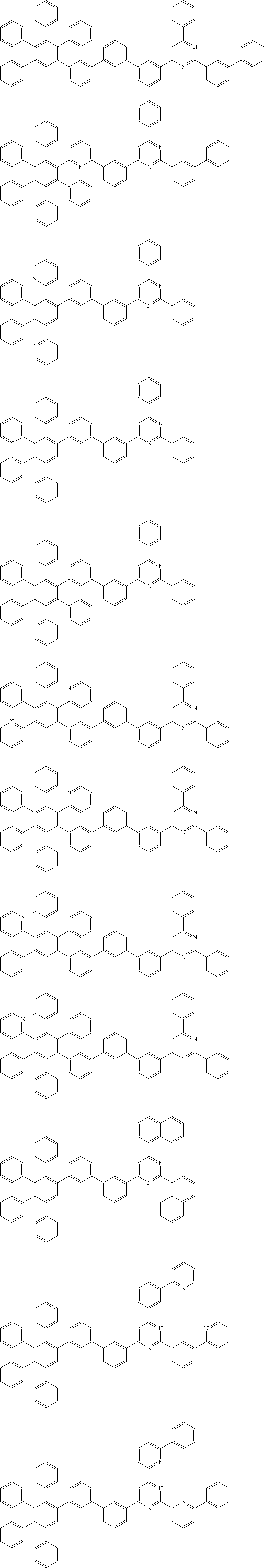

In an embodiment, the second compound and the third compound may each independently be selected from the compounds below:

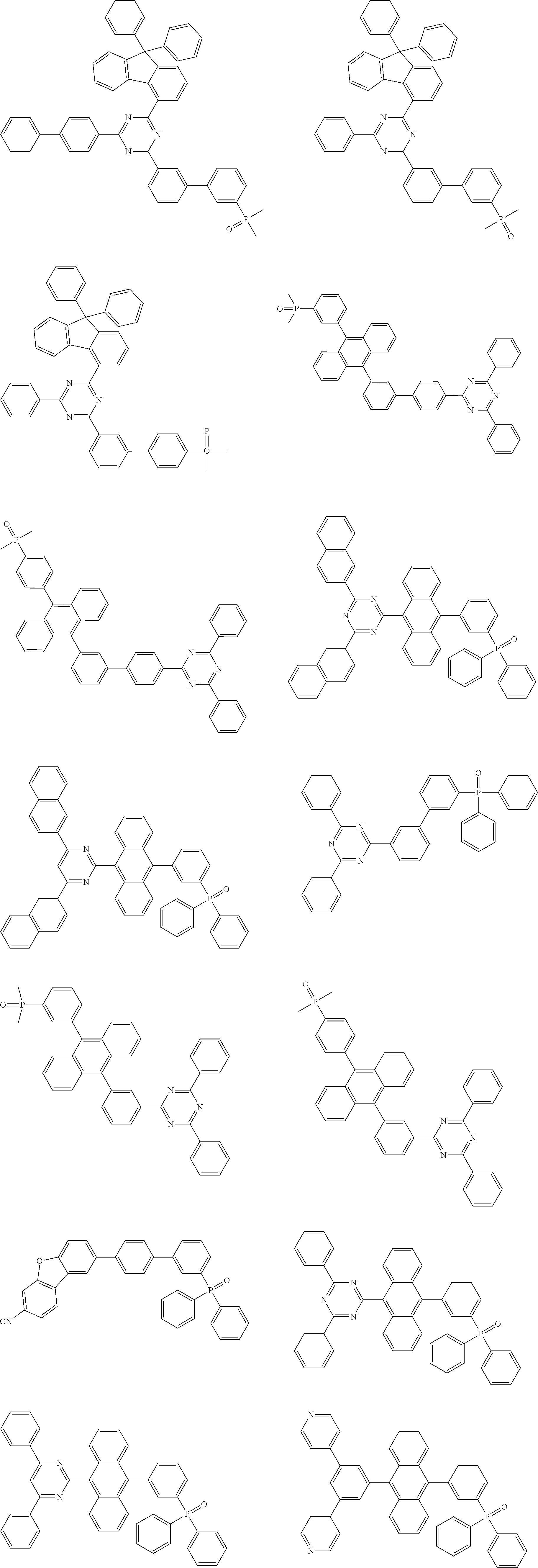

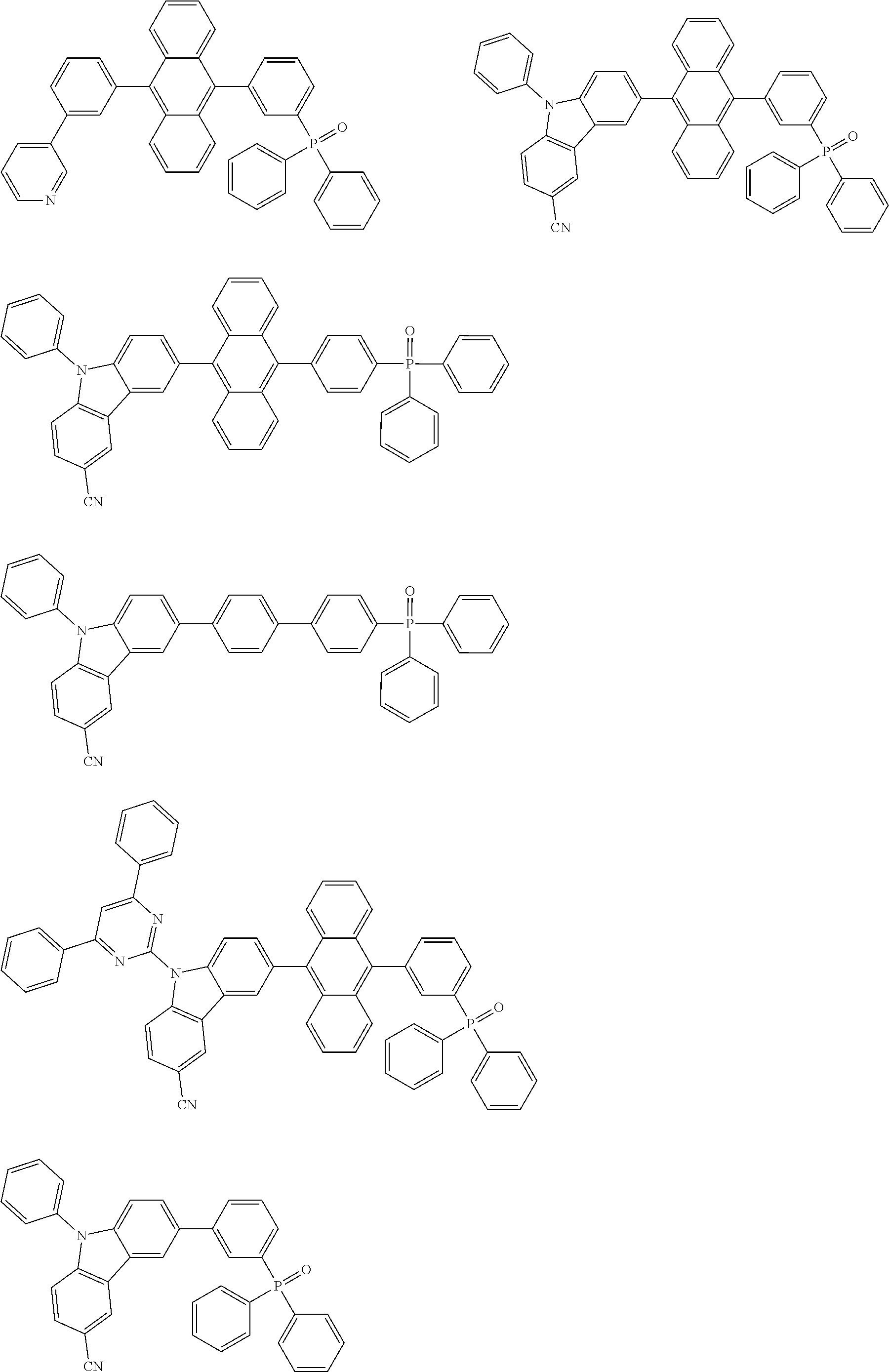

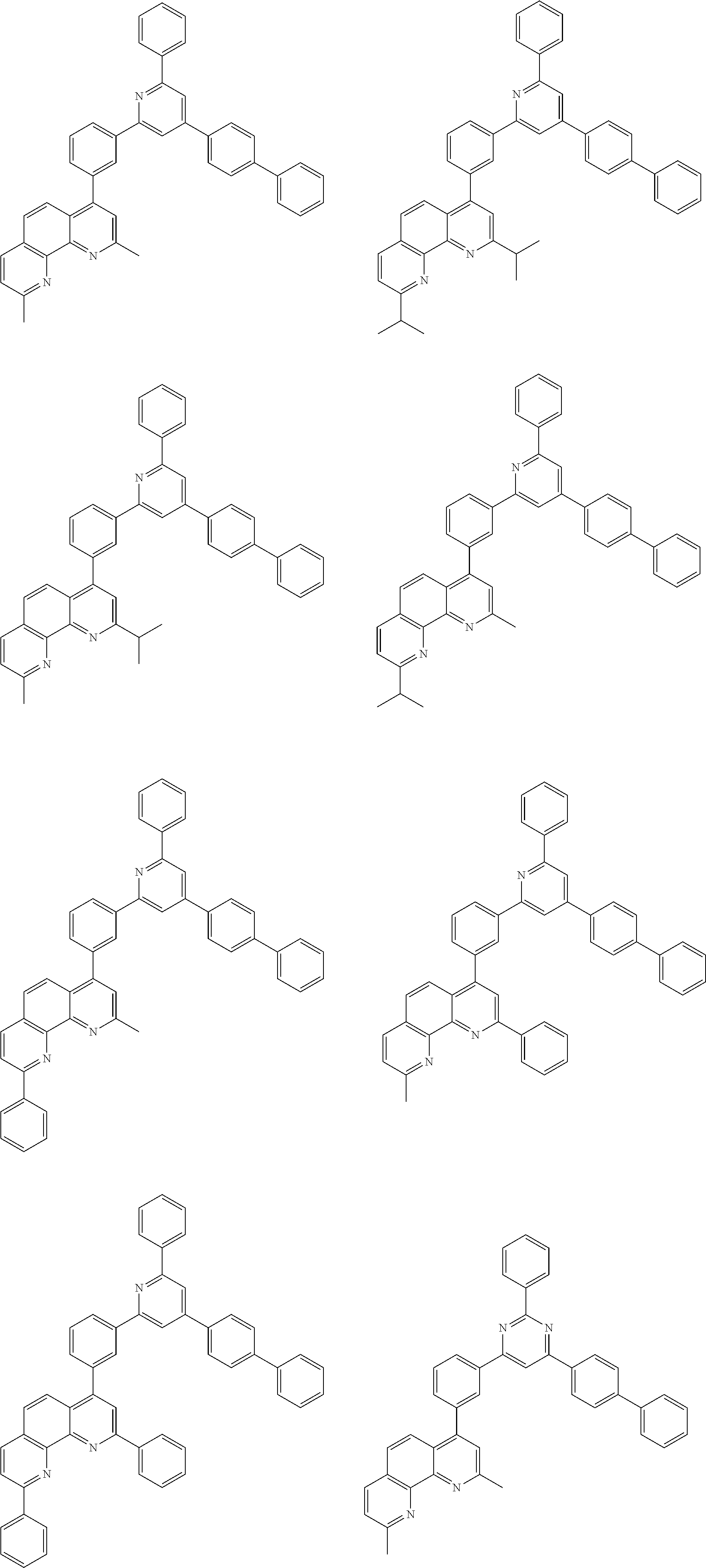

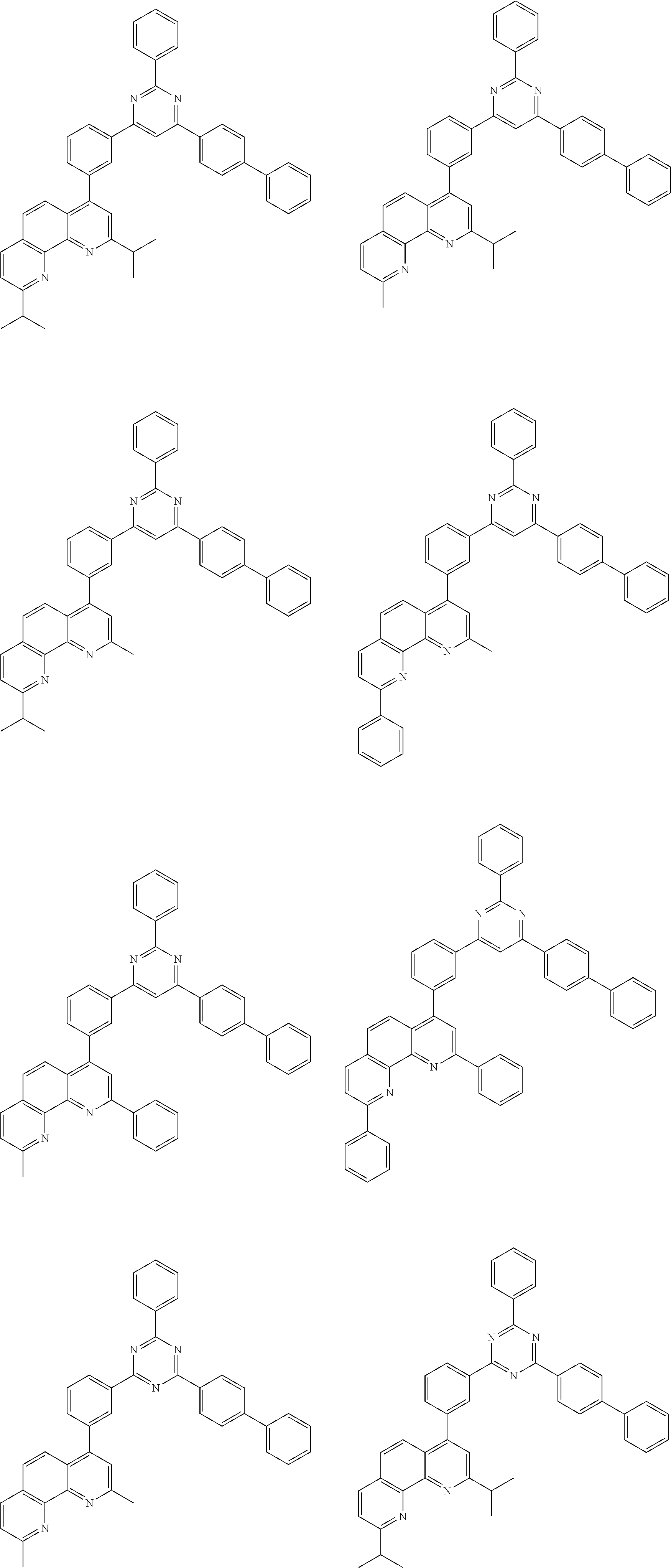

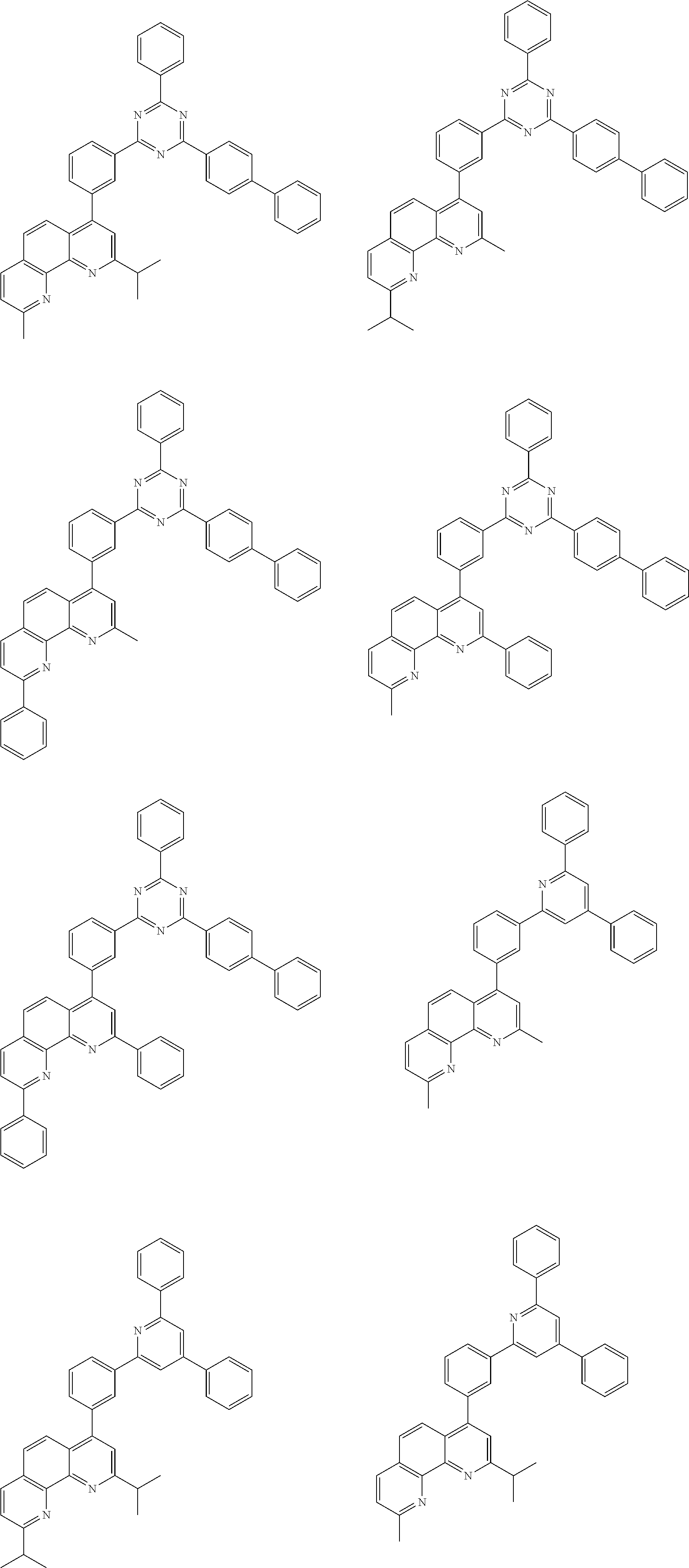

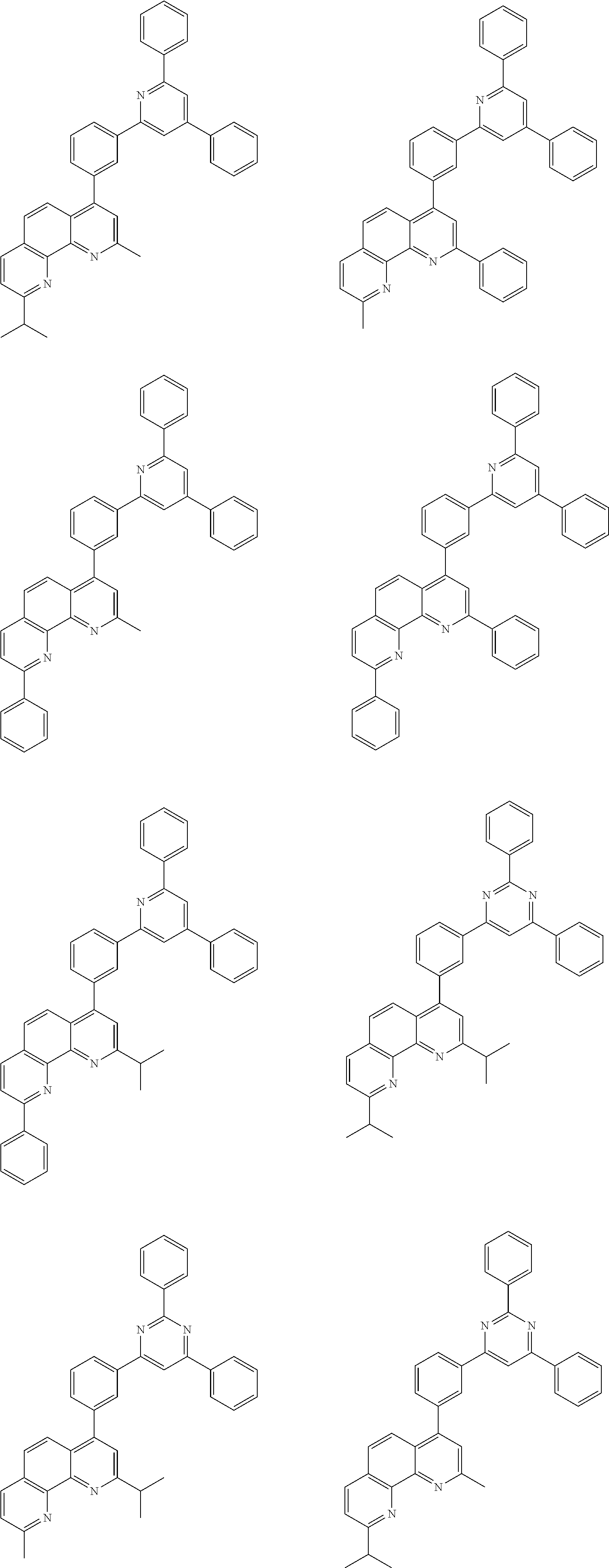

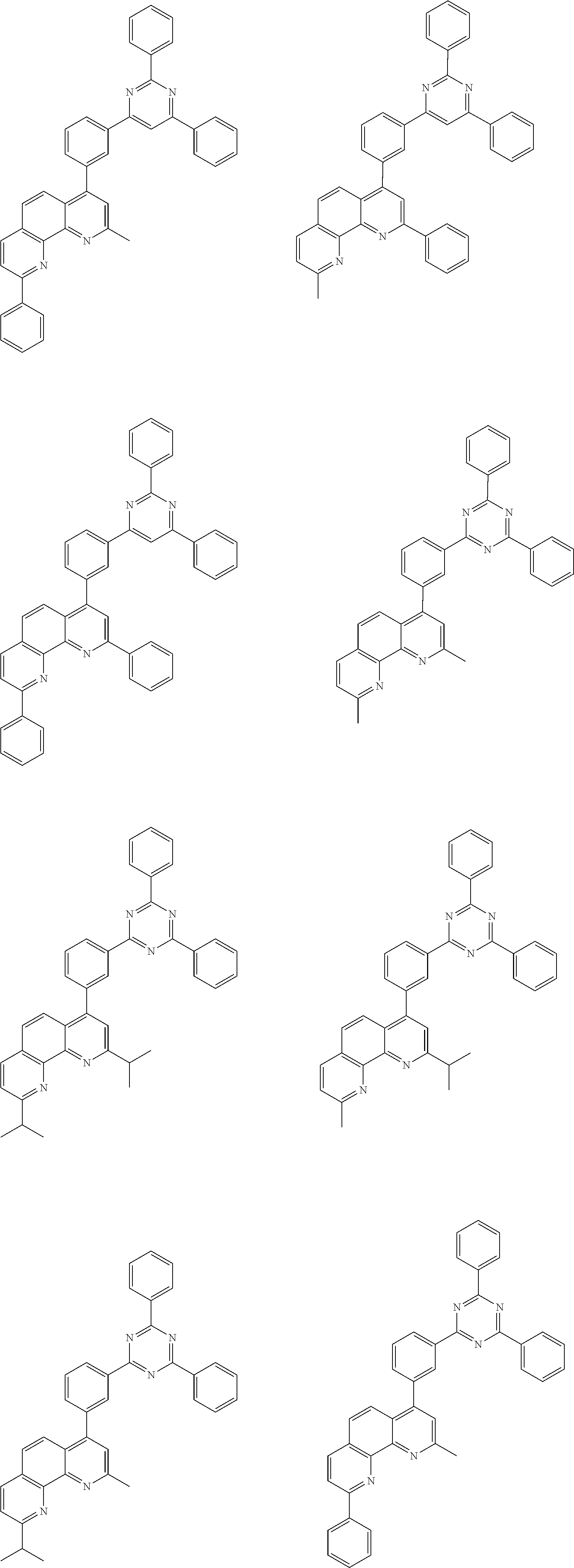

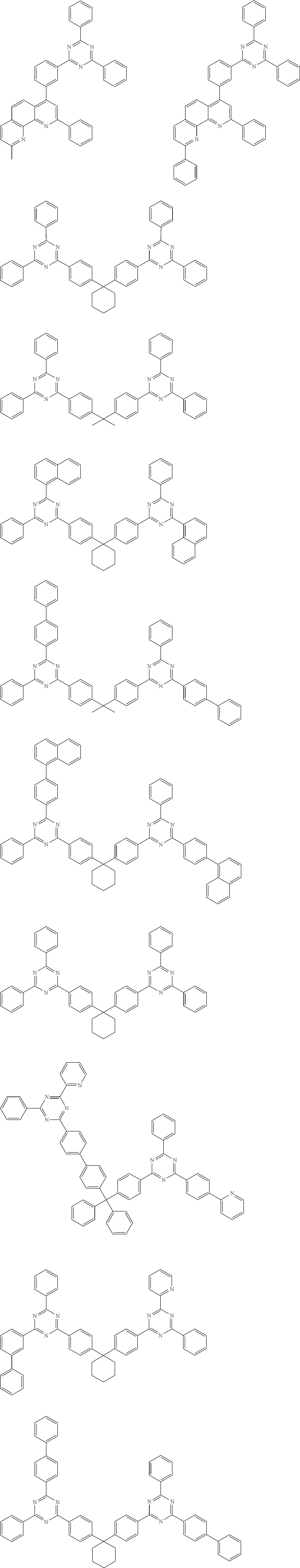

The light-emitting device includes m−1 charge generation layers between adjacent ones of the m emitting units.

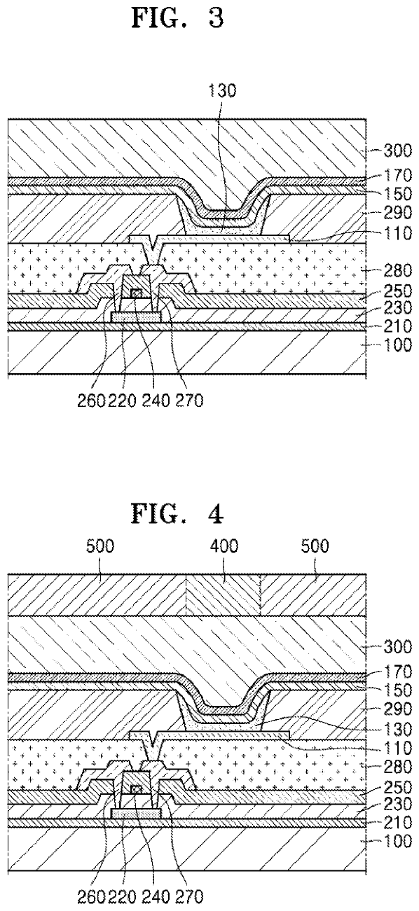

Referring to FIG. 2, an interlayer 130 may include m emitting units (145(1), . . . , 145(m)) and m−1 charge generation layers (144(m−1)) arranged between adjacent emitting units among the m emitting units, and at least one of the m emitting units may include the first emission layer, the second emission layer, the first electron transport layer, the second electron transport layer, and the third electron transport layer.

For example, when m is 2, the first electrode, a first emitting unit, a first charge generation layer, and a second emitting unit may be sequentially arranged. The first emitting unit may emit first-color light, the second emitting unit may emit second-color light, and a maximum emission wavelength of the first-color light and a maximum emission wavelength of the second-color light may be identical to or different from each other. One of the first emitting unit and the second emitting unit may include the first emission layer, the second emission layer, the first electron transport layer, the second electron transport layer, and the third electron transport layer.

In an embodiment, when m is 3, the first electrode, a first emitting unit, a first charge generation layer, a second emitting unit, a second charge generation layer, and a third emitting unit may be sequentially arranged. The first emitting unit may emit first-color light, the second emitting unit may emit second-color light, the third emitting unit may emit third-color light, and a maximum emission wavelength of the first-color light, a maximum emission wavelength of the second-color light, and a maximum emission wavelength of the third-color light may be identical to or different from each other. At least one of the first emitting unit, the second emitting unit, and the third emitting unit may each include the first emission layer, the second emission layer, the first electron transport layer, the second electron transport layer, and the third electron transport layer.

In an embodiment, when m is 4, the first electrode, a first emitting unit, a first charge generation layer, a second emitting unit, a second charge generation layer, a third emitting unit, a third charge generation layer, and a fourth emitting unit may be sequentially arranged. The first emitting unit may emit first-color light, the second emitting unit may emit second-color light, the third emitting unit may emit third-color light, the fourth emitting unit may emit fourth-color light, and a maximum emission wavelength of the first-color light, a maximum emission wavelength of the second-color light, a maximum emission wavelength of the third-color light, and a maximum emission wavelength of the fourth-color light may be identical to or different from each other.

At least one of the first emitting unit, the second emitting unit, the third emitting unit, and the fourth emitting unit may each include the first emission layer, the second emission layer, the first electron transport layer, the second electron transport layer, and the third electron transport layer.

A similar structure is applied to an embodiment where m is 5 to 7.

For example, when m is 5 or more,
three or more emitting units may each include the first emission layer, the second emission layer, the first electron transport layer, the second electron transport layer, and the third electron transport layer, and
the first emission layer may include the first host compound and the first dopant compound,
the second emission layer may include a second host compound and a second dopant compound, the first electron transport layer may include a first compound,
the third electron transport layer may include a second compound and a third compound,
the second electron transport layer may include the first compound, the second compound, and the third compound,
the second compound and/or the third compound may each independently include a phosphine oxide-based compound and/or a phenanthroline-based compound,
the first electron transport layer and the second emission layer may contact each other,
the second electron transport layer may be between the first electron transport layer and the third electron transport layer,
the third electron transport layer and an n-type charge generation layer of the m−1 charge generation layers may contact each other, and
the other two or fewer emitting units may each include a green emission layer.

In an embodiment, a maximum emission wavelength of light emitted from at least one emitting unit among the m emitting units may be different from a maximum emission wavelength of light emitted from at least one emitting unit among the remaining emitting units.

Referring to FIG. 2, among the m emitting units, an emitting unit which is m^{th} closest to the first electrode may be referred to as an m^{th} emitting unit 145(m).

An emitting unit which is closest to the first electrode among the m emitting units may be referred to as a first emitting unit 145(1), an emitting unit which is farthest from the first electrode may be referred to as the m^{th} emitting unit 145(m), and the first emitting unit 145(1) to the m^{th} emitting unit 145(m) are sequentially arranged. For example, an m−1^{th} emitting unit 145(m−1) may be arranged between the first electrode and the m^{th} emitting unit 145(m).

In the light-emitting device according to an embodiment, a hole transport region or an electron transport region may be arranged between an emission unit and a charge generation layer.

The hole transport region may include a hole injection layer, a hole transport layer, an electron blocking layer, or any combination thereof.

The electron transport region may include an electron injection layer, an electron transport layer, a hole blocking layer, or any combination thereof.

In an embodiment, among the m−1 charge generation layers, a charge generation layer which is m−1^{th} closest to the first electrode may be referred to as an m−1^{th} charge generation layer 144(m−1).

The light-emitting device according to an embodiment may include a structure in which the first emission layer, the second emission layer, the first electron transport layer, the second electron transport layer, the third electron transport layer, and an n-type charge generation layer are sequentially stacked.

Embodiments provide an electronic apparatus which may include the light-emitting device. The electronic apparatus may further include a thin-film transistor. For example, the electronic apparatus may further include a thin-film transistor including a source electrode and a drain electrode, and the first electrode of the light-emitting device may be electrically connected to the source electrode or the drain electrode.

The electronic apparatus may further include a color filter, a color-conversion layer, a touch screen layer, a polarizing layer, or any combination thereof. Further details on the electronic apparatus are as described herein.

The term “interlayer” as used herein may refer to a single layer and/or all layers between the first electrode and the second electrode of the light-emitting device.

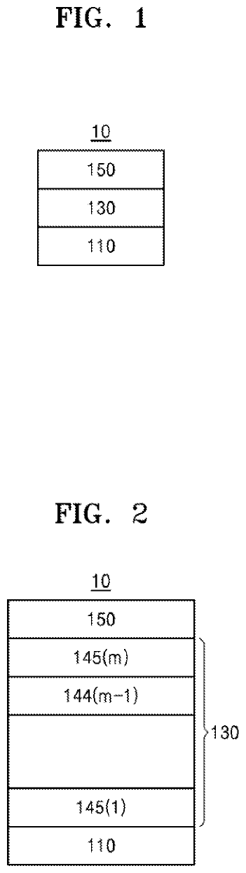

### [Description of FIG. 1]

FIG. 1 is a schematic cross-sectional view of a light-emitting device 10 according to an embodiment. The light-emitting device 10 includes a first electrode 110, an interlayer 130, and a second electrode 150.

Hereinafter, a structure of the light-emitting device 10 according to an embodiment and a method of manufacturing the light-emitting device 10 will be described with reference to FIG. 1.

### [First Electrode 110]

In FIG. 1, a substrate may be further included under the first electrode 110 or on the second electrode 150. The substrate may be a glass substrate or a plastic substrate. In an embodiment, the substrate may be a flexible substrate, and may include plastics with excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, applying a material for forming the first electrode 110 onto the substrate by using a deposition or sputtering method. When the first electrode 110 is an anode, a material for forming the first electrode 110 may be a high work function material to facilitate injection of holes.

The first electrode 110 may be a reflective electrode, a semi-transmissive electrode, or a transmissive electrode. When the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In an embodiment, when the first electrode 110 is a semi-transmissive electrode or a reflective electrode, magnesium (Mg), silver (Ag), aluminum (AI), aluminum-lithium (Al—Li), calcium (Ca), magnesium-indium (Mg—In), magnesium-silver (Mg—Ag), or any combination thereof may be used as a material for forming a first electrode.

The first electrode 110 may have a structure consisting of a single layer, or a structure including multiple layers. For example, the first electrode 110 may have a three-layered structure of ITO/Ag/ITO.

### [Interlayer 130]

The interlayer 130 is disposed on the first electrode 110. The interlayer 130 includes an emission layer. The emission layer may include a first emission layer and a second emission layer.

The interlayer 130 may further include a hole transport region between the first electrode 110 and the emission layer and an electron transport region between the emission layer and the second electrode 150.

The interlayer 130 may further include, in addition to various organic materials, a metal-containing compound such as an organometallic compound, an inorganic material such as a quantum dot, and the like.

In an embodiment, the interlayer 130 may include, two or more emission layers stacked between the first electrode 110 and the second electrode 150, and at least one charge generation layer between the two emission layers. When the interlayer 130 includes the two or more emission layers and the at least one charge generation layer as described above, the light-emitting device 10 may be a tandem light-emitting device.

### [Hole Transport Region in Interlayer 130]

A hole transport region may have a structure consisting of a layer consisting of a single material, a structure consisting of a layer including different materials, or a structure including multiple layers including different materials.

The hole transport region may include a hole injection layer, a hole transport layer, an emission auxiliary layer, an electron blocking layer, or any combination thereof.

In embodiments, the hole transport region may have a multilayer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein the layers of each structure may be stacked in its respective stated order from the first electrode 110, but the structure of the hole transport region is not limited thereto.

For example, the hole transport region may have a multilayer structure including a hole transport layer/emission auxiliary layer structure or a hole transport layer/electron blocking layer structure, wherein the layers of each structure may be stacked in its respective stated order from the first electrode 110.

The hole transport region may include a compound represented by Formula 201, a compound represented by Formula 202, or any combination thereof:

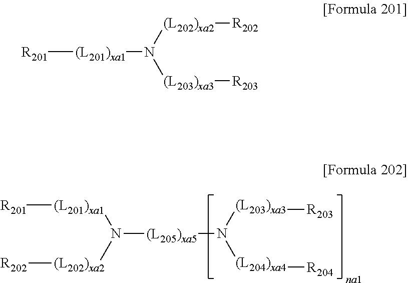

In Formulae 201 and 202,

L₂₀₁ to L₂₀₄ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
L₂₀₅ may be *—O—**, *—S—**, *—N(Q₂₀₁)—*′, a C₁-C₂₀ alkylene group that is unsubstituted or substituted with at least one R₁₀ₐ, a C₂-C₂₀ alkenylene group that is unsubstituted or substituted with at least one R₁₀ₐ, a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
R₂₀₁ and R₂₀₂ may optionally be linked together via a single bond, a C₁-C₅ alkylene group that is unsubstituted or substituted with at least one R₁₀ₐ, or a C₂-C₅ alkenylene group that is unsubstituted or substituted with at least one R₁₀ₐ, to form a C₈-C₆₀ polycyclic group (for example, a carbazole group or the like) unsubstituted or substituted with at least one R₁₀ₐ (for example, Compound HT16),
R₂₀₃ and R₂₀₄ may optionally be linked together via a single bond, a C₁-C₅ alkylene group that is unsubstituted or substituted with at least one R₁₀ₐ, or a C₂-C₅ alkenylene group that is unsubstituted or substituted with at least one R₁₀ₐ to form a C₈-C₆₀ polycyclic group that is unsubstituted or substituted with at least one R₁₀ₐ, and
na1 may be an integer from 1 to 4.

In an embodiment, the compound represented by Formula 201 and the compound represented by Formula 202 may each independently include at least one of groups represented by Formulae CY201 to CY217:

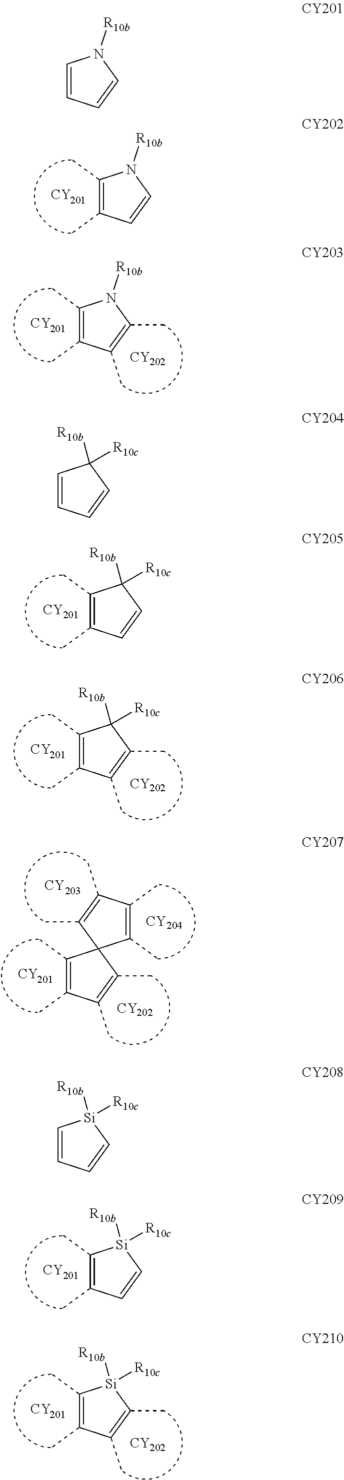

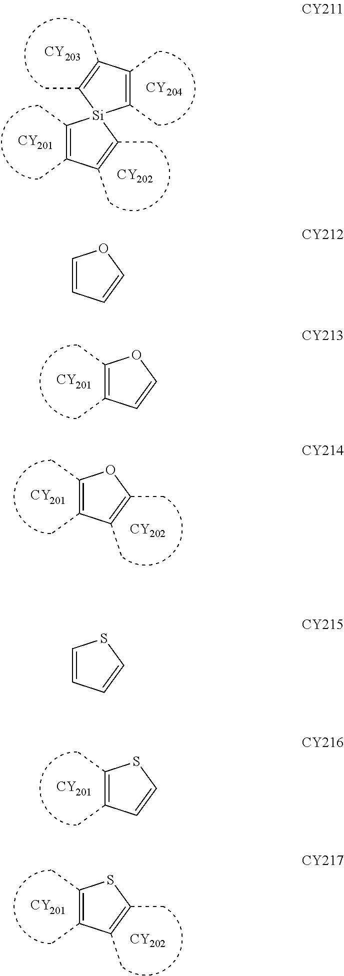

In Formulae CY201 to CY217, R_{10b} and R_{10c} may each independently be the same as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In an embodiment, in Formulae CY201 to CY217, ring CY₂₀₁ to ring CY₂₀₄ may each independently be a benzene group, a naphthalene group, a phenanthrene group, or an anthracene group.

In an embodiment, the compound represented by Formula 201 and the compound represented by Formula 202 may each independently include at least one of groups represented by Formulae CY201 to CY203.

In an embodiment, the compound represented by Formula 201 may include at least one of groups represented by Formulae CY201 to CY203 and at least one of groups represented by Formulae CY204 to CY217.

In an embodiment, in Formula 201, xa1 may be 1, R₂₀₁ may be a group represented by one of Formulae CY201 to CY203, xa2 may be 0, and R₂₀₂ may be a group represented by one of Formulae CY204 to CY207.

In an embodiment, the compound represented by Formula 201 and the compound represented by Formula 202 may each not include groups represented by Formulae CY201 to CY203.

In an embodiment, the compound represented by Formula 201 and the compound represented by Formula 202 may each not include groups represented by Formulae CY201 to CY203, and may each independently include at least one of groups represented by Formulae CY204 to CY217.

In an embodiment, the compound represented by Formula 201 and the compound represented by Formula 202 may each not include groups represented by Formulae CY201 to CY217.

In an embodiment, the hole transport region may include one of Compounds HT1 to HT46, m-MTDATA, TDATA, 2-TNATA, NPB(NPD), B-NPB, TPD, Spiro-TPD, Spiro-NPB, methylated NPB, TAPC, HMTPD, 4,4′, 4″-tris(N-carbazolyl)triphenylamine (TCTA), polyaniline/dodecylbenzene sulfonic acid (PANI/DBSA), poly(3,4-ethylene dioxythiophene)/poly(4-styrene sulfonate) (PEDOT/PSS), polyaniline/camphor sulfonic acid (PANI/CSA), polyaniline/poly(4-styrene sulfonate) (PANI/PSS), or any combination thereof:

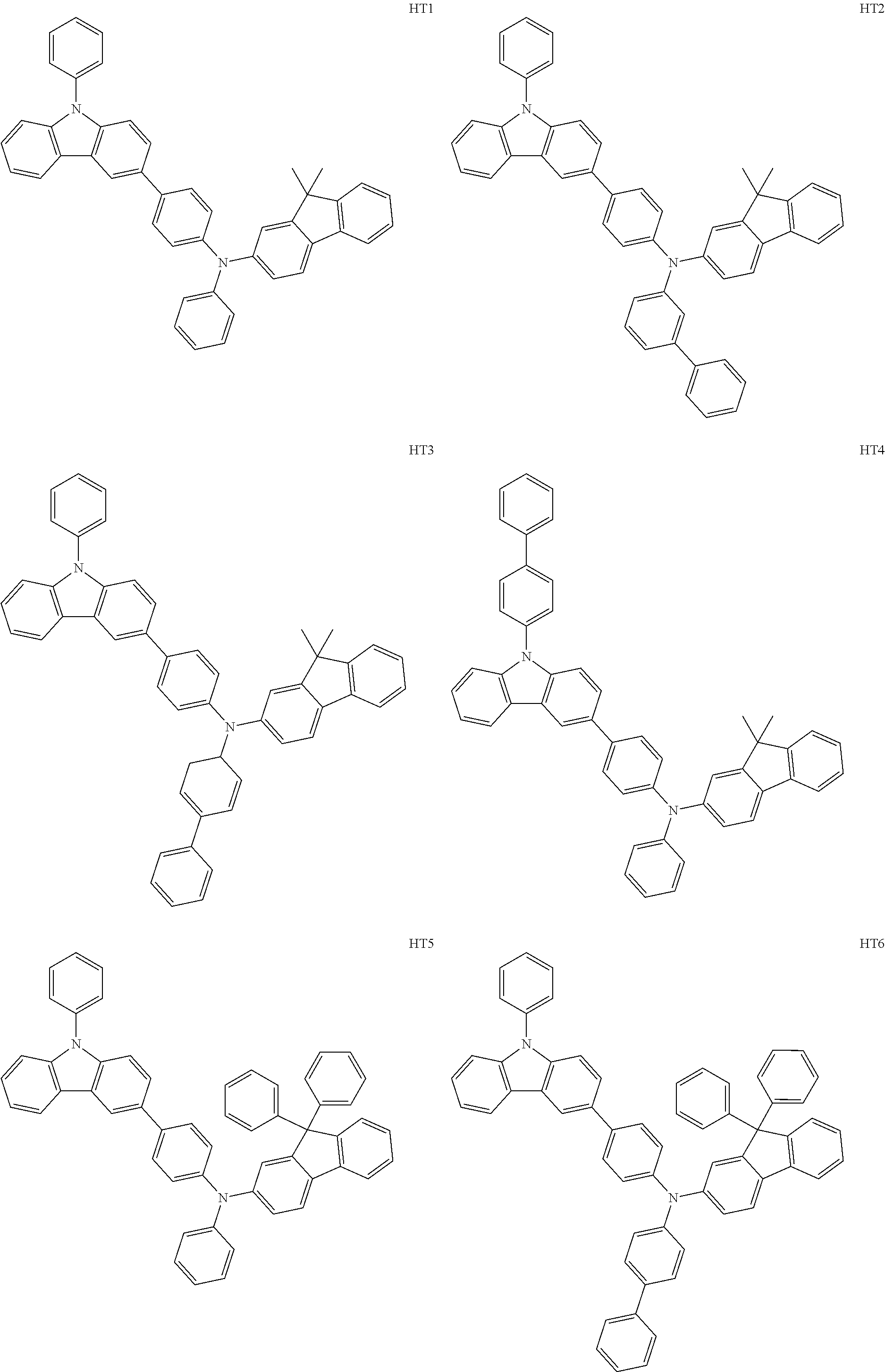

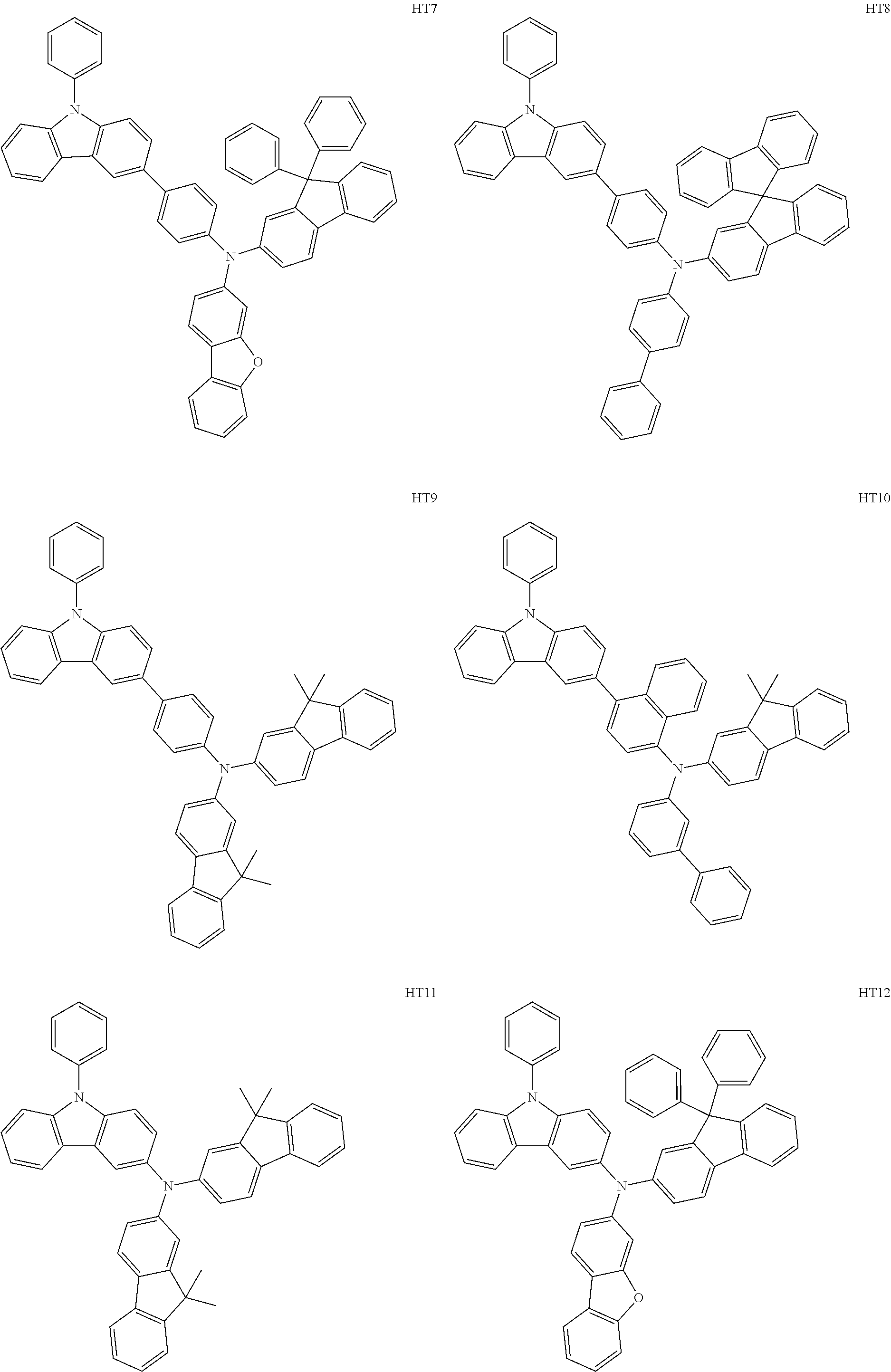

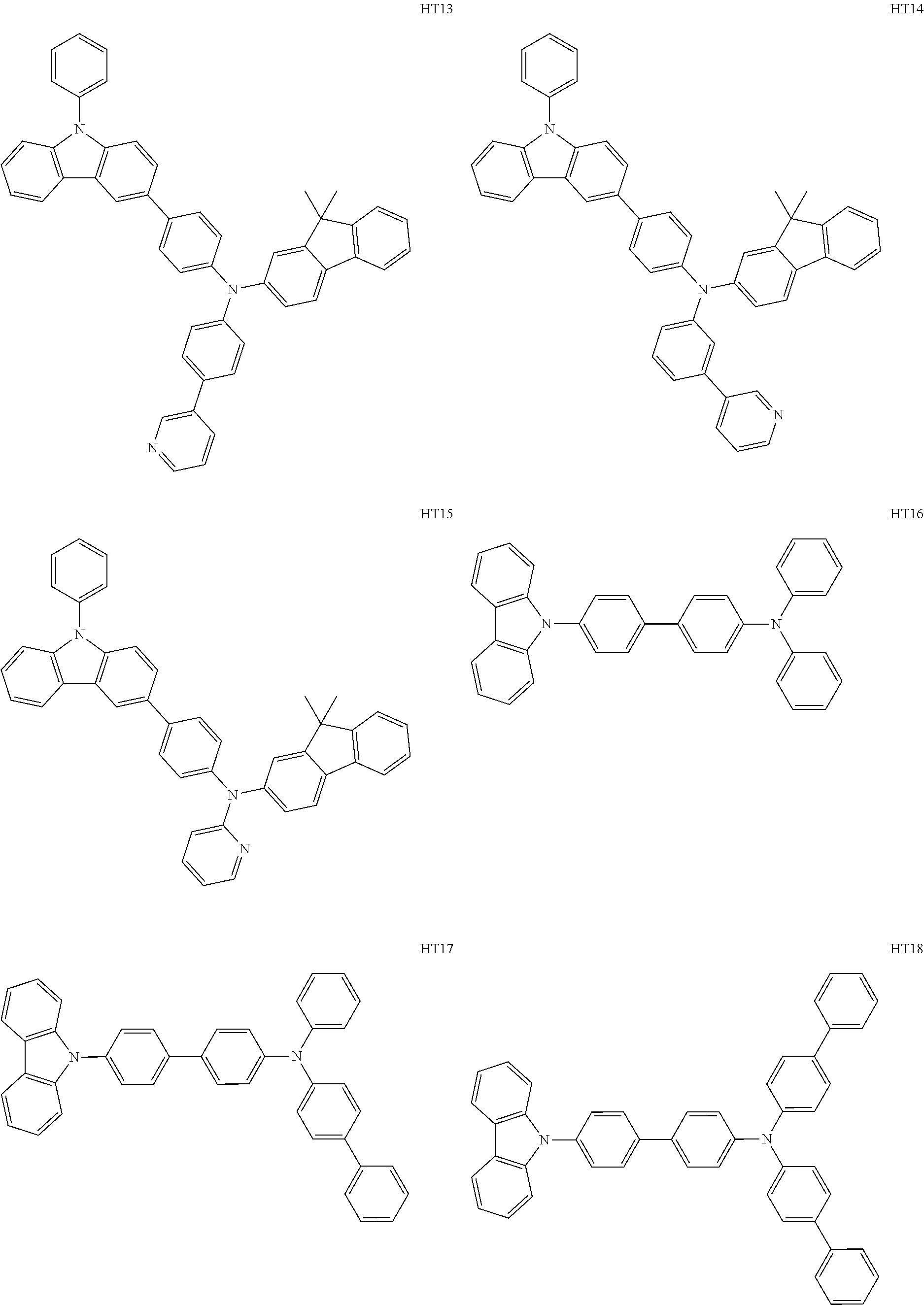 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

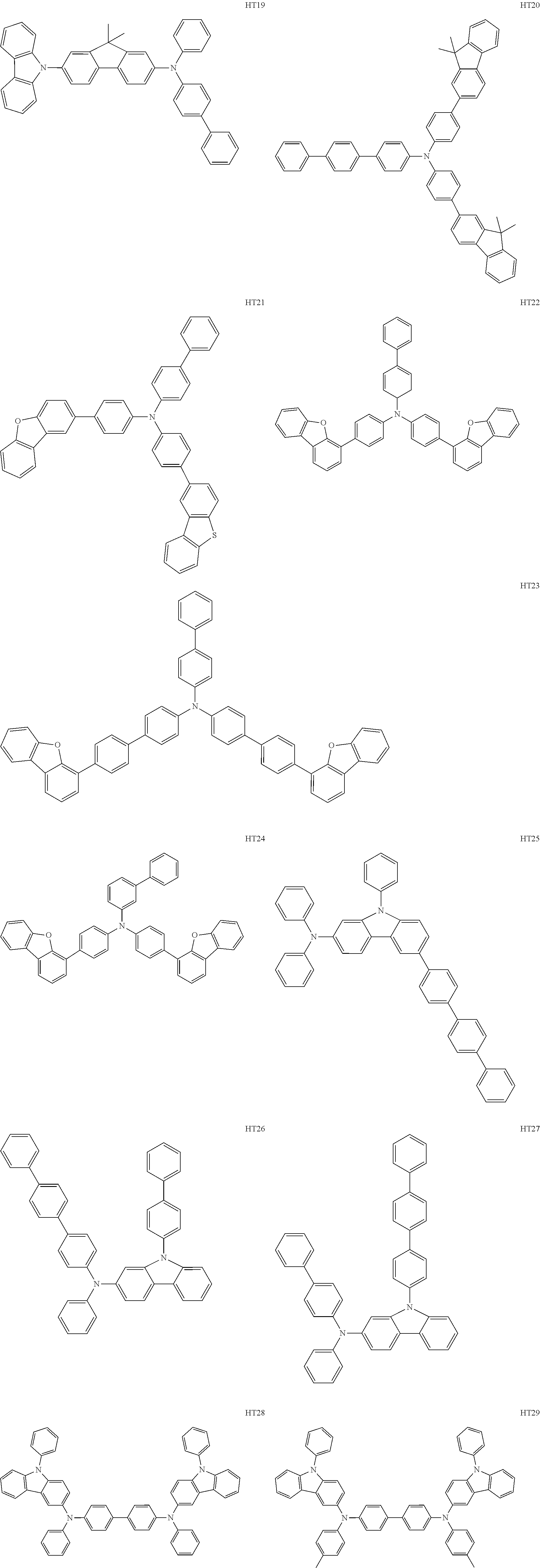

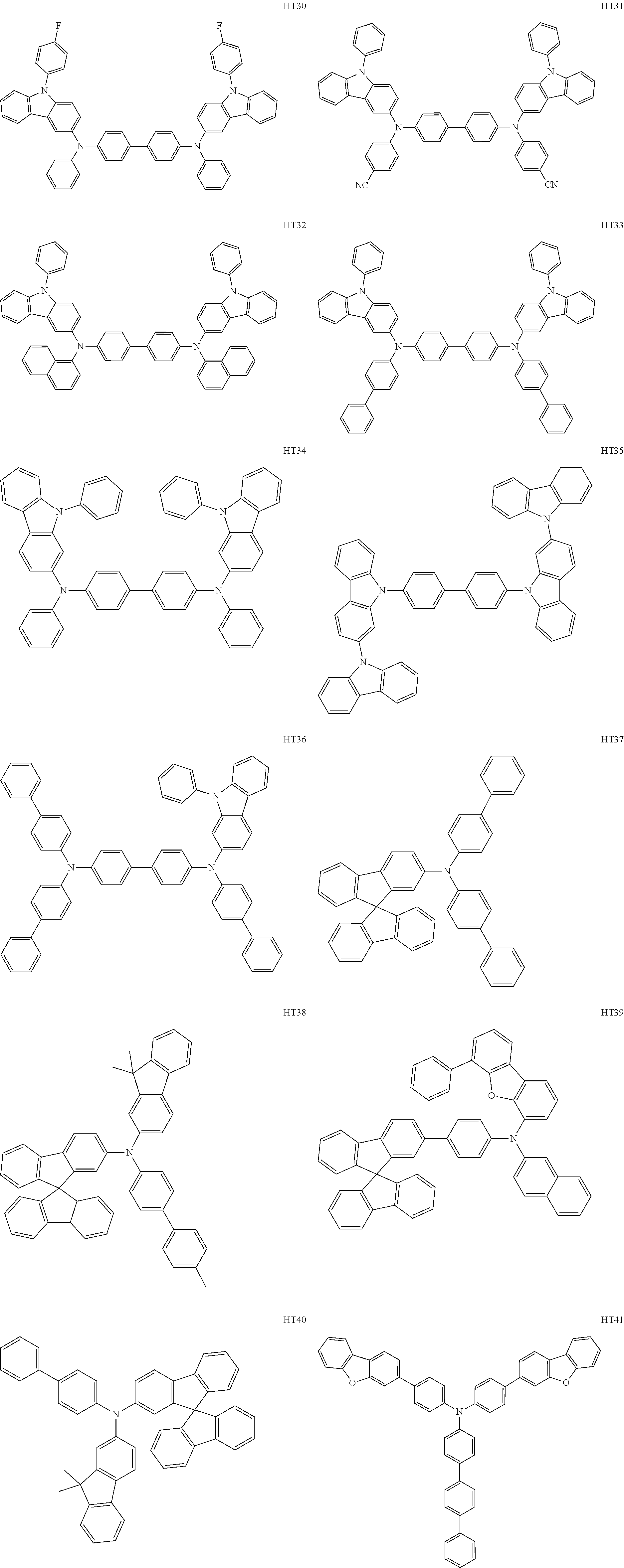

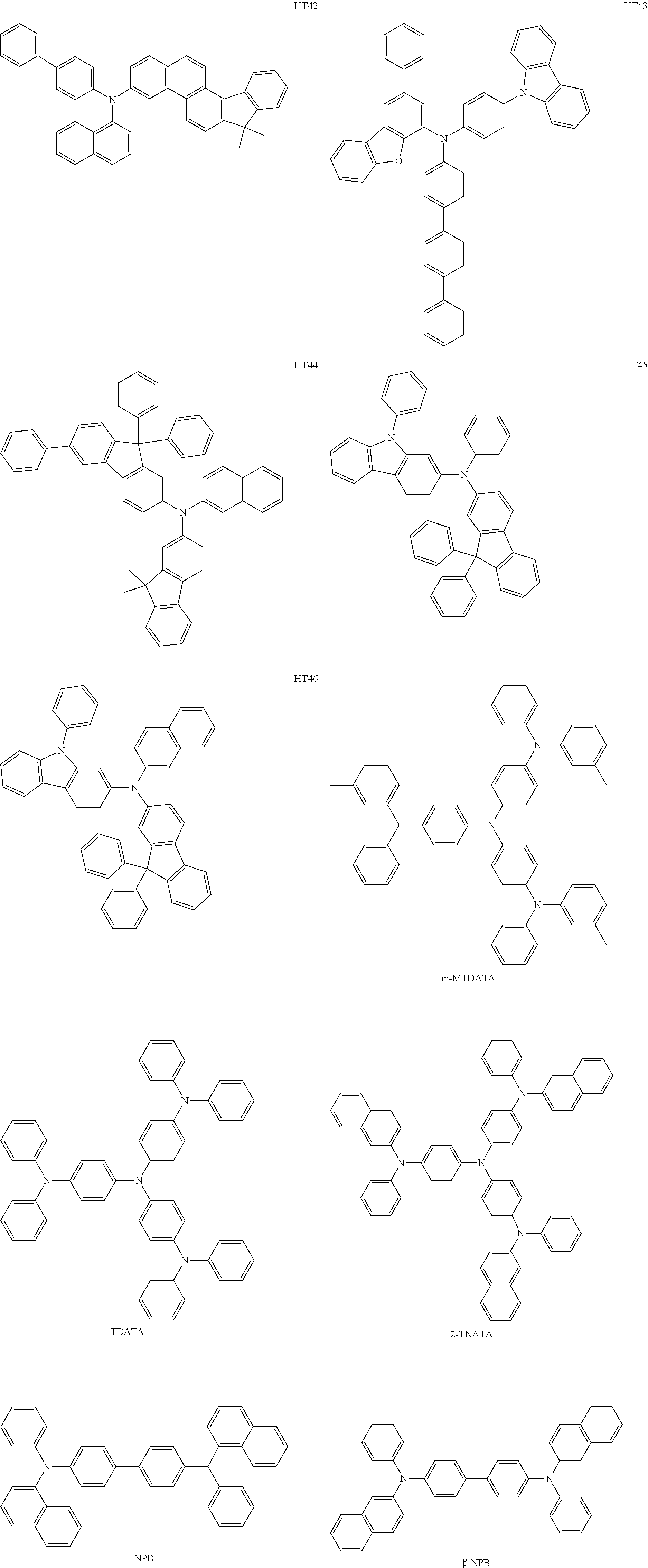

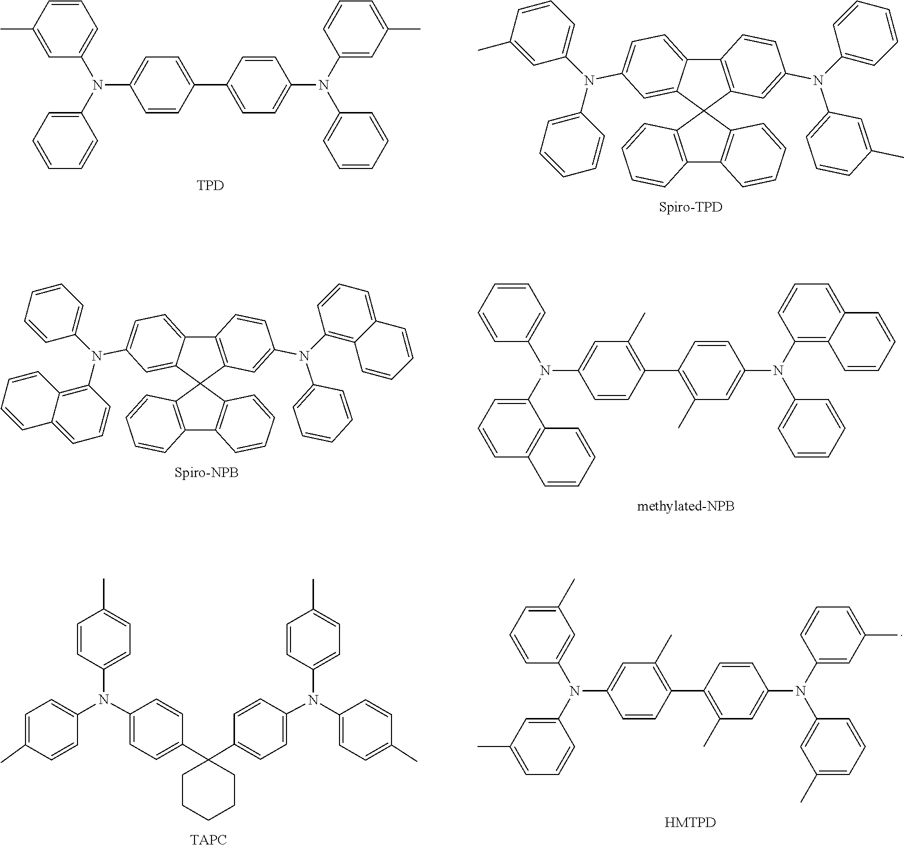

A thickness of the hole transport region may be in a range of about 50 Å to about 10,000 Å. For example, the thickness of the hole transport region may be in a range of about 100 Å to about 4,000 Å. When the hole transport region includes a hole transport layer, an electron blocking layer, or any combination thereof, a thickness of the hole transport layer may be in a range of about 50 Å to about 2,000 Å. For example, the thickness of the hole transport layer may be in a range of about 100 Å to about 1,500 Å. When the thicknesses of the hole transport region and the hole transport layer are within the ranges described above, satisfactory hole transporting characteristics may be obtained without a substantial increase in driving voltage.

The emission auxiliary layer may increase light-emission efficiency by compensating for an optical resonance distance of a wavelength of light emitted by an emission layer, and the electron blocking layer may block the leakage of electrons from an emission layer to a hole transport region. Materials that may be included in the hole transport region may be included in the emission auxiliary layer and the electron blocking layer.

[p-Dopant]

The hole transport region may further include, in addition to these materials, a charge-generation material for the improvement of conductive properties. The charge-generation material may be uniformly or non-uniformly dispersed in the hole transport region (for example, in the form of a single layer consisting of a charge-generation material).

The charge-generation material may be, for example, a p-dopant.

In an embodiment, a lowest unoccupied molecular orbital (LUMO) energy level of the p-dopant may be less than or equal to about −3.5 eV.

In an embodiment, the p-dopant may include a quinone derivative, a cyano group-containing compound, a compound including an element EL1 and an element EL2, or any combination thereof.

Examples of a quinone derivative may include TCNQ, F4-TCNQ, and the like.

Examples of a cyano group-containing compound may include HAT-CN and a compound represented by Formula 221:

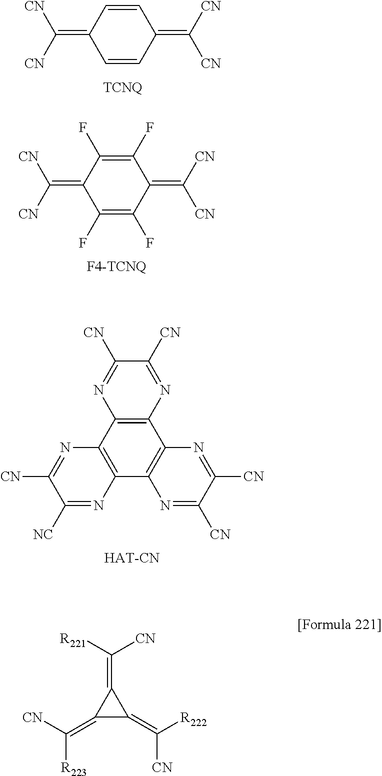

In Formula 221,
R₂₂₁ to R₂₂₃ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound containing an element EL1 and an element EL2, element EL1 may be a metal, a metalloid, or a combination thereof, and element EL2 may be a non-metal, a metalloid, or a combination thereof.

Examples of a metal may include: an alkali metal (for example, lithium (Li), sodium (Na), potassium (K), rubidium (Rb), cesium (Cs), etc.); an alkaline earth metal (for example, beryllium (Be), magnesium (Mg), calcium (Ca), strontium (Sr), barium (Ba), etc.); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (for example, zinc (Zn), indium (In), tin (Sn), etc.); and a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.).

Examples of a metalloid may include silicon (Si), antimony (Sb), and tellurium (Te).

Examples of a non-metal may include oxygen (O) and a halogen (for example, F, Cl, Br, I, etc.).

In an embodiment, examples of a compound containing the element EL1 and the element EL2 may include a metal oxide, a metal halide (for example, a metal fluoride, a metal chloride, a metal bromide, or a metal iodide), a metalloid halide (for example, a metalloid fluoride, a metalloid chloride, a metalloid bromide, or a metalloid iodide), a metal telluride, or any combination thereof.

Examples of a metal oxide may include a tungsten oxide (for example, WO, W₂O₃, WO₂, WO₃, W₂O₅, etc.), a vanadium oxide (for example, VO, V₂O₃, VO₂, V₂O₅, etc.), a molybdenum oxide (MoO, Mo₂O₃, MoO₂, MoO₃, Mo₂O₅, etc.), and a rhenium oxide (for example, ReOs, etc.).

Examples of a metal halide may include an alkali metal halide, an alkaline earth metal halide, a transition metal halide, a post-transition metal halide, and a lanthanide metal halide.

Examples of an alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, and CsI.

Examples of an alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, and BaI₂.

Examples of a transition metal halide may include a titanium halide (for example, TiF₄, TiCl₄, TiBr₄, TiI₄, etc.), a zirconium halide (for example, ZrF₄, ZrCl₄, ZrBr₄, ZrI₄, etc.), a hafnium halide (for example, HfF₄, HfCl₄, HfBr₄, HfI₄, etc.), a vanadium halide (for example, VF₃, VCl₃, VBr₃, VI₃, etc.), a niobium halide (for example, NbF₃, NbCl₃, NbBr₃, NbI₃, etc.), a tantalum halide (for example, TaF₃, TaCl₃, TaBr₃, TaI₃, etc.), a chromium halide (for example, CrF₃, CrCl₃, CrBr₃, CrI₃, etc.), a molybdenum halide (for example, MoF₃, MoCl₃, MoBr₃, MoI₃, etc.), a tungsten halide (for example, WF₃, WCl₃, WBr₃, WI₃, etc.), a manganese halide (for example, MnF₂, MnCl₂, MnBr₂, MnI₂, etc.), a technetium halide (for example, TcF₂, TcCl₂, TcBr₂, Tcl₂, etc.), a rhenium halide (for example, ReF₂, ReCl₂, ReBr₂, ReI₂, etc.), an iron halide (for example, FeF₂, FeCl₂, FeBr₂, FeI₂, etc.), a ruthenium halide (for example, RuF₂, RuCl₂, RuBr₂, RuI₂, etc.), an osmium halide (for example, OsF₂, OsCl₂, OsBr₂, OsI₂, etc.), a cobalt halide (for example, CoF₂, CoCl₂, CoBr₂, Col₂, etc.), a rhodium halide (for example, RhF₂, RhCl₂, RhBr₂, RhI₂, etc.), an iridium halide (for example, IrF₂, IrCl₂, IrBr₂, IrI₂, etc.), a nickel halide (for example, NiF₂, NiCl₂, NiBr₂, NiI₂, etc.), a palladium halide (for example, PdF₂, PdCl₂, PdBr₂, PdI₂, etc.), a platinum halide (for example, PtF₂, PtCl₂, PtBr₂, PtI₂, etc.), a copper halide (for example, CuF, CuCl, CuBr, CuI, etc.), a silver halide (for example, AgF, AgCl, AgBr, AgI, etc.), and a gold halide (for example, AuF, AuCl, AuBr, AuI, etc.).

Examples of a post-transition metal halide may include a zinc halide (for example, ZnF₂, ZnCl₂, ZnBr₂, ZnI₂, etc.), an indium halide (for example, InI₃, etc.), and a tin halide (for example, SnI₂, etc.).

Examples of a lanthanide metal halide may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, and SmI₃.

Examples of a metalloid halide may include an antimony halide (for example, SbCl₅, etc.).

Examples of a metal telluride may include an alkali metal telluride (for example, Li₂Te, Na₂Te, K₂Te, Rb₂Te, Cs₂Te, etc.), an alkaline earth metal telluride (for example, BeTe, MgTe, CaTe, SrTe, BaTe, etc.), a transition metal telluride (for example, TiTe₂, ZrTe₂, HfTe₂, V₂Te₃, Nb₂Te₃, Ta₂Tes, Cr₂Te₃, MozTe₃, W₂Te₃, MnTe, TcTe, ReTe, FeTe, RuTe, OsTe, CoTe, RhTe, IrTe, NiTe, PdTe, PtTe, CuzTe, CuTe, Ag₂Te, AgTe, Au₂Te, etc.), a post-transition metal telluride (for example, ZnTe, etc.), and a lanthanide metal telluride (for example, LaTe, CeTe, PrTe, NdTe, PmTe, EuTe, GdTe, TbTe, DyTe, HoTe, ErTe, TmTe, YbTe, LuTe, etc.).

### [Emission Layer in Interlayer 130]

When the light-emitting device 10 is a full-color light-emitting device, the emission layer may be patterned into a red emission layer, a green emission layer, and/or a blue emission layer, according to a subpixel. In an embodiment, the emission layer may have a stacked structure of two or more layers of a red emission layer, a green emission layer, and a blue emission layer, in which the two or more layers may contact each other or may be separated from each other. In an embodiment, the emission layer may include two or more materials of a red light-emitting material, a green light-emitting material, and a blue light-emitting material, in which the two or more materials may be mixed with each other in a single layer to emit white light.

The emission layer may include a first emission layer and a second emission layer. The first emission layer and the second emission layer may each independently include a host and a dopant.

An amount of the dopant in the emission layer may be in a range of about 0.01 wt % to about 15 wt %, based on 100 wt % of the host.

A thickness of the emission layer may be in a range of about 100 Å to about 1,000 Å. For example, the thickness of the emission layer may be in a range of about 200 Å to about 600 Å. For example, the first emission layer and the second emission layer may each independently have a thickness in a range of about 50 Å to about 500 Å. When the thickness of the emission layer is within any of these ranges, excellent light-emission characteristics may be obtained without a substantial increase in driving voltage.

### [Host]

The host may include a compound represented by Formula 301:

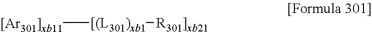

In Formula 301,
Ar₃₀₁ and L₃₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₃₀₁) (Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(—O)(Q₃₀₁)(Q₃₀₂),
xb21 may be an integer from 1 to 5, and
Q₃₀₁ to Q₃₀₃ may each independently be the same as described in connection with Q₁.

In an embodiment, in Formula 301, when xb11 is 2 or more, two or more Ar₃₀₁(s) may be linked together via a single bond.

In an embodiment, the host may include a compound represented by Formula 301-1, a compound represented by Formula 301-2, or any combination thereof:

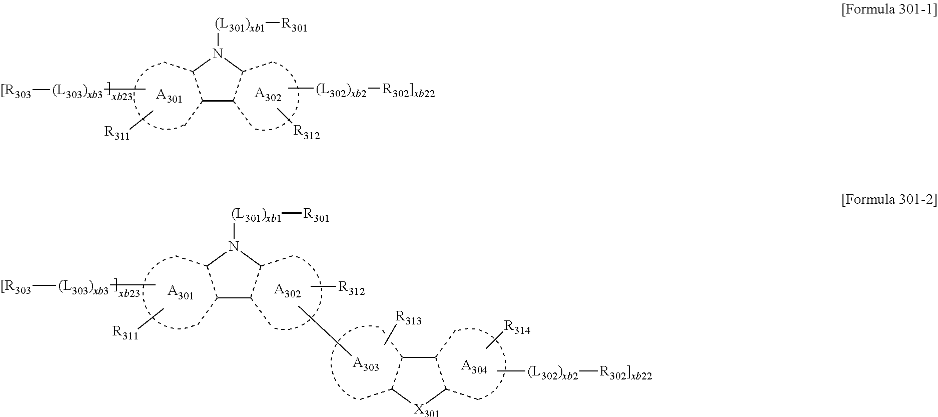

In Formulae 301-1 and 301-2,
rings A₃₀₁ to A₃₀₄ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
X₃₀₁ may be O, S, N-[(L₃₀₄)ₓ₆₄-R₃₀₄], C(R₃₀₄)(R₃₀₅), or Si(R₃₀₄)(R₃₀₅),
xb22 and xb23 may each independently be 0, 1, or 2, L₃₀₁, xb1, and R₃₀₁ may each be the same as described in the specification,
L₃₀₂ to L₃₀₄ may each independently be the same as described in connection with L₃₀₁,
xb2 to xb4 may each independently be the same as described in connection with xb1, and
R₃₀₂ to R₃₀₅ and R₃₁₁ to R₃₁₄ may each independently be the same as described in connection with R₃₀₁.

In an embodiment, the host may include an alkali earth metal complex, a post-transition metal complex, or a combination thereof. In an embodiment, the host may include a Be complex (for example, Compound H55), an Mg complex, a Zn complex, or a combination thereof.

In an embodiment, the host may include one of Compounds H1 to H128, 9,10-di(2-naphthyl)anthracene (ADN), 2-methyl-9,10-bis(naphthalen-2-yl)anthracene (MADN), 9,10-di(2-naphthyl)-2-t-butyl-anthracene (TBADN), 4,4′-bis(N-carbazolyl)-1,1′-biphenyl (CBP), 1,3-di-9-carbazolylbenzene (mCP), 1,3,5-tri(carbazol-9-yl)benzene (TCP), or any combination thereof:

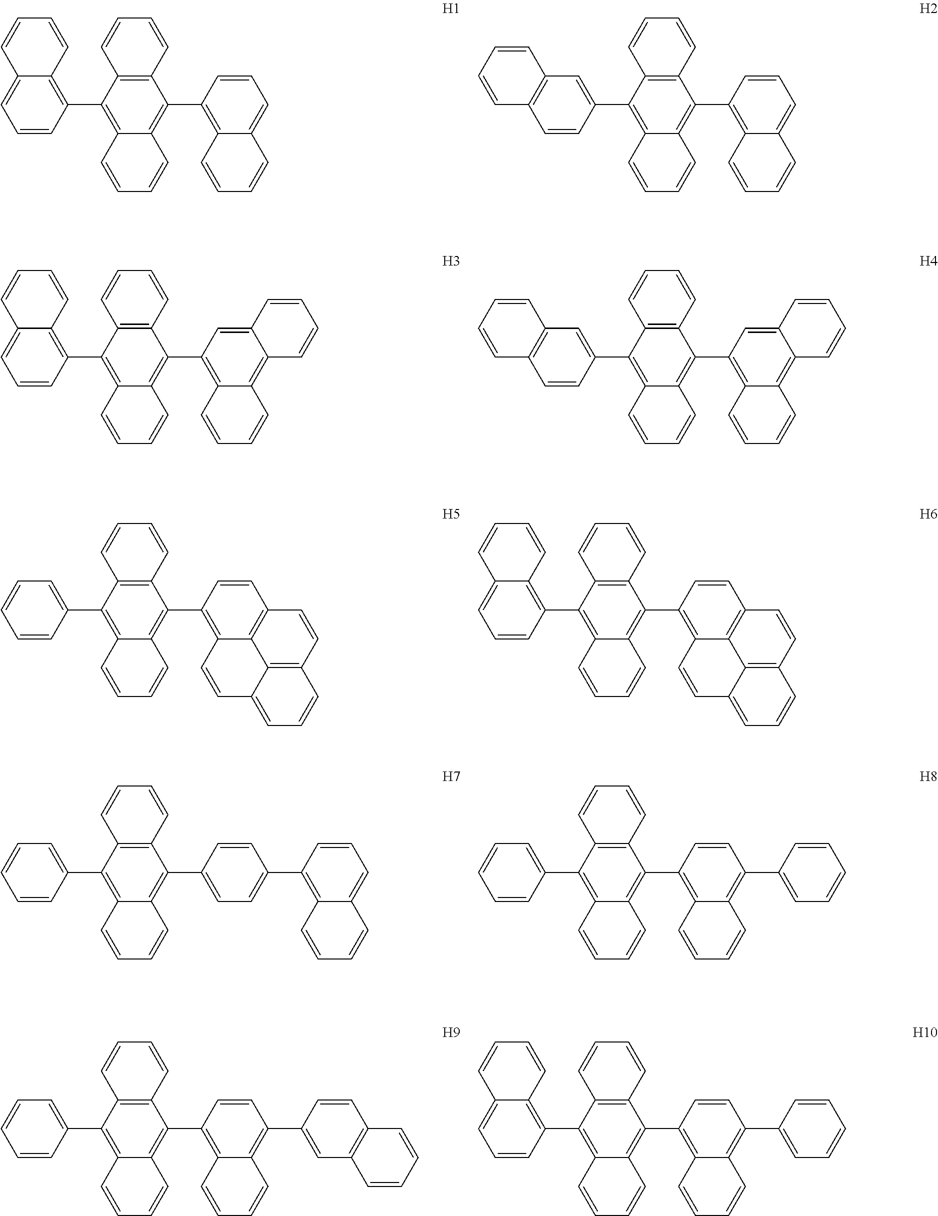

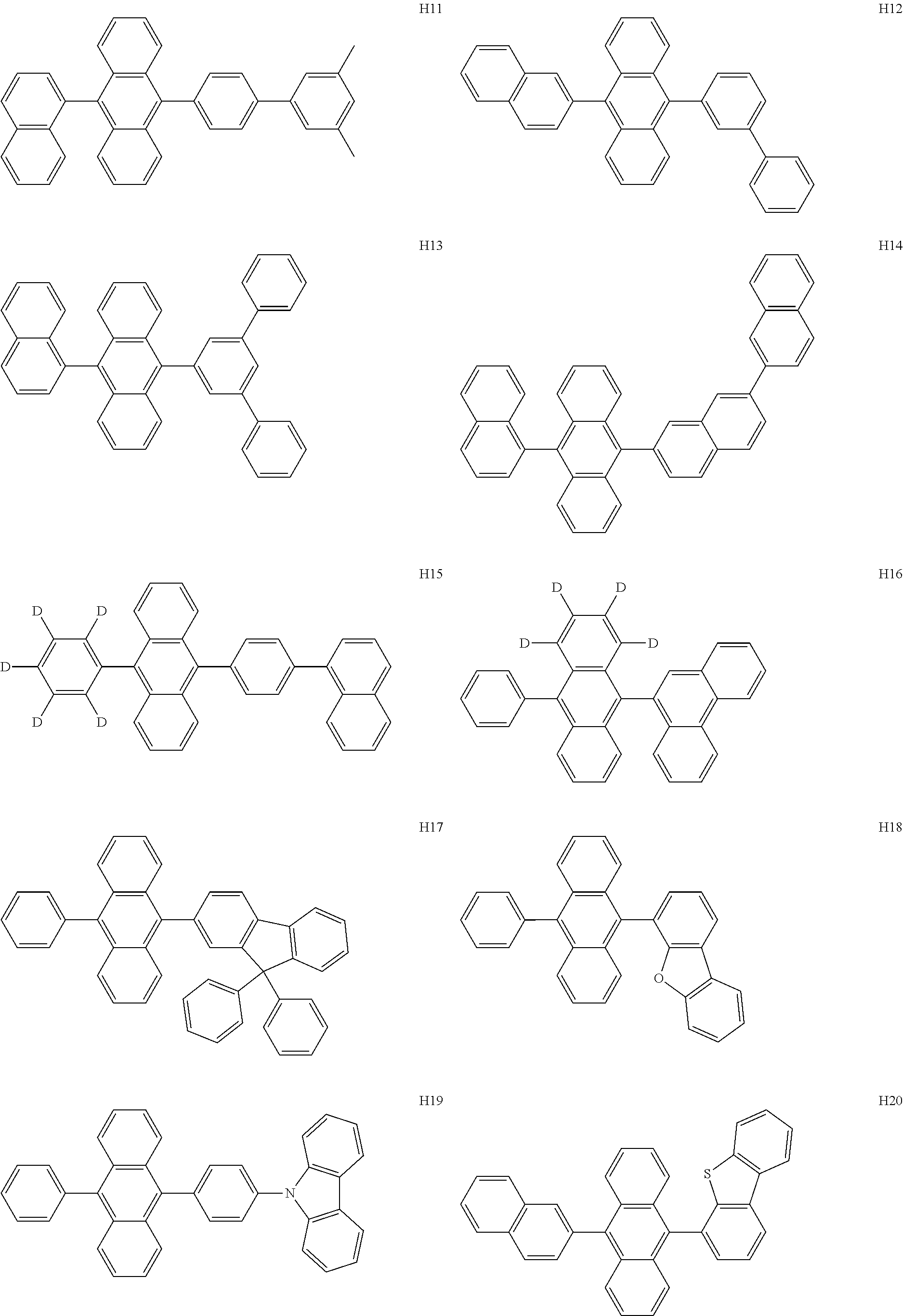

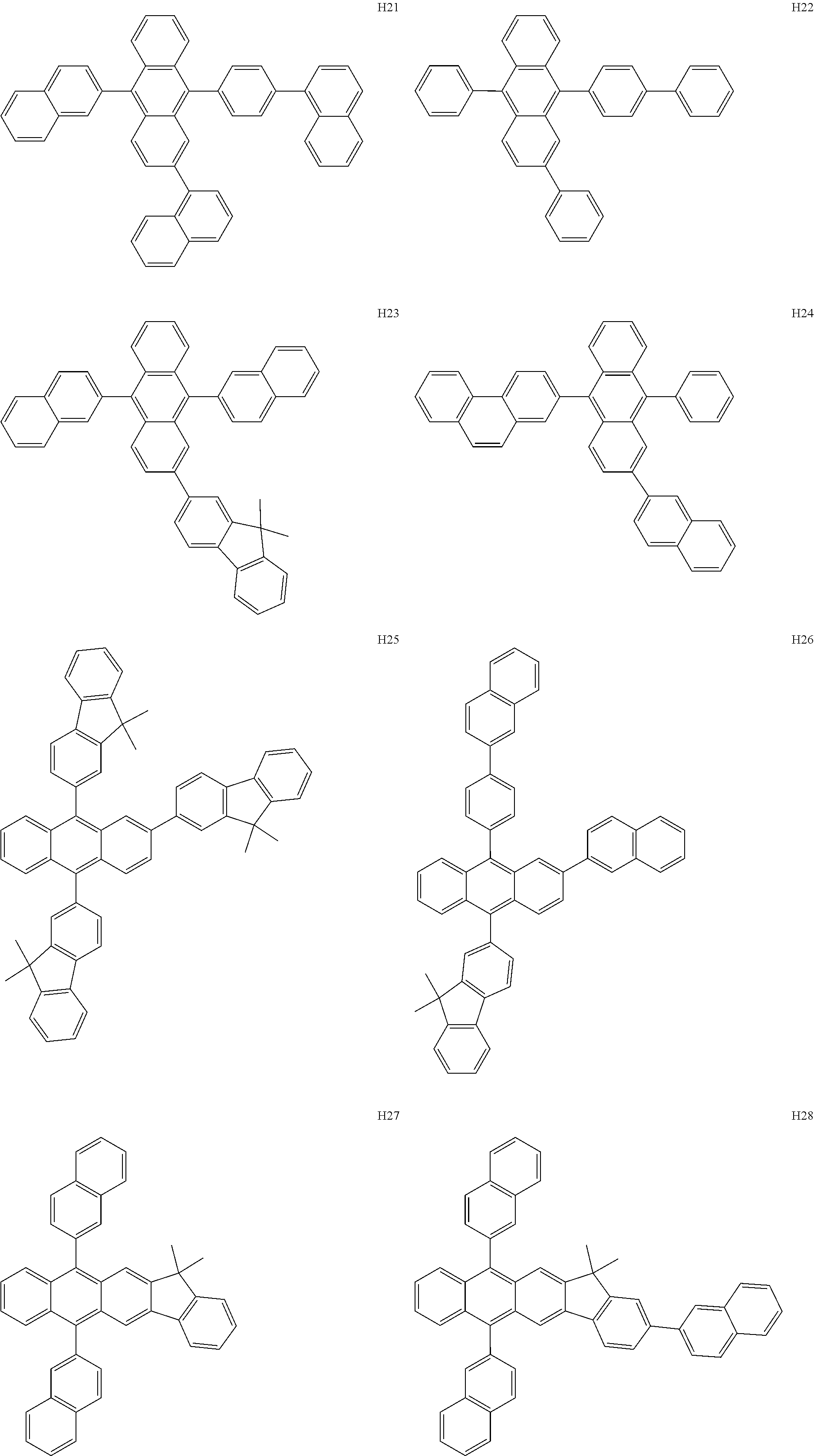

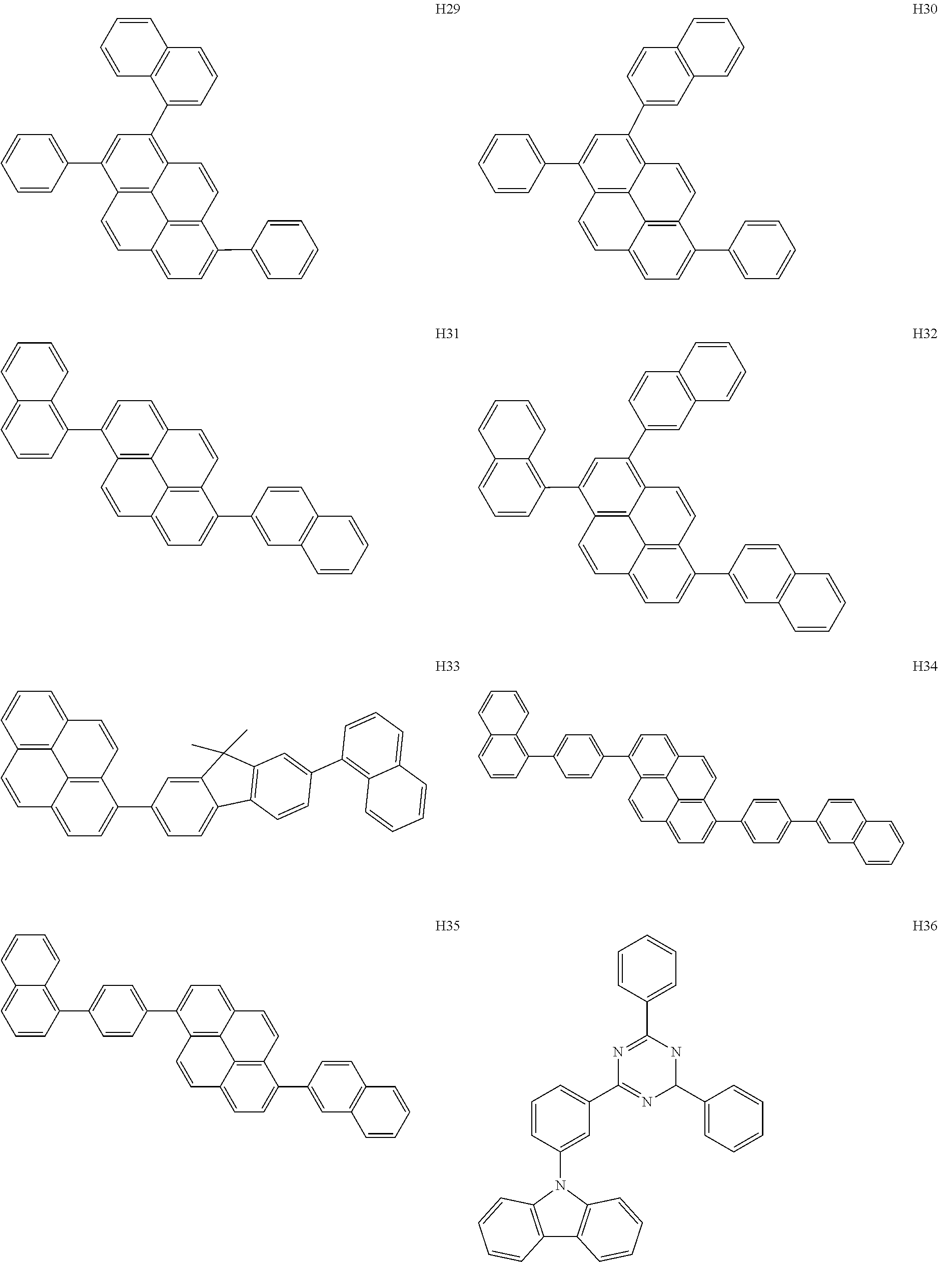

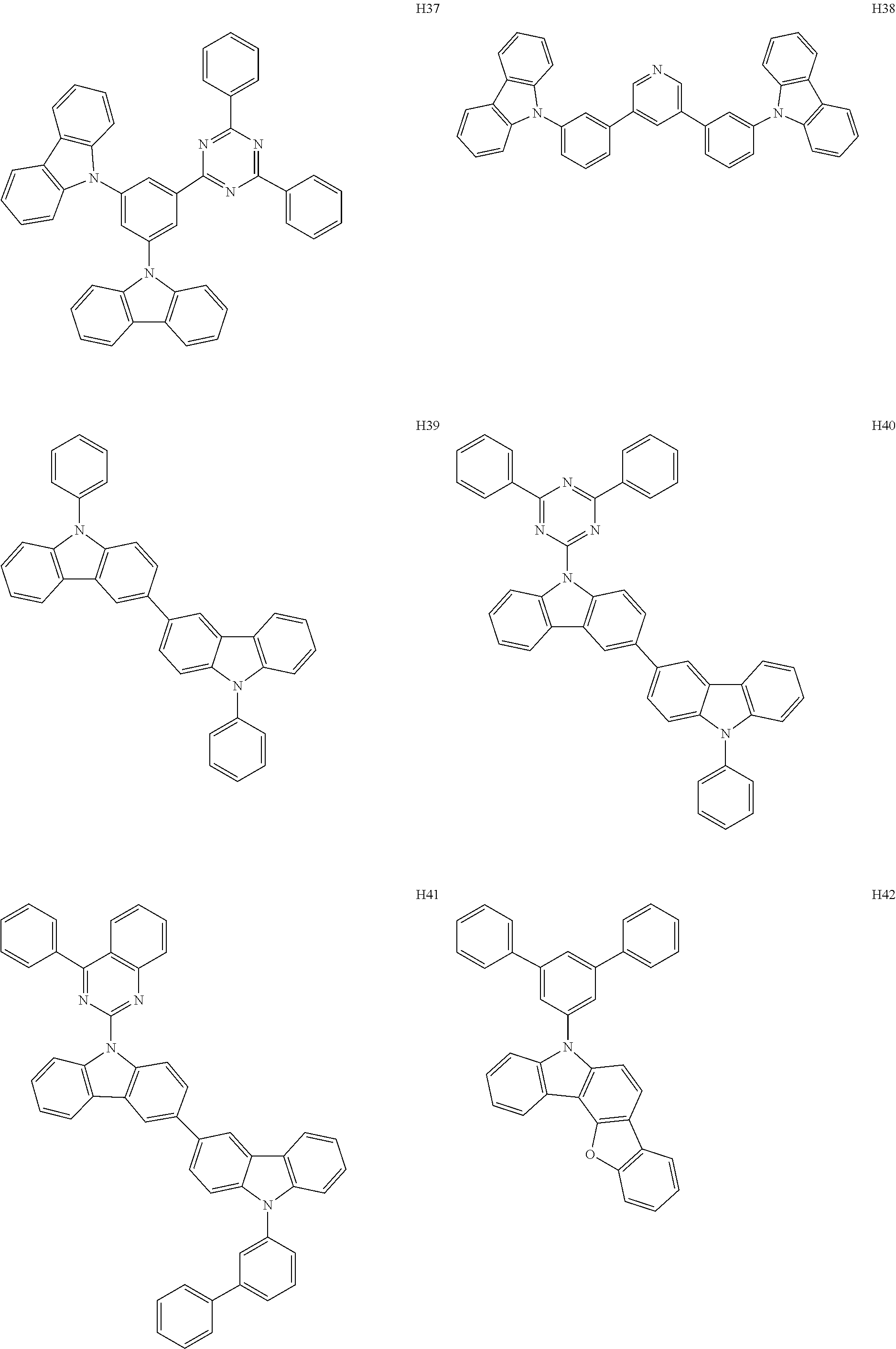 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1]

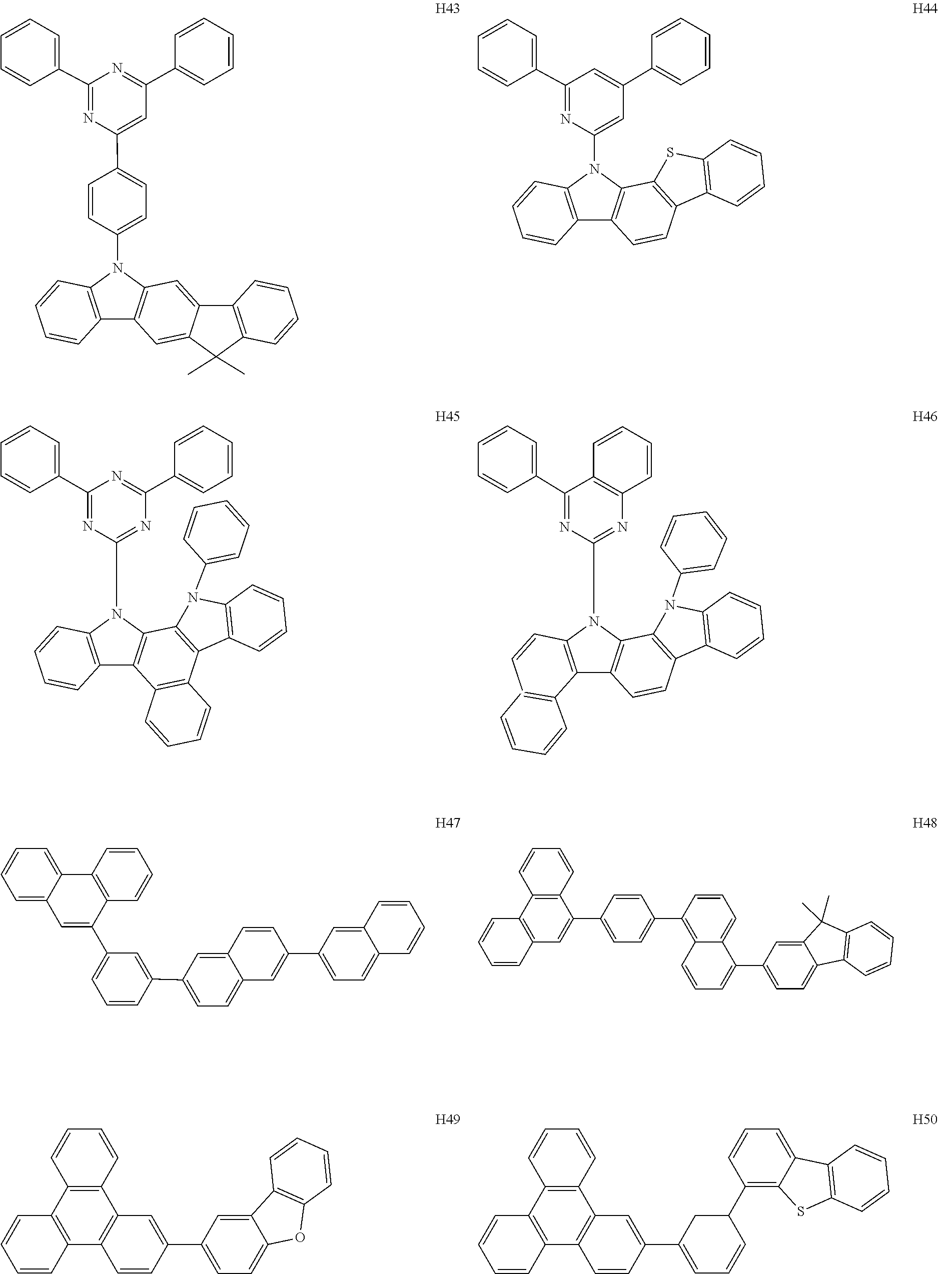

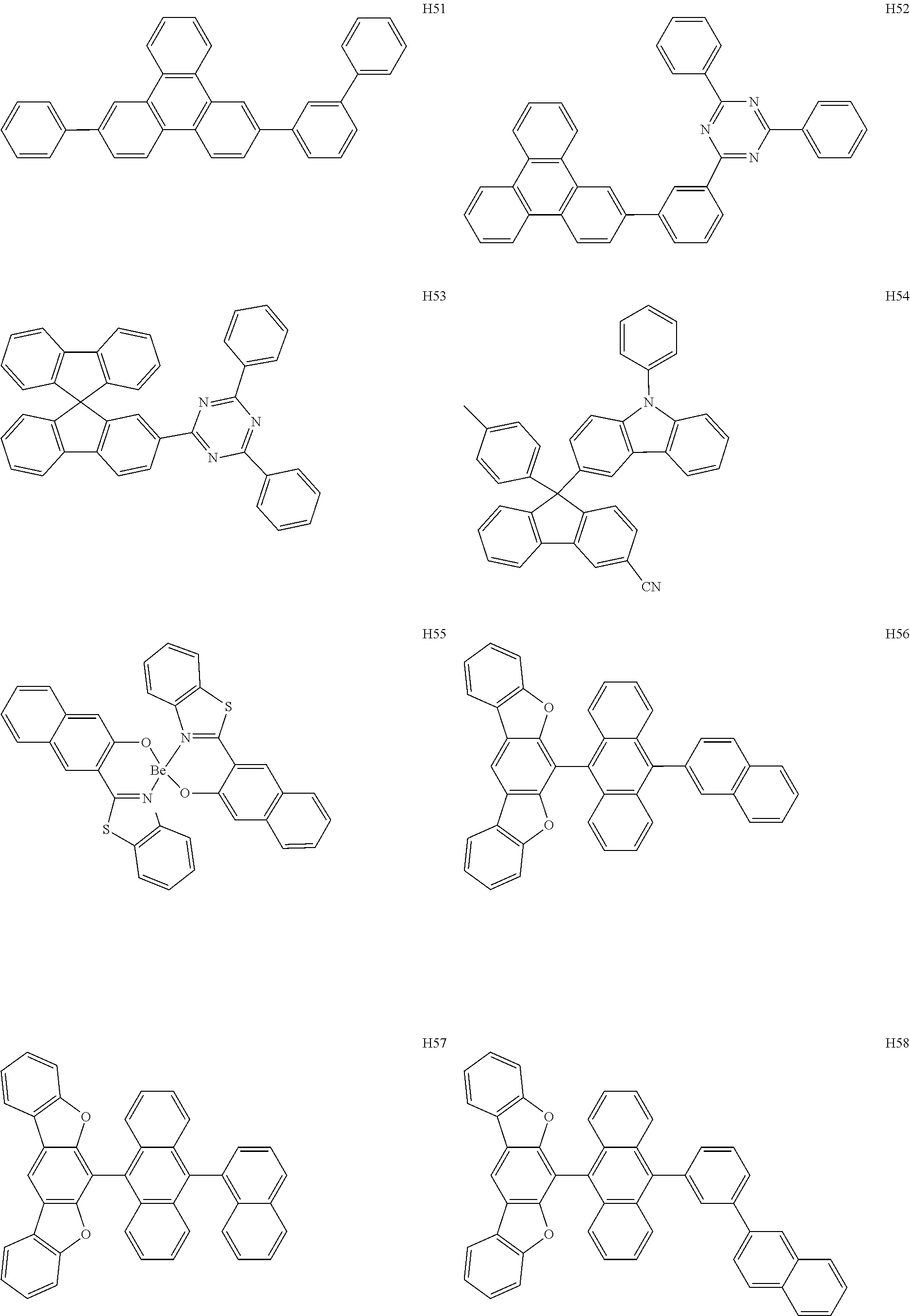

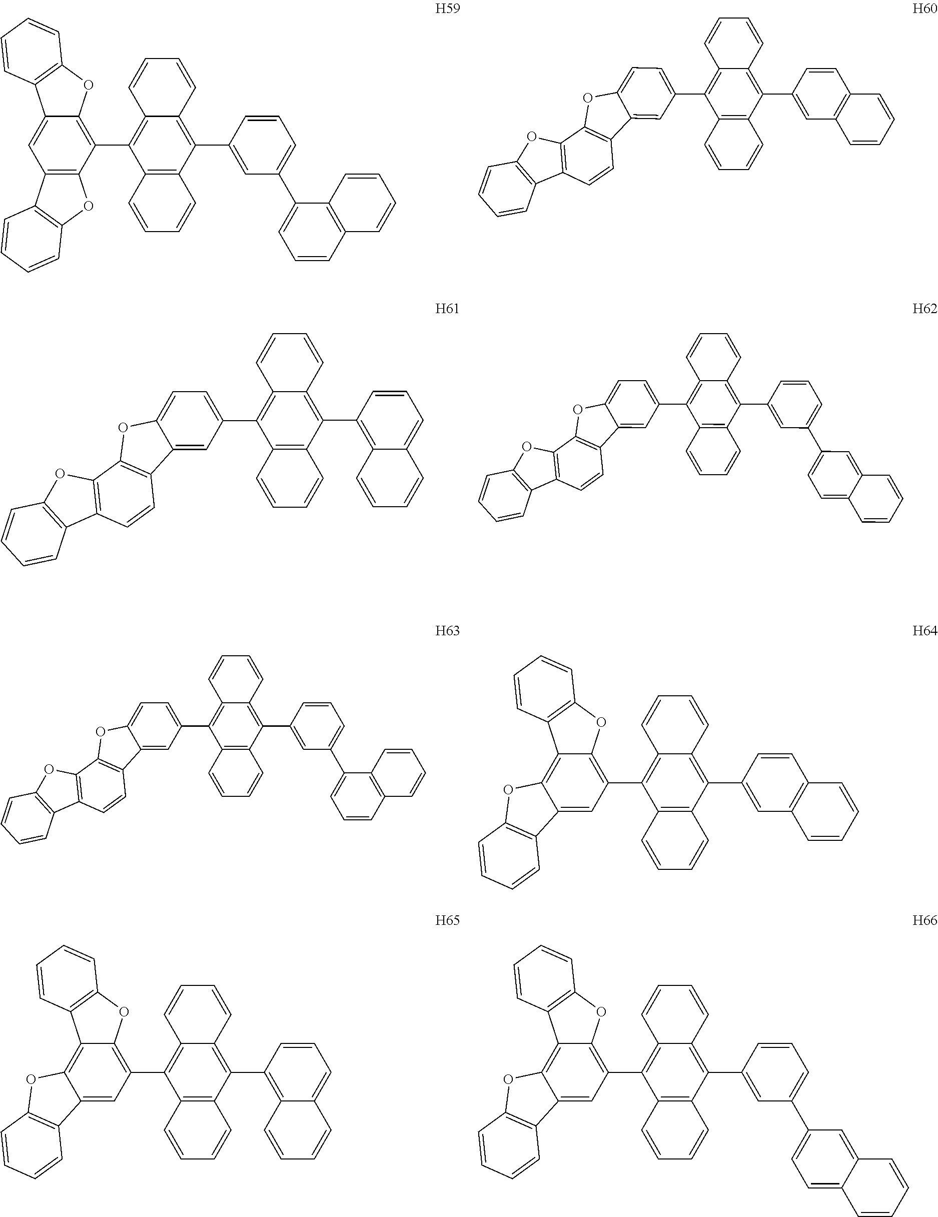

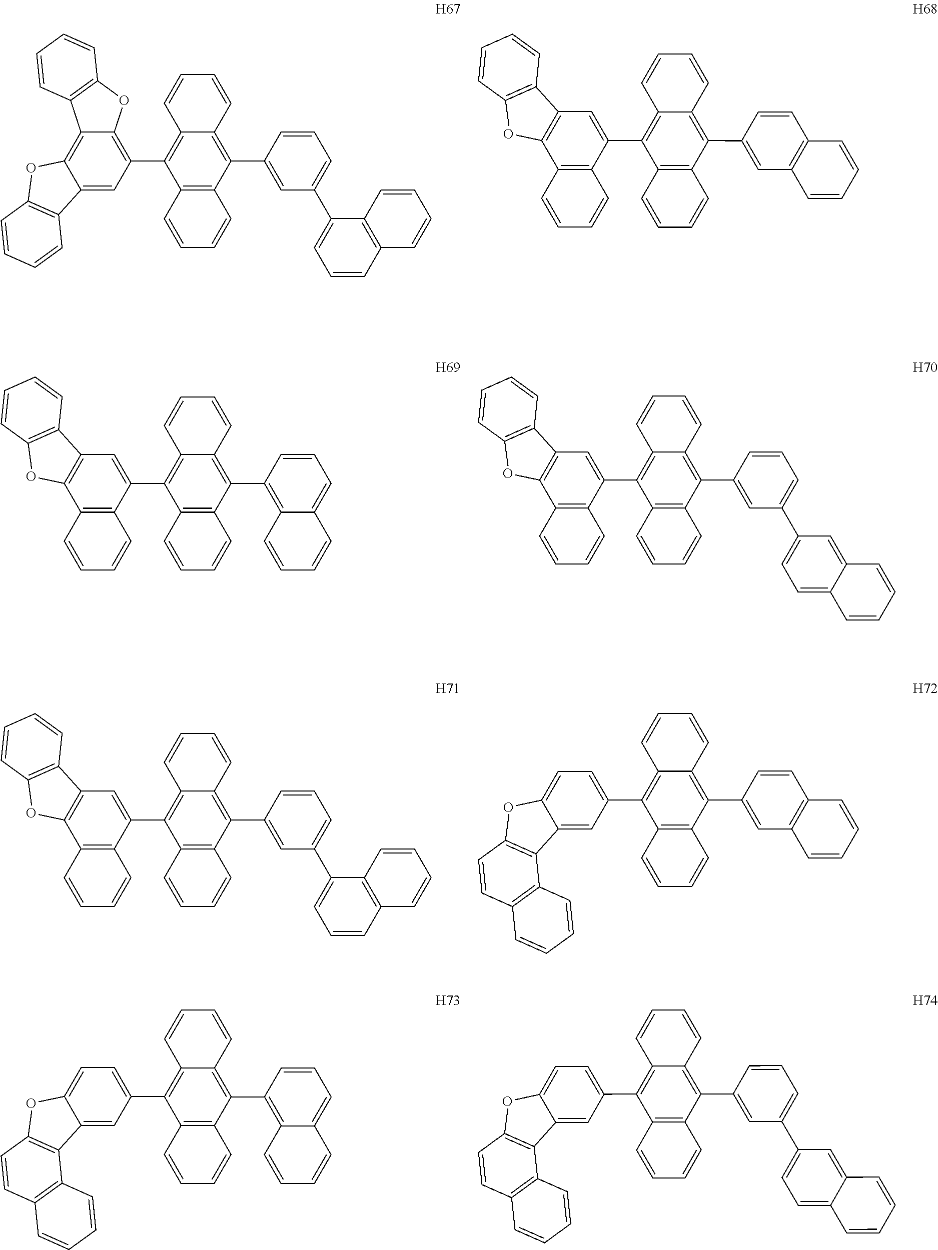

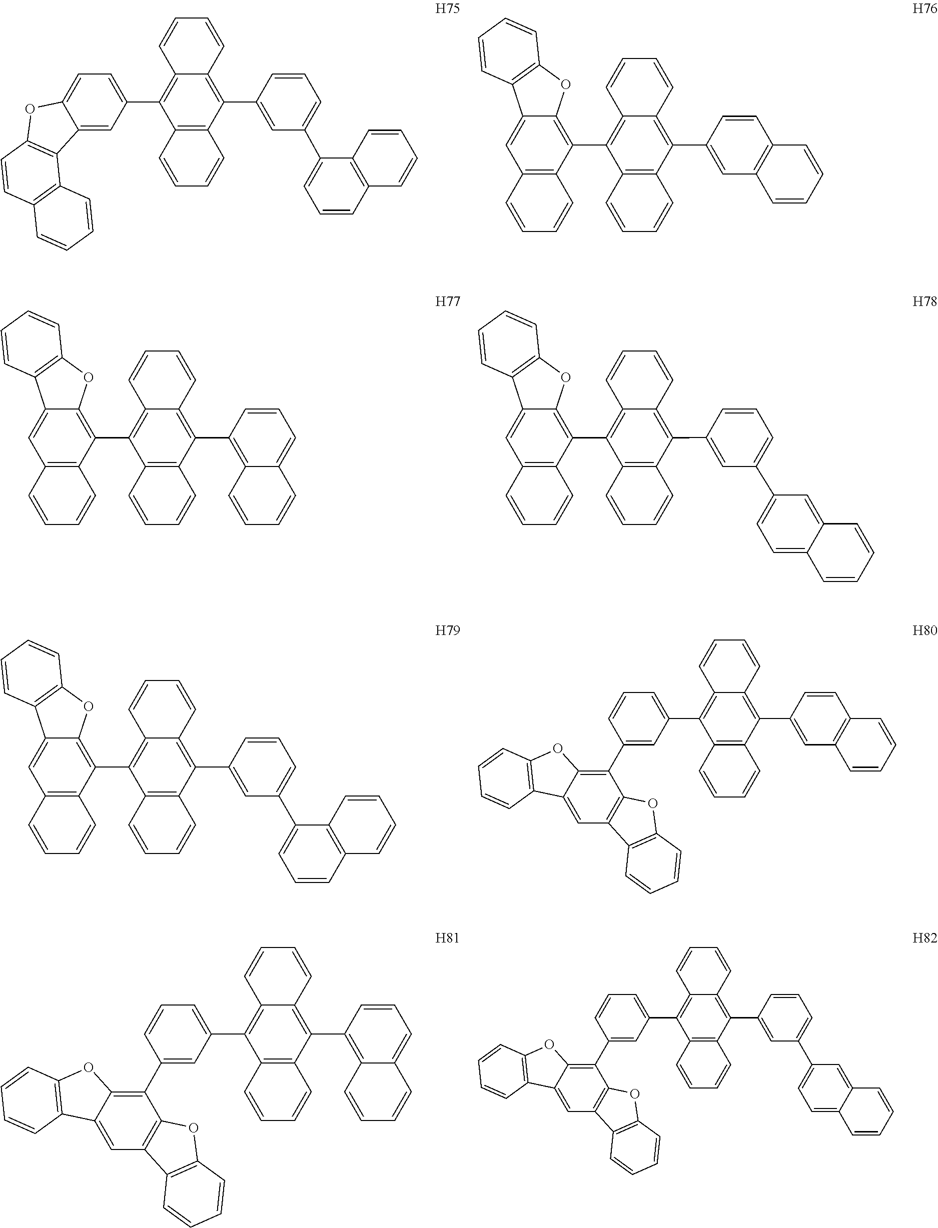

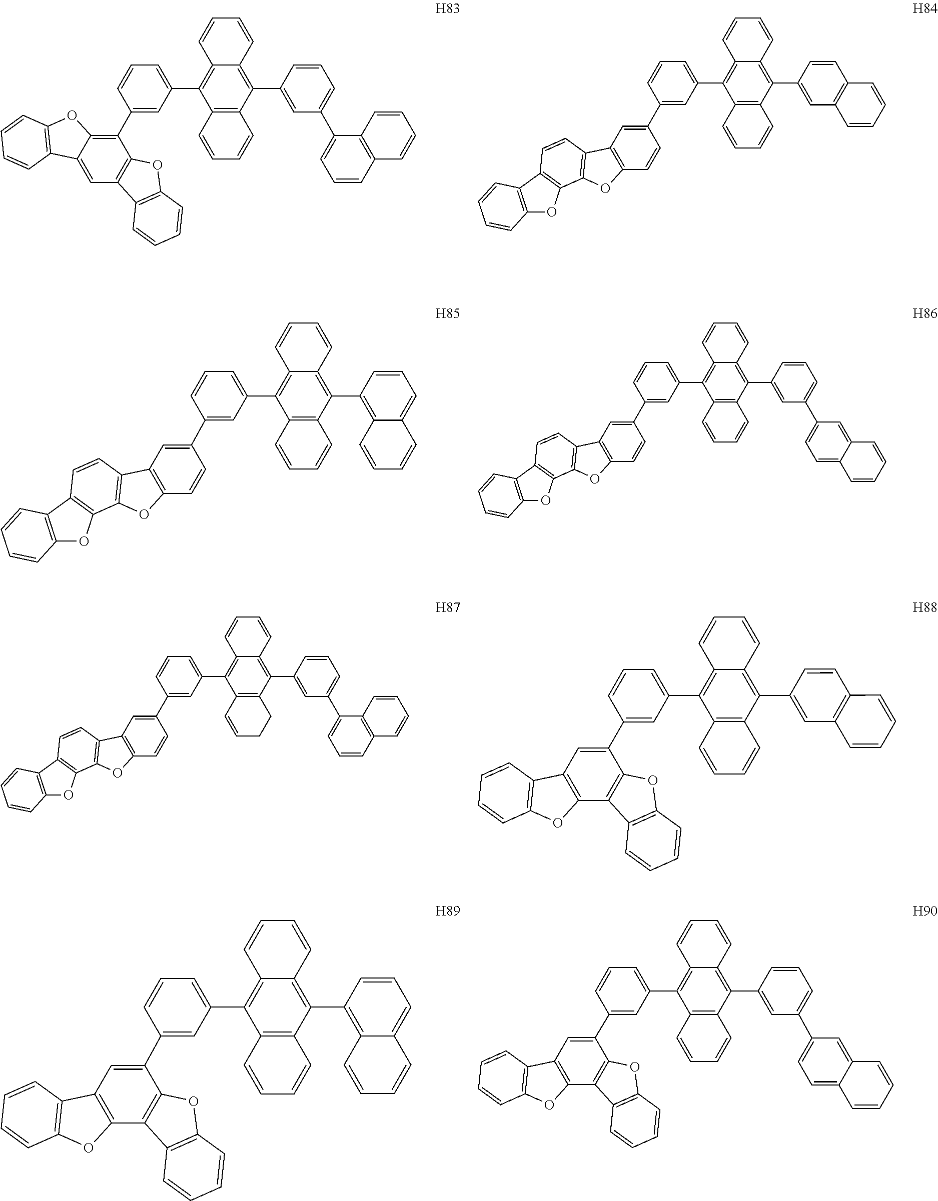

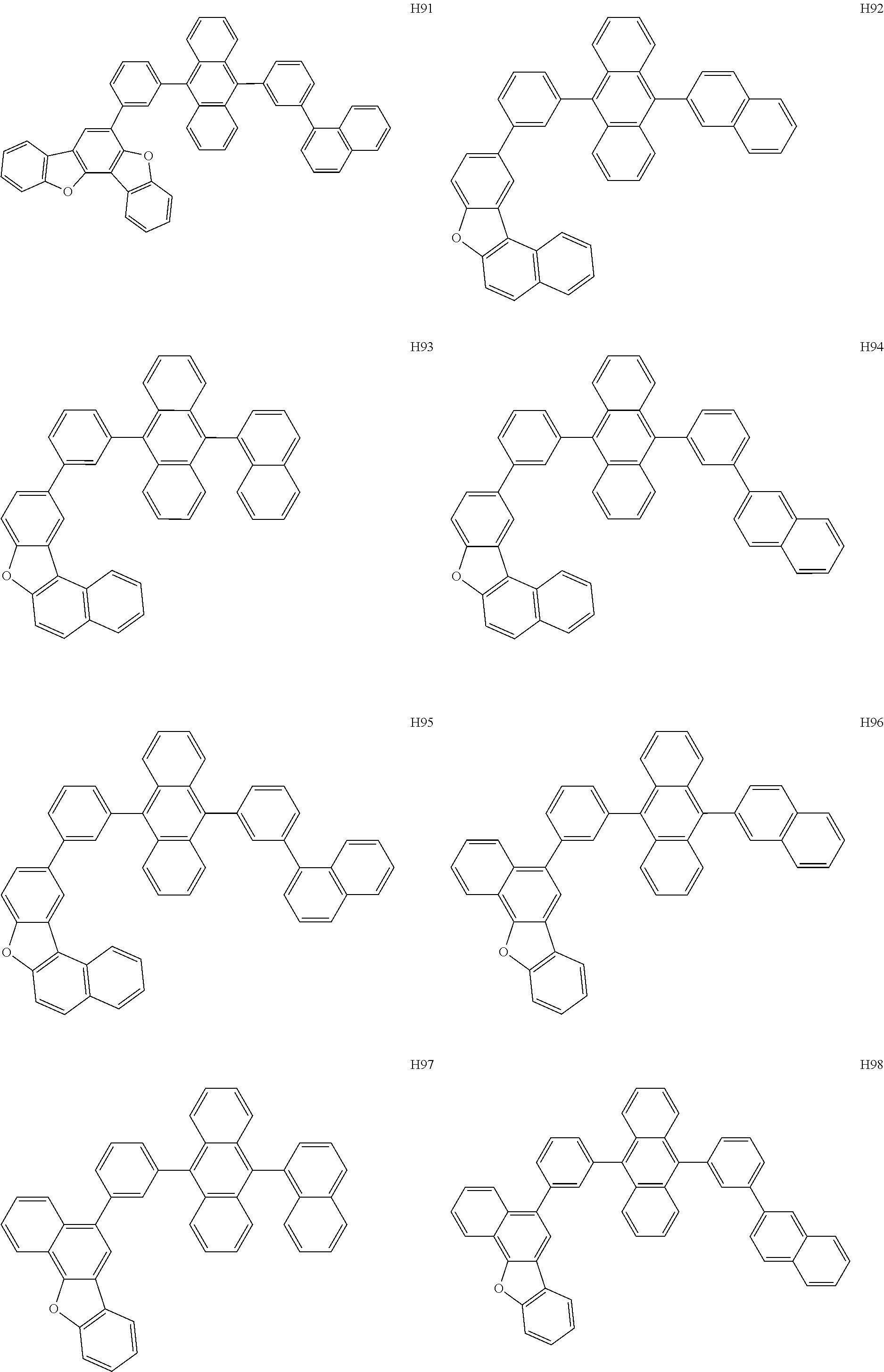

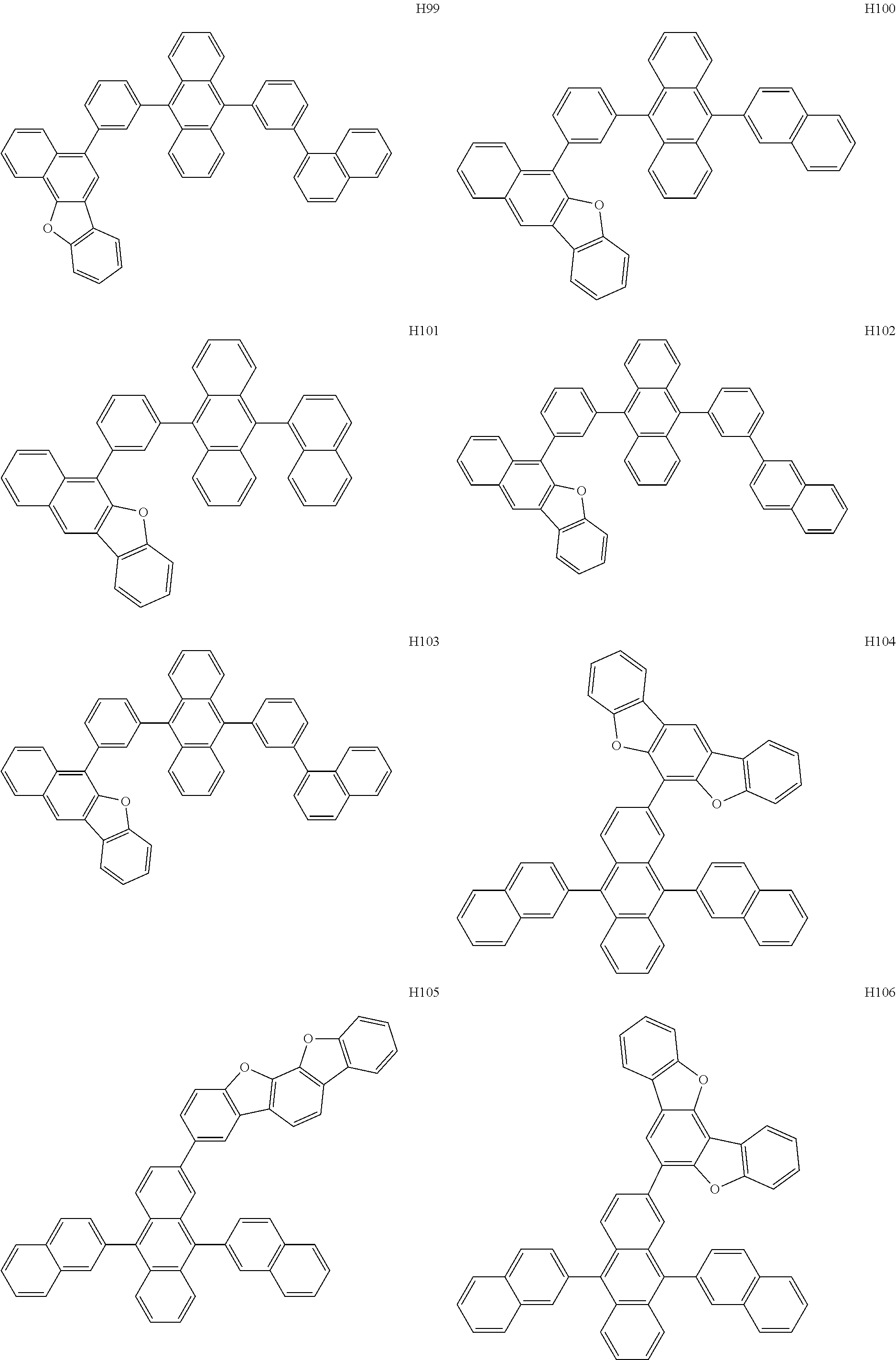

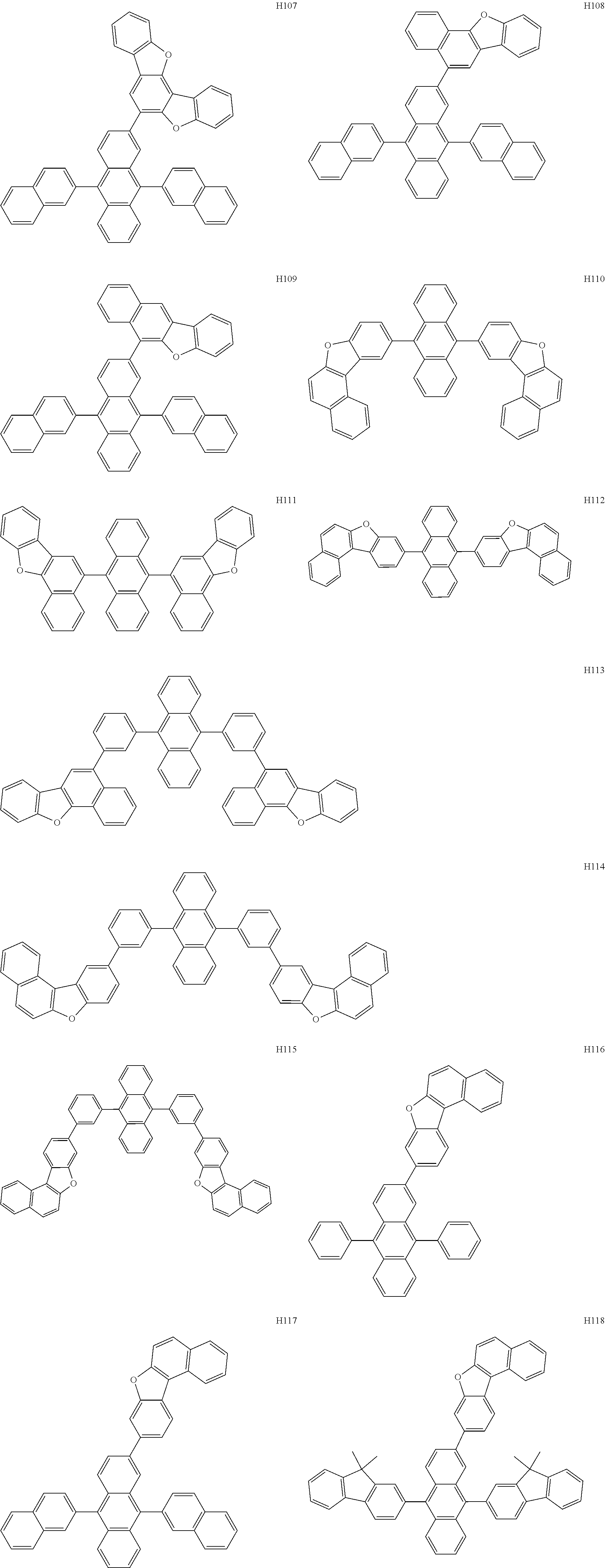

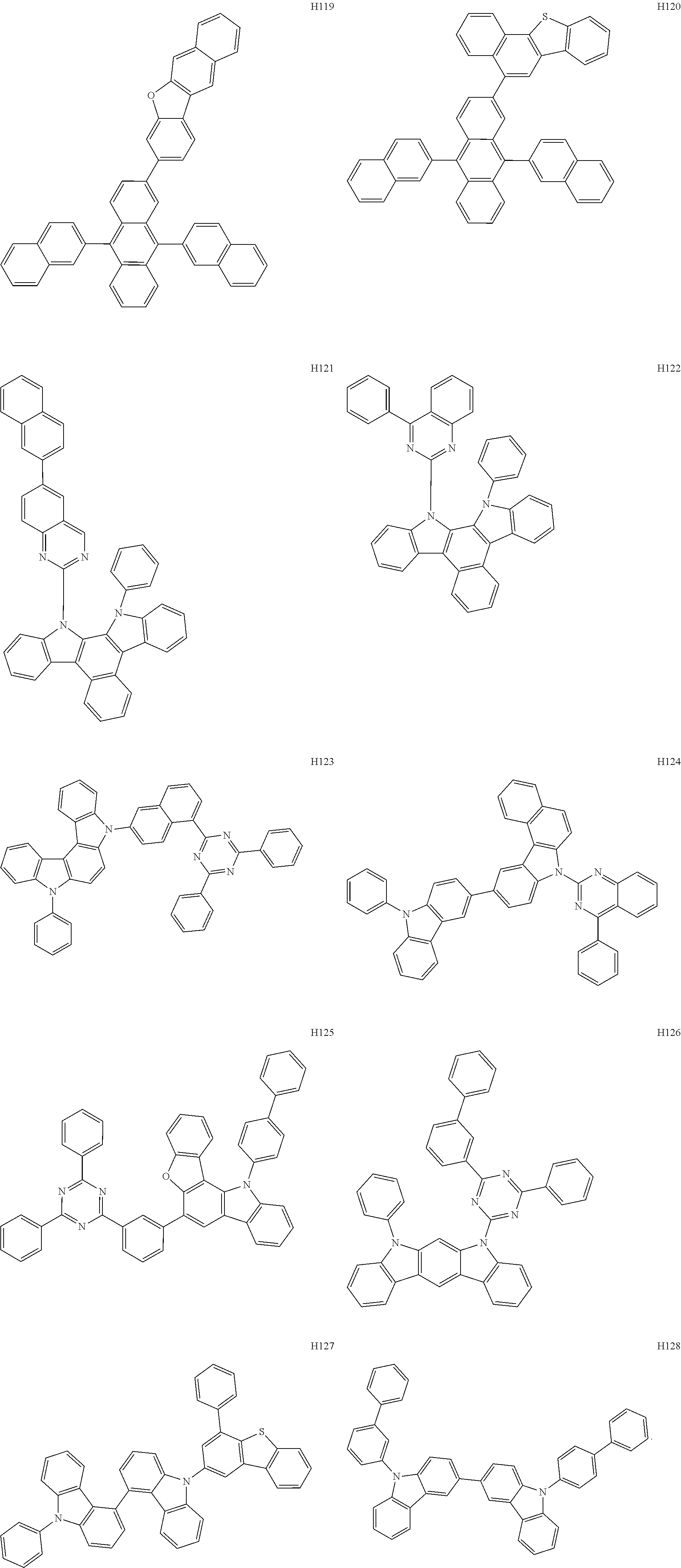

### [Phosphorescent Dopant]

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In an embodiment, the phosphorescent dopant may include an organometallic compound represented by Formula 401:

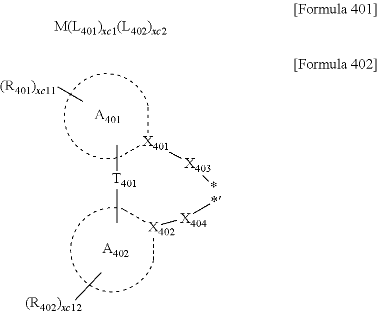

In Formulae 401 and 402,
M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein when xc1 is 2 or more, two or more L₄₀₁(s) may be identical to or different from each other,
L₄₀₂ may be an organic ligand, and xc2 may be 0, 1, 2, 3, or 4, wherein when xc2 is 2 or more, two or more L₄₀₂(s) may be identical to or different from each other,
X₄₀₁ and X₄₀₂ may each independently be nitrogen or carbon,
rings A₄₀₁ and A₄₀₂ may each independently be a C₃-C₆₀ carbocyclic group or a C₁-C₆₀ heterocyclic group,
T₄₀₁ may be a single bond, —O—, —S—, —C(═O)—, —N(Q₄₁₁)-, —C(Q₄₁₁)(Q₄₁₂)-, —C(Q₄₁₁)═C(Q₄₁₂)-, —C(Q₄₁₁)=, or ═C═,
X₄₀₃ and X₄₀₄ may each independently be a chemical bond (for example, a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each independently be the same as described in connection with Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group that is unsubstituted or substituted with at least one R₁₀ₐ, a C₁-C₂₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₄₀₁) (Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each independently be the same as described in connection with Q₁,
xc11 and xc12 may each independently be an integer from 0 to 10, and
* and *′ in Formula 402 may each indicate a binding site to M in Formula 401.

In an embodiment, in Formula 402, X₄₀₁ may be nitrogen and X₄₀₂ may be carbon, or X₄₀₁ and X₄₀₂ may each be nitrogen.

In an embodiment, in Formula 401, when xc1 is 2 or more, two rings A₄₀₁ among two or more L₄₀₁ may optionally be linked together via T₄₀₂ which is a linking group, or two rings A₄₀₂ may optionally be linked together via T₄₀₃ which is a linking group (see Compounds PD1 to PD4 and PD7). T₄₀₂ and T₄₀₃ may each independently be the same as described in connection with T₄₀₁.

In Formula 401, L₄₀₂ may be an organic ligand. In an embodiment, L₄₀₂ may include a halogen group, a diketone group (for example, an acetylacetonate group), a carboxylic acid group (for example, a picolinate group), —C(═O), an isonitrile group, —CN group, a phosphorus group (for example, a phosphine group, a phosphite group, etc.), or any combination thereof.

The phosphorescent dopant may include, for example, one of Compounds PD1 to PD39 or any combination thereof.

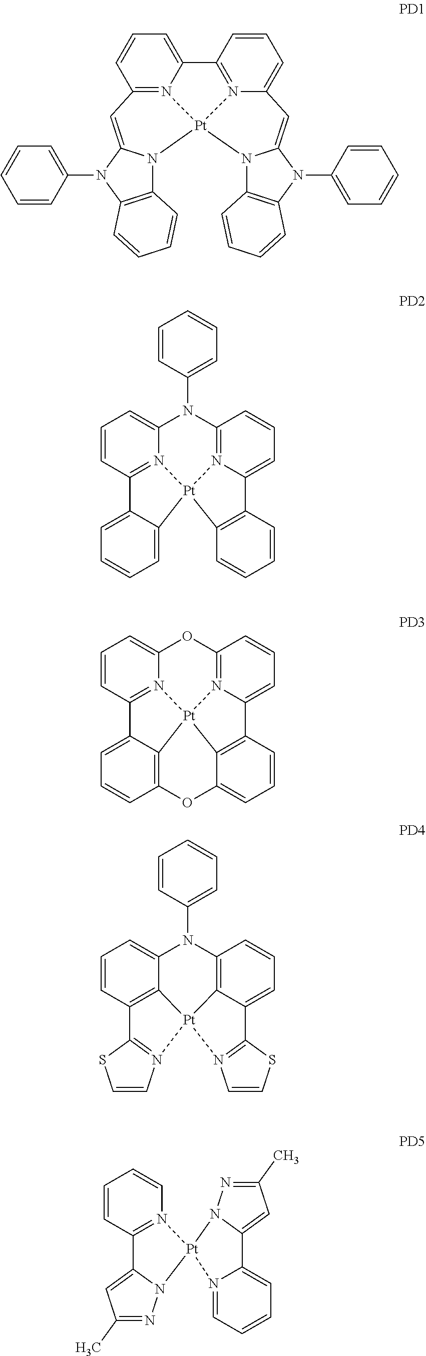

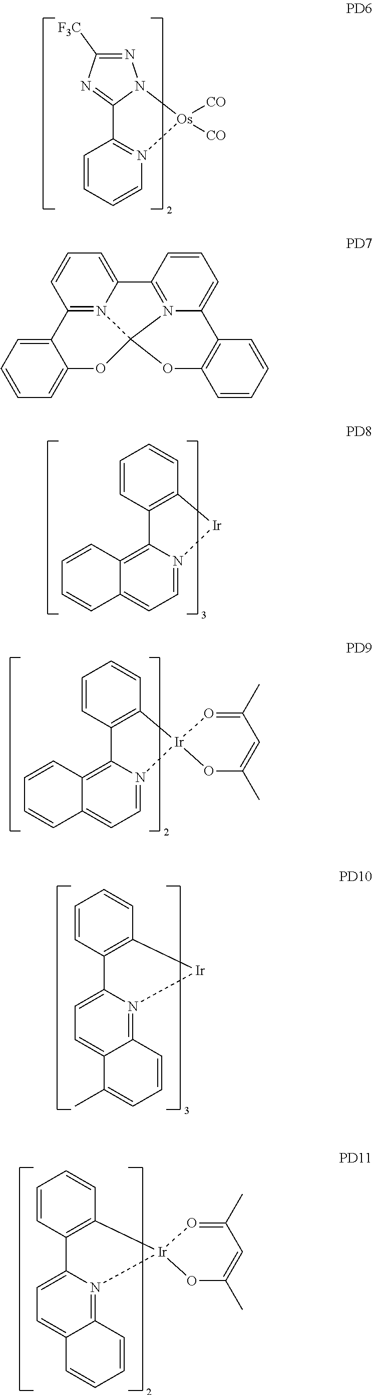

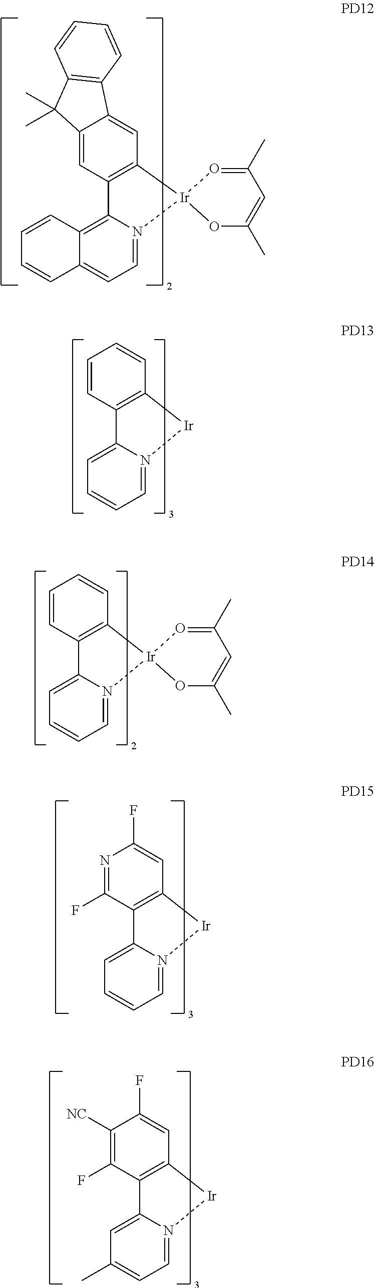

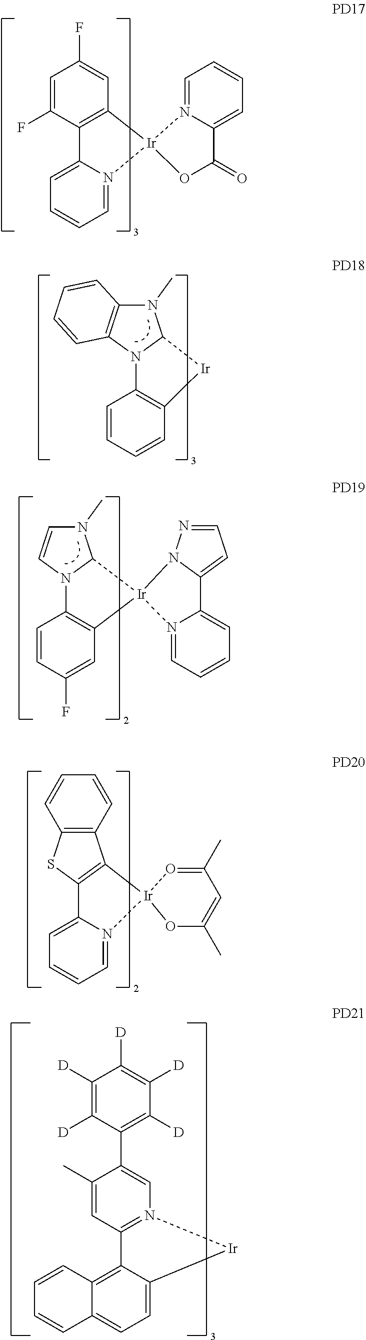

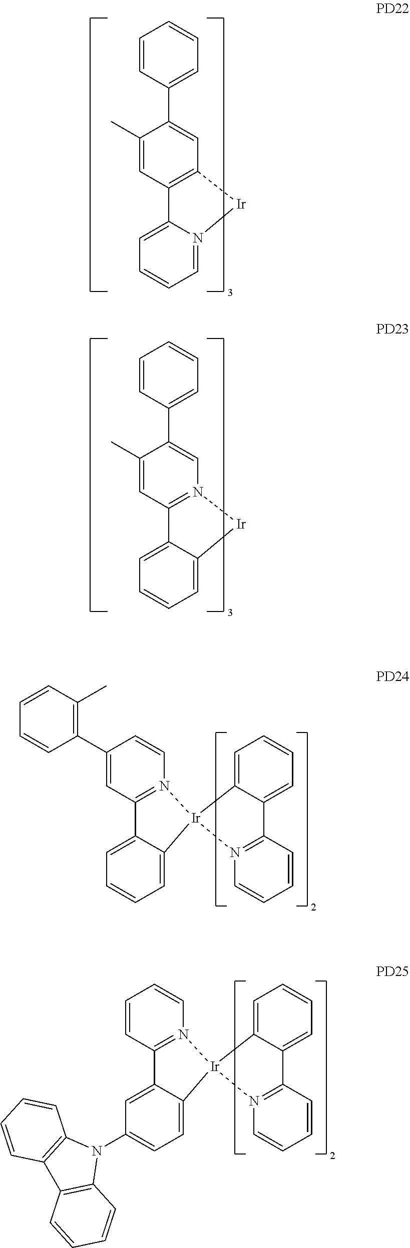

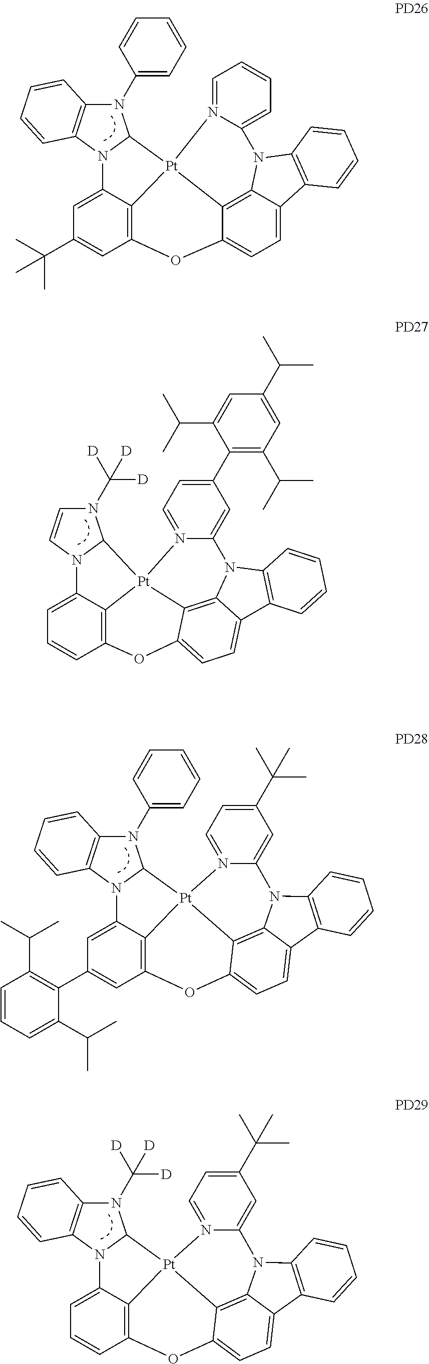

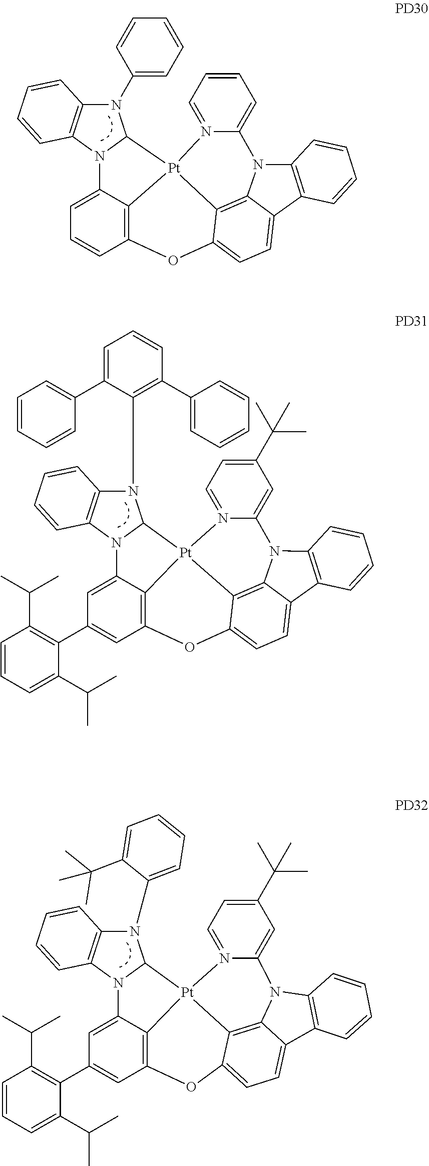

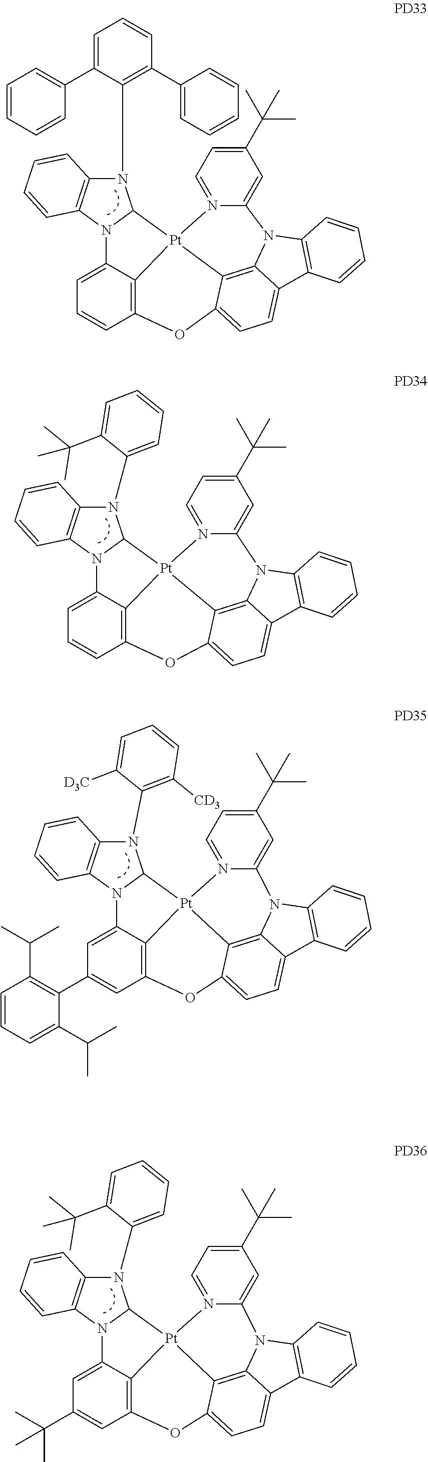

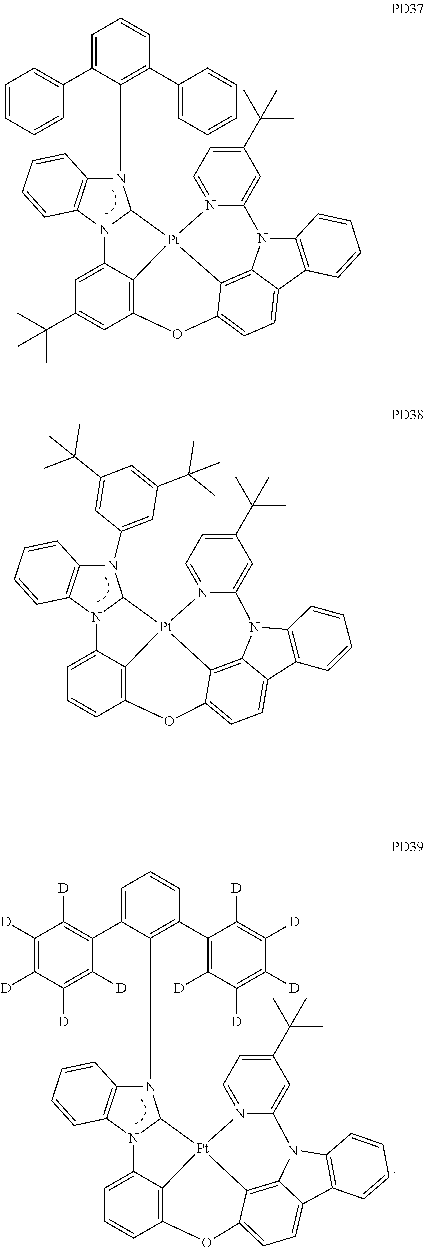

### [Fluorescent Dopant]

The fluorescent dopant may include an amine group-containing compound, a styryl group-containing compound, or any combination thereof.

In an embodiment, the fluorescent dopant may include a compound represented by Formula 501:

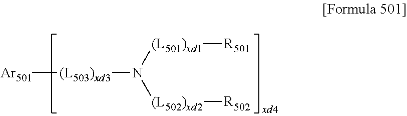

In Formula 501,
Ar₅₀₁, L₅₀₁ to L₅₀₃, R₅₀₁, and R₅₀₂ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xd1 to xd3 may each independently be 0, 1, 2, or 3, and
xd4 may be 1, 2, 3, 4, 5, or 6.

In an embodiment, in Formula 501, Ar₅₀₁ may be a condensed cyclic group (for example, an anthracene group, a chrysene group, or a pyrene group) in which three or more monocyclic groups are condensed together.

In an embodiment, in Formula 501, xd4 may be 2.

In an embodiment, the fluorescent dopant may include: one of Compounds FD1 to FD37; DPVBi; DPAVBi; or any combination thereof:

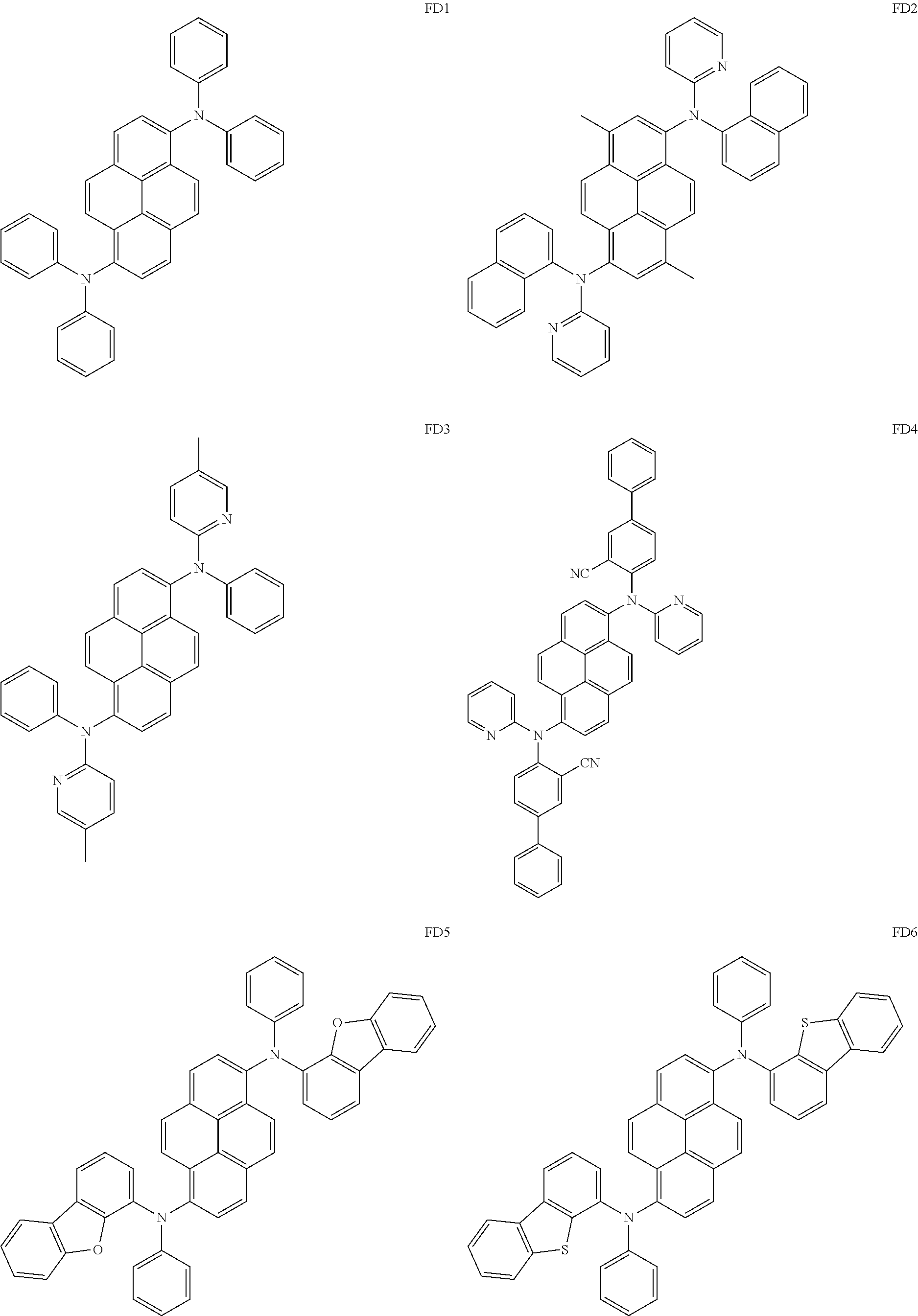

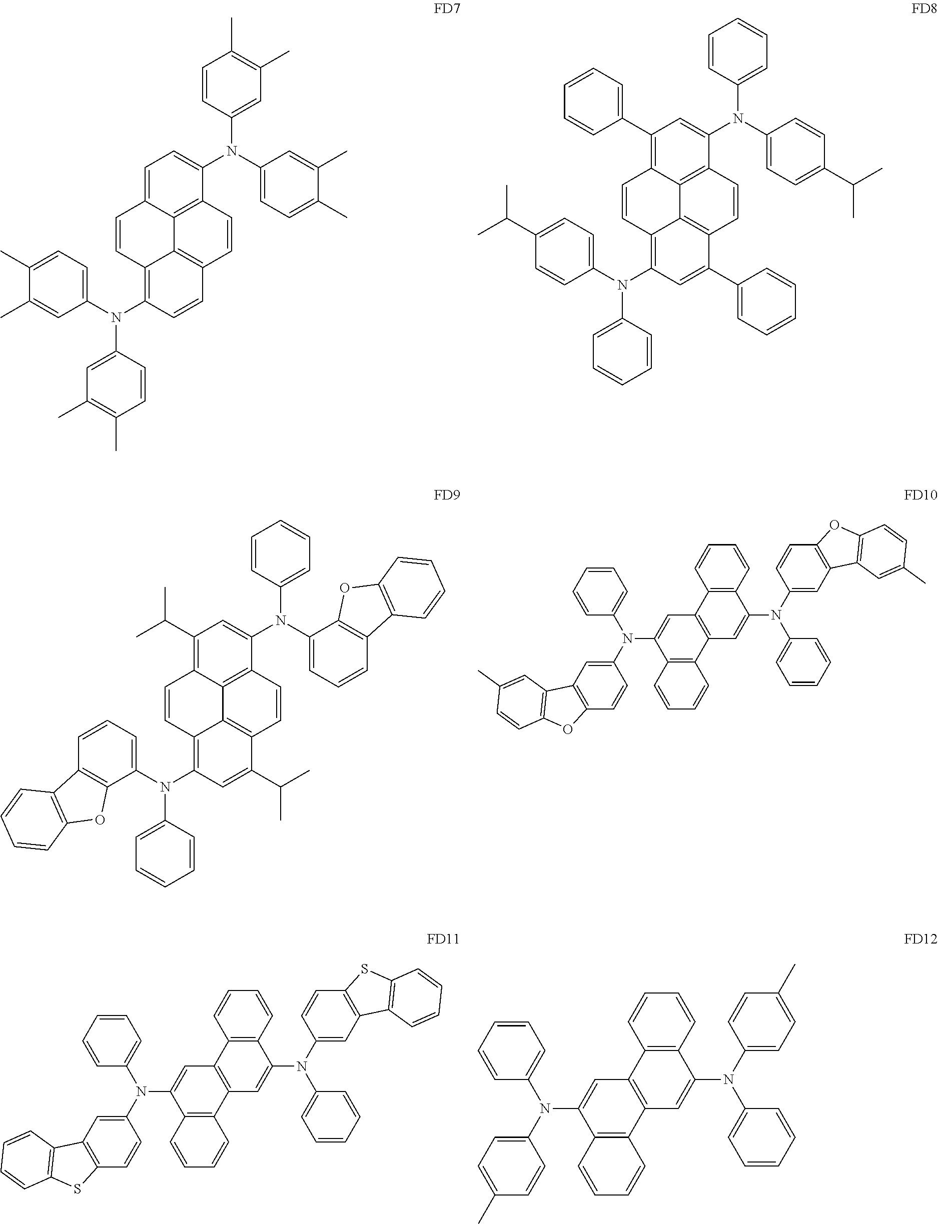

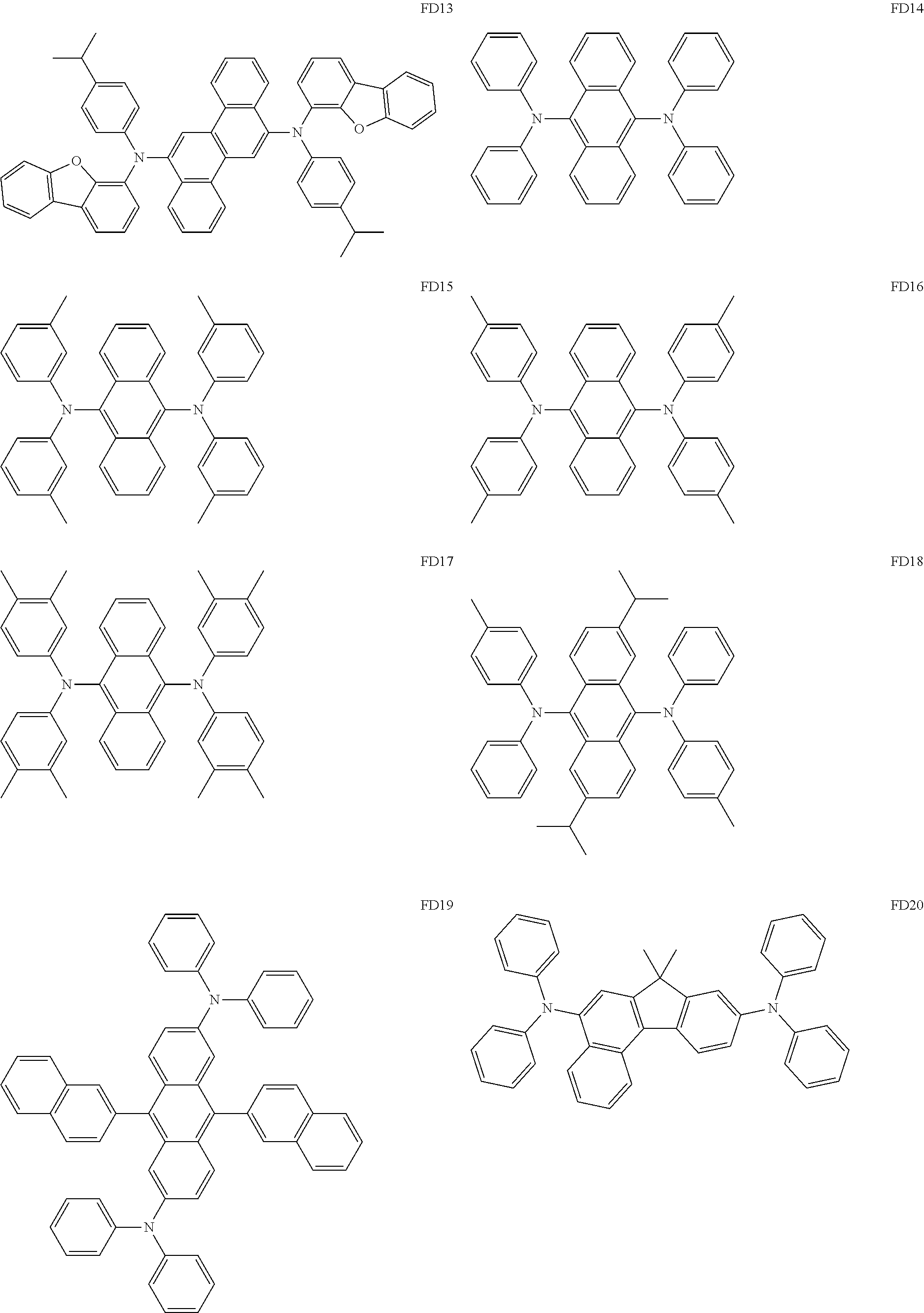

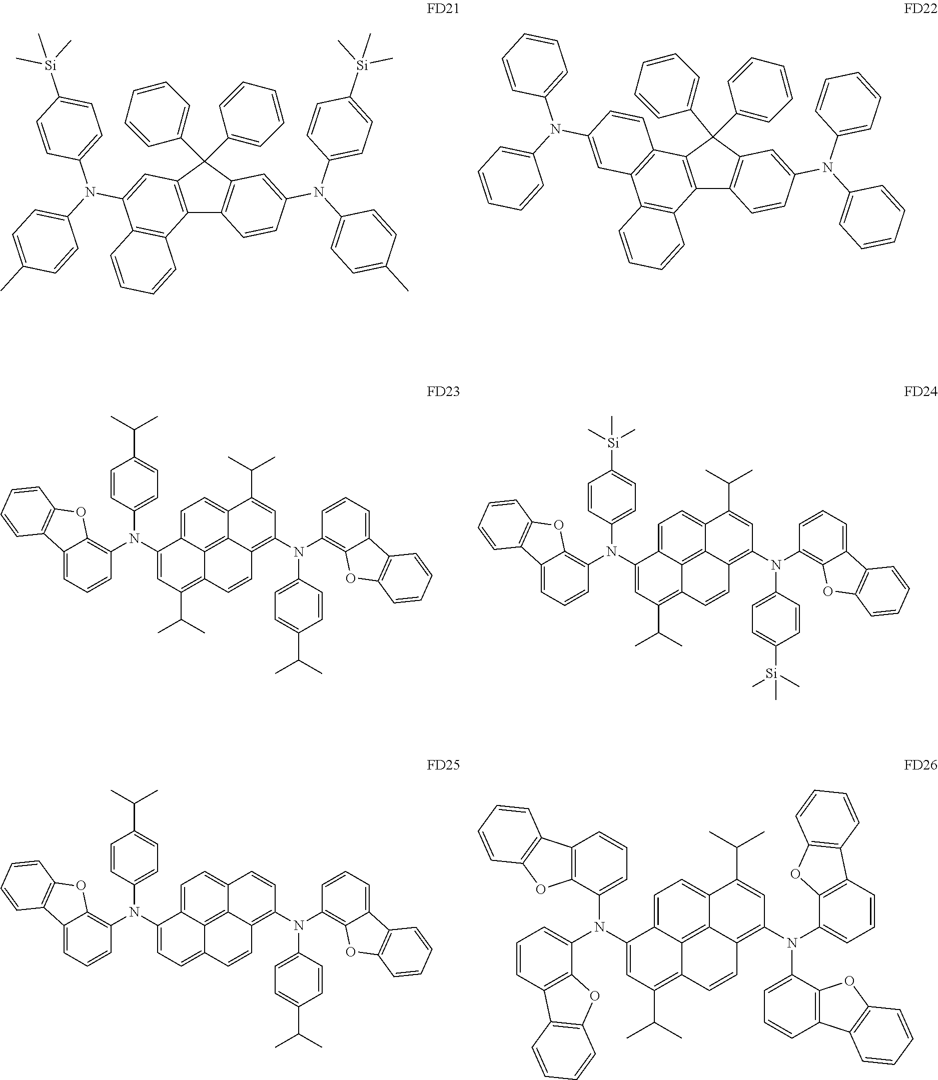

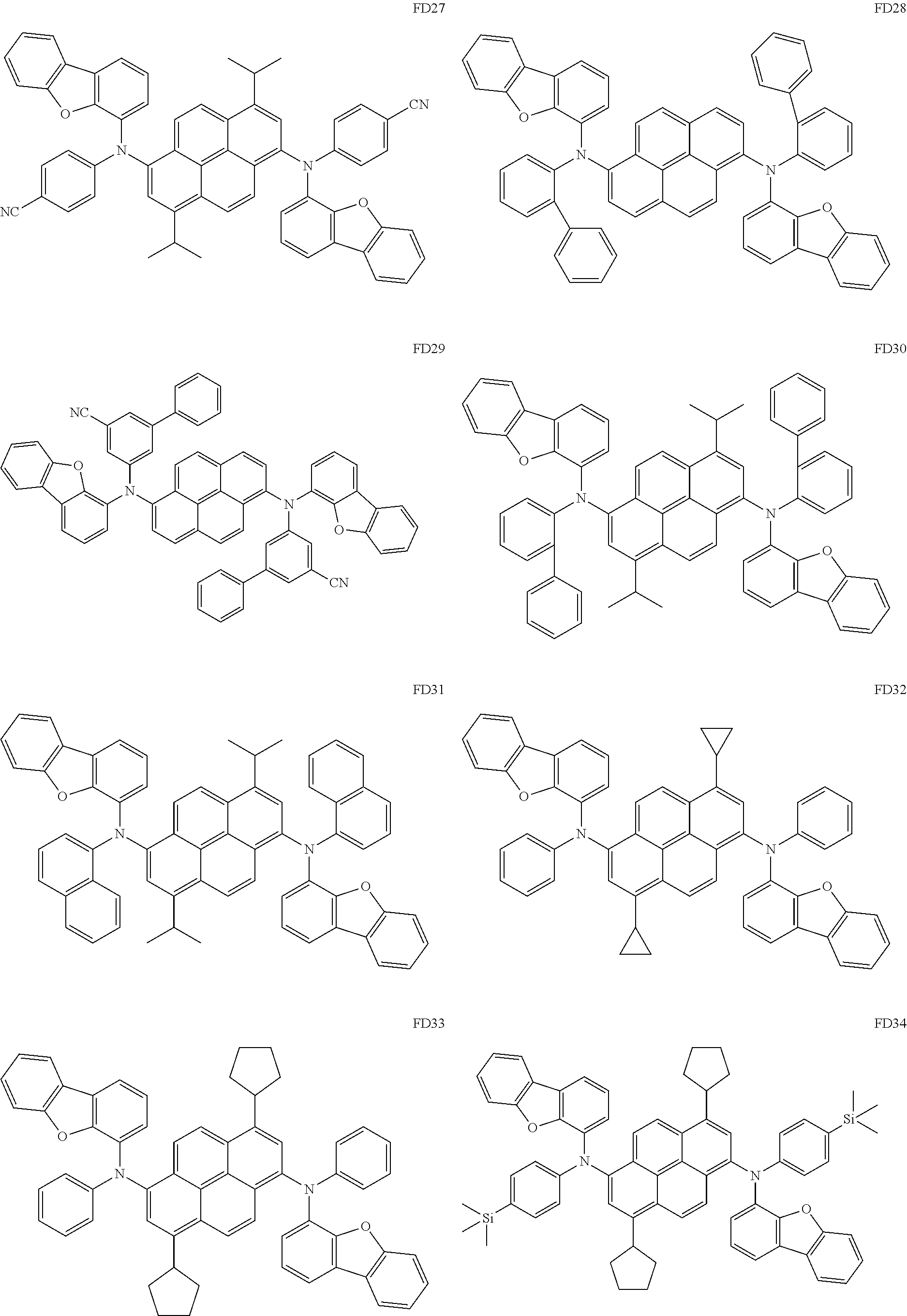

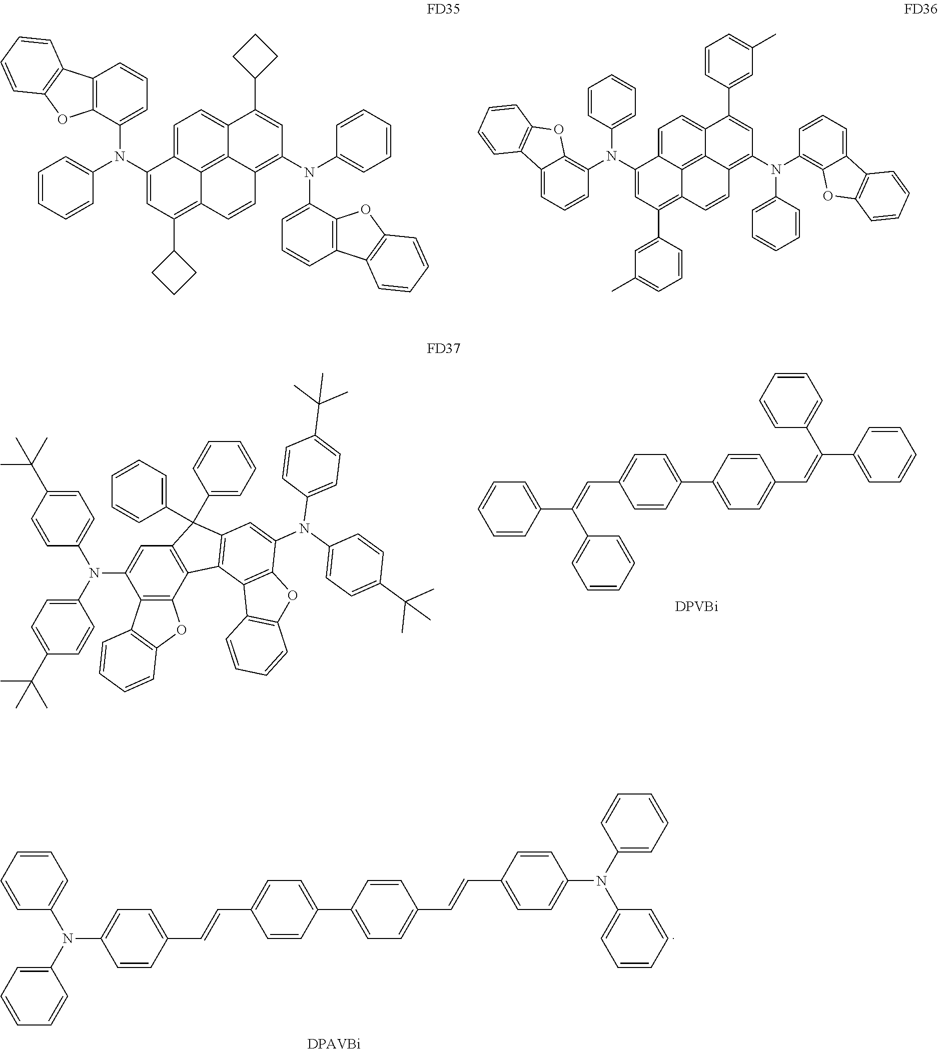

### [Delayed Fluorescence Dopant]

An emission layer may include a delayed fluorescence dopant.

The delayed fluorescence dopant described herein may be any suitable compound that emits delayed fluorescence according to a delayed fluorescence emission mechanism.

The delayed fluorescence dopant included in an emission layer may serve as a host or as a dopant, depending on the types of other materials included in the emission layer.

In an embodiment, a difference between a triplet energy level (eV) of the delayed fluorescence dopant and a singlet energy level (eV) of the delayed fluorescence dopant may be at least about 0 eV and not more than about 0.5 eV. When a difference between a triplet energy level (eV) of the delayed fluorescence dopant and a singlet energy level (eV) of the delayed fluorescence dopant is within this range, up-conversion from a triplet state to a singlet state in the delayed fluorescence dopant may effectively occur, thus improving emission efficiency and the like of the light-emitting device 10.

In embodiments, the delayed fluorescence dopant may include: a material including at least one electron donor (for example, a π electron-rich C₃-C₆₀ cyclic group such as a carbazole group) and at least one electron acceptor (for example, a sulfoxide group, a cyano group, and a π electron-deficient nitrogen-containing C₁-C₆₀ cyclic group); or a material including a C₈-C₆₀ polycyclic group including at least two cyclic groups condensed to each other while sharing boron (B).

Examples of a delayed fluorescence dopant may include at least one of Compounds DF1 to DF14:

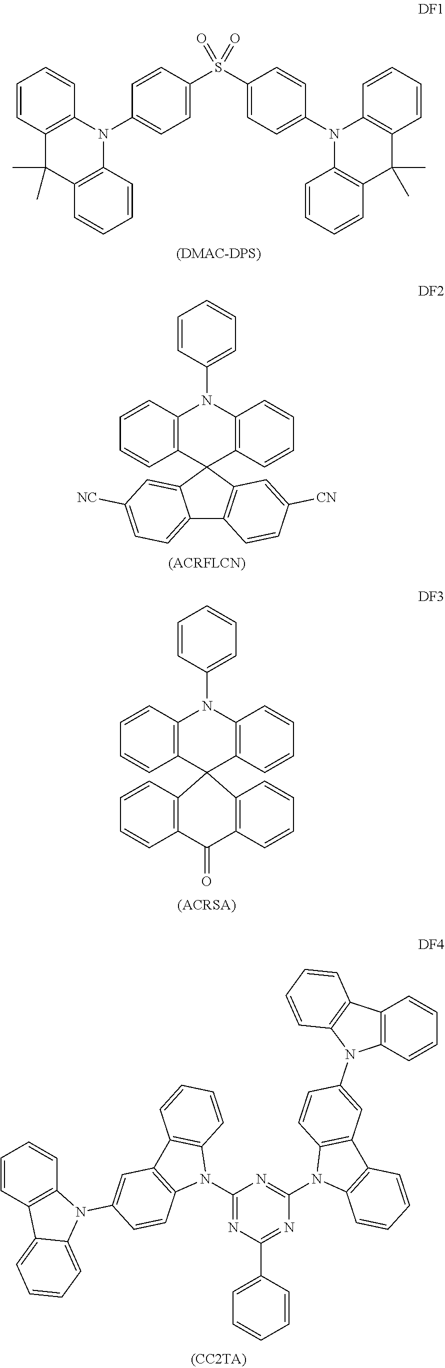

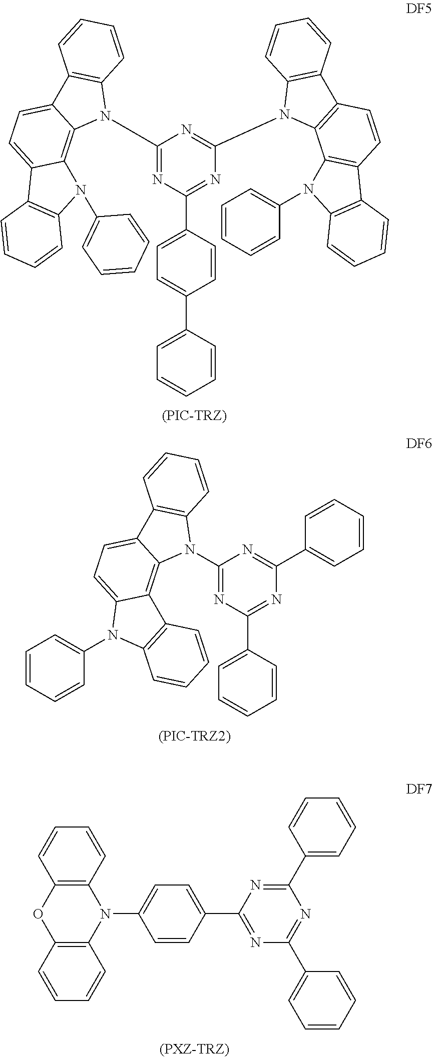 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1]

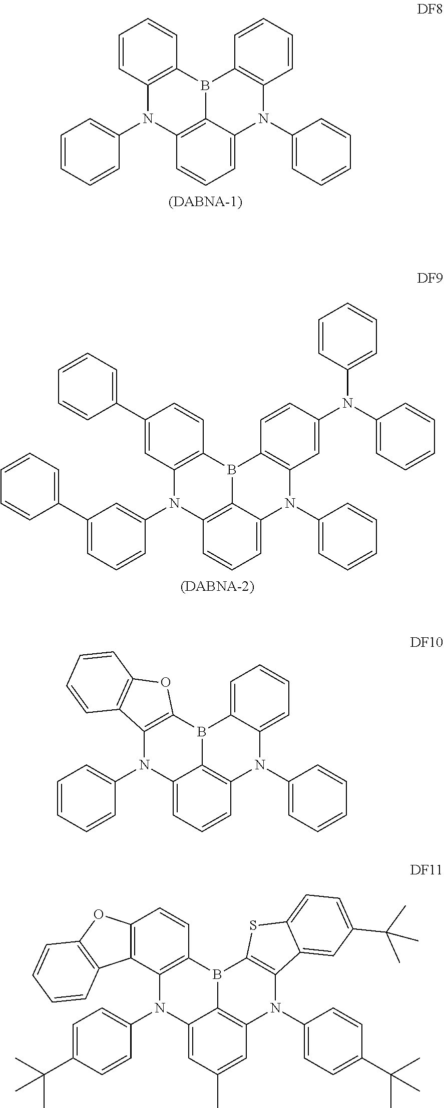

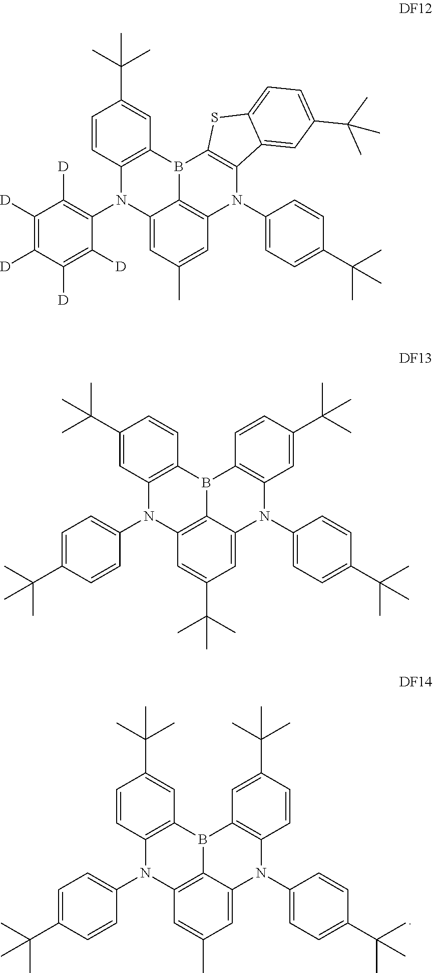

### [Quantum Dot]

The electronic apparatus may include quantum dots. For example, the electronic apparatus may include a color conversion layer, and the color conversion layer may include quantum dots.

In the specification, a quantum dot may be a crystal of a semiconductor compound, and may include any material capable of emitting light of various emission wavelengths according to a size of the crystal.

A diameter of the quantum dot may be, for example, in a range of about 1 nm to about 10 nm.

The quantum dot may be synthesized by a wet chemical process, a metal organic chemical vapor deposition process, a molecular beam epitaxy process, or any process similar thereto.

According to the wet chemical process, a precursor material is mixed with an organic solvent to grow a quantum dot particle crystal. As the crystal grows, the organic solvent naturally acts as a dispersant coordinated on the surface of the quantum dot crystal and controls the growth of the crystal so that the growth of quantum dot particles may be controlled through a process which may be more readily performed than vapor deposition methods, such as metal organic chemical vapor deposition (MOCVD) or molecular beam epitaxy (MBE), and which has a lower cost.

The quantum dot may include: a Group II-VI semiconductor compound; a Group III-V semiconductor compound; a Group III-VI semiconductor compound; a Group I-III-VI semiconductor compound; a Group IV-VI semiconductor compound; a Group IV element or compound; or any combination thereof.

Examples of a Group II-VI semiconductor compound may include: a binary compound, such as CdS, CdSe, CdTe, ZnS, ZnSe, ZnTe, ZnO, HgS, HgSe, HgTe, MgSe, or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS; a quaternary compound, such as CdZnSeS, CdZnSeTe, CdZnSTe, CdHgSeS, CdHgSeTe, CdHgSTe, HgZnSeS, HgZnSeTe, or HgZnSTe; or any combination thereof.

Examples of a Group III-V semiconductor compound may include: a binary compound, such as GaN, GaP, GaAs, GaSb, AlN, AlP, AlAs, AlSb, InN, InP, InAs, or InSb; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, or InPSb; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb; or any combination thereof. In an embodiment, the Group III-V semiconductor compound may further include a Group II element. Examples of a Group III-V semiconductor compound further including a Group Il element may include InZnP, InGaZnP, InAlZnP, and the like.

Examples of a Group III-VI semiconductor may include: a binary compound, such as GaS, GaSe, Ga₂Se₃, GaTe, InS, InSe, In₂Se₃, or InTe; a ternary compound, such as InGaS₃ or InGaSes; or any combination thereof.

Examples of a Group I-III-VI semiconductor compound may include: a ternary compound, such as AgInS, AgInS₂, CuInS, CuInS₂, CuGaO₂, AgGaO₂, or AgAlO₂; or any combination thereof.

Examples of a Group IV-VI semiconductor compound may include: a binary compound, such as SnS, SnSe, SnTe, PbS, PbSe, PbTe, or the like; a ternary compound, such as SnSeS, SnSeTe, SnSTe, PbSeS, PbSeTe, PbSTe, SnPbS, SnPbSe, SnPbTe, or the like; a quaternary compound, such as SnPbSSe, SnPbSeTe, SnPbSTe, or the like; or any combination thereof.

Examples of a Group IV element or compound may include: a single element material, such as Si or Ge; a binary compound, such as SiC or SiGe; or any combination thereof.

Each element included in a multi-element compound such as a binary compound, a ternary compound, or a quaternary compound, may exist in a particle at a uniform concentration or at a non-uniform concentration.

In an embodiment, the quantum dot may have a single structure or a core-shell structure. In the case of the quantum dot having a single structure, the concentration of each element included in the corresponding quantum dot may be uniform. In an embodiment, in the case of the quantum dot having a core-shell structure, a material contained in the core and a material contained in the shell may be different from each other.

The shell of the quantum dot may serve as a protective layer to prevent chemical degeneration of the core to maintain semiconductor characteristics and/or may serve as a charging layer to impart electrophoretic characteristics to the quantum dot. The shell may be a single layer or a multilayer. An element that is present at an interface between the core and the shell of the quantum dot may have a concentration gradient that decreases toward the center of the quantum dot.

Examples of a material forming the shell of the quantum dot may include a metal oxide, a metalloid oxide, a non-metal oxide, a semiconductor compound, or any combination thereof. Examples of a metal oxide, a metalloid oxide, or a non-metal oxide may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound, such as MgAl₂O₄, CoFe₂O₄, NiFe₂O₄, or CoMn₂O₄; or any combination thereof.

Examples of a semiconductor compound may include, as described herein, a Group II-VI semiconductor compound, a Group III-V semiconductor compound, a Group III-VI semiconductor compound, a Group I-III-VI semiconductor compound, a Group IV-VI semiconductor compound, or any combination thereof. For example, a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

A full width at half maximum (FWHM) of an emission wavelength spectrum of the quantum dot may be equal to or less than about 45 nm. For example, a FWHM of an emission wavelength spectrum of the quantum dot may be equal to or less than about 40 nm. For example, a FWHM of an emission wavelength spectrum of the quantum dot may be equal to or less than about 30 nm. Within any of these ranges, color purity or color reproducibility may be increased. Because the light emitted through the quantum dot is emitted in all directions, a wide viewing angle may be improved.

In embodiments, the quantum dot may be a spherical particle, a pyramidal particle, a multi-arm particle, a cubic nanoparticle, a nanotube particle, a nanowire particle, a nanofiber particle, or a nanoplate particle.

Because the energy band gap may be adjusted by controlling the size of the quantum dot, light having various wavelength bands may be obtained from a quantum dot emission layer. Therefore, by utilizing quantum dots of different sizes, a light-emitting device that emits light of various wavelengths may be implemented. In an embodiment, the size of the quantum dot may be selected to emit red light, green light, and/or blue light. In an embodiment, the size of the quantum dot may be configured to emit white light by combining light of various colors.

[Electron transport region in interlayer 130]

An electron transport region may have a structure consisting of a layer consisting of a single material, a structure consisting of a layer including different materials, or a structure including multiple layers including different materials.

For example, the electron transport region may include the first electron transport layer, the second electron transport layer, and the third electron transport layer.

For example, the electron transport region may include a first electron transport layer/second electron transport layer/third electron transport layer structure, wherein the layers may be stacked in this stated order from the second emission layer.

The first compound, the second compound, and the third compound included in the first electron transport layer, the second electron transport layer, and the third electron transport layer are the same as described above.

In an embodiment, the electron transport region may be arranged between an emission unit and a charge generation layer, and the electron transport region may include a hole blocking layer, an electron transport layer, an electron injection layer, or any combination thereof.

The electron transport region (for example, a hole blocking layer or an electron transport layer in the electron transport region) may include a metal-free compound including at least one π electron-deficient nitrogen-containing C₁-C₆₀ cyclic group.

In an embodiment, the electron transport region may include a compound represented by Formula 601:

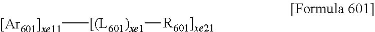

In Formula 601,
Ar₆₀₁ and L₆₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₆₀₁) (Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described in connection with Q₁,
xe21 may be 1, 2, 3, 4, or 5, and
at least one of Ar₆₀₁, L₆₀₁, and R₆₀₁ may each independently be a π electron-deficient nitrogen-containing C₁-C₆₀ cyclic group that is unsubstituted or substituted with at least one R₁₀ₐ.

In an embodiment, in Formula 601, when xe11 is 2 or more, two or more Ar₆₀₁(s) may be linked to each other via a single bond.

In an embodiment, in Formula 601, Ar₆₀₁ may be a substituted or unsubstituted anthracene group.

In an embodiment, the electron transport region may include a compound represented by Formula 601-1:

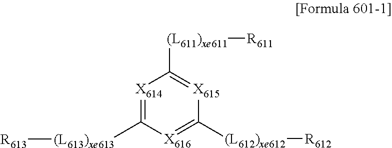

In Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may each be N,
L₆₁₁ to L₆₁₃ may each independently be the same as described in connection with L₆₀₁,
xe611 to xe613 may each independently be the same as described in connection with xe1,
R₆₁₁ to R₆₁₃ may each independently be the same as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group that is unsubstituted or substituted with at least one R₁₀ₐ, or a C₁-C₆₀ heterocyclic group that is unsubstituted or substituted with at least one R₁₀ₐ.

In an embodiment, in Formulae 601 and 601-1, xe1 and xe611 to xe613 may each independently be 0, 1, or 2.

In embodiments, the electron transport region may include one of Compounds ET1 to ET45, 2,9-dimethyl-4,7-diphenyl-1,10-phenanthroline (BCP), 4,7-diphenyl-1,10-phenanthroline (Bphen), Alq₃, BAIq, TAZ, NTAZ, or any combination thereof:

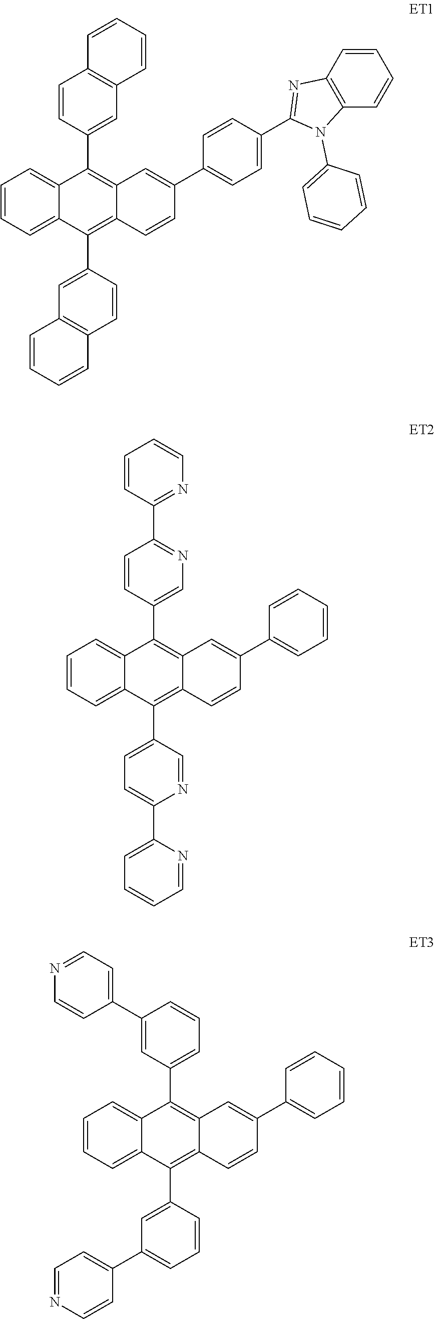 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

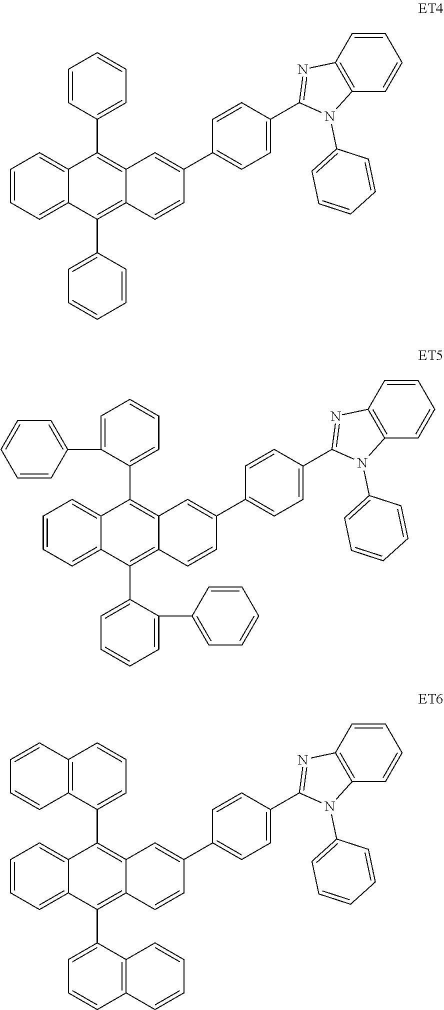 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

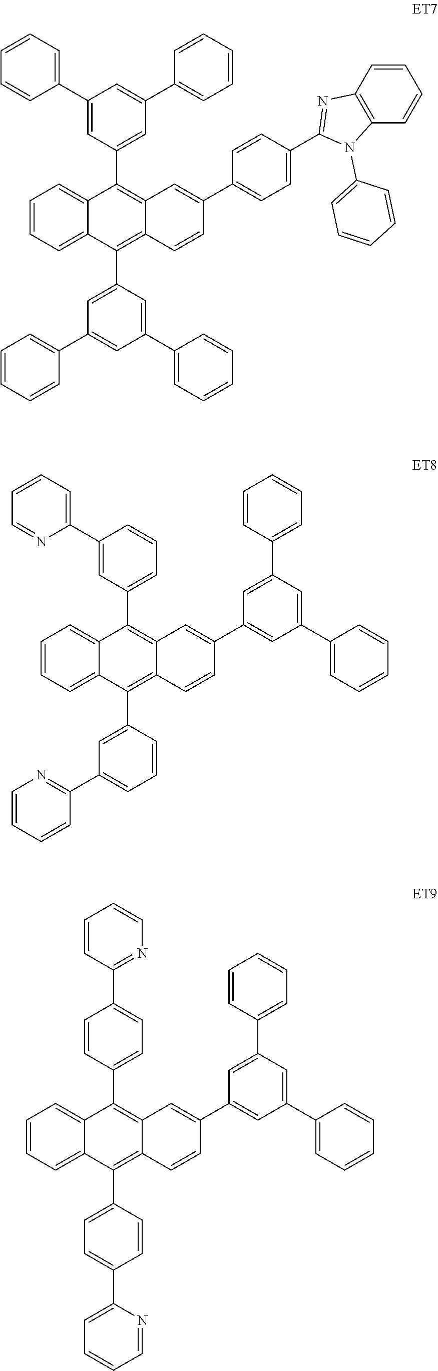 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

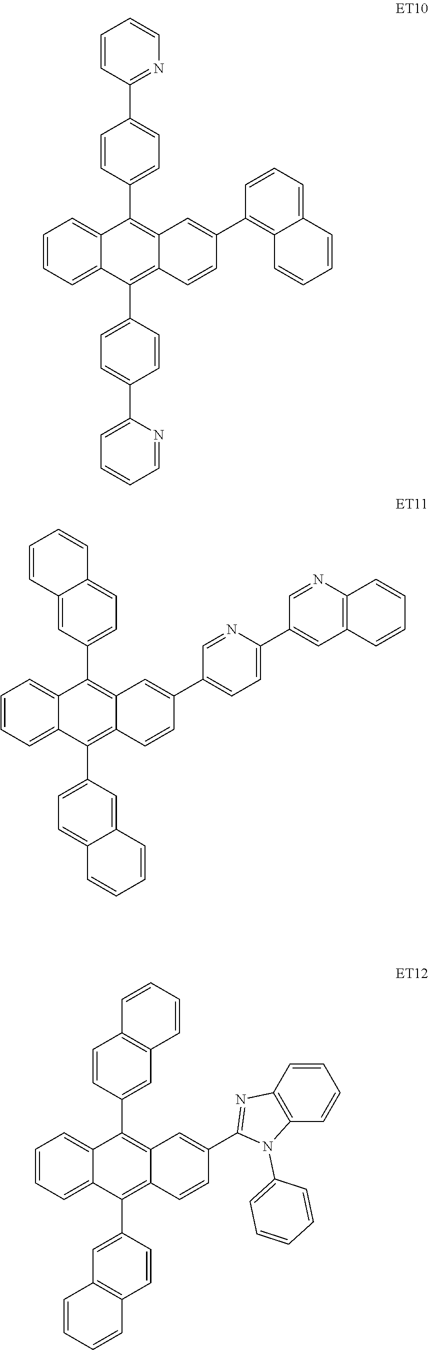 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

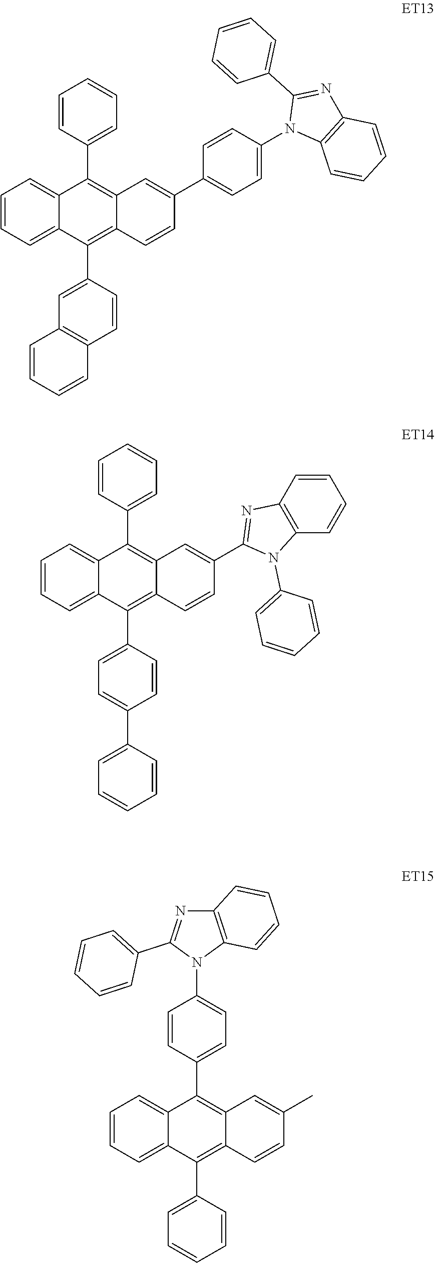 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

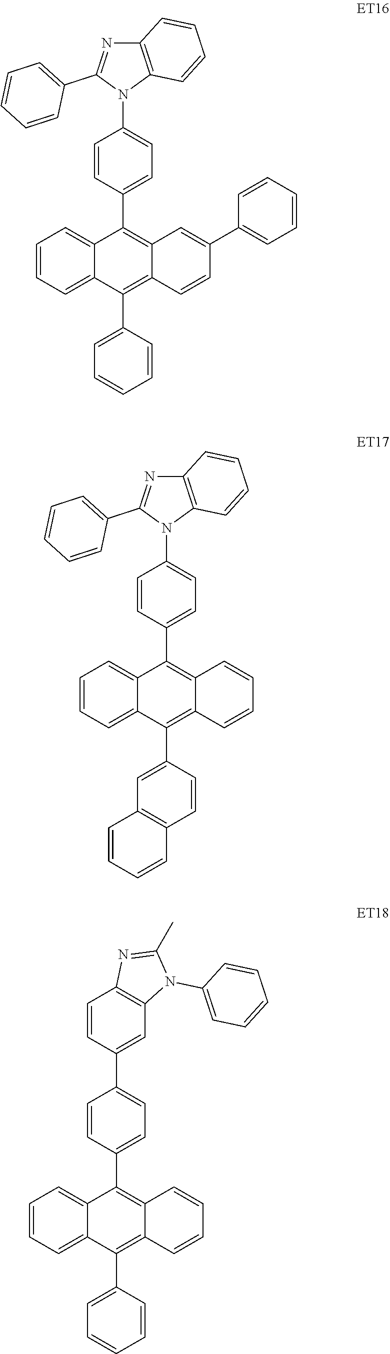 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

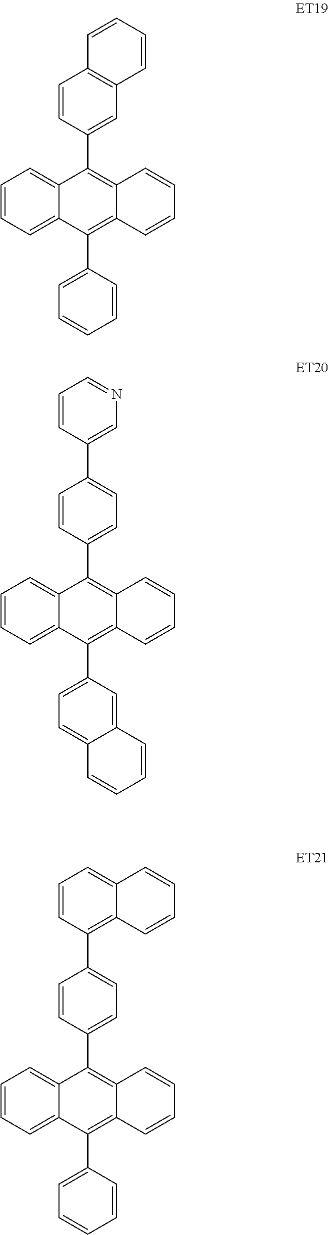

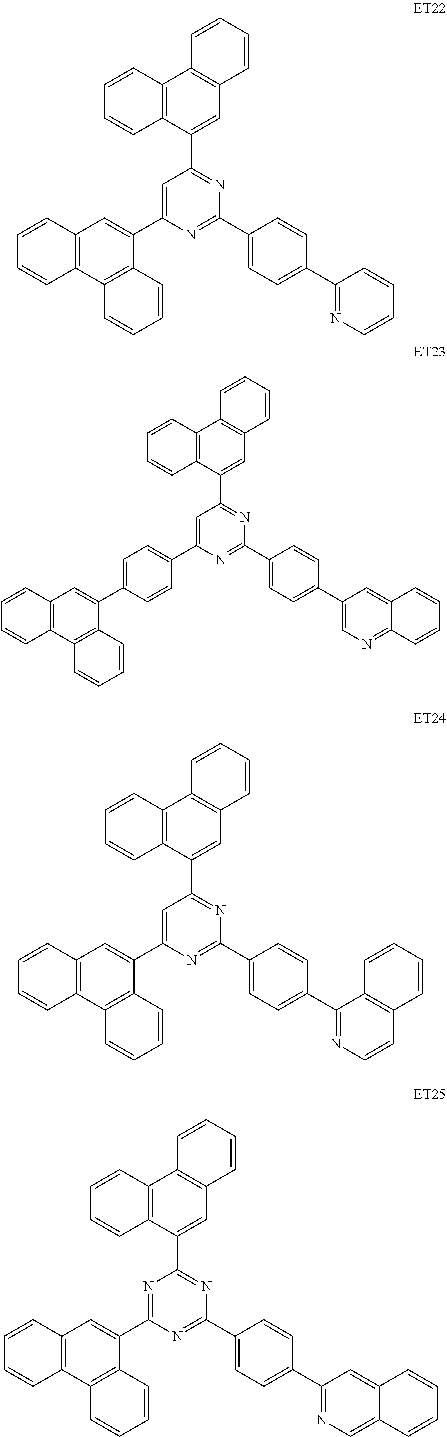 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2cc(-c3ccc(-c4nc(-c5cc6ccccc6c6ccccc56)nc(-c5cc6ccccc6c6ccccc56)n4)cc3)ncc2c1]

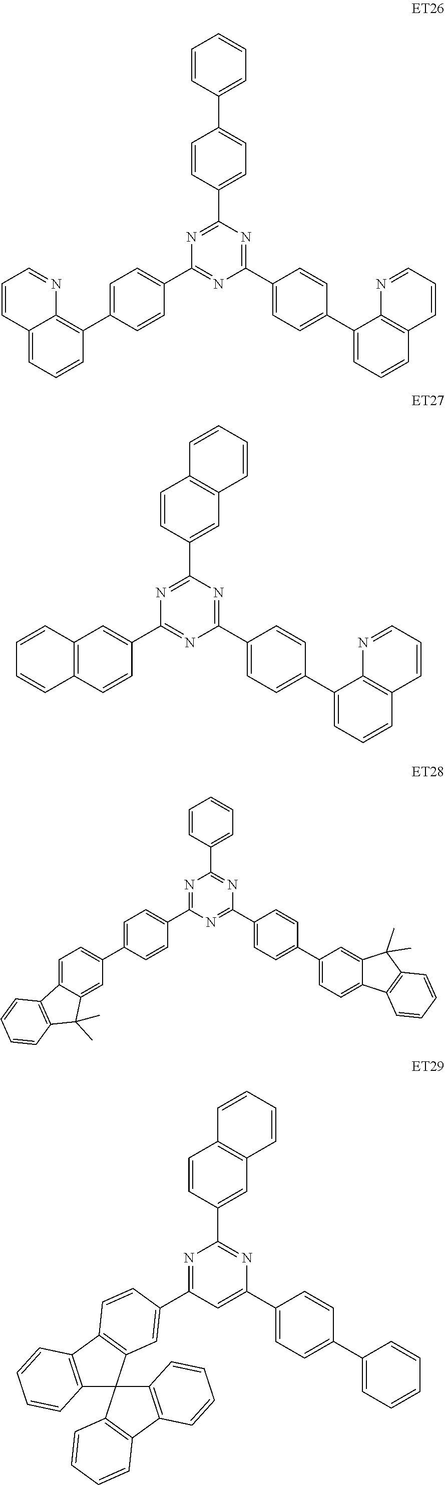 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

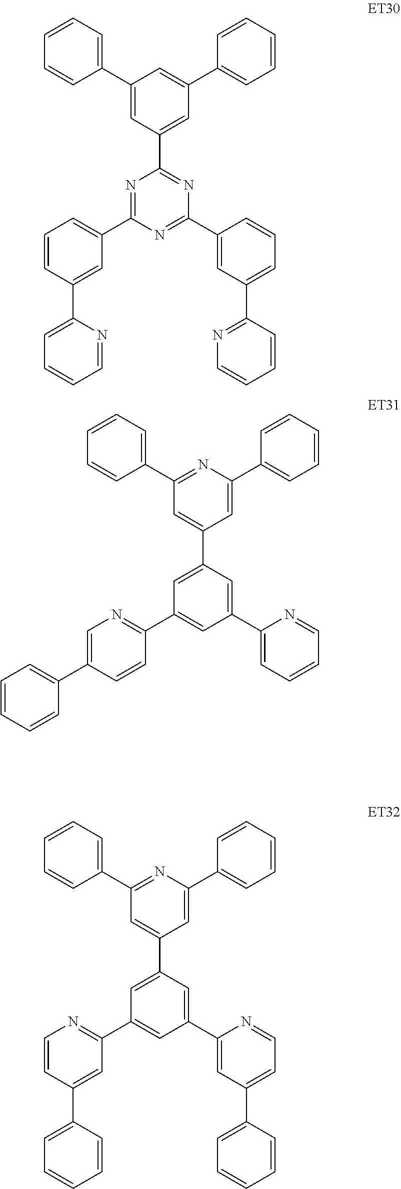 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

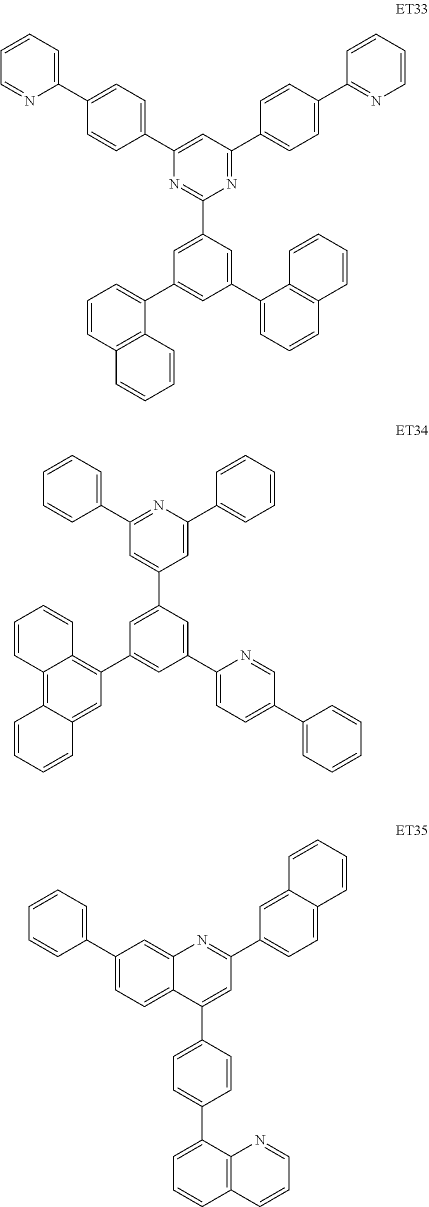 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1]

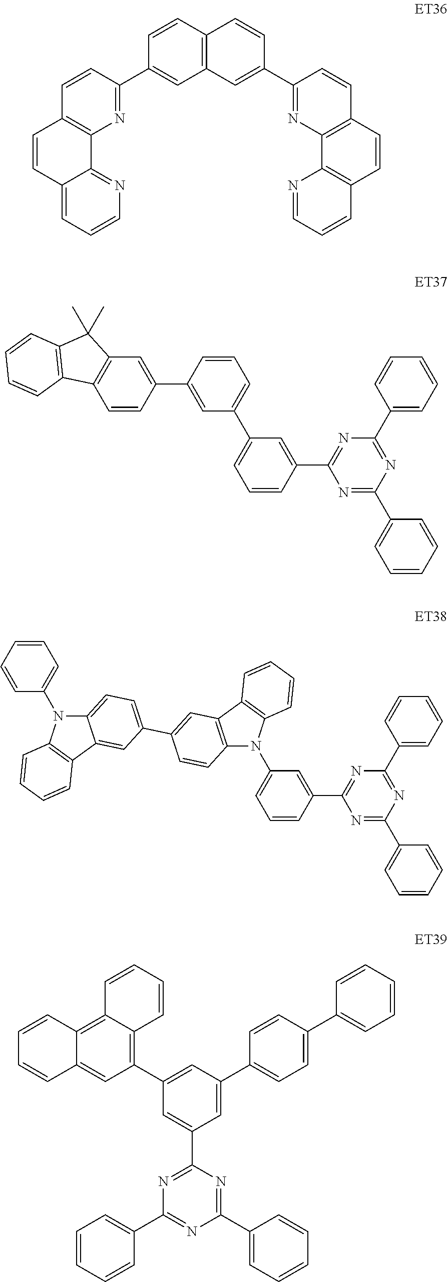 [SMILES: c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1]

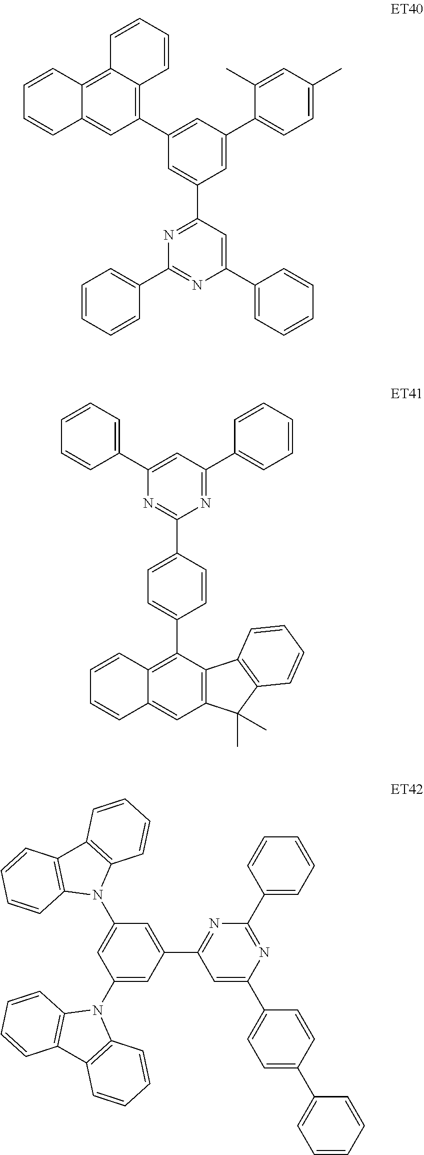 [SMILES: Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

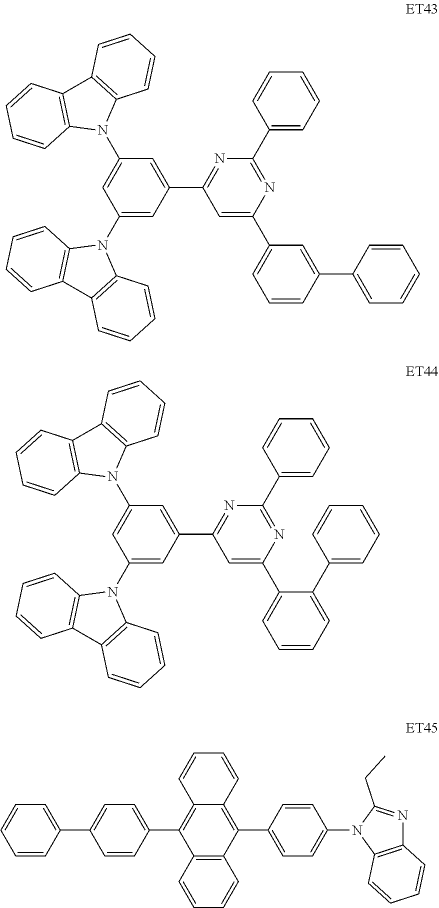

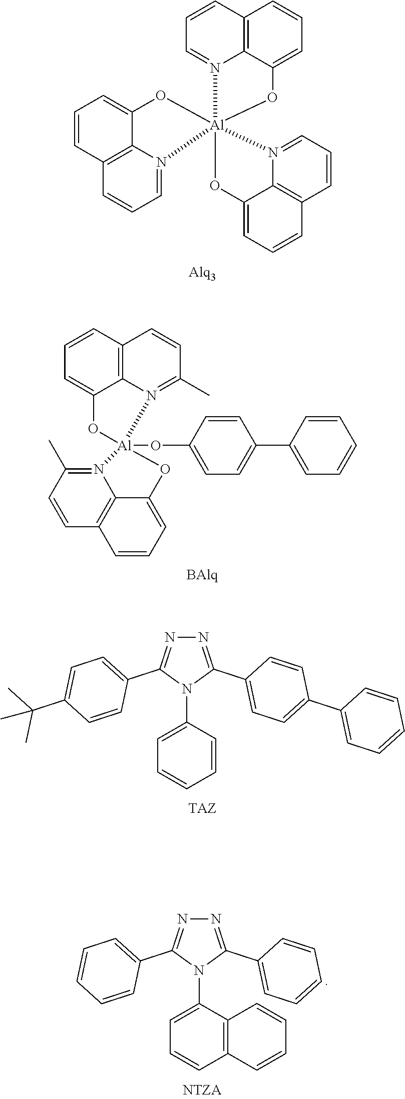

A thickness of the electron transport region may be in a range of about 100 Å to about 5,000 Å. For example, the thickness of the electron transport region may be in a range of about 160 Å to about 4,000 Å. When the electron transport region includes a hole blocking layer, an electron transport layer, or any combination thereof, thicknesses of the hole blocking layer and the electron transport layer may each independently be in a range of about 20 Å to about 1,000 Å, and a thickness of the electron transport layer may be about 100 Å to about 1,000 Å. For example, thicknesses of the hole blocking layer and the electron transport layer may each independently be in a range of about 30 Å to about 300 Å. For example, the thickness of the electron transport layer may be in a range of about 150 Å to about 500 Å. When the thicknesses of the electron transport region are within these ranges as described above, satisfactory electron transporting characteristics may be obtained without a substantial increase in driving voltage. When the thicknesses of the hole blocking layer and/or the electron transport layer are within these ranges as described above, satisfactory electron transporting characteristics may be obtained without a substantial increase in driving voltage.

A thickness of the first electron transport layer and a thickness of the second electron transport layer may each independently be in a range of about 10 Å to about 500 Å. For example, the thickness of the first electron transport layer and the thickness of the second electron transport layer may each independently be in a range of about 30 Å to about 300 Å. For example, the thickness of the first electron transport layer and the thickness of the second electron transport layer may each independently be in a range of about 40 Å to about 100 Å.

A thickness of the third electron transport layer may be in a range of about 30 Å to about 600 Å. For example, the thickness of the third electron transport layer may be in a range of about 50 Å to about 400 Å. For example, the thickness of the third electron transport layer may be in a range of about 60 Å to about 200 Å.

When a thickness of the first electron transport layer and a thickness of the second electron transport layer are each less than about 10 Å and when a thickness of the third electron transport layer is less than about 30 Å, electron injection control may be difficult. When a thickness of the first electron transport layer and a thickness of the second electron transport layer are each greater than about 500 Å and when a thickness of the third electron transport layer is greater than about 600 Å, driving voltage may sharply increase.

The electron transport region (for example, an electron transport layer in the electron transport region) may further include, in addition to the materials described above, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion.

A ligand coordinated with the metal ion of an alkali metal complex or an alkaline earth-metal complex may each independently include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or Compound ET-D2:

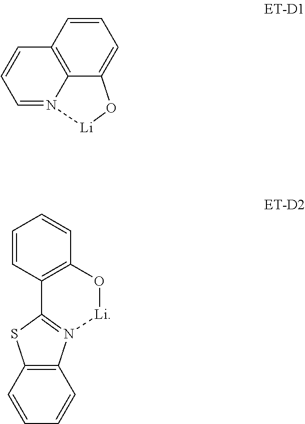

However, each of the first electron transport layer, the second electron transport layer, and the third electron transport layer does not include a metal complex.

The electron transport region may include an electron injection layer to facilitate the injection of electrons from the second electrode 150. The electron injection layer may directly contact the second electrode 150.

The electron injection layer may have a structure consisting of a layer consisting of a single material, a structure consisting of a layer including different materials, or a structure including multiple layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (for example, fluorides, chlorides, bromides, or iodides), or tellurides of the alkali metal, the alkaline earth metal, and the rare earth metal, or any combination thereof.

The alkali metal-containing compound may include: an alkali metal oxide, such as Li₂O, Cs₂O, or K₂O; an alkali metal halide, such as LiF, NaF, CsF, KF, LiI, NaI, CsI, or KI; or any combination thereof. The alkaline earth metal-containing compound may include an alkaline earth metal compound, such as BaO, SrO, CaO, BaxSr₁₋ₓO (x is a real number satisfying the condition of 0<x<1), BaxCa₁₋ₓO (x is a real number satisfying the condition of 0<x<1), or the like. The rare earth metal-containing compound may include YbF₃, ScF₃, SC₂O₃, Y₂O₃, Ce₂O₃, GdF₃, TbF₃, YbI₃, ScI₃, TbI₃, or any combination thereof. In an embodiment, the rare earth metal-containing compound may include a lanthanide metal telluride. Examples of a lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and LuzTe₃.

The alkali metal complex, the alkaline earth-metal complex, and the rare earth metal complex may include: an alkali metal ion, an alkaline earth metal ion, or a rare earth metal ion; and a ligand bonded to the metal ion (for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof).

In an embodiment, the electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In an embodiment, the electron injection layer may further include an organic material (for example, a compound represented by Formula 601).

In an embodiment, the electron injection layer may consist of an alkali metal-containing compound (for example, an alkali metal halide); or the electron injection layer may consist of an alkali metal-containing compound (for example, an alkali metal halide), and an alkali metal, an alkaline earth metal, a rare earth metal, or any combination thereof. For example, the electron injection layer may be a KI:Yb co-deposited layer, a RbI:Yb co-deposited layer, a LiF:Yb co-deposited layer, or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combination thereof may be homogeneously or non-homogeneously dispersed in a matrix including the organic material.

A thickness of the electron injection layer may be in a range of about 1 Å to about 100 Å. For example, the thickness of the electron injection layer may be in a range of about 3 Å to about 90 Å. When the thickness of the electron injection layer is within the range described above, satisfactory electron injection characteristics may be obtained without a substantial increase in driving voltage.

### [Second Electrode 150]

The second electrode 150 may be disposed on the interlayer 130. The second electrode 150 may be a cathode, which is an electron injection electrode. A material for the second electrode 150 may be a material having a low work function, such as a metal, an alloy, an electrically conductive compound, or any combination thereof.

In an embodiment, the second electrode 150 may include lithium (Li), silver (Ag), magnesium (Mg), aluminum (AI), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layered structure or a multilayered structure.

### [Capping Layer]

In an embodiment, the light-emitting device 10 may include a first capping layer outside the first electrode 110, and/or a second capping layer outside the second electrode 150. For example, the light-emitting device 10 may have a structure in which the first capping layer, the first electrode 110, the interlayer 130, and the second electrode 150 are stacked in this stated order, a structure in which the first electrode 110, the interlayer 130, the second electrode 150, and the second capping layer are stacked in this stated order, or a structure in which the first capping layer, the first electrode 110, the interlayer 130, the second electrode 150, and the second capping layer are stacked in this stated order.

Light generated in an emission layer of the interlayer 130 of the light-emitting device 10 may be extracted toward the outside through the first electrode 110, which may be a semi-transmissive electrode or a transmissive electrode, and through the first capping layer; or light generated in an emission layer of the interlayer 130 of the light-emitting device 10 may be extracted toward the outside through the second electrode 150, which may be a semi-transmissive electrode or a transmissive electrode, and through the second capping layer.

The first capping layer and the second capping layer may each increase external luminescence efficiency according to the principle of constructive interference. Accordingly, the light extraction efficiency of the light-emitting device 10 is increased, so that the emission efficiency of the light-emitting device 10 may be improved.

The first capping layer and the second capping layer may each include a material having a refractive index equal to or greater than about 1.6 (with respect to a wavelength of about 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include a carbocyclic compound, a heterocyclic compound, an amine group-containing compound, a porphyrin derivative, a phthalocyanine derivative, a naphthalocyanine derivative, an alkali metal complex, an alkaline earth metal complex, or any combination thereof. The carbocyclic compound, the heterocyclic compound, and the amine group-containing compound may be optionally substituted with a substituent containing O, N, S, Se, Si, F, Cl, Br, I, or any combination thereof.

In an embodiment, at least one of the first capping layer and the second capping layer may each independently include an amine group-containing compound.

In an embodiment, at least one of the first capping layer and the second capping layer may each independently include a compound represented by Formula 201, a compound represented by Formula 202, or any combination thereof.

In an embodiment, at least one of the first capping layer and the second capping layer may each independently include one of Compounds HT28 to HT33, one of Compounds CP1 to CP6, β-NPB, or any combination thereof:

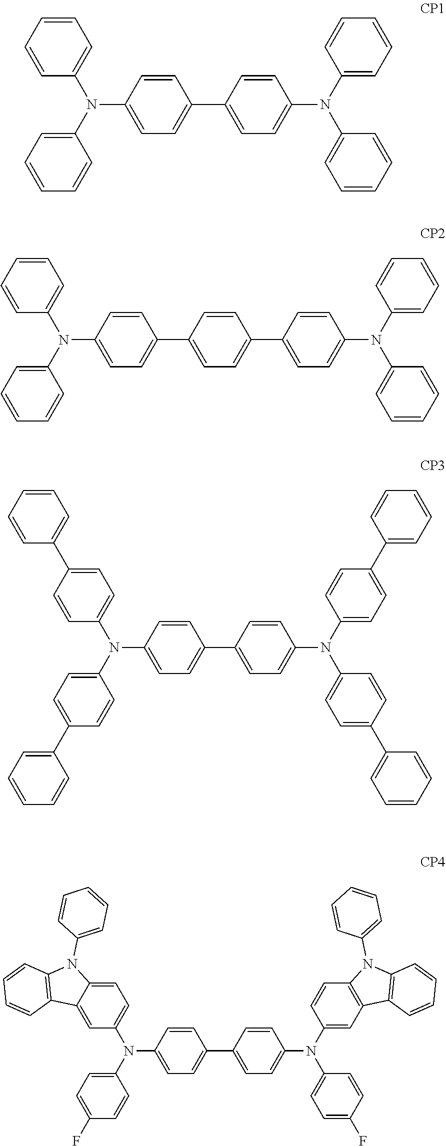 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

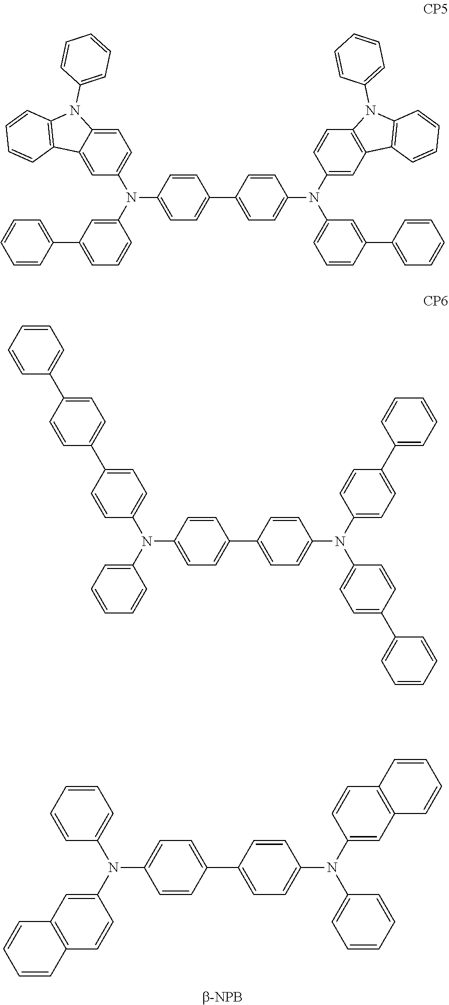 [SMILES: c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### [Electronic Apparatus]

The light-emitting device may be included in various electronic apparatuses. In an embodiment, the electronic apparatus including the light-emitting device may be a light-emitting apparatus, an authentication apparatus, or the like.

The electronic apparatus (for example, a light-emitting apparatus) may further include, in addition to the light-emitting device, a color filter, a color conversion layer, or a color filter and a color conversion layer. The color filter and/or the color conversion layer may be located in at least one traveling direction of light emitted from the light-emitting device. In an embodiment, the light emitted from the light-emitting device may be blue light. The light-emitting device may be the same as described above. In an embodiment, the color conversion layer may include quantum dots. The quantum dot may be, for example, a quantum dot as described herein.

The electronic apparatus may include a first substrate. The first substrate may include subpixels, the color filter may include color filter areas respectively corresponding to the subpixels, and the color conversion layer may include color conversion areas respectively corresponding to the subpixels.

A pixel-defining layer may be arranged between the subpixels to define each subpixel.

The color filter may further include color filter areas and light-shielding patterns located between the color filter areas, and the color conversion layer may include color conversion areas and light-shielding patterns located between the color conversion areas.

The color filter areas (or the color conversion areas) may include a first area emitting first color light, a second area emitting second color light, and/or a third area emitting third color light, and the first color light, the second color light, and/or the third color light may have different maximum emission wavelengths from one another. In an embodiment, the first color light may be red light, the second color light may be green light, and the third color light may be blue light. In an embodiment, the color filter areas (or the color conversion areas) may include quantum dots. For example, the first area may include a red quantum dot, the second area may include a green quantum dot, and the third area may not include a quantum dot. The quantum dot may be the same as described in the specification. The first area, the second area, and/or the third area may each further include a scatterer.

In an embodiment, the light-emitting device may emit a first light, the first area may absorb the first light to emit a first first-color light, the second area may absorb the first light to emit a second first-color light, and the third area may absorb the first light to emit a third first-color light. In this regard, the first first-color light, the second first-color light, and the third first-color light may have different maximum emission wavelengths from one another. For example, the first light may be blue light, the first first-color light may be red light, the second first-color light may be green light, and the third first-color light may be blue light.

The electronic apparatus may further include a thin-film transistor, in addition to the light-emitting device as described above. The thin-film transistor may include a source electrode, a drain electrode, and an active layer, wherein any one of the source electrode and the drain electrode may be electrically connected to any one of the first electrode and the second electrode of the light-emitting device.

The thin-film transistor may further include a gate electrode, a gate insulating film, etc.

The active layer may include crystalline silicon, amorphous silicon, organic semiconductor, oxide semiconductor, or the like.

The electronic apparatus may further include a sealing portion for sealing the light-emitting device. The sealing portion may be arranged between the color filter and/or the color-conversion layer, and the light-emitting device. The sealing portion may allow light from the light-emitting device to be extracted to the outside, and may simultaneously prevent ambient air and moisture from penetrating into the light-emitting device. The sealing portion may be a sealing substrate including a transparent glass substrate or a plastic substrate. The sealing portion may be a thin-film encapsulation layer including an organic layer and/or an inorganic layer. When the sealing portion is a thin-film encapsulation layer, the electronic apparatus may be flexible.

Various functional layers may be further included on the sealing portion, in addition to the color filter and/or the color conversion layer, according to the use of the electronic apparatus. Examples of a functional layer may include a touch screen layer, a polarizing layer, and the like. The touch screen layer may be a pressure-sensitive touch screen layer, a capacitive touch screen layer, or an infrared touch screen layer. The authentication apparatus may be, for example, a biometric authentication apparatus that authenticates an individual by utilizing biometric information of a living body (for example, fingertips, pupils, etc.).

The authentication apparatus may further include, in addition to the light-emitting device, a biometric information collector.

The electronic apparatus may be applied to various displays, light sources, lighting, personal computers (for example, a mobile personal computer), mobile phones, digital cameras, electronic diaries, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (for example, meters for a vehicle, an aircraft, and a vessel), projectors, and the like.

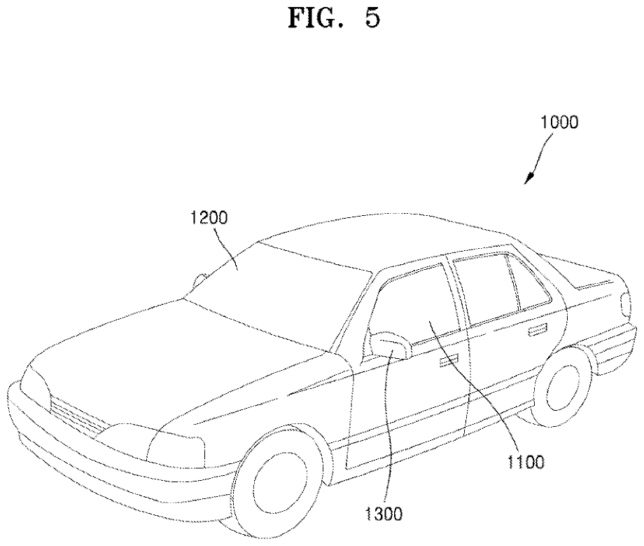

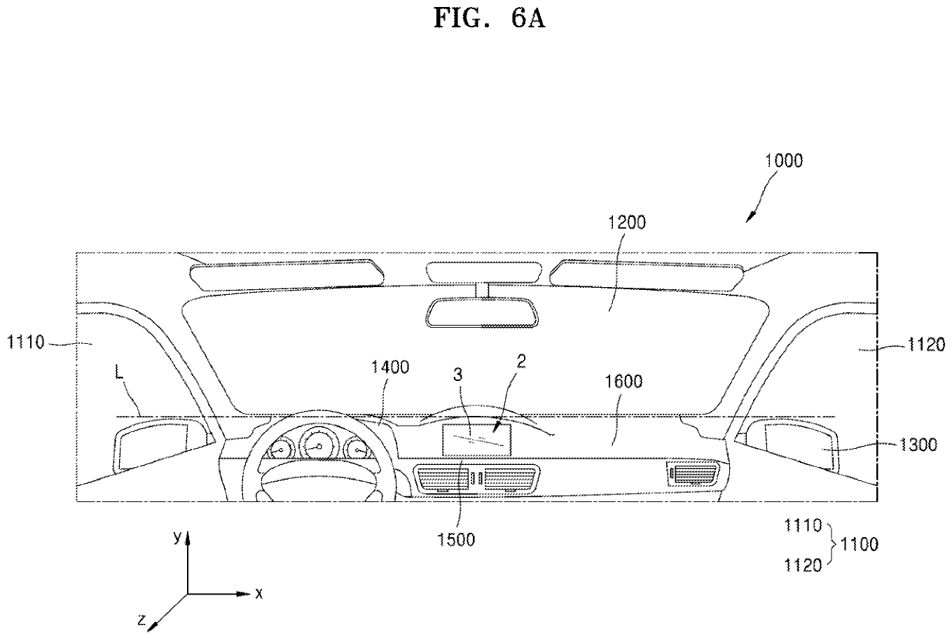

### [Description of FIGS. 3 and 4]

FIG. 3 is a schematic cross-sectional view of an electronic apparatus according to an embodiment.

The electronic apparatus of FIG. 3 includes a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be formed on the substrate 100. The buffer layer 210 may prevent penetration of impurities through the substrate 100 and may provide a flat surface on the substrate 100.

A TFT may be disposed on the buffer layer 210. The TFT may include an active layer 220, a gate electrode 240, a source electrode 260, and a drain electrode 270.

The active layer 220 may include an inorganic semiconductor such as silicon or polysilicon, an organic semiconductor, or an oxide semiconductor, and may include a source region, a drain region, and a channel region.

A gate insulating film 230 for insulating the active layer 220 from the gate electrode 240 may be disposed above the active layer 220, and the gate electrode 240 may be disposed above the gate insulating film 230.

An interlayer insulating film 250 may be disposed on the gate electrode 240. The interlayer insulating film 250 may be arranged between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be disposed on the interlayer insulating film 250. The interlayer insulating film 250 and the gate insulating film 230 may be formed to expose a source region and a drain region of the active layer 220, and the source electrode 260 and the drain electrode 270 may respectively contact the exposed portions of the source region and the drain region of the active layer 220.

The TFT is electrically connected to a light-emitting device to drive the light-emitting device, and is covered and protected by a passivation layer 280. The passivation layer 280 may include an inorganic insulating film, an organic insulating film, or a combination thereof. A light-emitting device is provided on the passivation layer 280. The light-emitting device may include a first electrode 110, an interlayer 130, and a second electrode 150.

The first electrode 110 may be disposed on the passivation layer 280. The passivation layer 280 may not completely cover the drain electrode 270 and may expose a region of the drain electrode 270. The first electrode 110 may be electrically connected to the exposed region of the drain electrode 270.

A pixel-defining layer 290 containing an insulating material may be disposed on the first electrode 110. The pixel-defining layer 290 exposes a region of the first electrode 110, and an interlayer 130 may be formed in the exposed region of the first electrode 110. The pixel-defining layer 290 may be a polyimide or polyacrylic organic film. Although not shown in FIG. 3, at least some layers of the interlayer 130 may extend beyond the upper portion of the pixel defining layer 290 and may thus be provided in the form of a common layer.

The second electrode 150 may be disposed on the interlayer 130, and a capping layer 170 may be further included on the second electrode 150. The capping layer 170 may be formed to cover the second electrode 150.

The encapsulation portion 300 may be disposed on the capping layer 170. The encapsulation portion 300 may be disposed on a light-emitting device to protect the light-emitting device from moisture and/or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, or the like), an epoxy-based resin (for example, aliphatic glycidyl ether (AGE), or the like), or any combination thereof; or a combination of the inorganic film and the organic film.

FIG. 4 is a schematic cross-sectional view of an electronic apparatus according to another embodiment.

The electronic apparatus of FIG. 4 may differ from the electronic apparatus of FIG. 3, at least in that a light-shielding pattern 500 and a functional region 400 are further included on the encapsulation portion 300. The functional region 400 may be a color filter area, a color conversion area, or a combination of the color filter area and the color conversion area. In an embodiment, the light-emitting device included in the electronic apparatus of FIG. 4 may be a tandem light-emitting device.

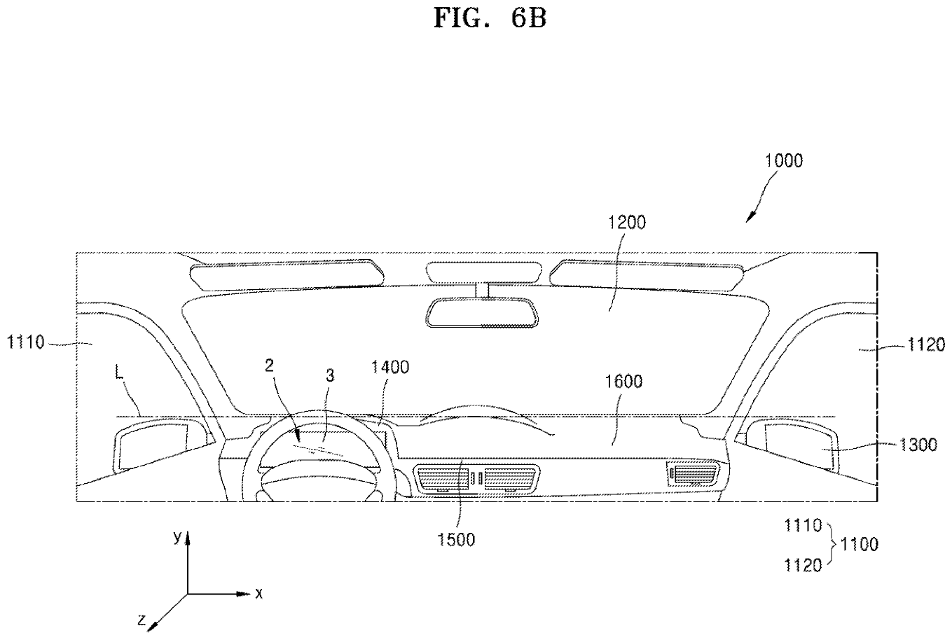

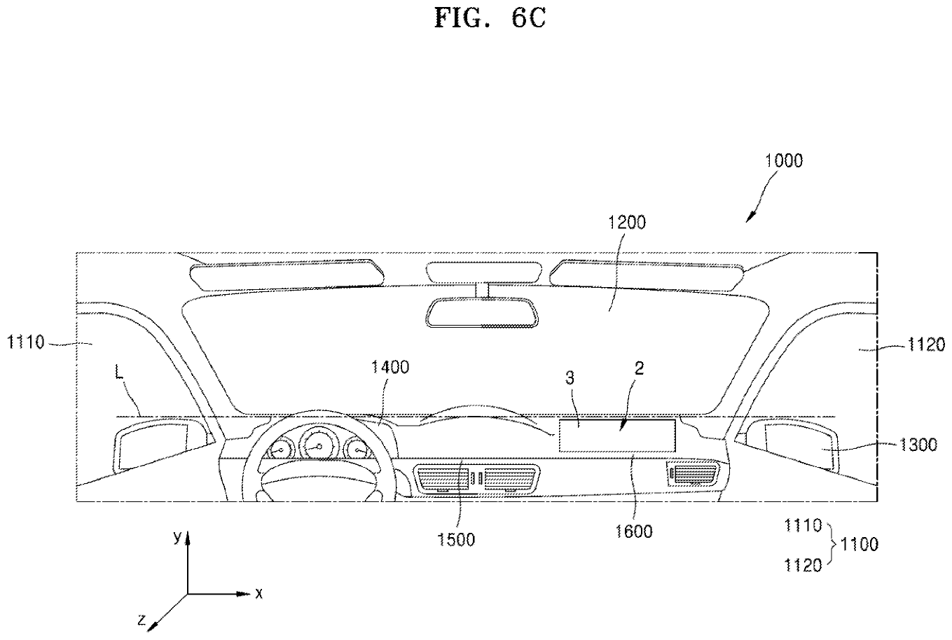

### [Descriptions of FIGS. 5 and 6A to 6C]

FIG. 5 is a schematic perspective view of an exterior of a vehicle 1000 as an electronic device including a light-emitting device, according to an embodiment. FIGS. 6A to 6C are each a schematic diagram of an interior of the vehicle 1000, according to embodiments.

Referring to FIGS. 5, 6A, 6B, and 6C, the vehicle 1000 may refer to various apparatuses for moving a subject to be transported, such as a person, an object, or an animal, from a departure point to a destination. Examples of a vehicle 1000 may include a vehicle traveling on a road or track, a vessel moving over the sea or river, and an airplane flying in the sky using the action of air.

The vehicle 1000 may travel on a road or track. The vehicle 1000 may move in a given direction according to the rotation of at least one wheel. In an embodiment, examples of the vehicle 1000 may include a three-wheeled or four-wheeled vehicle, a construction vehicle, a two-wheeled vehicle, a prime mover apparatus, a bicycle, and a train traveling on a track.

The vehicle 1000 may include a body having interior trims and exterior trims, and a chassis that is a portion excluding the body in which mechanical apparatuses necessary for driving are installed. The exterior trims of the body may include a front panel, a bonnet, a roof panel, a rear panel, a trunk, a door, and a pillar provided at a boundary between any of the aforementioned components. The chassis of the vehicle 1000 may include a power generating apparatus, a power transmitting apparatus, a driving apparatus, a steering apparatus, a braking apparatus, a suspension apparatus, a transmission apparatus, a fuel apparatus, and front, rear, left, and right wheels.

The vehicle 1000 may include a side window glass 1100, a front window glass 1200, a side-view mirror 1300, a cluster 1400, a center fascia 1500, a front passenger seat dashboard 1600, and a display apparatus 2.

The side window glass 1100 and the front window glass 1200 may be partitioned by a pillar between the side window glass 1100 and the front window glass 1200.

The side window glass 1100 may be installed on a side of the vehicle 1000. In an embodiment, the side window glass 1100 may be installed in a door of the vehicle 1000. Multiple side window glasses 1100 may be provided and may face each other. In an embodiment, the side window glass 1100 may include a first side window glass 1110 and a second side window glass 1120. In an embodiment, the first side window glass 1110 may be arranged adjacent to the cluster 1400, and the second side window glass 1120 may be arranged adjacent to the front passenger seat dashboard 1600.

In an embodiment, the side window glasses 1100 may be spaced apart from each other in an x direction or in a −x direction. For example, the first side window glass 1110 and the second side window glass 1120 may be spaced apart from each other in the x direction or in the −x direction. For example, a virtual straight line L connecting the side window glasses 1100 to each other may extend in the x direction or in the −x direction. For example, the virtual straight line L connecting the first side window glass 1110 to the second side window glass 1120 may extend in the x direction or in the −x direction.

The front window glass 1200 may be installed on front of the vehicle 1000. The front window glass 1200 may be arranged between the side window glasses 1100 facing each other.

The side-view mirror 1300 may provide a rear view of the vehicle 1000. The side-view mirror 1300 may be installed on the exterior trim of the body. In an embodiment, multiple side-view mirrors 1300 may be provided. One of the side-view mirrors 1300 may be arranged outside the first side window glass 1110. Another of the side-view mirrors 1300 may be arranged outside the second side window glass 1120.

The cluster 1400 may be located in front of a steering wheel. The cluster 1400 may include a tachometer, a speedometer, a coolant thermometer, a fuel gauge, and a turn signal indicator light, a high beam indicator light, a warning light, a seat belt warning light, an odometer, an automatic gear selector lever indicator light, a door open warning light, an engine oil warning light, and/or a low fuel warning light.

The center fascia 1500 may include a control panel on which buttons for adjusting an audio apparatus, an air conditioning apparatus, and a seat heater are arranged. The center fascia 1500 may be arranged on a side of the cluster 1400.

The front passenger seat dashboard 1600 may be spaced apart from the cluster 1400 with the center fascia 1500 therebetween. In an embodiment, the cluster 1400 may be arranged to correspond to a driver's seat (not shown), and the front passenger seat dashboard 1600 may be arranged to correspond to a front passenger seat (not shown). In an embodiment, the cluster 1400 may be adjacent to the first side window glass 1110, and the front passenger seat dashboard 1600 may be adjacent to the second side window glass 1120.

In an embodiment, the display apparatus 2 may include a display panel 3, and the display panel 3 may display an image. The display apparatus 2 may be arranged inside the vehicle 1000. In an embodiment, the display apparatus 2 may be arranged between the side window glasses 1100 facing each other. The display apparatus 2 may be arranged in at least one of the cluster 1400, the center fascia 1500, and the front passenger seat dashboard 1600.

The display apparatus 2 may include an organic light-emitting display, an inorganic electroluminescent (EL) light-emitting display (inorganic light-emitting display), and a quantum dot display. Hereinafter, an organic light-emitting display including a light-emitting device according to an embodiment is described as an example of the display apparatus 2 according to an embodiment, but in embodiments of the disclosure, various types of display apparatuses as described above may be used.

Referring to FIG. 6A, the display apparatus 2 may be arranged in the center fascia 1500. In an embodiment, the display apparatus 2 may display navigation information. In an embodiment, the display apparatus 2 may display information about audio settings, video settings, or vehicle settings.

Referring to FIG. 6B, the display apparatus 2 may be arranged in the cluster 1400. The cluster 1400 may express driving information and the like through the display apparatus 2. For example, the cluster 1400 may digitally implement driving information. The digital cluster 1400 may display vehicle information and driving information as images. For example, a tachometer needle, gauges, and various warning light icons may be displayed by digital signals.

Referring to FIG. 6C, the display apparatus 2 may be arranged in the front passenger seat dashboard 1600. The display apparatus 2 may be embedded in the front passenger seat dashboard 1600 or may be located on the front passenger seat dashboard 1600. In an embodiment, the display apparatus 2 arranged on the front passenger seat dashboard 1600 may display an image related to information displayed on the cluster 1400 and/or an image related to information displayed on the center fascia 1500. In an embodiment, the display apparatus 2 arranged on the front passenger seat dashboard 1600 may display information that is different from the information displayed on the cluster 1400 and/or the information displayed on the center fascia 1500.

### [Manufacture Method]

Respective layers included in the hole transport region, the emission layer, and respective layers included in the electron transport region may be formed in a selected region by using one or more suitable methods selected from vacuum deposition, spin coating, casting, Langmuir-Blodgett (LB) deposition, ink-jet printing, laser-printing, and laser-induced thermal imaging.

When layers constituting the hole transport region, an emission layer, and layers constituting the electron transport region are formed by vacuum deposition, the deposition may be performed at a deposition temperature of about 100° C. to about 500° C., a vacuum degree of about 10-8 torr to about 10-3 torr, and a deposition speed of about 0.01 Å/sec to about 100 Å/sec, depending on a material to be included in a layer to be formed and the structure of a layer to be formed.

When layers constituting the hole transport region, an emission layer, and layers constituting the electron transport region are formed by spin coating, the spin coating may be performed at a coating speed of about 2,000 rpm to about 5,000 rpm and at a heat treatment temperature of about 80° C. to about 200° ° C. by taking into account a material to be included in a layer to be formed and a structure of a layer to be formed.

### [Definitions of Terms]

The term “C₃-C₆₀ carbocyclic group” as used herein may be a cyclic group consisting of carbon as the only ring-forming atoms and having three to sixty carbon atoms, and the term “C₁-C₆₀ heterocyclic group” as used herein may be a cyclic group that has one to sixty carbon atoms and further has, in addition to carbon, at least one heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. In an embodiment, a C₁-C₆₀ heterocyclic group may have 3 to 61 ring-forming atoms.

The term “cyclic group” as used herein may be a C₃-C₆₀ carbocyclic group or a C₁-C₆₀ heterocyclic group.

The term “π electron-rich C₃-C₆₀ cyclic group” as used herein may be a cyclic group that has three to sixty carbon atoms and may not include *—N═*′ as a ring-forming moiety, and the term “π electron-deficient nitrogen-containing C₁-C₆₀ cyclic group” as used herein may be a heterocyclic group that has one to sixty carbon atoms and may include *—N═*′ as a ring-forming moiety.

In embodiments,
a C₃-C₆₀ carbocyclic group may be a T1 group or a group in which two or more T1 groups are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
a C₁-C₆₀ heterocyclic group may be a T2 group, a group in which two or more T2 groups are condensed with each other, or a group in which at least one T2 group and at least one T1 group are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
a π electron-rich C₃-C₆₀ cyclic group may be a T1 group, a group in which two or more T1 groups are condensed with each other, a T3 group, a group in which two or more T3 groups are condensed with each other, or a group in which at least one T3 group and at least one T1 group are condensed with each other (for example, a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.), and
a π electron-deficient nitrogen-containing C₁-C₆₀ cyclic group may be a T4 group, a group in which two or more T4 groups are condensed with each other, a group in which at least one T4 group and at least one T1 group are condensed with each other, a group in which at least one T4 group and at least one T3 group are condensed with each other, or a group in which at least one T4 group, at least one T1 group, and at least one T3 group are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
wherein the T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group,
the T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
the T3 group may be a furan group, a thiophene group, a 1H-pyrrole group, a silole group, or a borole group, and
the T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group”, “C₃-C₆₀ carbocyclic group”, “C₁-C₆₀ heterocyclic group”, “π electron-rich C₃-C₆₀ cyclic group”, or “π electron-deficient nitrogen-containing C₁-C₆₀ cyclic group” as used herein may each be a group condensed to any cyclic group, a monovalent group, or a polyvalent group (for example, a divalent group, a trivalent group, a tetravalent group, etc.), depending on the structure of a formula in connection with which the terms are used. For example, a “benzene group” may be a benzo group, a phenyl group, a phenylene group, or the like, which may be readily understood by those of ordinary skill in the art according to the structure of a formula including the “benzene group.”

Examples of a monovalent C₃-C₆₀ carbocyclic group or a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of a divalent C₃-C₆₀ carbocyclic group or a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein may be a linear or branched aliphatic hydrocarbon monovalent group that has one to sixty carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as used herein may be a divalent group having a same structure as the C₁-C₆₀ alkyl group.

The term “C₂-C₆₀ alkenyl group” as used herein may be a monovalent hydrocarbon group having at least one carbon-carbon double bond in the middle or at a terminus of a C₂-C₆₀ alkyl group, and examples thereof may include an ethenyl group, a propenyl group, and a butenyl group. The term “C₂-C₆₀ alkenylene group” as used herein may be a divalent group having a same structure as the C₂-C₆₀ alkenyl group.

The term “C₂-C₆₀ alkynyl group” as used herein may be a monovalent hydrocarbon group having at least one carbon-carbon triple bond in the middle or at a terminus of a C₂-C₆₀ alkyl group, and examples thereof may include an ethynyl group and a propynyl group. The term “C₂-C₆₀ alkynylene group” as used herein may be a divalent group having a same structure as the C₂-C₆₀ alkynyl group.

The term “C₁-C₆₀ alkoxy group” as used herein may be a monovalent group represented by —O(A₁₀₁) (wherein A₁₀₁ may be C₁-C₆₀ alkyl group), and examples thereof may include a methoxy group, an ethoxy group, and an isopropyloxy group.

The term “C₃-C₁₀ cycloalkyl group” as used herein may be a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or a bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as used herein may be a divalent group having a same structure as the C₃-C₁₀ cycloalkyl group.

The term “C₁-C₁₀ heterocycloalkyl group” as used herein may be a monovalent cyclic group that further includes, in addition to a carbon atom, at least one heteroatom as a ring-forming atom and has 1 to 10 carbon atoms, and examples thereof may include a 1,2,3,4-oxatriazolidinyl group, a tetrahydrofuranyl group, and a tetrahydrothiophenyl group. The term “C₁-C₁₀ heterocycloalkylene group” as used herein may be a divalent group having a same structure as the C₁-C₁₀ heterocycloalkyl group.

The term “C₃-C₁₀ cycloalkenyl group” as used herein may be a monovalent cyclic group that has three to ten carbon atoms and at least one carbon-carbon double bond in the ring thereof and no aromaticity, and examples thereof may include a cyclopentenyl group, a cyclohexenyl group, and a cycloheptenyl group. The term “C₃-C₁₀ cycloalkenylene group” as used herein may be a divalent group having a same structure as the C₃-C₁₀ cycloalkenyl group.

The term “C₁-C₁₀ heterocycloalkenyl group” as used herein may be a monovalent cyclic group that has, in addition to a carbon atom, at least one heteroatom as a ring-forming atom, 1 to 10 carbon atoms, and at least one double bond in the cyclic structure thereof. Examples of a C₁-C₁₀ heterocycloalkenyl group may include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as used herein may be a divalent group having a same structure as the C₁-C₁₀ heterocycloalkenyl group.

The term “C₆-C₆₀ aryl group” as used herein may be a monovalent group having a carbocyclic aromatic system having six to sixty carbon atoms, and the term “C₆-C₆₀ arylene group” as used herein may be a divalent group having a carbocyclic aromatic system having six to sixty carbon atoms. Examples of a C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each include two or more rings, the respective rings may be condensed with each other.

The term “C₁-C₆₀ heteroaryl group” as used herein may be a monovalent group having a heterocyclic aromatic system that has, in addition to a carbon atom, at least one heteroatom as a ring-forming atom, and 1 to 60 carbon atoms. The term “C₁-C₆₀ heteroarylene group” as used herein may be a divalent group having a heterocyclic aromatic system that has, in addition to a carbon atom, at least one heteroatom as a ring-forming atom, and 1 to 60 carbon atoms. Examples of a C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the respective rings may be condensed with each other.

The term “monovalent non-aromatic condensed polycyclic group” as used herein may be a monovalent group having two or more rings condensed to each other, only carbon atoms (for example, having 8 to 60 carbon atoms) as ring-forming atoms, and non-aromaticity in its molecular structure when considered as a whole. Examples of a monovalent non-aromatic condensed polycyclic group may include an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as used herein may be a divalent group having a same structure as a monovalent non-aromatic condensed polycyclic group.

The term “monovalent non-aromatic condensed heteropolycyclic group” as used herein may be a monovalent group having two or more rings condensed to each other, at least one heteroatom other than carbon atoms (for example, having 1 to 60 carbon atoms), as a ring-forming atom, and non-aromaticity in its molecular structure when considered as a whole. Examples of a monovalent non-aromatic condensed heteropolycyclic group may include a pyrrolyl group, a thiophenyl group, a furanyl group, an indolyl group, a benzoindolyl group, a naphtho indolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein may be a divalent group having a same structure as a monovalent non-aromatic condensed heteropolycyclic group.

The term “C₆-C₆₀ aryloxy group” as used herein may be a group represented by —O(A₁₀₂) (wherein A₁₀₂ may be C₆-C₆₀ aryl group), and the term “C₆-C₆₀ arylthio group” as used herein may be a group represented by —S(A₁₀₃) (wherein A₁₀₃ may be C₆-C₆₀ aryl group).

The term “C₇-C₆₀ arylalkyl group” as used herein may be a group represented by -(A₁₀₄) (A₁₀₅) (wherein A₁₀₄ may be a C₁-C₅₄ alkylene group, and A₁₀₅ may be a C₆-C₅₉ aryl group), and the term “C₂-C₆₀ heteroarylalkyl group” as used herein may be a group represented by -(A₁₀₆) (A₁₀₇) (wherein A₁₀₆ may be a C₁-C₅₉ alkylene group, and A₁₀₇ may be a C₁-C₅₉ heteroaryl group).

In the specification, the group R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁) (Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the specification, Q₁, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as used herein may be any atom other than a carbon atom or a hydrogen atom. Examples of a heteroatom include O, S, N, P, Si, B, Ge, Se, or any combination thereof.

The term “third-row transition metal” as used herein may be hafnium (Hf), tantalum (Ta), tungsten (W), rhenium (Re), osmium (Os), iridium (Ir), platinum (Pt), gold (Au), or the like.

The term “Ph” as used herein refers to a phenyl group, the term “Me” as used herein refers to a methyl group, the term “Et” as used herein refers to an ethyl group, the terms “ter-Bu” or “But” as used herein each refer to a tert-butyl group, and the term “OMe” as used herein refers to a methoxy group.

The term “biphenyl group” as used herein may be a “phenyl group substituted with a phenyl group.” For example, a “biphenyl group” may be a substituted phenyl group having a C₆-C₆₀ aryl group as a substituent.

The term “terphenyl group” as used herein may be a “phenyl group substituted with a biphenyl group”. For example, a “terphenyl group” may be a substituted phenyl group having, as a substituent, a C₆-C₆₀ aryl group substituted with a C₆-C₆₀ aryl group.

The symbols * and *′ as used herein, unless defined otherwise, each refer to a binding site to a neighboring atom in a corresponding formula.

Hereinafter, a compound and a light-emitting device according to an embodiment will be described in detail with reference to the following Examples.

### Examples

### Manufacture of Light-Emitting Device

### Comparative Example 1 (No Second Electron Transport Layer)

A 15 Ω/cm² ITO/Ag/ITO (120 Å/500 Å/120 Å) glass substrate (a product of Corning Inc.) was cut to a size of 50 mm×50 mm×0.7 mm, sonicated with isopropyl alcohol and pure water each for 5 minutes, and cleaned by irradiation of ultraviolet rays and exposure to ozone for 15 minutes. The resultant glass substrate was loaded onto a vacuum deposition apparatus.

HATCN was deposited on the ITO/Ag/ITO anode of the glass substrate to form a hole injection layer having a thickness of 50 Å, NPB was deposited on the hole injection layer to form a hole transport layer having a thickness of 300 Å, and TCTA was deposited on the hole transport layer to form an auxiliary layer having a thickness of 50 Å.

BH1 and BD were co-deposited on the auxiliary layer at a weight ratio of 97:3 to form a first emission layer (blue) having a thickness of 85 Å, and BH2 and BD were co-deposited on the first emission layer at a weight ratio of 97:3 to form a second emission layer (blue) having a thickness of 85 Å. HB1 was deposited on the second emission layer to form a first electron transport layer having a thickness of 50 Å, and without formation of a second electron transport layer, ET5 and Liq were co-deposited on the first electron transport layer at a weight ratio of 1:1 to form a third electron transport layer having a thickness of 100 Å [first emitting unit].

CG1 and Li were co-deposited on the third electron transport layer at a weight ratio of 99:1 to form an n-type charge generation layer having a thickness of 50 Å, and HATCN was deposited on the n-type charge generation layer to form a p-type charge generation layer having a thickness of 50 Å.

NPB was deposited on the p-type charge generation layer to form a hole transport layer having a thickness of 500 Å, and TCTA was deposited on the hole transport layer to form an auxiliary layer having a thickness of 50 Å.

BH1 and BD were co-deposited on the auxiliary layer at a weight ratio of 97:3 to form a first emission layer (blue) having a thickness of 85 Å, and BH2 and BD were co-deposited on the first emission layer at a weight ratio of 97:3 to form a second emission layer (blue) having a thickness of 85 Å. HB1 was deposited on the second emission layer to form a first electron transport layer having a thickness of 50 Å, and without formation of the second electron transport layer, ET5 and Liq were co-deposited on the first electron transport layer at a weight ratio of 1:1 to form a third electron transport layer having a thickness of 100 Å [second emitting unit].

CG1 and Li were co-deposited on the third electron transport layer at a weight ratio of 99:1 to form an n-type charge generation layer having a thickness of 50 Å, and HATCN was deposited on the n-type charge generation layer to form a p-type charge generation layer having a thickness of 50 Å.

NPB was deposited on the p-type charge generation layer to form a hole transport layer having a thickness of 150 Å, TPBI and Ir(ppy)₃ were co-deposited on the hole transport layer at a weight ratio of 97:3 to form an emission layer (green) having a thickness of 150 Å, and TPM-TAZ and Liq were co-deposited on the emission layer at a weight ratio of 1:1 to form an electron transport layer having a thickness of 100 Å [third emitting unit].

CG1 and Li were co-deposited on the electron transport layer at a weight ratio of 99:1 to form an n-type charge generation layer having a thickness of 50 Å, and HATCN was deposited on the n-type charge generation layer to form a p-type charge generation layer having a thickness of 50 Å.

NPB was deposited on the p-type charge generation layer to form a hole transport layer having a thickness of 150 Å, and TCTA was deposited on the hole transport layer to form an auxiliary layer having a thickness of 50 Å.

BH1 and BD were co-deposited on the auxiliary layer at a weight ratio of 97:3 to form a first emission layer (blue) having a thickness of 85 Å, and BH2 and BD were co-deposited on the first emission layer at a weight ratio of 97:3 to form a second emission layer (blue) having a thickness of 85 Å. HB1 was deposited on the second emission layer to form a first electron transport layer having a thickness of 50 Å, and without formation of the second electron transport layer, ET5 and Liq were co-deposited on the first electron transport layer at a weight ratio of 1:1 to form a third electron transport layer having a thickness of 100 Å [fourth emitting unit].

CG1 and Li were co-deposited on the third electron transport layer at a weight ratio of 99:1 to form an n-type charge generation layer having a thickness of 50 Å, and HATCN was deposited on the n-type charge generation layer to form a p-type charge generation layer having a thickness of 50 Å.

NPB was deposited on the p-type charge generation layer to form a hole transport layer having a thickness of 300 Å, TPBI and Ir(ppy)₃ were co-deposited on the hole transport layer at a weight ratio of 97:3 to form an emission layer (green) having a thickness of 150 Å, and TPM-TAZ and Liq were co-deposited on the emission layer at a weight ratio of 1:1 to form an electron transport layer having a thickness of 300 Å [fifth emitting unit].

Yb was deposited on the electron transport layer to a thickness of 10 Å, Ag and Mg were co-deposited thereon at a weight ratio of 9:1 to form a cathode having a thickness of 100 Å, and CPL was deposited on the cathode to form a capping layer having a thickness of 700 Å, thereby completing the manufacture of a tandem light-emitting device.

### Comparative Examples 2 to 14 (No Second Electron Transport Layer)

Tandem light-emitting devices were manufactured in the same manner as in Comparative Example 1, except that the first and third electron transport layers of the first, second, and fourth emitting units were formed of compounds shown in Table 1 below. Results of the light-emitting devices are shown in Table 1.

Driving voltages of the light-emitting devices source were measured by using a source meter (Keithley Instrument Inc., 2400 series), and efficiencies and lifespans thereof were measured by using a measurement apparatus C9920-2-12 of Hamamatsu Photonics Inc.

TABLE 1

| | First | | Third | | | |
|---|---|---|---|---|---|---|
| | electron | Second | electron | | | |
| | transport | electron | transport | | | |
| | layer | transport | layer | Driving | | |
| | (50 Å) | layer | (100 Å) | voltage | Efficiency | Lifespan |
| Comparative | HB1 | None | ET5:Liq | 100% | 100% | 100% |
| Example 1 | | | | | | |
| Comparative | HB1 | None | ET6:Liq | 100% | 100% | 99% |
| Example 2 | | | | | | |
| Comparative | HB1 | None | ET5 | 160% | 95% | 74% |
| Example 3 | | | | | | |
| Comparative | HB1 | None | ET6 | 150% | 98% | 70% |
| Example 4 | | | | | | |
| Comparative | HB1 | None | ET1 | 98% | 104% | 100% |
| Example 5 | | | | | | |
| Comparative | HB1 | None | ET2 | 97% | 103% | 100% |
| Example 6 | | | | | | |
| Comparative | HB1 | None | ET3 | 98% | 104% | 99% |
| Example 7 | | | | | | |
| Comparative | HB1 | None | ET4 | 99% | 103% | 98% |
| Example 8 | | | | | | |
| Comparative | HB2 | None | ET5:Liq | 102% | 95% | 96% |
| Example 9 | | | | | | |
| Comparative | HB2 | None | ET6:Liq | 103% | 95% | 97% |
| Example 10 | | | | | | |
| Comparative | HB2 | None | ET1 | 101% | 101% | 96% |
| Example 11 | | | | | | |
| Comparative | HB2 | None | ET2 | 101% | 100% | 95% |
| Example 12 | | | | | | |
| Comparative | HB2 | None | ET3 | 100% | 101% | 96% |
| Example 13 | | | | | | |
| Comparative | HB2 | None | ET4 | 101% | 100% | 95% |
| Example 14 | | | | | | |

Referring to Table 1, in the case of Comparative Examples 3 and 4, it was found out that device operation is unstable without a metal complex (Liq).

### Comparative Examples 15 to 20 (No Second Electron Transport Layer)

Tandem light-emitting devices were manufactured in the same manner as in Comparative Example 1, except that the first and third electron transport layers of the first, second, and fourth emitting units were formed of compounds shown in Table 2 below. Results of the light-emitting devices are shown in Table 2.

### Example 1 to 6

Tandem light-emitting devices were manufactured in the same manner as in Comparative Example 1, except that the first, second, and third electron transport layers of the first, second, and fourth emitting units were formed of compounds (in the case of multiple compounds, a weight ratio is shown) shown in Table 2, and were formed to have layer thicknesses shown in Table 2. Results of the light-emitting devices are shown in Table 2.

TABLE 2

| | First | | Third | | | |
|---|---|---|---|---|---|---|
| | electron | Second | electron | | | |
| | transport | electron | transport | | | |
| | layer | transport | layer | Driving | | |
| | (50 Å) | layer | (100 Å) | voltage | Efficiency | Lifespan |
| Comparative | HB1 | None | ET1:ET2 = | 97% | 105% | 100% |
| Example 15 | | | 7:3 | | | |
| Comparative | HB1 | None | ET3:ET4 = | 98% | 103% | 101% |
| Example 16 | | | 7:3 | | | |
| Comparative | HB1 | None | ET1:ET3 = | 97% | 104% | 103% |
| Example 17 | | | 7:3 | | | |
| Comparative | HB1 | None | ET1:ET4 = | 98% | 103% | 102% |
| Example 18 | | | 7:3 | | | |
| Comparative | HB1 | None | ET2:ET3 = | 98% | 103% | 101% |
| Example 19 | | | 7:3 | | | |
| Comparative | HB1 | None | ET2:ET4 = | 97% | 104% | 100% |
| Example 20 | | | 7:3 | | | |

| | First | Second | Third | | | |
|---|---|---|---|---|---|---|
| | electron | electron | electron | | | |
| | transport | transport | transport | | | |
| | layer | layer | layer | | | |
| | (40 Å) | (70 Å) | (40 Å) | | | |
| Example 1 | HB1 | HB1:ET1:ET2 = | ET1:ET2 = | 90% | 121% | 140% |
| | | 10:7:3 | 7:3 | | | |
| Example 2 | HB1 | HB1:ET3:ET4 = | ET3:ET4 = | 89% | 117% | 135% |
| | | 10:7:3 | 7:3 | | | |
| Example 3 | HB1 | HB1:ET1:ET3 = | ET1:ET3 = | 87% | 116% | 132% |
| | | 10:7:3 | 7:3 | | | |
| Example 4 | HB1 | HB1:ET1:ET4 = | ET1:ET4 = | 91% | 117% | 130% |
| | | 10:7:3 | 7:3 | | | |
| Example 5 | HB1 | HB1:ET2:ET3 = | ET2:ET3 = | 92% | 117% | 133% |
| | | 10:7:3 | 7:3 | | | |
| Example 6 | HB1 | HB1:ET2:ET4 = | ET2:ET4 = | 88% | 118% | 135% |
| | | 10:7:3 | 7:3 | | | |

Referring to Table 2, it was found out that the devices of the Examples exhibited better results than the devices of Comparative Examples.

### HOMO and LUMO Energy Values of Compounds

HOMO and LUMO energy values of compounds of the second host compound, the first compound, the second compound, the third compound, and the n-type charge generation layer of the light-emitting device are shown in Table 3.

TABLE 3

| | HOMO energy | LUMO energy |
|---|---|---|
| | value (eV) | value (eV) |
| Second host compound | BH2: −5.66 | BH2: −2.60 |
| First compound | HB1: −6.25 | HB1: −2.73 |
| Second compound and | ET1: −5.60 | ET1: −2.81 |
| Third compound | ET2: −5.60 | ET2: −2.79 |
| | ET3: −5.62 | ET3: −2.78 |
| | ET4: −5.61 | ET4: −2.80 |
| n-type charge generation | CG1: −5.92 | CG1: −2.66 |
| layer compound | | |

### Comparative Examples 21 to 26

Tandem light-emitting devices were manufactured in the same manner as in Comparative Example 1, except that the first and third electron transport layers of the first, second, and fourth emitting units were formed of compounds (in the case of multiple compounds, a weight ratio is shown) shown in Table 4. Results of the light-emitting devices are shown in Table 4.

### Examples 7 to 12

Tandem light-emitting devices were manufactured in the same manner as in Comparative Example 1, except that the first, second, and third electron transport layers of the first, second, and fourth emitting units were formed of compounds (in the case of multiple compounds, a weight ratio is shown) shown in Table 4, and were formed to have layer thicknesses shown in Table 4. Results of the light-emitting devices are shown in Table 4.

TABLE 4

| | First | | Third | | | |
|---|---|---|---|---|---|---|
| | electron | Second | electron | | | |
| | transport | electron | transport | | | |
| | layer | transport | layer | Driving | | |
| | (50 Å) | layer | (100 Å) | voltage | Efficiency | Lifespan |
| Comparative | HB2 | None | ET1:ET2 = | 100% | 102% | 98% |
| Example 21 | | | 7:3 | | | |
| Comparative | HB2 | None | ET3:ET4 = | 101% | 100% | 97% |
| Example 22 | | | 7:3 | | | |
| Comparative | HB2 | None | ET1:ET3 = | 100% | 101% | 96% |
| Example 23 | | | 7:3 | | | |
| Comparative | HB2 | None | ET1:ET4 = | 101% | 100% | 98% |
| Example 24 | | | 7:3 | | | |
| Comparative | HB2 | None | ET2:ET3 = | 100% | 100% | 97% |
| Example 25 | | | 7:3 | | | |
| Comparative | HB2 | None | ET2:ET4 = | 99% | 101% | 97% |
| Example 26 | | | 7:3 | | | |

| | First | Second | Third | | | |
|---|---|---|---|---|---|---|
| | electron | electron | electron | | | |
| | transport | transport | transport | | | |
| | layer | layer | layer | | | |
| | (40 Å) | (70 Å) | (40 Å) | | | |
| Example 7 | HB2 | HB2:ET1:ET2 = | ET1:ET2 = | 92% | 118% | 126% |
| | | 10:7:3 | 7:3 | | | |
| Example 8 | HB2 | HB2:ET3:ET4 = | ET3:ET4 = | 93% | 114% | 120% |
| | | 10:7:3 | 7:3 | | | |
| Example 9 | HB2 | HB2:ET1:ET3 = | ET1:ET3 = | 95% | 112% | 121% |
| | | 10:7:3 | 7:3 | | | |
| Example 10 | HB2 | HB2:ET1:ET4 = | ET1:ET4 = | 93% | 112% | 122% |
| | | 10:7:3 | 7:3 | | | |
| Example 11 | HB2 | HB2:ET2:ET3 = | ET2:ET3 = | 94% | 113% | 123% |
| | | 10:7:3 | 7:3 | | | |
| Example 12 | HB2 | HB2:ET2:ET4 = | ET2:ET4 = | 93% | 112% | 120% |
| | | 10:7:3 | 7:3 | | | |

Referring to Table 4, it was found out that the devices of Examples exhibited better results than the devices of Comparative Examples.

### HOMO and LUMO Energy Values of Compounds

HOMO and LUMO energy values of compounds of the second host compound, the first compound, the second compound, the third compound, and the n-type charge generation layer of the light-emitting device are shown in Table 5.

TABLE 5

| | HOMO energy | LUMO energy |
|---|---|---|
| | value (eV) | value (eV) |
| Second host compound | BH2: −5.66 | BH2: −2.60 |
| First compound | HB1: −6.25 | HB1: −2.73 |
| Second compound and | ET1: −5.60 | ET1: −2.81 |
| Third compound | ET2: −5.60 | ET2: −2.79 |
| | ET3: −5.62 | ET3: −2.78 |
| | ET4: −5.61 | ET4: −2.80 |
| n-type charge generation | CG1: −5.92 | CG1: −2.66 |
| layer compound | | |

### Comparative Examples 27 to 30

Tandem light-emitting devices were manufactured in the same manner as in Comparative Example 1, except that the first and third electron transport layers of the first, second, and fourth emitting units were formed of compounds (in the case of multiple compounds, a weight ratio is shown) shown in Table 6. Results of the light-emitting devices are shown in Table 6.

### Examples 13 to 16

Tandem light-emitting devices were manufactured in the same manner as in Comparative Example 1, except that the first, second, and third electron transport layers of the first, second, and fourth emitting units were formed of compounds (in the case of multiple compounds, a weight ratio is shown) shown in Table 6, and were formed to have layer thicknesses shown in Table 6. Results of the light-emitting devices are shown in Table 6.

TABLE 6

| | First | | Third | | | |
|---|---|---|---|---|---|---|
| | electron | Second | electron | | | |
| | transport | electron | transport | | | |
| | layer | transport | layer | Driving | | |
| | (50 Å) | layer | (100 Å) | voltage | Efficiency | Lifespan |
| Comparative | HB1 | None | ET1:ET5 = | 100% | 101% | 99% |
| Example 27 | | | 7:3 | | | |
| Comparative | HB1 | None | ET2:ET5 = | 101% | 100% | 100% |
| Example 28 | | | 7:3 | | | |
| Comparative | HB1 | None | ET3:ET5 = | 100% | 99% | 100% |
| Example 29 | | | 7:3 | | | |
| Comparative | HB1 | None | ET4:ET5 = | 101% | 99% | 99% |
| Example 30 | | | 7:3 | | | |

| | First | Second | Third | | | |
|---|---|---|---|---|---|---|
| | electron | electron | electron | | | |
| | transport | transport | transport | | | |
| | layer | layer | layer | | | |
| | (40 Å) | (70 Å) | (40 Å) | | | |
| Example 13 | HB1 | HB1:ET1:ET5 = | ET1:ET5 = | 96% | 115% | 121% |
| | | 10:7:3 | 7:3 | | | |
| Example 14 | HB1 | HB1:ET2:ET5 = | ET2:ET5 = | 97% | 112% | 118% |
| | | 10:7:3 | 7:3 | | | |
| Example 15 | HB1 | HB1:ET3:ET5 = | ET3:ET5 = | 98% | 110% | 115% |
| | | 10:7:3 | 7:3 | | | |
| Example 16 | HB1 | HB1:ET4:ET5 = | ET4:ET5 = | 99% | 111% | 114% |
| | | 10:7:3 | 7:3 | | | |

Referring to Table 6, it was found out that the devices of Examples exhibited better results than the devices of Comparative Examples.

### HOMO and LUMO Energy Values of Compounds

HOMO and LUMO energy values of compounds of the second host compound, the first compound, the second compound, the third compound, and the n-type charge generation layer of the light-emitting device are shown in Table 7.

TABLE 7

| | HOMO energy | LUMO energy |
|---|---|---|
| | value (eV) | value (eV) |
| Second host compound | BH2: −5.66 | BH2: −2.60 |
| First compound | HB1: −6.25 | HB1: −2.73 |
| Second compound and | ET1: −5.60 | ET1: −2.81 |
| Third compound | ET2: −5.60 | ET2: −2.79 |
| | ET3: −5.62 | ET3: −2.78 |
| | ET4: −5.61 | ET4: −2.80 |
| | ET5: −5.51 | ET5: −2.54 |
| n-type charge generation | CG1: −5.92 | CG1: −2.66 |
| layer compound | | |

### Comparative Examples 31 and 32

Tandem light-emitting devices were manufactured in the same manner as in Comparative Example 1, except that the first, second, and third electron transport layers of the first, second, and fourth emitting units were formed of compounds (in the case of multiple compounds, a weight ratio is shown) shown in Table 8, and were formed to have layer thicknesses shown in Table 8. Results of the light-emitting devices are shown in Table 8.

### Examples 17 to 24

Tandem light-emitting devices were manufactured in the same manner as in Comparative Example 1, except that the first, second, and third electron transport layers of the first, second, and fourth emitting units were formed of compounds (in the case of multiple compounds, a weight ratio is shown) shown in Table 8, and were formed to have layer thicknesses shown in Table 8. Results of the light-emitting devices are shown in Table 8.

TABLE 8

| | First | Second | Third | | | |
|---|---|---|---|---|---|---|
| | electron | electron | electron | | | |
| | transport | transport | transport | | | |
| | layer | layer | layer | Driving | | |
| | (thickness) | (thickness) | (thickness) | Voltage | Efficiency | Lifespan |
| Comparative | HB1 (50 Å) | None | ET1:ET2 = | 97% | 105% | 100% |
| Example 1 | | | 7:3 (100 Å) | | | |
| Example 1 | HB1 (40 Å) | HB1:ET1:ET2 = | ET1:ET2 = | 90% | 121% | 140% |
| | | 10:7:3 (70 Å) | 7:3 (40 Å) | | | |
| Example 17 | HB1 (40 Å) | HB1:ET1:ET2 = | ET1:ET2 = | 93% | 117% | 135% |
| | | 10:9:1 (70 Å) | 9:1 (40 Å) | | | |
| Example 18 | HB1 (40 Å) | HB1:ET1:ET2 = | ET1:ET2 = | 95% | 119% | 138% |
| | | 10:5:5 (70 Å) | 5:5 (40 Å) | | | |
| Example 19 | HB1 (40 Å) | HB1:ET1:ET2 = | ET1:ET2 = | 95% | 118% | 136% |
| | | 10:3:7 (70 Å) | 3:7 (40 Å) | | | |
| Example 20 | HB1 (40 Å) | HB1:ET1:ET2 = | ET1:ET2 = | 96% | 115% | 130% |
| | | 10:1:9 (70 Å) | 1:9 (40 Å) | | | |
| Comparative | HB1 (40 Å) | HB1:ET1:ET2 = | ET1:ET2 = | 97% | 104% | 100% |
| Example 31 | | 20:7:3 (70 Å) | 7:3 (40 Å) | | | |
| Example 21 | HB1 (40 Å) | HB1:ET1:ET2 = | ET1:ET2 = | 95% | 109% | 110% |
| | | 15:7:3 (70 Å) | 7:3 (40 Å) | | | |
| Example 22 | HB1 (40 Å) | HB1:ET1:ET2 = | ET1:ET2 = | 92% | 116% | 136% |
| | | 7:7:3 (70 Å) | 7:3 (40 Å) | | | |
| Example 23 | HB1 (40 Å) | HB1:ET1:ET2 = | ET1:ET2 = | 95% | 112% | 125% |
| | | 5:7:3 (70 Å) | 7:3 (40 Å) | | | |
| Example 24 | HB1 (40 Å) | HB1:ET1:ET2 = | ET1:ET2 = | 97% | 109% | 112% |
| | | 3:7:3 (70 Å) | 7:3 (40 Å) | | | |
| Comparative | HB1 (40 Å) | HB1:ET1:ET2 = | ET1:ET2 = | 97% | 105% | 100% |
| Example 32 | | 1:7:3 (70 Å) | 7:3 (40 Å) | | | |

Referring to Table 8, it was found out that results of the devices of Examples were excellent even in various weight ratio ranges of the second and third compounds.

Referring to the results of Comparative Examples 31 and 32, when, in the second electron transport layer, a ratio of a weight of the first compound to a total weight of the second compound and the third compound is 20:10 and 1:10, the results of Comparative Examples 31 and 32 are not as good as the results of Examples 21 to 24.

### HOMO and LUMO Energy Values of Compounds

HOMO and LUMO energy values of compounds of the second host compound, the first compound, the second compound, the third compound, and the n-type charge generation layer of the light-emitting device are shown in Table 9.

TABLE 9

| | HOMO energy | LUMO energy |
|---|---|---|
| | value (eV) | value (eV) |
| Second host compound | BH2: −5.66 | BH2: −2.60 |
| First compound | HB1: −6.25 | HB1: −2.73 |
| Second compound and | ET1: −5.60 | ET1: −2.81 |
| Third compound | ET2: −5.60 | ET2: −2.79 |
| n-type charge generation | CG1: −5.92 | CG1: −2.66 |
| layer compound | | |

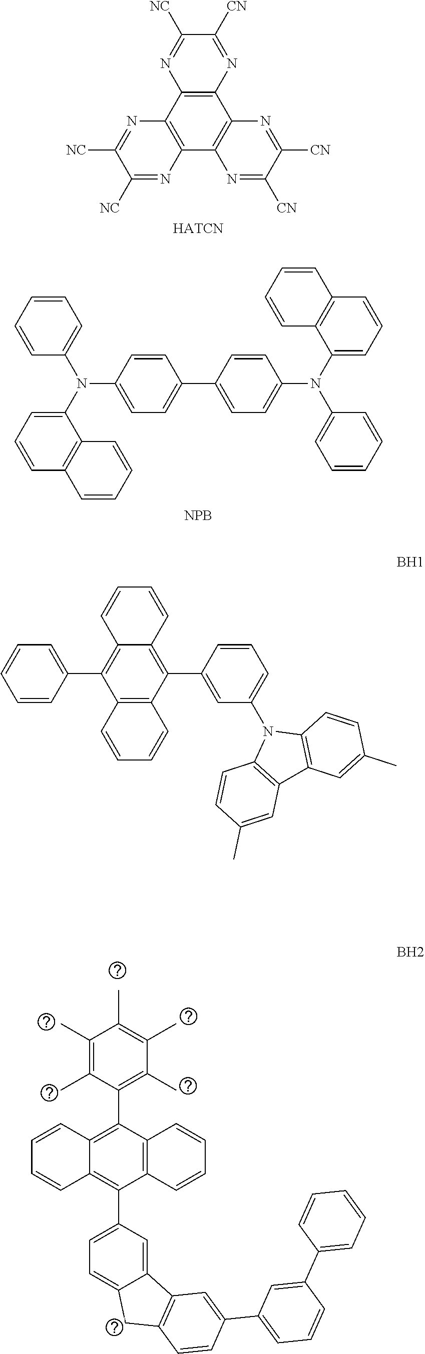

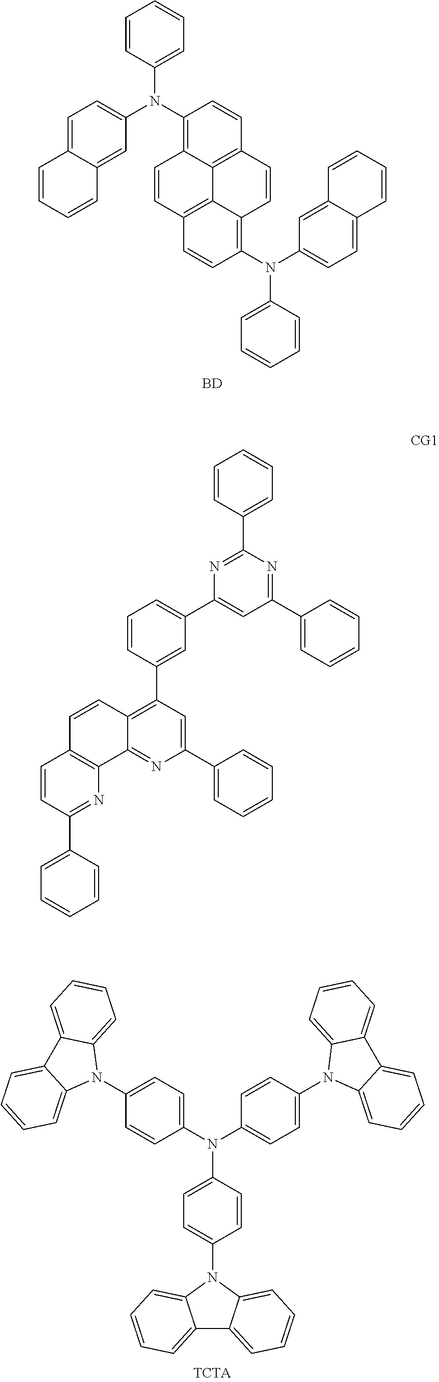 [SMILES: c1ccc(N(c2ccc3ccccc3c2)c2ccc3ccc4c(N(c5ccccc5)c5ccc6ccccc6c5)ccc5ccc2c3c54)cc1 ; "BD" ; c1ccc(-c2cc(-c3cccc(-c4cc(-c5ccccc5)nc5c4ccc4ccc(-c6ccccc6)nc45)c3)nc(-c3ccccc3)n2)cc1 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

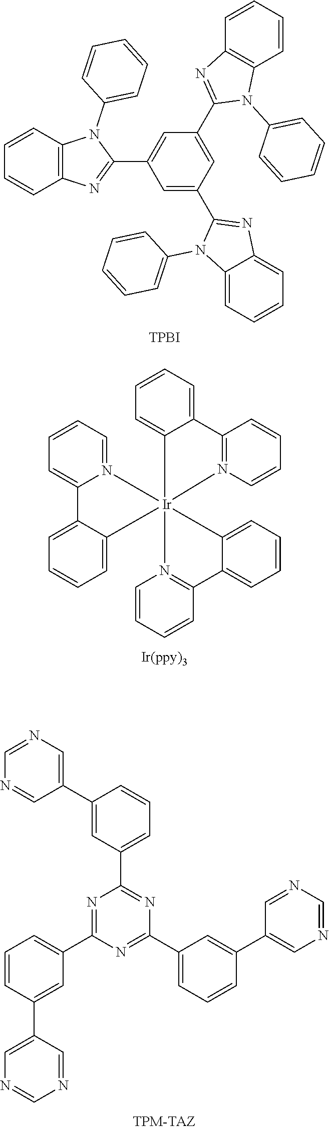

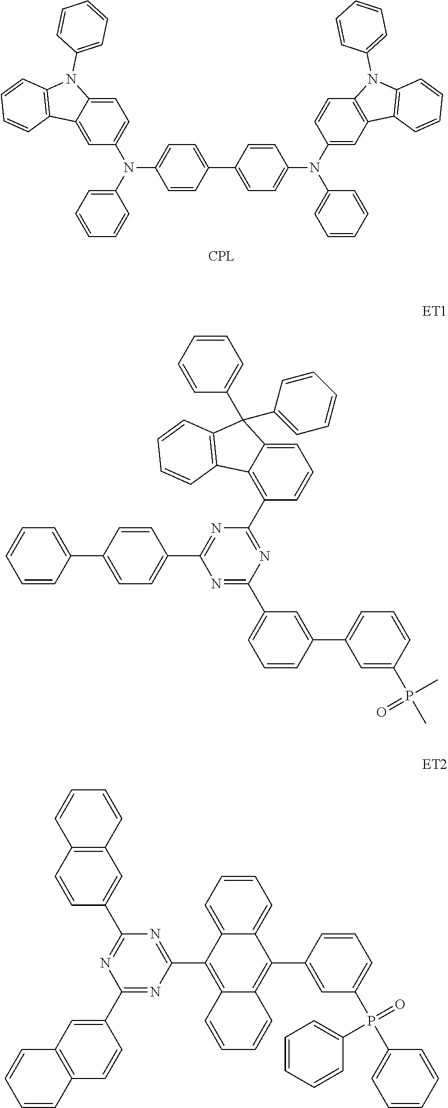 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CP(C)(=O)c1cccc(-c2cccc(-c3nc(-c4ccc(-c5ccccc5)cc4)nc(-c4cccc5c4-c4ccccc4C5(c4ccccc4)c4ccccc4)n3)c2)c1 ; O=P(c1ccccc1)(c1ccccc1)c1cccc(-c2c3ccccc3c(-c3nc(-c4ccc5ccccc5c4)nc(-c4ccc5ccccc5c4)n3)c3ccccc23)c1]

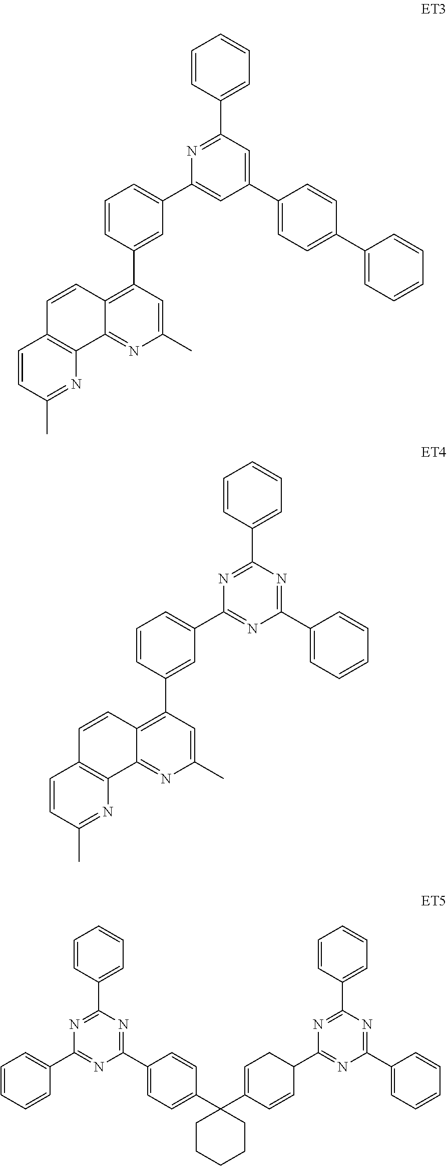 [SMILES: Cc1ccc2ccc3c(-c4cccc(-c5cc(-c6ccc(-c7ccccc7)cc6)cc(-c6ccccc6)n5)c4)cc(C)nc3c2n1 ; Cc1ccc2ccc3c(-c4cccc(-c5nc(-c6ccccc6)nc(-c6ccccc6)n5)c4)cc(C)nc3c2n1 ; C1=CC(c2nc(-c3ccccc3)nc(-c3ccccc3)n2)CC=C1C1(c2ccc(-c3nc(-c4ccccc4)nc(-c4ccccc4)n3)cc2)CCCCC1]

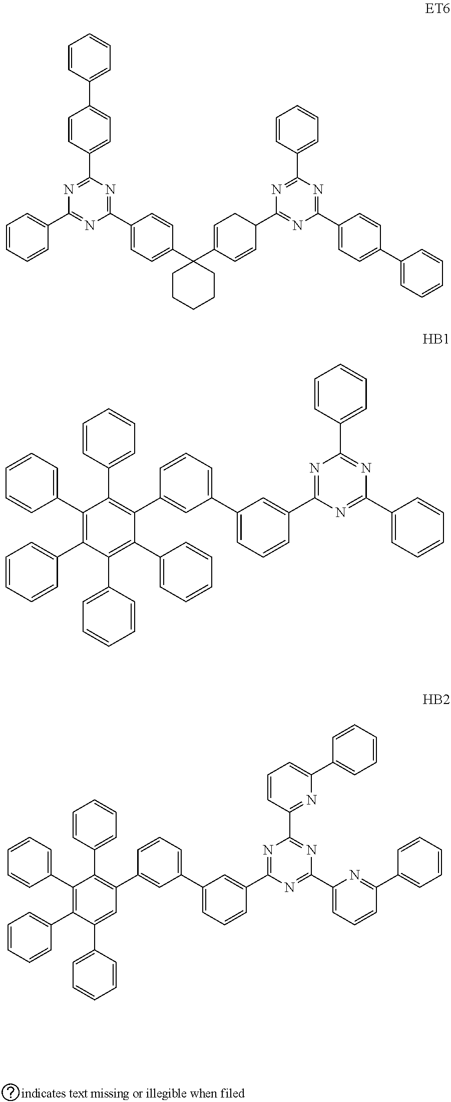 [SMILES: C1=CC(c2nc(-c3ccccc3)nc(-c3ccc(-c4ccccc4)cc3)n2)CC=C1C1(c2ccc(-c3nc(-c4ccccc4)nc(-c4ccc(-c5ccccc5)cc4)n3)cc2)CCCCC1 ; c1ccc(-c2nc(-c3ccccc3)nc(-c3cccc(-c4cccc(-c5c(-c6ccccc6)c(-c6ccccc6)c(-c6ccccc6)c(-c6ccccc6)c5-c5ccccc5)c4)c3)n2)cc1 ; c1ccc(-c2cccc(-c3nc(-c4cccc(-c5cccc(-c6cc(-c7ccccc7)c(-c7ccccc7)c(-c7ccccc7)c6-c6ccccc6)c5)c4)nc(-c4cccc(-c5ccccc5)n4)n3)n2)cc1]

The light-emitting device according to an embodiment exhibits improved results in terms of efficiency and lifespan, as compared with devices in the related art.

Embodiments have been disclosed herein, and although terms are employed, they are used and are to be interpreted in a generic and descriptive sense only and not for the purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light-emitting device comprising:
a first electrode;
a second electrode facing the first electrode;
m emitting units between the first electrode and the second electrode; and
m−1 charge generation layers between adjacent ones of the m emitting units, and each comprising an n-type charge generation layer and a p-type charge generation layer, wherein
m is an integer of 2 or more,
at least one emitting unit of the m emitting units comprises a first emission layer, a second emission layer, a first electron transport layer, a second electron transport layer, and a third electron transport layer,
the first emission layer comprises a first host compound and a first dopant compound,
the second emission layer comprises a second host compound and a second dopant compound,
the first electron transport layer comprises a first compound,
the third electron transport layer comprises a second compound and a third compound,
the second electron transport layer comprises the first compound, the second compound, and the third compound,
the second compound and/or the third compound each independently comprises a phosphine oxide-based compound and/or a phenanthroline-based compound,
the first electron transport layer and the second emission layer contact each other,
the second electron transport layer is between the first electron transport layer and the third electron transport layer,
the third electron transport layer and an n-type charge generation layer of the m−1 charge generation layers contact each other, and
each of the first electron transport layer, the second electron transport layer, and the third electron transport layer does not comprise a metal complex.

2. The light-emitting device of claim 1, wherein the second electron transport layer contacts the first electron transport layer and the third electron transport layer.

3. The light-emitting device of claim 1, wherein the first emission layer and the second emission layer each emit blue light.

4. The light-emitting device of claim 1, wherein a difference between an absolute value of a highest occupied molecular orbital (HOMO) energy of the second host compound and an absolute value of a HOMO energy of the first compound is in a range of about 0.5 eV to about 1.2 eV.

5. The light-emitting device of claim 1, wherein
a difference between an absolute value of a lowest unoccupied molecular orbital (LUMO) energy of the second compound and an absolute value of a LUMO energy of the first compound is less than or equal to about 0.15 eV, and
a difference between an absolute value of a LUMO energy of the third compound and an absolute value of the LUMO energy of the first compound is less than or equal to about 0.15 eV.

6. The light-emitting device of claim 1, wherein
a difference between an absolute value of a highest occupied molecular orbital (HOMO) energy of the second compound and an absolute value of a HOMO energy of the second host compound is less than or equal to about 0.2 eV, and
a difference between an absolute value of a HOMO energy of the third compound and an absolute value of the HOMO energy of the second host compound is less than or equal to about 0.2 eV.

7. The light-emitting device of claim 1, wherein the n-type charge generation layer contacting the third electron transport layer comprises:
a phosphine oxide-based compound and/or a phenanthroline-based compound; and
a metal.

8. The light-emitting device of claim 7, wherein the metal comprises Yb, Li, Cu, Ag, Au, Al, Mg, or a combination thereof.

9. The light-emitting device of claim 7, wherein a weight ratio of the phosphine oxide-based compound and/or the phenanthroline-based compound, to the metal is in a range of about 9:0.1 to about 0.1:9.

10. The light-emitting device of claim 7, wherein:
a difference between a smaller value among an absolute value of a lowest unoccupied molecular orbital (LUMO) energy of the phosphine oxide-based compound of the n-type charge generation layer and an absolute value of a LUMO energy of the phenanthroline-based compound of the n-type charge generation layer, and an absolute value of a LUMO energy of the second compound, is less than or equal to about 0.20 eV; or
a difference between a smaller value among an absolute value of a LUMO energy of the phosphine oxide-based compound of the n-type charge generation layer and an absolute value of a LUMO energy of the phenanthroline-based compound of the n-type charge generation layer, and an absolute value of a LUMO energy of the third compound, is less than or equal to about 0.20 eV.

11. The light-emitting device of claim 1, wherein, in the second electron transport layer,
the second compound and the third compound are different from each other, and
a weight ratio of the second compound to the third compound is in a range of about 1:15 to about 15:1.

12. The light-emitting device of claim 1, wherein, in the third electron transport layer, a weight ratio of the second compound to the third compound is in a range of about 1:15 to about 15:1.

13. The light-emitting device of claim 1, wherein a weight ratio of the second compound to the third compound in the second electron transport layer and a weight ratio of the second compound to the third compound in the third electron transport layer are equal to each other.

14. The light-emitting device of claim 1, wherein, in the second electron transport layer, a weight ratio of the first compound to a total weight of the second compound and the third compound is in a range of about 19:10 to about 0.5:10.

15. The light-emitting device of claim 1, wherein the first compound is represented by Formula 1: 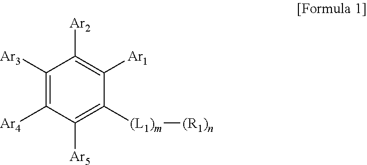
wherein in Formula 1,
Ar₁ to Ar₅ and R₁ are each independently hydrogen, deuterium, a C₆-C₆₀ aryl group that is unsubstituted or substituted with at least one R₁₀ₐ, or a C₁-C₆₀ heteroaryl group that is unsubstituted or substituted with at least one R₁₀ₐ,
L₁ is a C₆-C₆₀ arylene group that is unsubstituted or substituted with at least one R₁₀ₐ or a C₁-C₆₀ heteroarylene group that is unsubstituted or substituted with at least one R₁₀ₐ,
m and n are each independently an integer from 1 to 4,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁₁ to Q₁₃, Q₂₁ to Q₂₃, and Q₃₁ to Q₃₃ are each independently: hydrogen;
deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or a combination thereof.

16. The light-emitting device of claim 15, wherein four or more of Ar₁ to Ar₅ are each independently a C₆-C₆₀ aryl group that is unsubstituted or substituted with at least one R₁₀ₐ or a C₁-C₆₀ heteroaryl group that is unsubstituted or substituted with at least one R₁₀ₐ.

17. The light-emitting device of claim 1, wherein the first compound is selected from the compounds below:

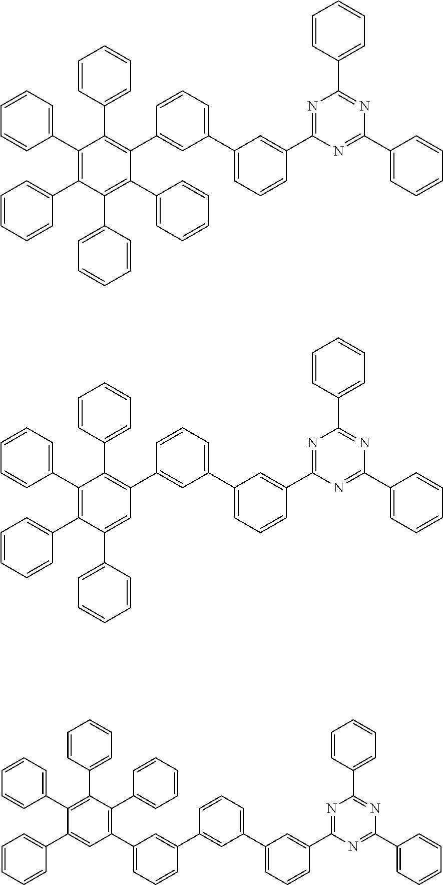 [SMILES: c1ccc(-c2nc(-c3ccccc3)nc(-c3cccc(-c4cccc(-c5c(-c6ccccc6)c(-c6ccccc6)c(-c6ccccc6)c(-c6ccccc6)c5-c5ccccc5)c4)c3)n2)cc1 ; c1ccc(-c2nc(-c3ccccc3)nc(-c3cccc(-c4cccc(-c5cc(-c6ccccc6)c(-c6ccccc6)c(-c6ccccc6)c5-c5ccccc5)c4)c3)n2)cc1 ; c1ccc(-c2nc(-c3ccccc3)nc(-c3cccc(-c4cccc(-c5cccc(-c6cc(-c7ccccc7)c(-c7ccccc7)c(-c7ccccc7)c6-c6ccccc6)c5)c4)c3)n2)cc1]

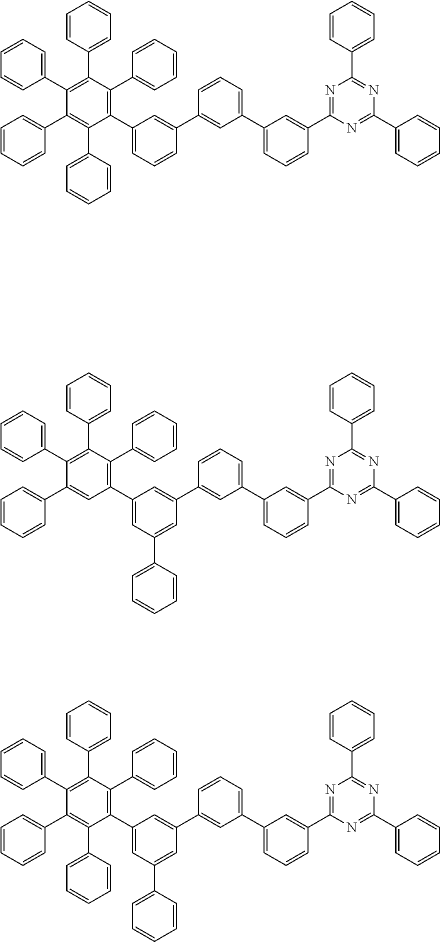 [SMILES: c1ccc(-c2nc(-c3ccccc3)nc(-c3cccc(-c4cccc(-c5cccc(-c6c(-c7ccccc7)c(-c7ccccc7)c(-c7ccccc7)c(-c7ccccc7)c6-c6ccccc6)c5)c4)c3)n2)cc1 ; c1ccc(-c2cc(-c3cccc(-c4cccc(-c5nc(-c6ccccc6)nc(-c6ccccc6)n5)c4)c3)cc(-c3cc(-c4ccccc4)c(-c4ccccc4)c(-c4ccccc4)c3-c3ccccc3)c2)cc1 ; c1ccc(-c2cc(-c3cccc(-c4cccc(-c5nc(-c6ccccc6)nc(-c6ccccc6)n5)c4)c3)cc(-c3c(-c4ccccc4)c(-c4ccccc4)c(-c4ccccc4)c(-c4ccccc4)c3-c3ccccc3)c2)cc1]

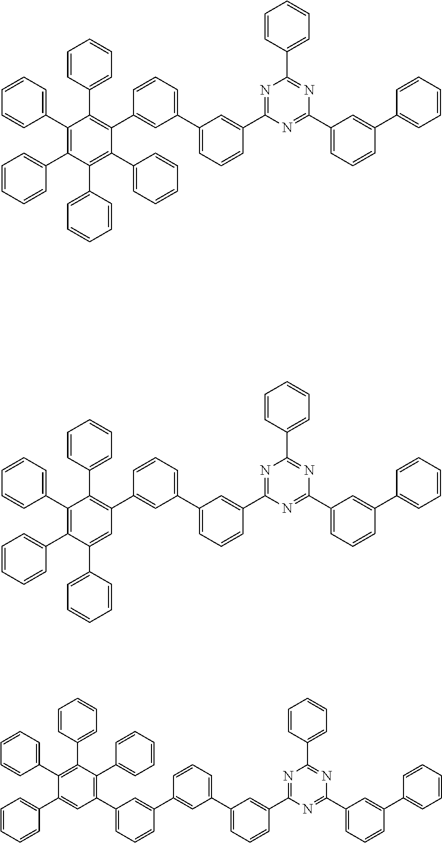 [SMILES: c1ccc(-c2cccc(-c3nc(-c4ccccc4)nc(-c4cccc(-c5cccc(-c6c(-c7ccccc7)c(-c7ccccc7)c(-c7ccccc7)c(-c7ccccc7)c6-c6ccccc6)c5)c4)n3)c2)cc1 ; c1ccc(-c2cccc(-c3nc(-c4ccccc4)nc(-c4cccc(-c5cccc(-c6cc(-c7ccccc7)c(-c7ccccc7)c(-c7ccccc7)c6-c6ccccc6)c5)c4)n3)c2)cc1 ; c1ccc(-c2cccc(-c3nc(-c4ccccc4)nc(-c4cccc(-c5cccc(-c6cccc(-c7cc(-c8ccccc8)c(-c8ccccc8)c(-c8ccccc8)c7-c7ccccc7)c6)c5)c4)n3)c2)cc1]

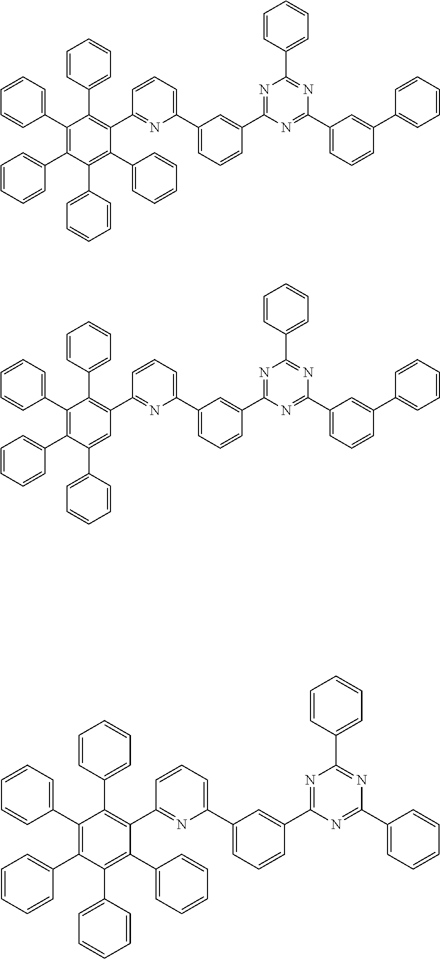 [SMILES: c1ccc(-c2cccc(-c3nc(-c4ccccc4)nc(-c4cccc(-c5cccc(-c6c(-c7ccccc7)c(-c7ccccc7)c(-c7ccccc7)c(-c7ccccc7)c6-c6ccccc6)n5)c4)n3)c2)cc1 ; c1ccc(-c2cccc(-c3nc(-c4ccccc4)nc(-c4cccc(-c5cccc(-c6cc(-c7ccccc7)c(-c7ccccc7)c(-c7ccccc7)c6-c6ccccc6)n5)c4)n3)c2)cc1 ; c1ccc(-c2nc(-c3ccccc3)nc(-c3cccc(-c4cccc(-c5c(-c6ccccc6)c(-c6ccccc6)c(-c6ccccc6)c(-c6ccccc6)c5-c5ccccc5)n4)c3)n2)cc1]

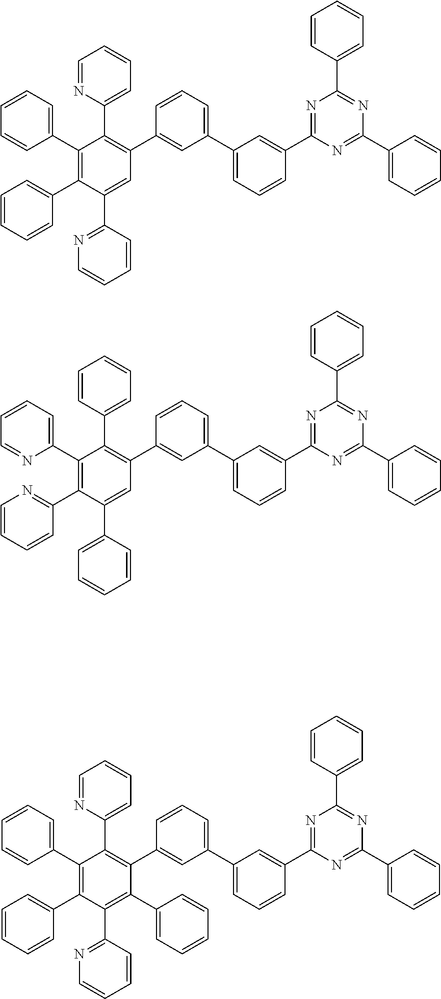 [SMILES: c1ccc(-c2nc(-c3ccccc3)nc(-c3cccc(-c4cccc(-c5cc(-c6ccccn6)c(-c6ccccc6)c(-c6ccccc6)c5-c5ccccn5)c4)c3)n2)cc1 ; c1ccc(-c2nc(-c3ccccc3)nc(-c3cccc(-c4cccc(-c5cc(-c6ccccc6)c(-c6ccccn6)c(-c6ccccn6)c5-c5ccccc5)c4)c3)n2)cc1 ; c1ccc(-c2nc(-c3ccccc3)nc(-c3cccc(-c4cccc(-c5c(-c6ccccc6)c(-c6ccccn6)c(-c6ccccc6)c(-c6ccccc6)c5-c5ccccn5)c4)c3)n2)cc1]

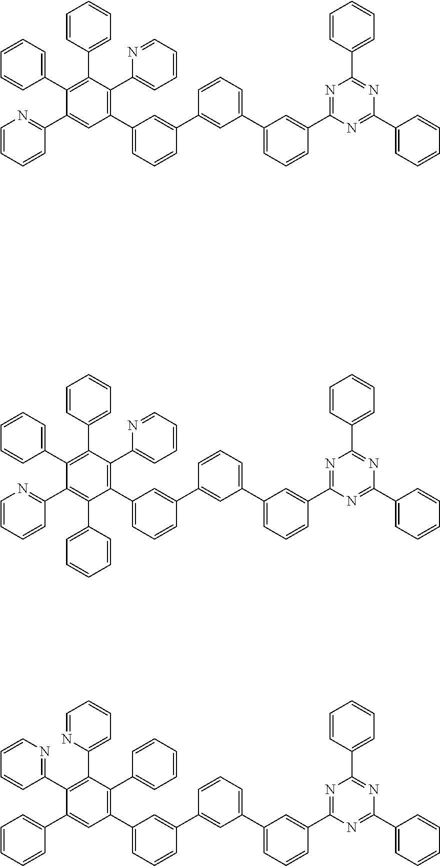 [SMILES: c1ccc(-c2nc(-c3ccccc3)nc(-c3cccc(-c4cccc(-c5cccc(-c6cc(-c7ccccn7)c(-c7ccccc7)c(-c7ccccc7)c6-c6ccccn6)c5)c4)c3)n2)cc1 ; c1ccc(-c2nc(-c3ccccc3)nc(-c3cccc(-c4cccc(-c5cccc(-c6c(-c7ccccc7)c(-c7ccccn7)c(-c7ccccc7)c(-c7ccccc7)c6-c6ccccn6)c5)c4)c3)n2)cc1 ; c1ccc(-c2nc(-c3ccccc3)nc(-c3cccc(-c4cccc(-c5cccc(-c6cc(-c7ccccc7)c(-c7ccccn7)c(-c7ccccn7)c6-c6ccccc6)c5)c4)c3)n2)cc1]

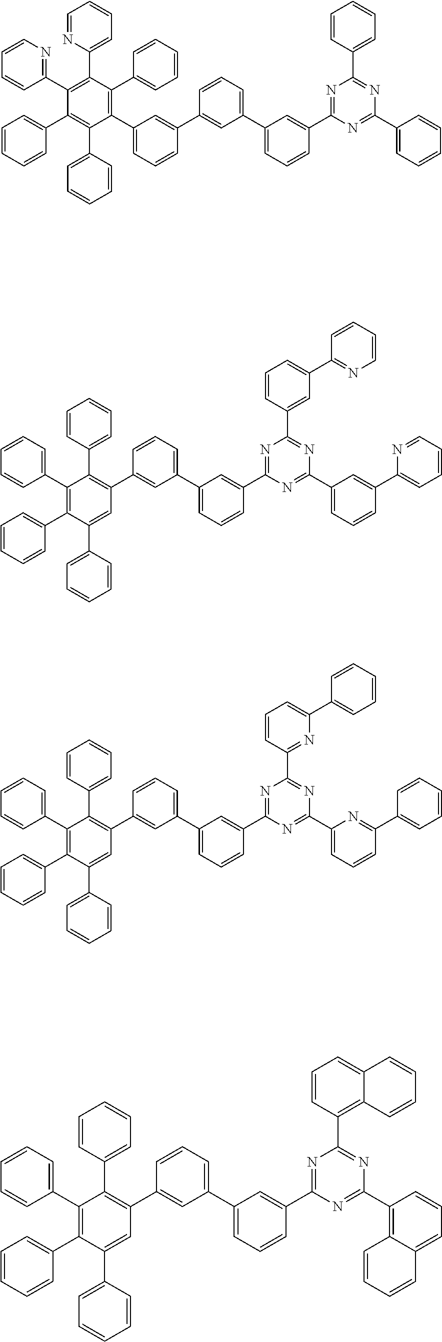

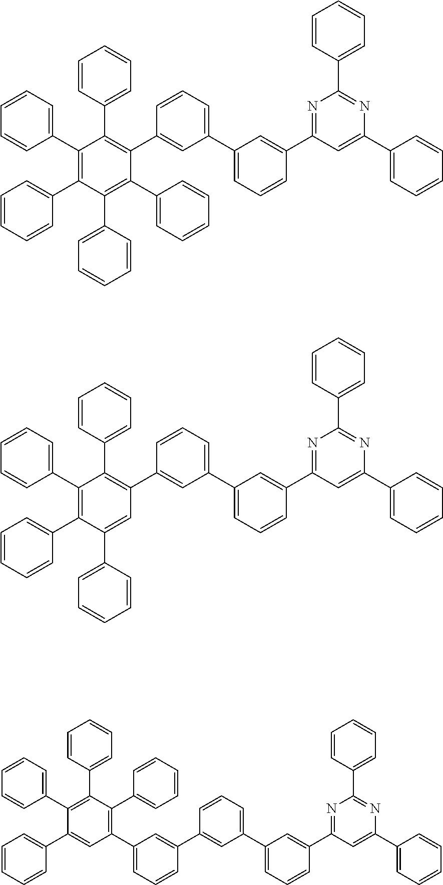 [SMILES: c1ccc(-c2cc(-c3cccc(-c4cccc(-c5c(-c6ccccc6)c(-c6ccccc6)c(-c6ccccc6)c(-c6ccccc6)c5-c5ccccc5)c4)c3)nc(-c3ccccc3)n2)cc1 ; c1ccc(-c2cc(-c3cccc(-c4cccc(-c5cc(-c6ccccc6)c(-c6ccccc6)c(-c6ccccc6)c5-c5ccccc5)c4)c3)nc(-c3ccccc3)n2)cc1 ; c1ccc(-c2cc(-c3cccc(-c4cccc(-c5cccc(-c6cc(-c7ccccc7)c(-c7ccccc7)c(-c7ccccc7)c6-c6ccccc6)c5)c4)c3)nc(-c3ccccc3)n2)cc1]

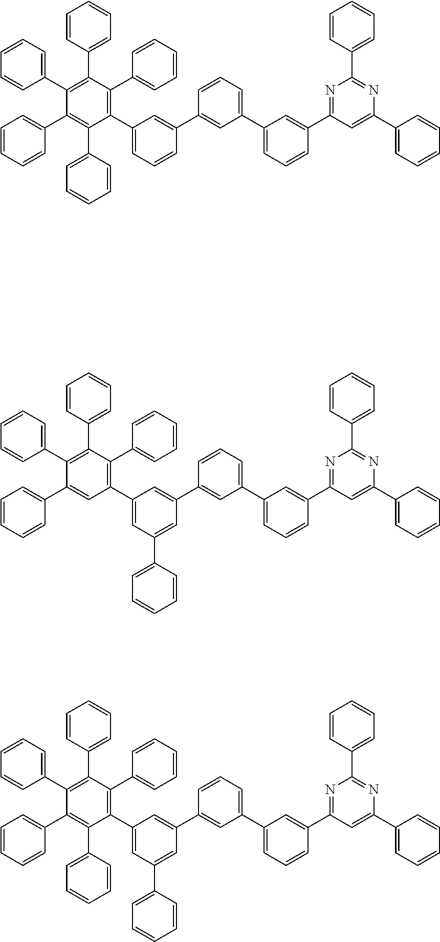 [SMILES: c1ccc(-c2cc(-c3cccc(-c4cccc(-c5cccc(-c6c(-c7ccccc7)c(-c7ccccc7)c(-c7ccccc7)c(-c7ccccc7)c6-c6ccccc6)c5)c4)c3)nc(-c3ccccc3)n2)cc1 ; c1ccc(-c2cc(-c3cccc(-c4cccc(-c5cc(-c6ccccc6)nc(-c6ccccc6)n5)c4)c3)cc(-c3cc(-c4ccccc4)c(-c4ccccc4)c(-c4ccccc4)c3-c3ccccc3)c2)cc1 ; c1ccc(-c2cc(-c3cccc(-c4cccc(-c5cc(-c6ccccc6)nc(-c6ccccc6)n5)c4)c3)cc(-c3c(-c4ccccc4)c(-c4ccccc4)c(-c4ccccc4)c(-c4ccccc4)c3-c3ccccc3)c2)cc1]

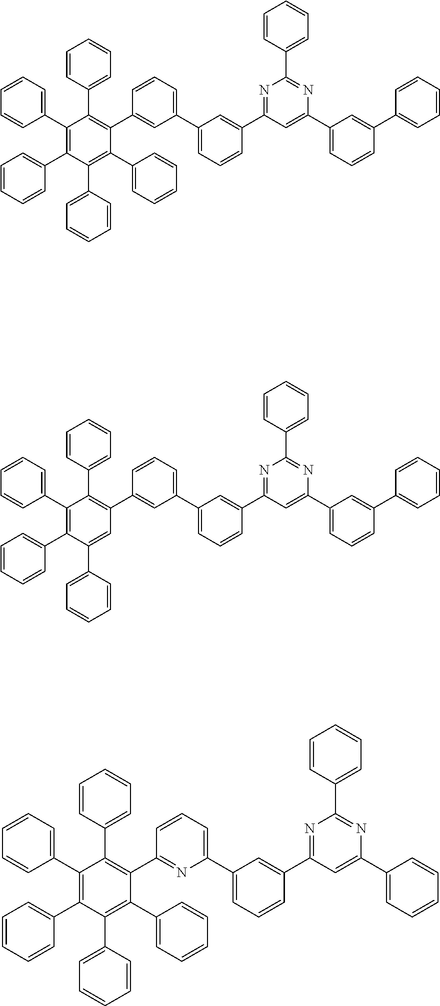 [SMILES: c1ccc(-c2cccc(-c3cc(-c4cccc(-c5cccc(-c6c(-c7ccccc7)c(-c7ccccc7)c(-c7ccccc7)c(-c7ccccc7)c6-c6ccccc6)c5)c4)nc(-c4ccccc4)n3)c2)cc1 ; c1ccc(-c2cccc(-c3cc(-c4cccc(-c5cccc(-c6cc(-c7ccccc7)c(-c7ccccc7)c(-c7ccccc7)c6-c6ccccc6)c5)c4)nc(-c4ccccc4)n3)c2)cc1 ; c1ccc(-c2cc(-c3cccc(-c4cccc(-c5c(-c6ccccc6)c(-c6ccccc6)c(-c6ccccc6)c(-c6ccccc6)c5-c5ccccc5)n4)c3)nc(-c3ccccc3)n2)cc1]

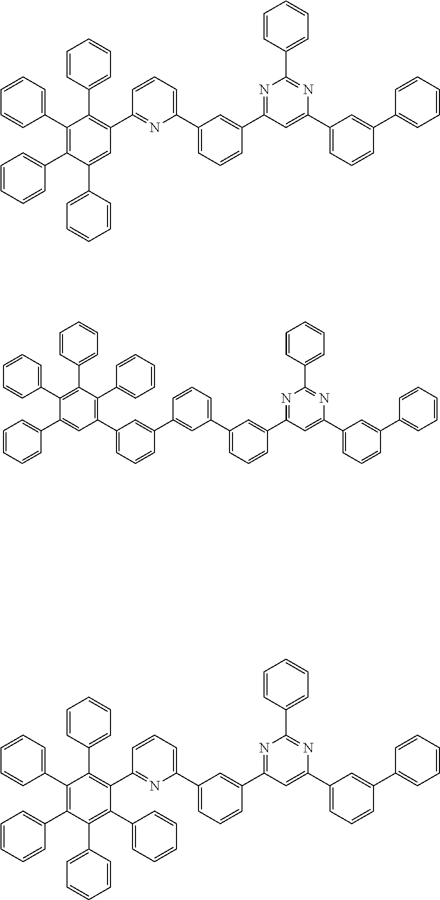 [SMILES: c1ccc(-c2cccc(-c3cc(-c4cccc(-c5cccc(-c6cc(-c7ccccc7)c(-c7ccccc7)c(-c7ccccc7)c6-c6ccccc6)n5)c4)nc(-c4ccccc4)n3)c2)cc1 ; c1ccc(-c2cccc(-c3cc(-c4cccc(-c5cccc(-c6cccc(-c7cc(-c8ccccc8)c(-c8ccccc8)c(-c8ccccc8)c7-c7ccccc7)c6)c5)c4)nc(-c4ccccc4)n3)c2)cc1 ; c1ccc(-c2cccc(-c3cc(-c4cccc(-c5cccc(-c6c(-c7ccccc7)c(-c7ccccc7)c(-c7ccccc7)c(-c7ccccc7)c6-c6ccccc6)n5)c4)nc(-c4ccccc4)n3)c2)cc1]

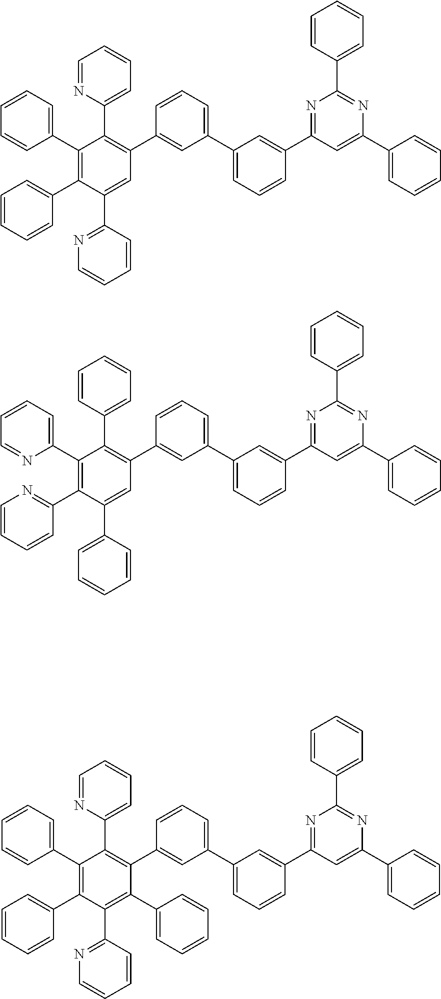 [SMILES: c1ccc(-c2cc(-c3cccc(-c4cccc(-c5cc(-c6ccccn6)c(-c6ccccc6)c(-c6ccccc6)c5-c5ccccn5)c4)c3)nc(-c3ccccc3)n2)cc1 ; c1ccc(-c2cc(-c3cccc(-c4cccc(-c5cc(-c6ccccc6)c(-c6ccccn6)c(-c6ccccn6)c5-c5ccccc5)c4)c3)nc(-c3ccccc3)n2)cc1 ; c1ccc(-c2cc(-c3cccc(-c4cccc(-c5c(-c6ccccc6)c(-c6ccccn6)c(-c6ccccc6)c(-c6ccccc6)c5-c5ccccn5)c4)c3)nc(-c3ccccc3)n2)cc1]

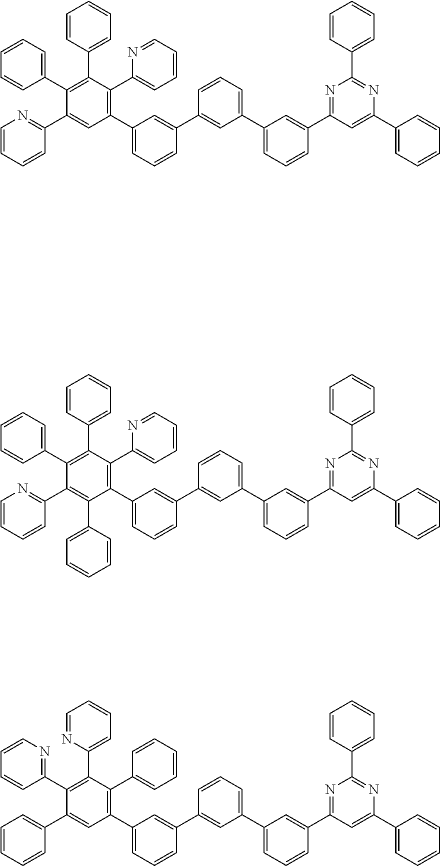 [SMILES: c1ccc(-c2cc(-c3cccc(-c4cccc(-c5cccc(-c6cc(-c7ccccn7)c(-c7ccccc7)c(-c7ccccc7)c6-c6ccccn6)c5)c4)c3)nc(-c3ccccc3)n2)cc1 ; c1ccc(-c2cc(-c3cccc(-c4cccc(-c5cccc(-c6c(-c7ccccc7)c(-c7ccccn7)c(-c7ccccc7)c(-c7ccccc7)c6-c6ccccn6)c5)c4)c3)nc(-c3ccccc3)n2)cc1 ; c1ccc(-c2cc(-c3cccc(-c4cccc(-c5cccc(-c6cc(-c7ccccc7)c(-c7ccccn7)c(-c7ccccn7)c6-c6ccccc6)c5)c4)c3)nc(-c3ccccc3)n2)cc1]

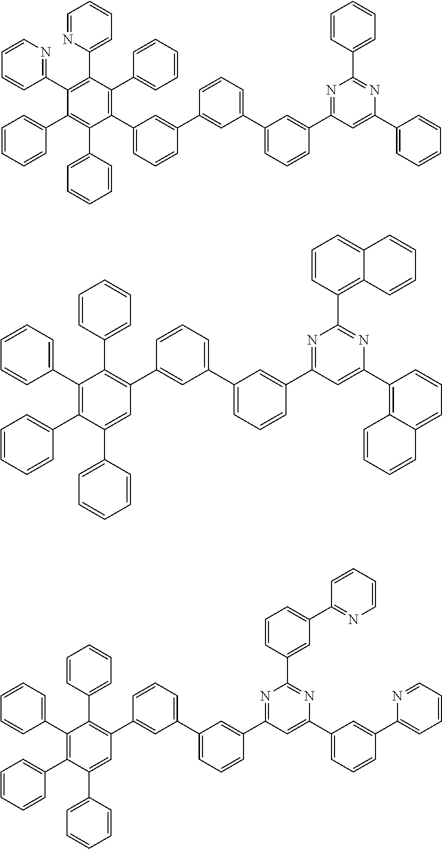 [SMILES: c1ccc(-c2cc(-c3cccc(-c4cccc(-c5cccc(-c6c(-c7ccccc7)c(-c7ccccc7)c(-c7ccccn7)c(-c7ccccn7)c6-c6ccccc6)c5)c4)c3)nc(-c3ccccc3)n2)cc1 ; c1ccc(-c2cc(-c3cccc(-c4cccc(-c5cc(-c6cccc7ccccc67)nc(-c6cccc7ccccc67)n5)c4)c3)c(-c3ccccc3)c(-c3ccccc3)c2-c2ccccc2)cc1 ; c1ccc(-c2cc(-c3cccc(-c4cccc(-c5cc(-c6cccc(-c7ccccn7)c6)nc(-c6cccc(-c7ccccn7)c6)n5)c4)c3)c(-c3ccccc3)c(-c3ccccc3)c2-c2ccccc2)cc1]

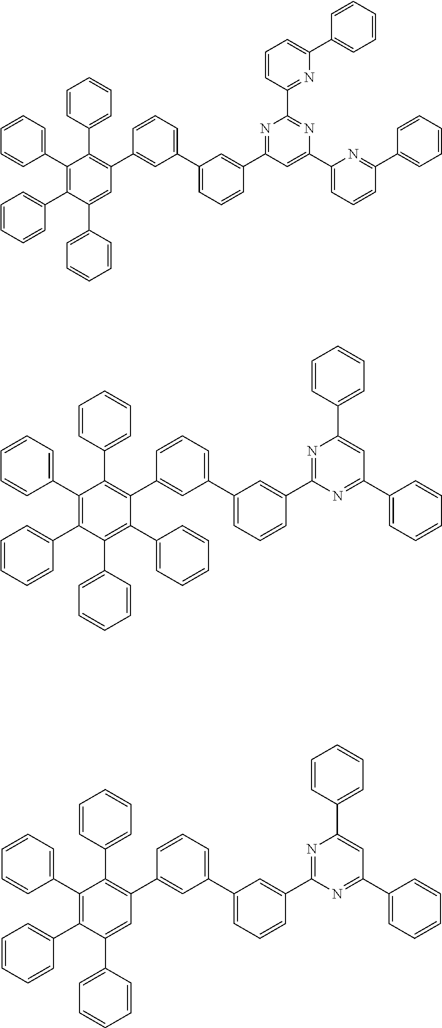 [SMILES: c1ccc(-c2cccc(-c3cc(-c4cccc(-c5cccc(-c6cc(-c7ccccc7)c(-c7ccccc7)c(-c7ccccc7)c6-c6ccccc6)c5)c4)nc(-c4cccc(-c5ccccc5)n4)n3)n2)cc1 ; c1ccc(-c2cc(-c3ccccc3)nc(-c3cccc(-c4cccc(-c5c(-c6ccccc6)c(-c6ccccc6)c(-c6ccccc6)c(-c6ccccc6)c5-c5ccccc5)c4)c3)n2)cc1 ; c1ccc(-c2cc(-c3ccccc3)nc(-c3cccc(-c4cccc(-c5cc(-c6ccccc6)c(-c6ccccc6)c(-c6ccccc6)c5-c5ccccc5)c4)c3)n2)cc1]

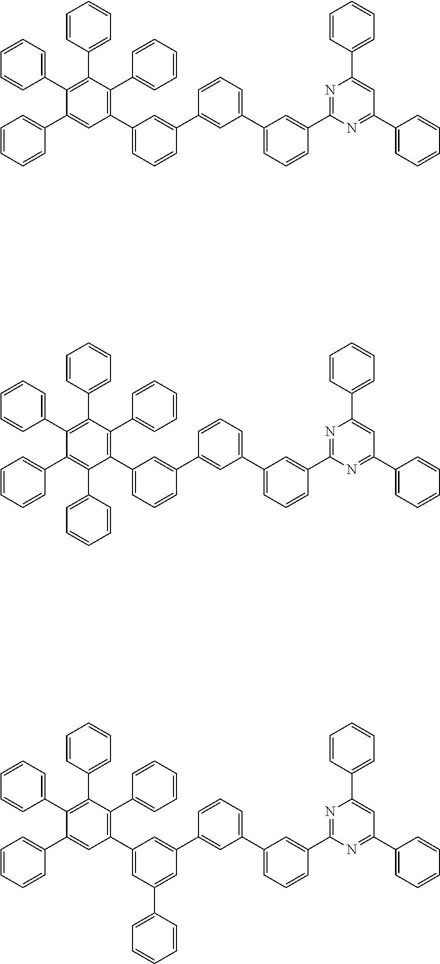 [SMILES: c1ccc(-c2cc(-c3ccccc3)nc(-c3cccc(-c4cccc(-c5cccc(-c6cc(-c7ccccc7)c(-c7ccccc7)c(-c7ccccc7)c6-c6ccccc6)c5)c4)c3)n2)cc1 ; c1ccc(-c2cc(-c3ccccc3)nc(-c3cccc(-c4cccc(-c5cccc(-c6c(-c7ccccc7)c(-c7ccccc7)c(-c7ccccc7)c(-c7ccccc7)c6-c6ccccc6)c5)c4)c3)n2)cc1 ; c1ccc(-c2cc(-c3cccc(-c4cccc(-c5nc(-c6ccccc6)cc(-c6ccccc6)n5)c4)c3)cc(-c3cc(-c4ccccc4)c(-c4ccccc4)c(-c4ccccc4)c3-c3ccccc3)c2)cc1]

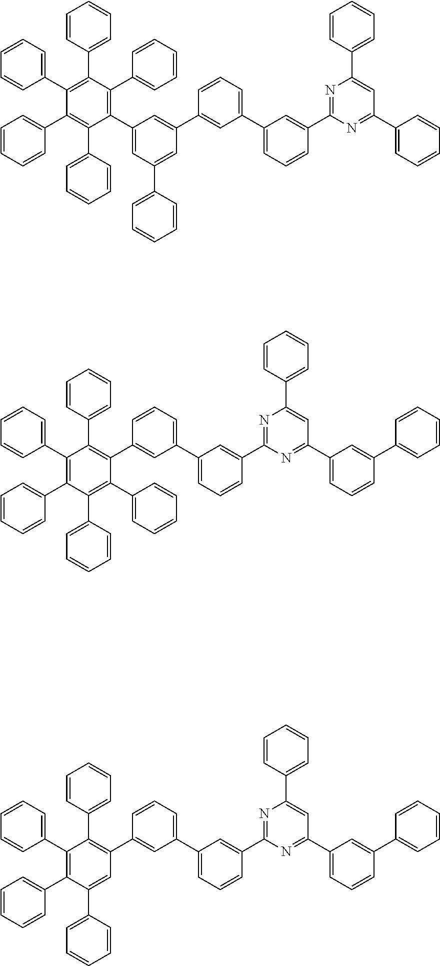 [SMILES: c1ccc(-c2cc(-c3cccc(-c4cccc(-c5nc(-c6ccccc6)cc(-c6ccccc6)n5)c4)c3)cc(-c3c(-c4ccccc4)c(-c4ccccc4)c(-c4ccccc4)c(-c4ccccc4)c3-c3ccccc3)c2)cc1 ; c1ccc(-c2cccc(-c3cc(-c4ccccc4)nc(-c4cccc(-c5cccc(-c6c(-c7ccccc7)c(-c7ccccc7)c(-c7ccccc7)c(-c7ccccc7)c6-c6ccccc6)c5)c4)n3)c2)cc1 ; c1ccc(-c2cccc(-c3cc(-c4ccccc4)nc(-c4cccc(-c5cccc(-c6cc(-c7ccccc7)c(-c7ccccc7)c(-c7ccccc7)c6-c6ccccc6)c5)c4)n3)c2)cc1]

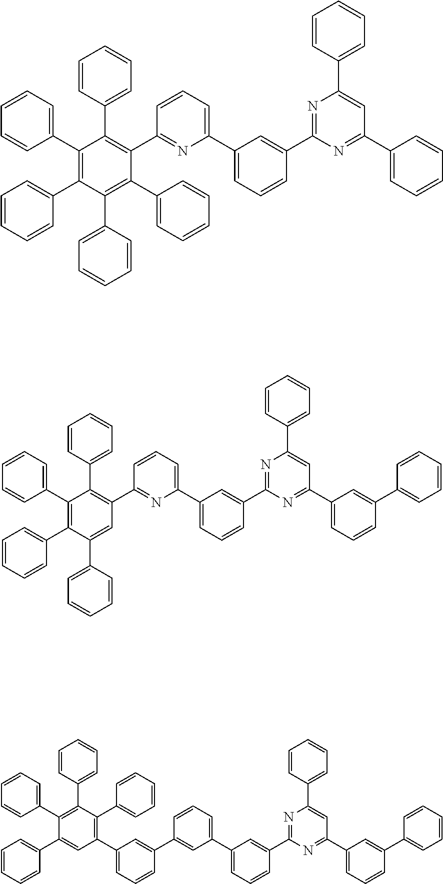 [SMILES: c1ccc(-c2cc(-c3ccccc3)nc(-c3cccc(-c4cccc(-c5c(-c6ccccc6)c(-c6ccccc6)c(-c6ccccc6)c(-c6ccccc6)c5-c5ccccc5)n4)c3)n2)cc1 ; c1ccc(-c2cccc(-c3cc(-c4ccccc4)nc(-c4cccc(-c5cccc(-c6cc(-c7ccccc7)c(-c7ccccc7)c(-c7ccccc7)c6-c6ccccc6)n5)c4)n3)c2)cc1 ; c1ccc(-c2cccc(-c3cc(-c4ccccc4)nc(-c4cccc(-c5cccc(-c6cccc(-c7cc(-c8ccccc8)c(-c8ccccc8)c(-c8ccccc8)c7-c7ccccc7)c6)c5)c4)n3)c2)cc1]

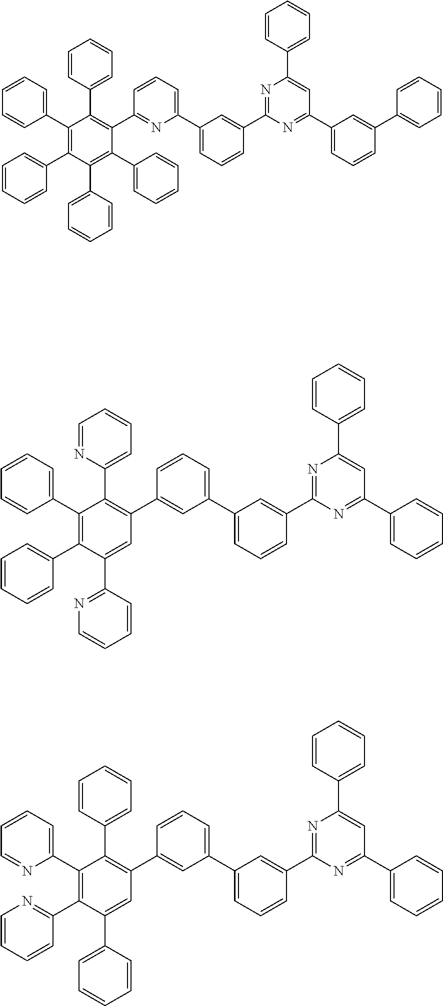 [SMILES: c1ccc(-c2cccc(-c3cc(-c4ccccc4)nc(-c4cccc(-c5cccc(-c6c(-c7ccccc7)c(-c7ccccc7)c(-c7ccccc7)c(-c7ccccc7)c6-c6ccccc6)n5)c4)n3)c2)cc1 ; c1ccc(-c2cc(-c3ccccc3)nc(-c3cccc(-c4cccc(-c5cc(-c6ccccn6)c(-c6ccccc6)c(-c6ccccc6)c5-c5ccccn5)c4)c3)n2)cc1 ; c1ccc(-c2cc(-c3ccccc3)nc(-c3cccc(-c4cccc(-c5cc(-c6ccccc6)c(-c6ccccn6)c(-c6ccccn6)c5-c5ccccc5)c4)c3)n2)cc1]

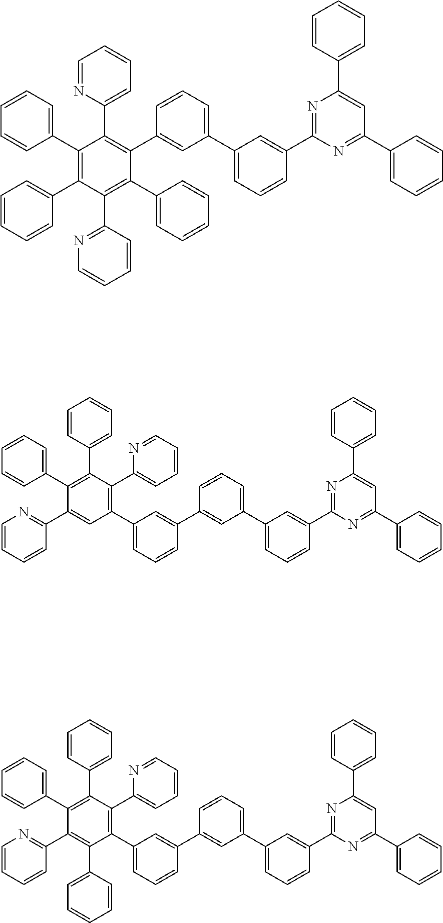 [SMILES: c1ccc(-c2cc(-c3ccccc3)nc(-c3cccc(-c4cccc(-c5c(-c6ccccc6)c(-c6ccccn6)c(-c6ccccc6)c(-c6ccccc6)c5-c5ccccn5)c4)c3)n2)cc1 ; c1ccc(-c2cc(-c3ccccc3)nc(-c3cccc(-c4cccc(-c5cccc(-c6cc(-c7ccccn7)c(-c7ccccc7)c(-c7ccccc7)c6-c6ccccn6)c5)c4)c3)n2)cc1 ; c1ccc(-c2cc(-c3ccccc3)nc(-c3cccc(-c4cccc(-c5cccc(-c6c(-c7ccccc7)c(-c7ccccn7)c(-c7ccccc7)c(-c7ccccc7)c6-c6ccccn6)c5)c4)c3)n2)cc1]

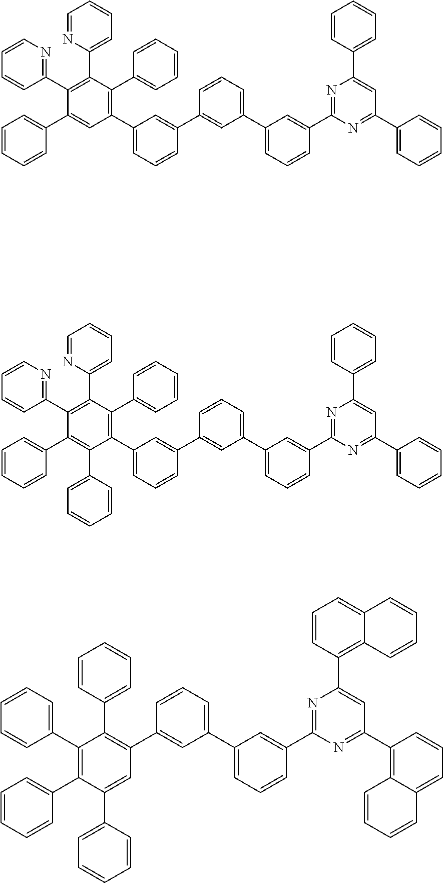 [SMILES: c1ccc(-c2cc(-c3ccccc3)nc(-c3cccc(-c4cccc(-c5cccc(-c6cc(-c7ccccc7)c(-c7ccccn7)c(-c7ccccn7)c6-c6ccccc6)c5)c4)c3)n2)cc1 ; c1ccc(-c2cc(-c3ccccc3)nc(-c3cccc(-c4cccc(-c5cccc(-c6c(-c7ccccc7)c(-c7ccccc7)c(-c7ccccn7)c(-c7ccccn7)c6-c6ccccc6)c5)c4)c3)n2)cc1 ; c1ccc(-c2cc(-c3cccc(-c4cccc(-c5nc(-c6cccc7ccccc67)cc(-c6cccc7ccccc67)n5)c4)c3)c(-c3ccccc3)c(-c3ccccc3)c2-c2ccccc2)cc1]

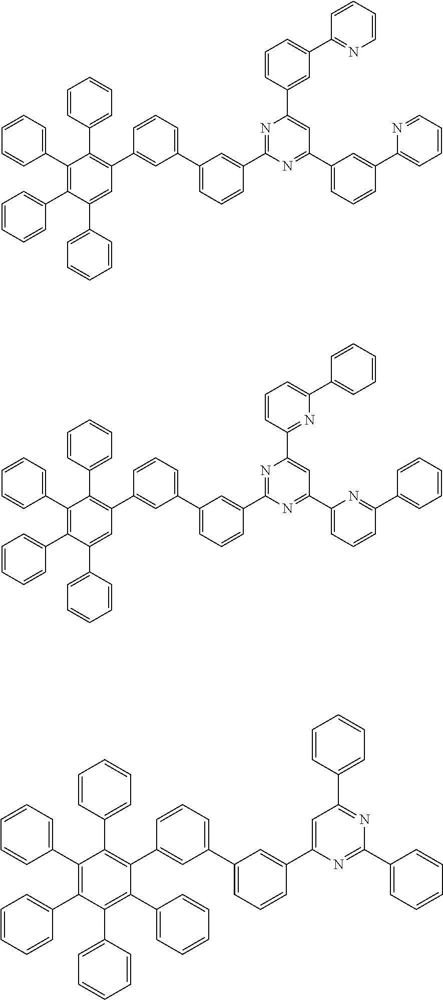 [SMILES: c1ccc(-c2cc(-c3cccc(-c4cccc(-c5nc(-c6cccc(-c7ccccn7)c6)cc(-c6cccc(-c7ccccn7)c6)n5)c4)c3)c(-c3ccccc3)c(-c3ccccc3)c2-c2ccccc2)cc1 ; c1ccc(-c2cccc(-c3cc(-c4cccc(-c5ccccc5)n4)nc(-c4cccc(-c5cccc(-c6cc(-c7ccccc7)c(-c7ccccc7)c(-c7ccccc7)c6-c6ccccc6)c5)c4)n3)n2)cc1 ; c1ccc(-c2cc(-c3cccc(-c4cccc(-c5c(-c6ccccc6)c(-c6ccccc6)c(-c6ccccc6)c(-c6ccccc6)c5-c5ccccc5)c4)c3)nc(-c3ccccc3)n2)cc1]

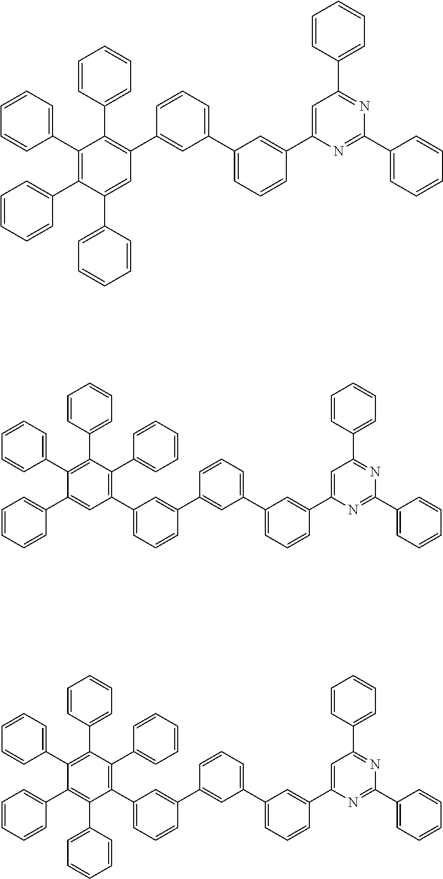 [SMILES: c1ccc(-c2cc(-c3cccc(-c4cccc(-c5cc(-c6ccccc6)c(-c6ccccc6)c(-c6ccccc6)c5-c5ccccc5)c4)c3)nc(-c3ccccc3)n2)cc1 ; c1ccc(-c2cc(-c3cccc(-c4cccc(-c5cccc(-c6cc(-c7ccccc7)c(-c7ccccc7)c(-c7ccccc7)c6-c6ccccc6)c5)c4)c3)nc(-c3ccccc3)n2)cc1 ; c1ccc(-c2cc(-c3cccc(-c4cccc(-c5cccc(-c6c(-c7ccccc7)c(-c7ccccc7)c(-c7ccccc7)c(-c7ccccc7)c6-c6ccccc6)c5)c4)c3)nc(-c3ccccc3)n2)cc1]

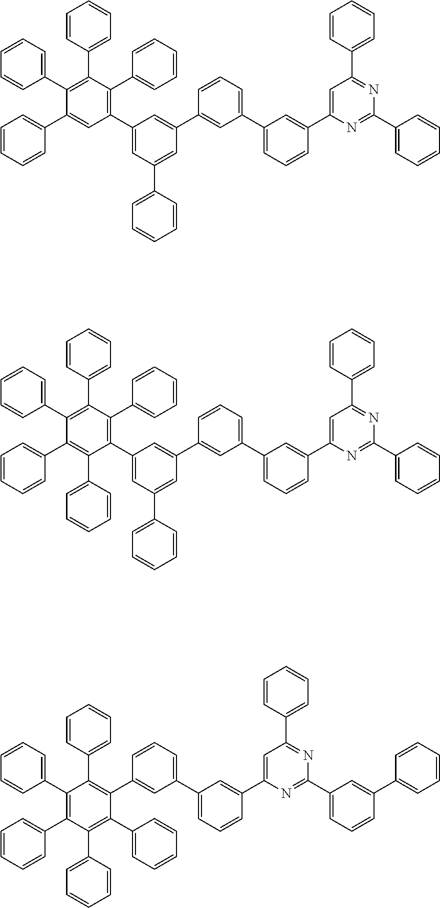 [SMILES: c1ccc(-c2cc(-c3cccc(-c4cccc(-c5cc(-c6ccccc6)nc(-c6ccccc6)n5)c4)c3)cc(-c3cc(-c4ccccc4)c(-c4ccccc4)c(-c4ccccc4)c3-c3ccccc3)c2)cc1 ; c1ccc(-c2cc(-c3cccc(-c4cccc(-c5cc(-c6ccccc6)nc(-c6ccccc6)n5)c4)c3)cc(-c3c(-c4ccccc4)c(-c4ccccc4)c(-c4ccccc4)c(-c4ccccc4)c3-c3ccccc3)c2)cc1 ; c1ccc(-c2cccc(-c3nc(-c4ccccc4)cc(-c4cccc(-c5cccc(-c6c(-c7ccccc7)c(-c7ccccc7)c(-c7ccccc7)c(-c7ccccc7)c6-c6ccccc6)c5)c4)n3)c2)cc1]

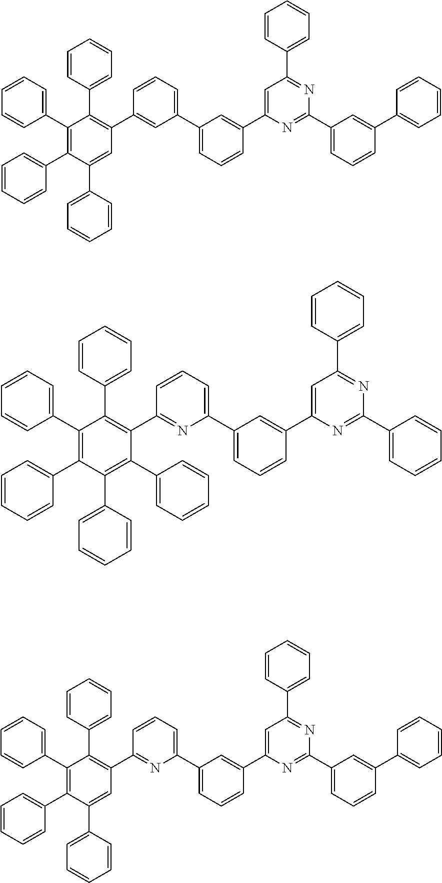 [SMILES: c1ccc(-c2cccc(-c3nc(-c4ccccc4)cc(-c4cccc(-c5cccc(-c6cc(-c7ccccc7)c(-c7ccccc7)c(-c7ccccc7)c6-c6ccccc6)c5)c4)n3)c2)cc1 ; c1ccc(-c2cc(-c3cccc(-c4cccc(-c5c(-c6ccccc6)c(-c6ccccc6)c(-c6ccccc6)c(-c6ccccc6)c5-c5ccccc5)n4)c3)nc(-c3ccccc3)n2)cc1 ; c1ccc(-c2cccc(-c3nc(-c4ccccc4)cc(-c4cccc(-c5cccc(-c6cc(-c7ccccc7)c(-c7ccccc7)c(-c7ccccc7)c6-c6ccccc6)n5)c4)n3)c2)cc1]

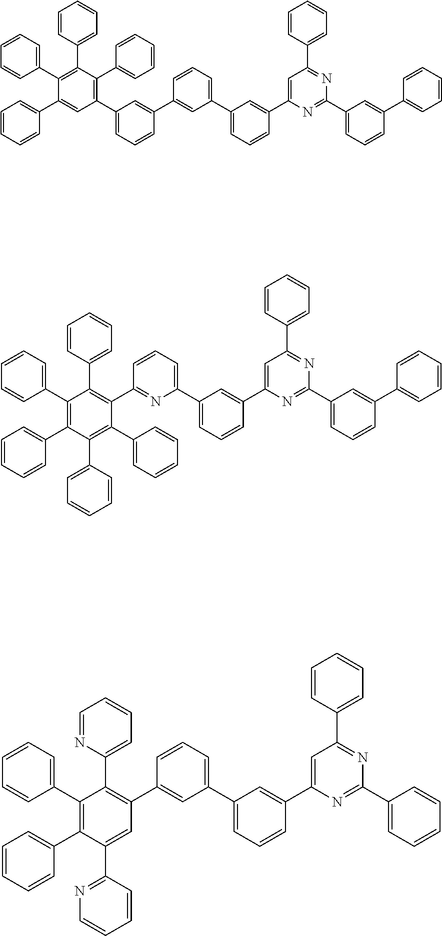 [SMILES: c1ccc(-c2cccc(-c3nc(-c4ccccc4)cc(-c4cccc(-c5cccc(-c6cccc(-c7cc(-c8ccccc8)c(-c8ccccc8)c(-c8ccccc8)c7-c7ccccc7)c6)c5)c4)n3)c2)cc1 ; c1ccc(-c2cccc(-c3nc(-c4ccccc4)cc(-c4cccc(-c5cccc(-c6c(-c7ccccc7)c(-c7ccccc7)c(-c7ccccc7)c(-c7ccccc7)c6-c6ccccc6)n5)c4)n3)c2)cc1 ; c1ccc(-c2cc(-c3cccc(-c4cccc(-c5cc(-c6ccccn6)c(-c6ccccc6)c(-c6ccccc6)c5-c5ccccn5)c4)c3)nc(-c3ccccc3)n2)cc1]

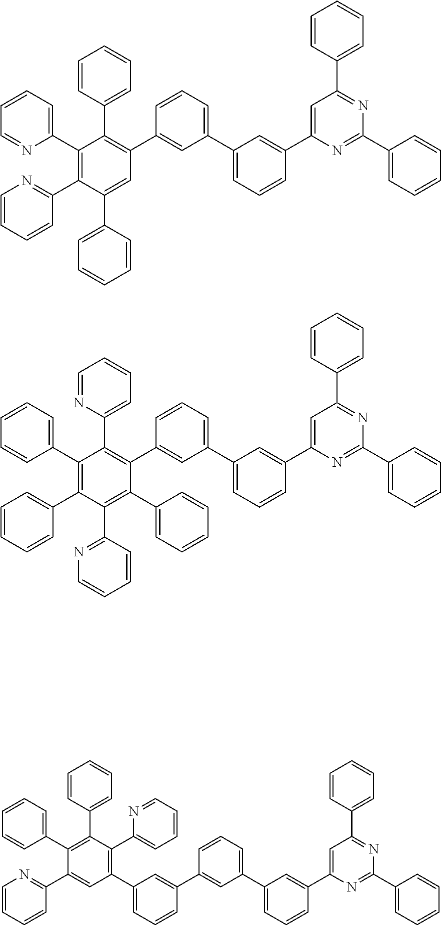 [SMILES: c1ccc(-c2cc(-c3cccc(-c4cccc(-c5cc(-c6ccccc6)c(-c6ccccn6)c(-c6ccccn6)c5-c5ccccc5)c4)c3)nc(-c3ccccc3)n2)cc1 ; c1ccc(-c2cc(-c3cccc(-c4cccc(-c5c(-c6ccccc6)c(-c6ccccn6)c(-c6ccccc6)c(-c6ccccc6)c5-c5ccccn5)c4)c3)nc(-c3ccccc3)n2)cc1 ; c1ccc(-c2cc(-c3cccc(-c4cccc(-c5cccc(-c6cc(-c7ccccn7)c(-c7ccccc7)c(-c7ccccc7)c6-c6ccccn6)c5)c4)c3)nc(-c3ccccc3)n2)cc1]

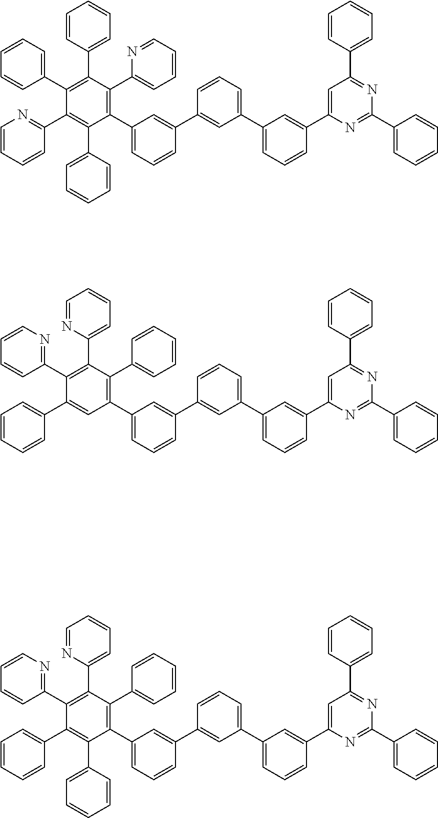 [SMILES: c1ccc(-c2cc(-c3cccc(-c4cccc(-c5cccc(-c6c(-c7ccccc7)c(-c7ccccn7)c(-c7ccccc7)c(-c7ccccc7)c6-c6ccccn6)c5)c4)c3)nc(-c3ccccc3)n2)cc1 ; c1ccc(-c2cc(-c3cccc(-c4cccc(-c5cccc(-c6cc(-c7ccccc7)c(-c7ccccn7)c(-c7ccccn7)c6-c6ccccc6)c5)c4)c3)nc(-c3ccccc3)n2)cc1 ; c1ccc(-c2cc(-c3cccc(-c4cccc(-c5cccc(-c6c(-c7ccccc7)c(-c7ccccc7)c(-c7ccccn7)c(-c7ccccn7)c6-c6ccccc6)c5)c4)c3)nc(-c3ccccc3)n2)cc1]

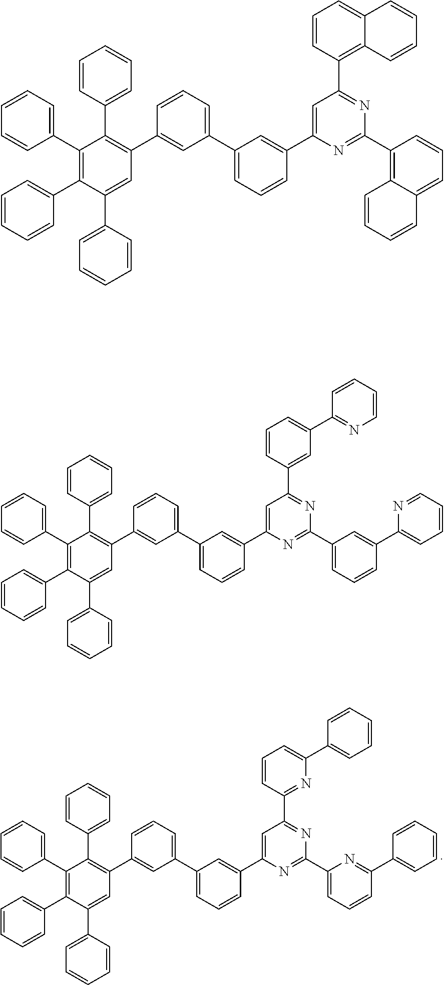 [SMILES: c1ccc(-c2cc(-c3cccc(-c4cccc(-c5cc(-c6cccc7ccccc67)nc(-c6cccc7ccccc67)n5)c4)c3)c(-c3ccccc3)c(-c3ccccc3)c2-c2ccccc2)cc1 ; c1ccc(-c2cc(-c3cccc(-c4cccc(-c5cc(-c6cccc(-c7ccccn7)c6)nc(-c6cccc(-c7ccccn7)c6)n5)c4)c3)c(-c3ccccc3)c(-c3ccccc3)c2-c2ccccc2)cc1 ; c1ccc(-c2cccc(-c3cc(-c4cccc(-c5cccc(-c6cc(-c7ccccc7)c(-c7ccccc7)c(-c7ccccc7)c6-c6ccccc6)c5)c4)nc(-c4cccc(-c5ccccc5)n4)n3)n2)cc1]

18. The light-emitting device of claim 1, wherein the second compound and the third compound are each independently selected from the compounds below:

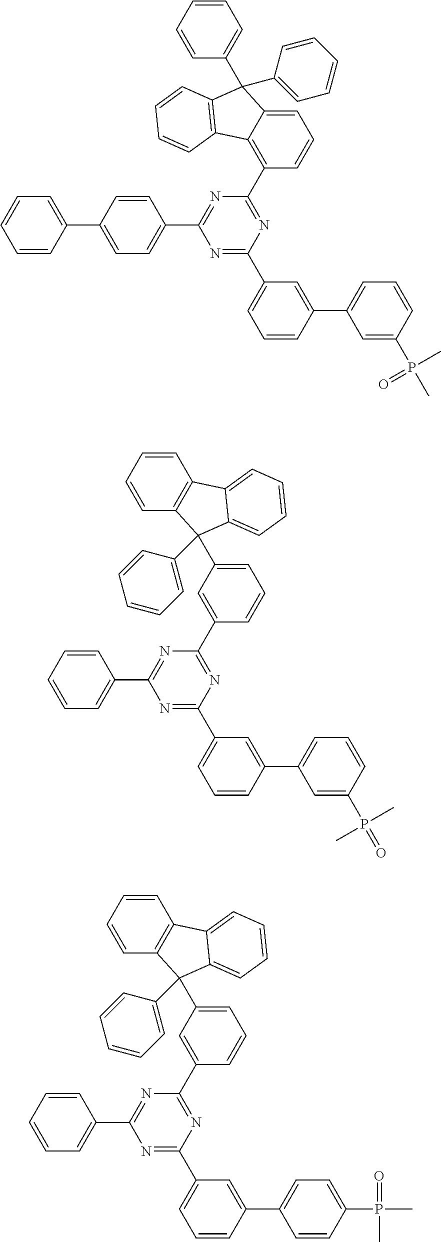 [SMILES: CP(C)(=O)c1cccc(-c2cccc(-c3nc(-c4ccc(-c5ccccc5)cc4)nc(-c4cccc5c4-c4ccccc4C5(c4ccccc4)c4ccccc4)n3)c2)c1 ; CP(C)(=O)c1cccc(-c2cccc(-c3nc(-c4ccccc4)nc(-c4cccc(C5(c6ccccc6)c6ccccc6-c6ccccc65)c4)n3)c2)c1 ; CP(C)(=O)c1ccc(-c2cccc(-c3nc(-c4ccccc4)nc(-c4cccc(C5(c6ccccc6)c6ccccc6-c6ccccc65)c4)n3)c2)cc1]

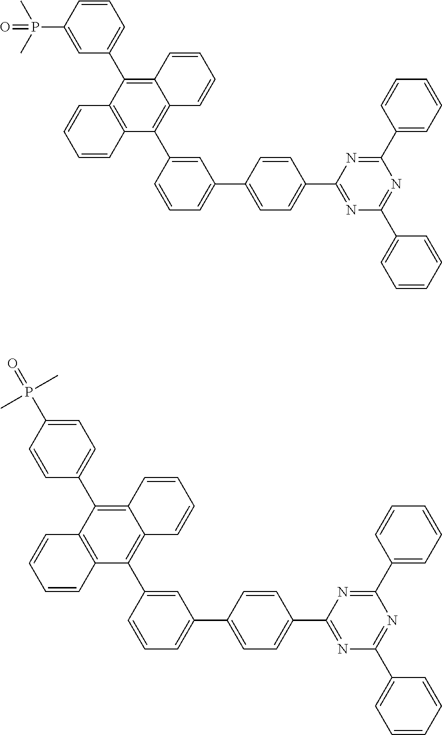 [SMILES: CP(C)(=O)c1cccc(-c2c3ccccc3c(-c3cccc(-c4ccc(-c5nc(-c6ccccc6)nc(-c6ccccc6)n5)cc4)c3)c3ccccc23)c1 ; CP(C)(=O)c1ccc(-c2c3ccccc3c(-c3cccc(-c4ccc(-c5nc(-c6ccccc6)nc(-c6ccccc6)n5)cc4)c3)c3ccccc23)cc1]

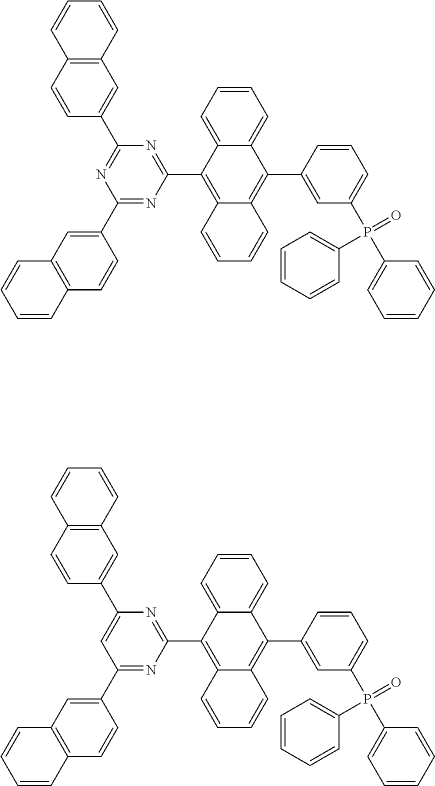 [SMILES: O=P(c1ccccc1)(c1ccccc1)c1cccc(-c2c3ccccc3c(-c3nc(-c4ccc5ccccc5c4)nc(-c4ccc5ccccc5c4)n3)c3ccccc23)c1 ; O=P(c1ccccc1)(c1ccccc1)c1cccc(-c2c3ccccc3c(-c3nc(-c4ccc5ccccc5c4)cc(-c4ccc5ccccc5c4)n3)c3ccccc23)c1]

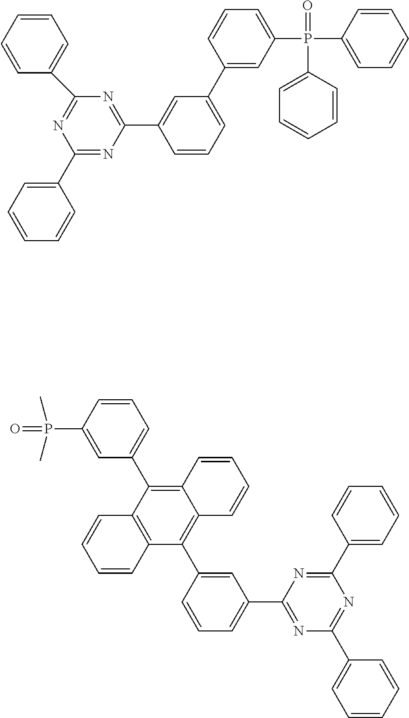 [SMILES: O=P(c1ccccc1)(c1ccccc1)c1cccc(-c2cccc(-c3nc(-c4ccccc4)nc(-c4ccccc4)n3)c2)c1 ; CP(C)(=O)c1cccc(-c2c3ccccc3c(-c3cccc(-c4nc(-c5ccccc5)nc(-c5ccccc5)n4)c3)c3ccccc23)c1]

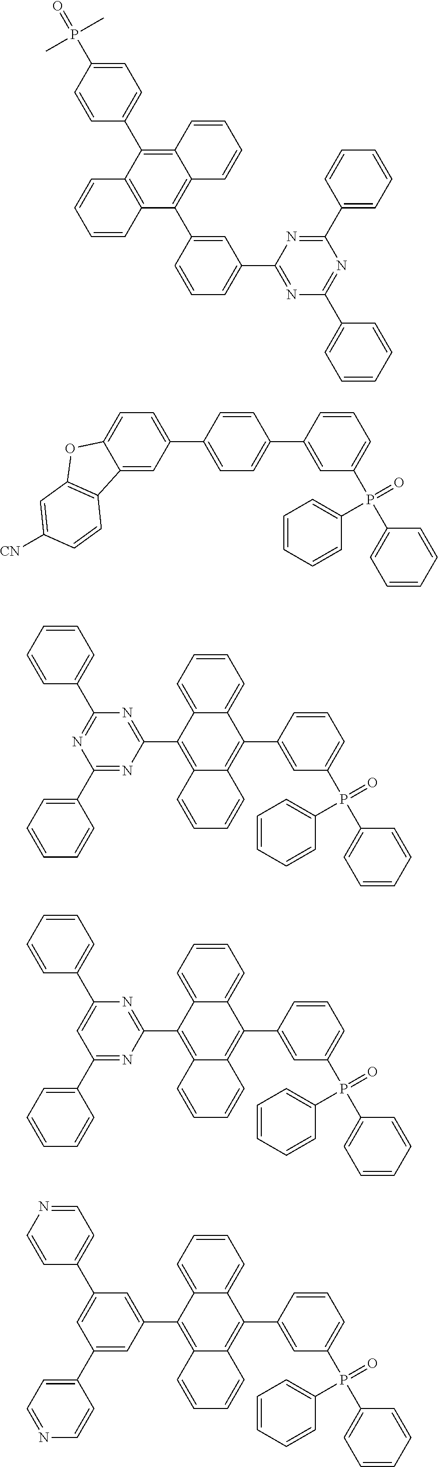

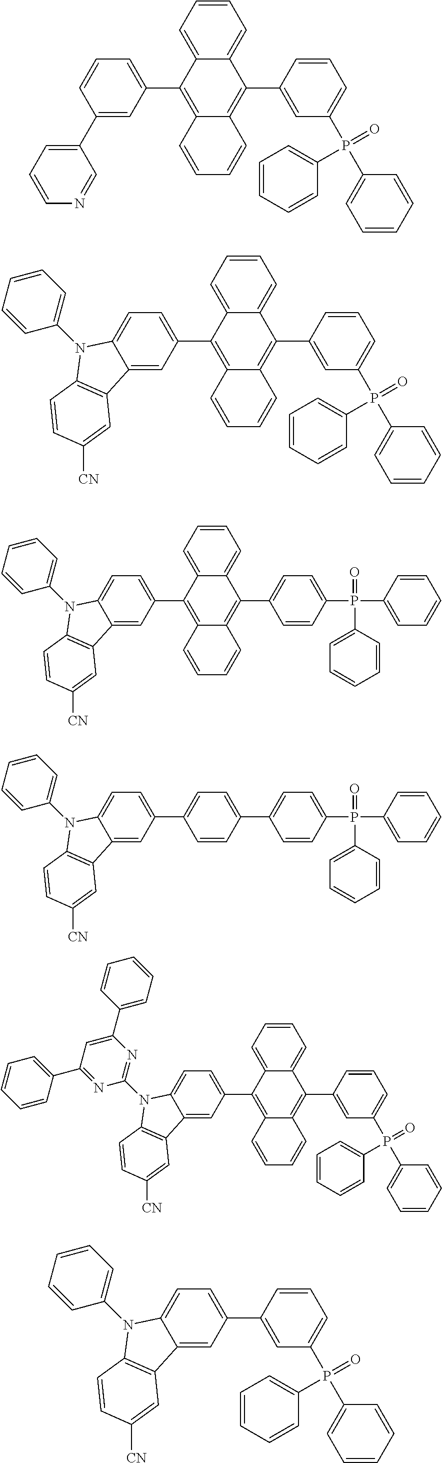

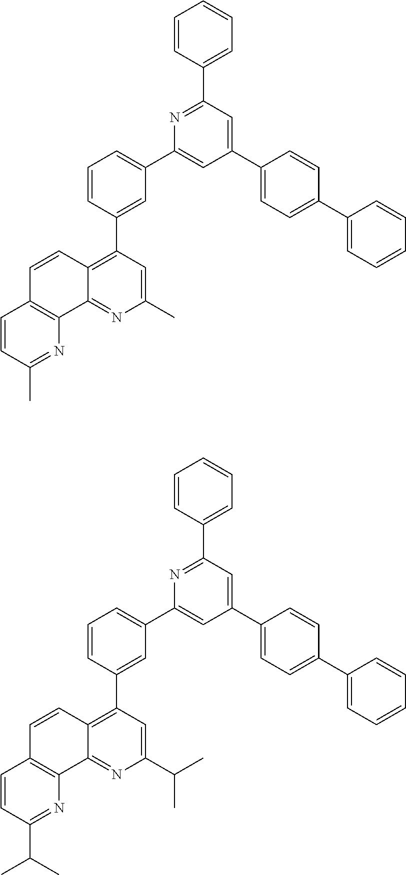 [SMILES: Cc1ccc2ccc3c(-c4cccc(-c5cc(-c6ccc(-c7ccccc7)cc6)cc(-c6ccccc6)n5)c4)cc(C)nc3c2n1 ; CC(C)c1ccc2ccc3c(-c4cccc(-c5cc(-c6ccc(-c7ccccc7)cc6)cc(-c6ccccc6)n5)c4)cc(C(C)C)nc3c2n1]

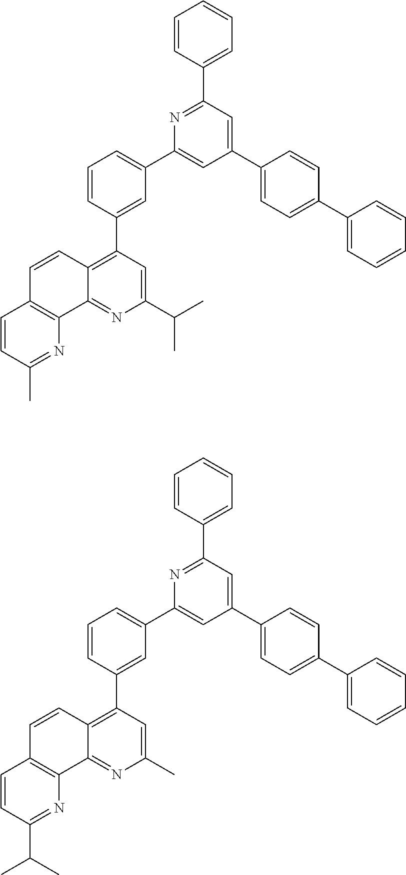 [SMILES: Cc1ccc2ccc3c(-c4cccc(-c5cc(-c6ccc(-c7ccccc7)cc6)cc(-c6ccccc6)n5)c4)cc(C(C)C)nc3c2n1 ; Cc1cc(-c2cccc(-c3cc(-c4ccc(-c5ccccc5)cc4)cc(-c4ccccc4)n3)c2)c2ccc3ccc(C(C)C)nc3c2n1]

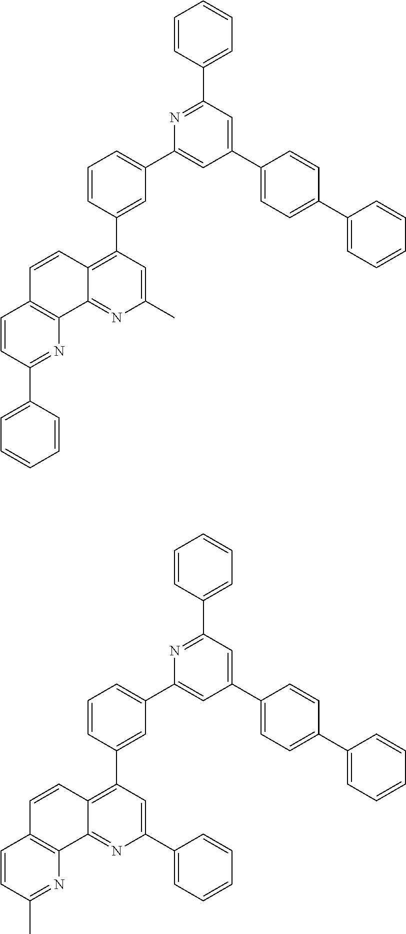 [SMILES: Cc1cc(-c2cccc(-c3cc(-c4ccc(-c5ccccc5)cc4)cc(-c4ccccc4)n3)c2)c2ccc3ccc(-c4ccccc4)nc3c2n1 ; Cc1ccc2ccc3c(-c4cccc(-c5cc(-c6ccc(-c7ccccc7)cc6)cc(-c6ccccc6)n5)c4)cc(-c4ccccc4)nc3c2n1]

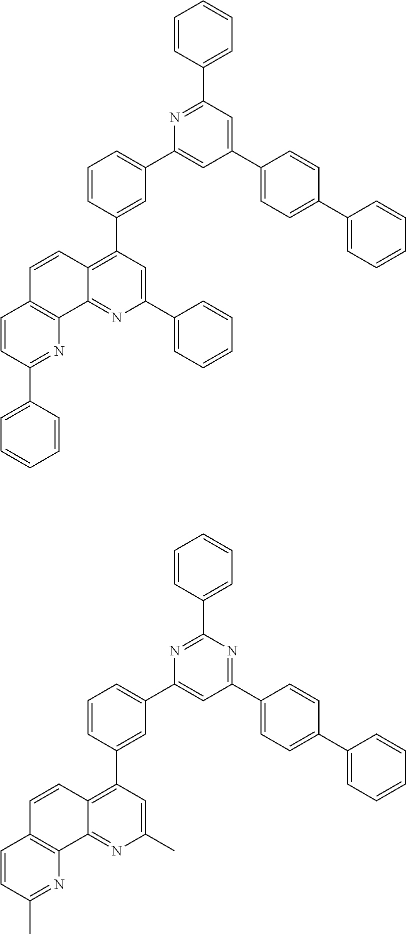 [SMILES: c1ccc(-c2ccc(-c3cc(-c4ccccc4)nc(-c4cccc(-c5cc(-c6ccccc6)nc6c5ccc5ccc(-c7ccccc7)nc56)c4)c3)cc2)cc1 ; Cc1ccc2ccc3c(-c4cccc(-c5cc(-c6ccc(-c7ccccc7)cc6)nc(-c6ccccc6)n5)c4)cc(C)nc3c2n1]

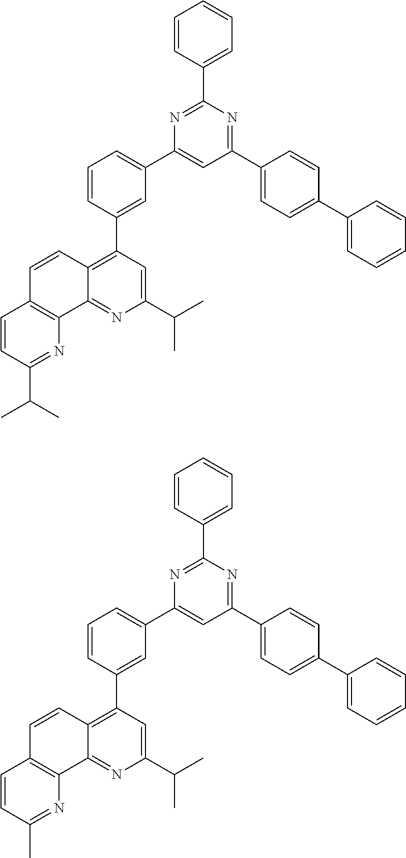 [SMILES: CC(C)c1ccc2ccc3c(-c4cccc(-c5cc(-c6ccc(-c7ccccc7)cc6)nc(-c6ccccc6)n5)c4)cc(C(C)C)nc3c2n1 ; Cc1ccc2ccc3c(-c4cccc(-c5cc(-c6ccc(-c7ccccc7)cc6)nc(-c6ccccc6)n5)c4)cc(C(C)C)nc3c2n1]

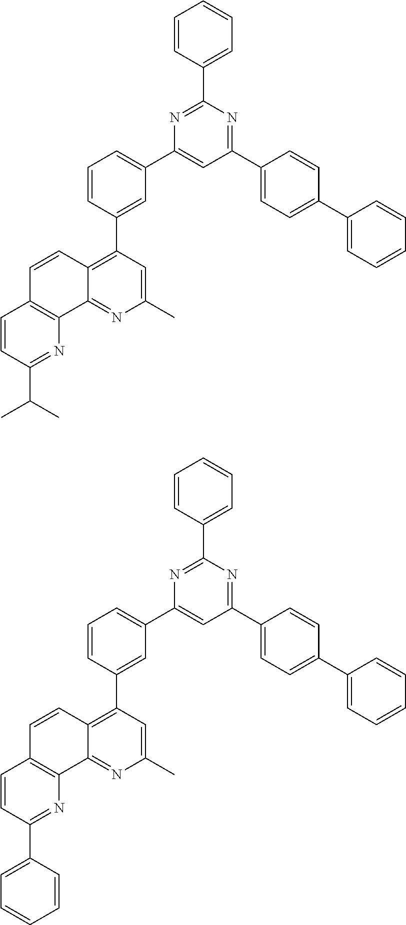 [SMILES: Cc1cc(-c2cccc(-c3cc(-c4ccc(-c5ccccc5)cc4)nc(-c4ccccc4)n3)c2)c2ccc3ccc(C(C)C)nc3c2n1 ; Cc1cc(-c2cccc(-c3cc(-c4ccc(-c5ccccc5)cc4)nc(-c4ccccc4)n3)c2)c2ccc3ccc(-c4ccccc4)nc3c2n1]

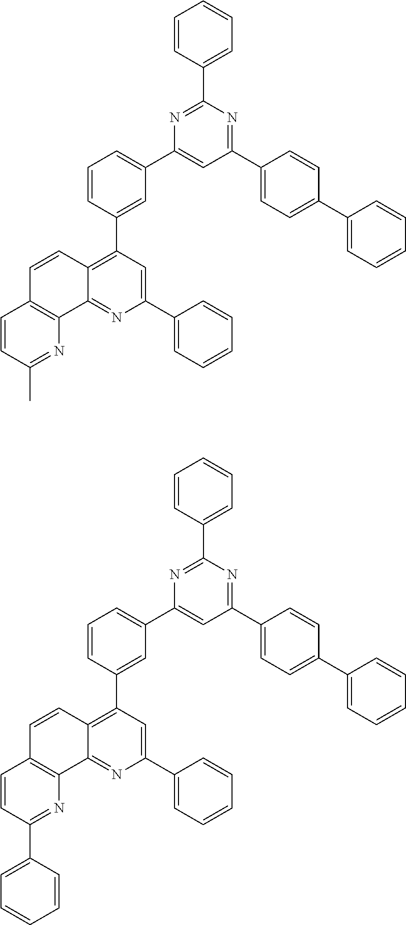 [SMILES: Cc1ccc2ccc3c(-c4cccc(-c5cc(-c6ccc(-c7ccccc7)cc6)nc(-c6ccccc6)n5)c4)cc(-c4ccccc4)nc3c2n1 ; c1ccc(-c2ccc(-c3cc(-c4cccc(-c5cc(-c6ccccc6)nc6c5ccc5ccc(-c7ccccc7)nc56)c4)nc(-c4ccccc4)n3)cc2)cc1]

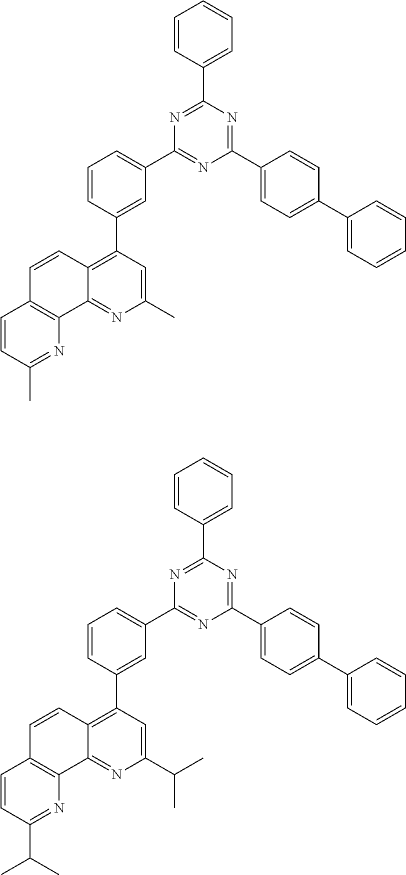 [SMILES: Cc1ccc2ccc3c(-c4cccc(-c5nc(-c6ccccc6)nc(-c6ccc(-c7ccccc7)cc6)n5)c4)cc(C)nc3c2n1 ; CC(C)c1ccc2ccc3c(-c4cccc(-c5nc(-c6ccccc6)nc(-c6ccc(-c7ccccc7)cc6)n5)c4)cc(C(C)C)nc3c2n1]

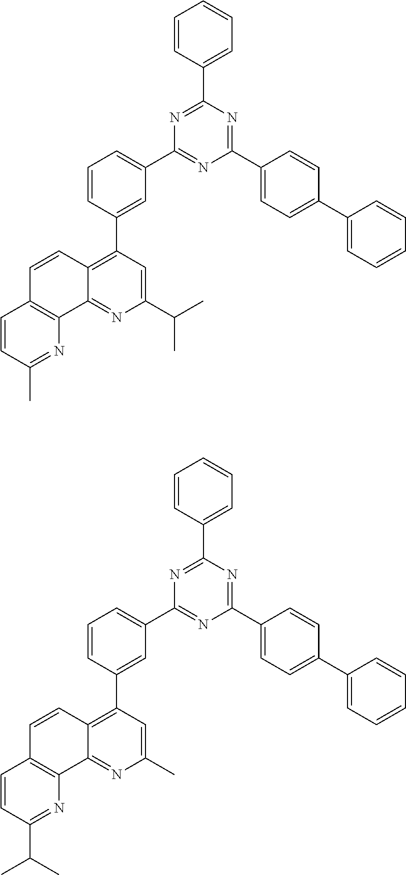 [SMILES: Cc1ccc2ccc3c(-c4cccc(-c5nc(-c6ccccc6)nc(-c6ccc(-c7ccccc7)cc6)n5)c4)cc(C(C)C)nc3c2n1 ; Cc1cc(-c2cccc(-c3nc(-c4ccccc4)nc(-c4ccc(-c5ccccc5)cc4)n3)c2)c2ccc3ccc(C(C)C)nc3c2n1]

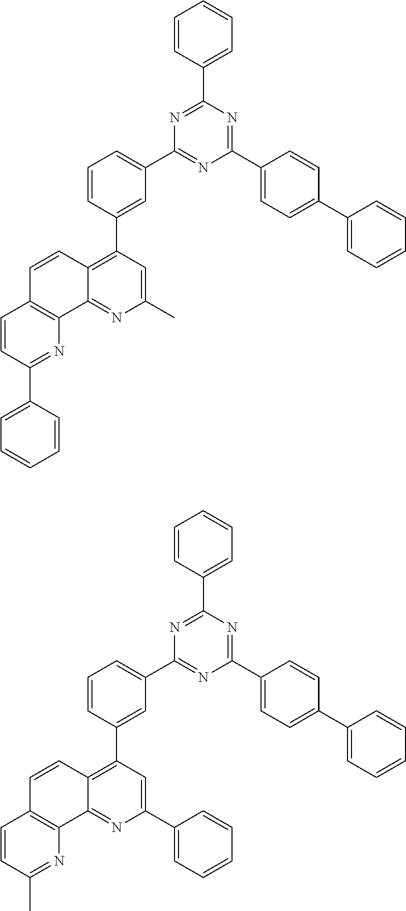 [SMILES: Cc1cc(-c2cccc(-c3nc(-c4ccccc4)nc(-c4ccc(-c5ccccc5)cc4)n3)c2)c2ccc3ccc(-c4ccccc4)nc3c2n1 ; Cc1ccc2ccc3c(-c4cccc(-c5nc(-c6ccccc6)nc(-c6ccc(-c7ccccc7)cc6)n5)c4)cc(-c4ccccc4)nc3c2n1]

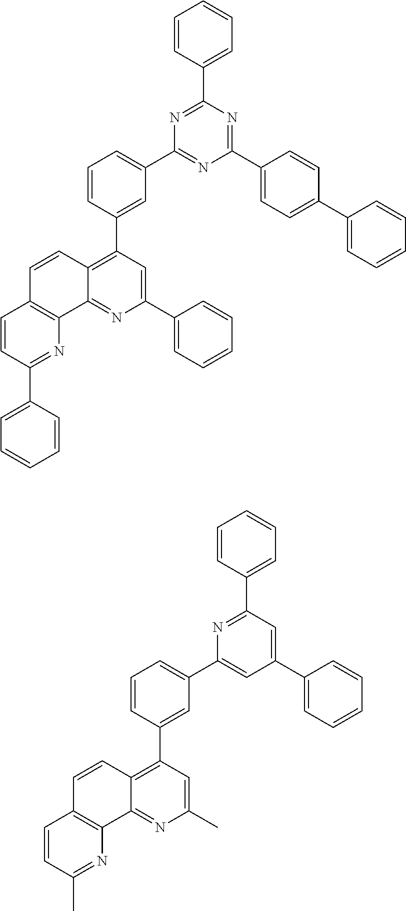 [SMILES: c1ccc(-c2ccc(-c3nc(-c4ccccc4)nc(-c4cccc(-c5cc(-c6ccccc6)nc6c5ccc5ccc(-c7ccccc7)nc56)c4)n3)cc2)cc1 ; Cc1ccc2ccc3c(-c4cccc(-c5cc(-c6ccccc6)cc(-c6ccccc6)n5)c4)cc(C)nc3c2n1]

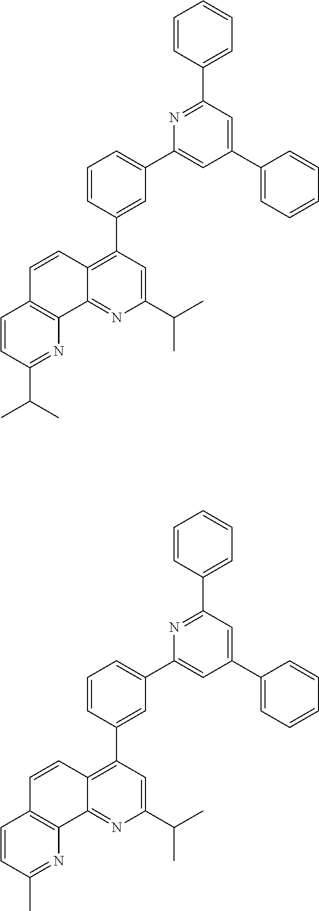 [SMILES: CC(C)c1ccc2ccc3c(-c4cccc(-c5cc(-c6ccccc6)cc(-c6ccccc6)n5)c4)cc(C(C)C)nc3c2n1 ; Cc1ccc2ccc3c(-c4cccc(-c5cc(-c6ccccc6)cc(-c6ccccc6)n5)c4)cc(C(C)C)nc3c2n1]

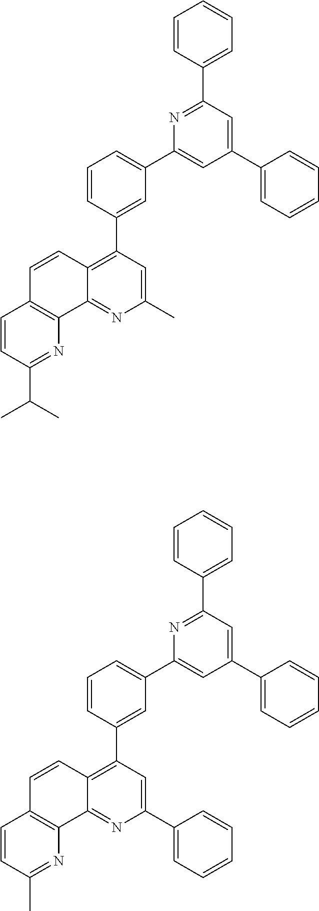 [SMILES: Cc1cc(-c2cccc(-c3cc(-c4ccccc4)cc(-c4ccccc4)n3)c2)c2ccc3ccc(C(C)C)nc3c2n1 ; Cc1ccc2ccc3c(-c4cccc(-c5cc(-c6ccccc6)cc(-c6ccccc6)n5)c4)cc(-c4ccccc4)nc3c2n1]

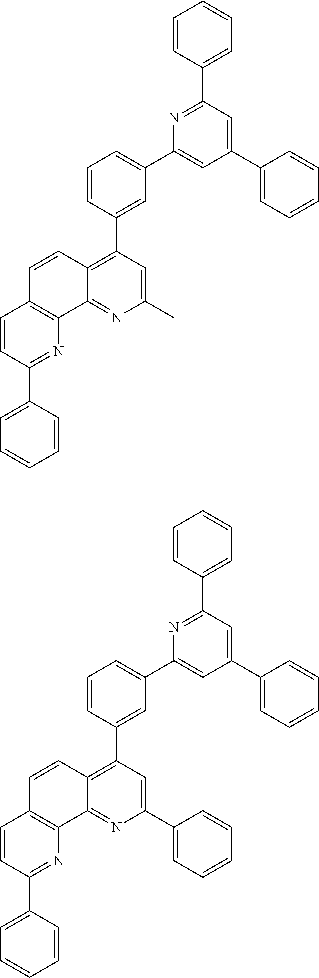 [SMILES: Cc1cc(-c2cccc(-c3cc(-c4ccccc4)cc(-c4ccccc4)n3)c2)c2ccc3ccc(-c4ccccc4)nc3c2n1 ; c1ccc(-c2cc(-c3ccccc3)nc(-c3cccc(-c4cc(-c5ccccc5)nc5c4ccc4ccc(-c6ccccc6)nc45)c3)c2)cc1]

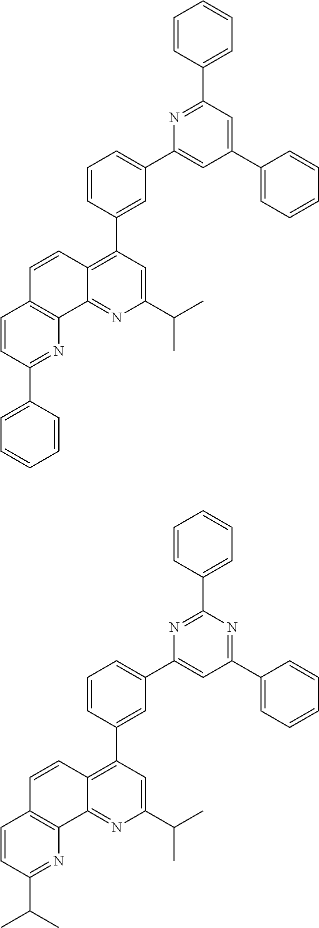 [SMILES: CC(C)c1cc(-c2cccc(-c3cc(-c4ccccc4)cc(-c4ccccc4)n3)c2)c2ccc3ccc(-c4ccccc4)nc3c2n1 ; CC(C)c1ccc2ccc3c(-c4cccc(-c5cc(-c6ccccc6)nc(-c6ccccc6)n5)c4)cc(C(C)C)nc3c2n1]

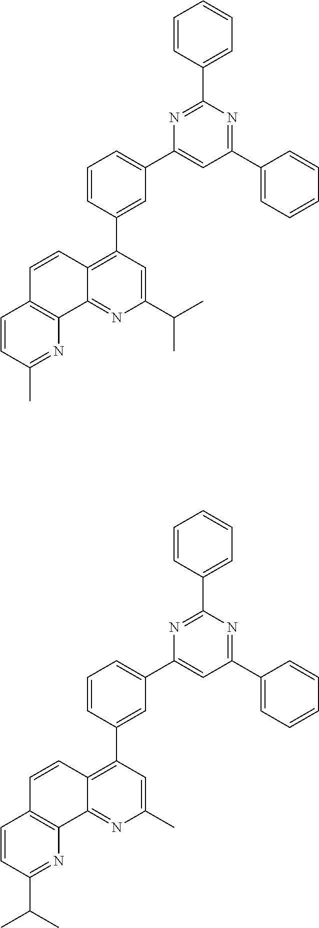 [SMILES: Cc1ccc2ccc3c(-c4cccc(-c5cc(-c6ccccc6)nc(-c6ccccc6)n5)c4)cc(C(C)C)nc3c2n1 ; Cc1cc(-c2cccc(-c3cc(-c4ccccc4)nc(-c4ccccc4)n3)c2)c2ccc3ccc(C(C)C)nc3c2n1]

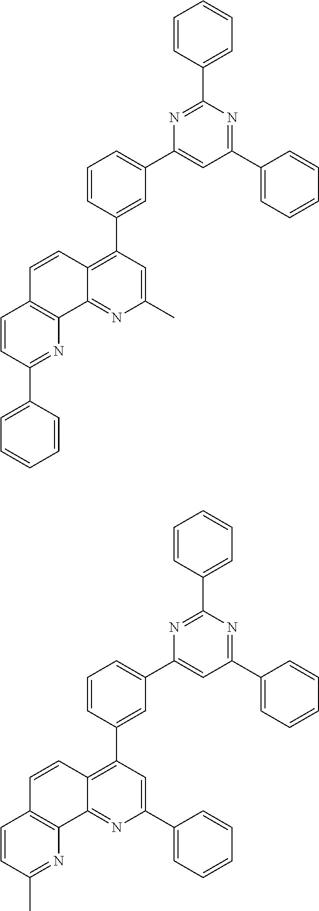 [SMILES: Cc1cc(-c2cccc(-c3cc(-c4ccccc4)nc(-c4ccccc4)n3)c2)c2ccc3ccc(-c4ccccc4)nc3c2n1 ; Cc1ccc2ccc3c(-c4cccc(-c5cc(-c6ccccc6)nc(-c6ccccc6)n5)c4)cc(-c4ccccc4)nc3c2n1]

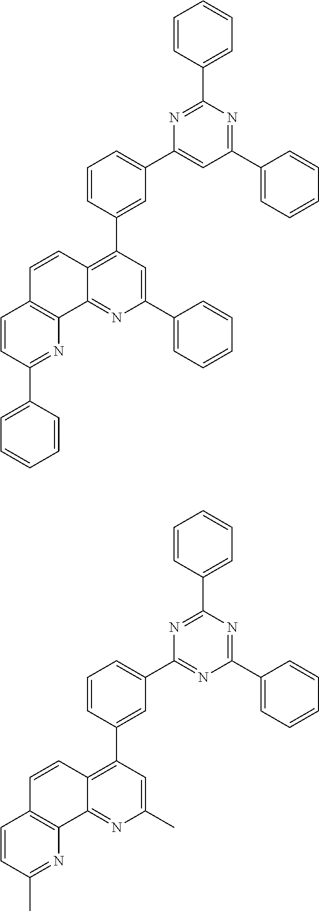 [SMILES: c1ccc(-c2cc(-c3cccc(-c4cc(-c5ccccc5)nc5c4ccc4ccc(-c6ccccc6)nc45)c3)nc(-c3ccccc3)n2)cc1 ; Cc1ccc2ccc3c(-c4cccc(-c5nc(-c6ccccc6)nc(-c6ccccc6)n5)c4)cc(C)nc3c2n1]

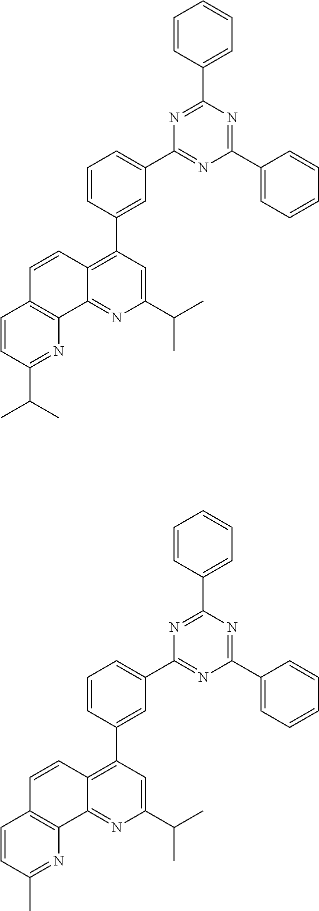 [SMILES: CC(C)c1ccc2ccc3c(-c4cccc(-c5nc(-c6ccccc6)nc(-c6ccccc6)n5)c4)cc(C(C)C)nc3c2n1 ; Cc1ccc2ccc3c(-c4cccc(-c5nc(-c6ccccc6)nc(-c6ccccc6)n5)c4)cc(C(C)C)nc3c2n1]

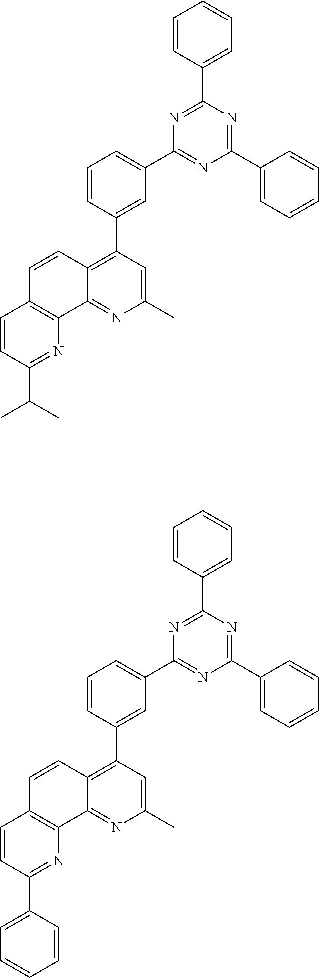 [SMILES: Cc1cc(-c2cccc(-c3nc(-c4ccccc4)nc(-c4ccccc4)n3)c2)c2ccc3ccc(C(C)C)nc3c2n1 ; Cc1cc(-c2cccc(-c3nc(-c4ccccc4)nc(-c4ccccc4)n3)c2)c2ccc3ccc(-c4ccccc4)nc3c2n1]

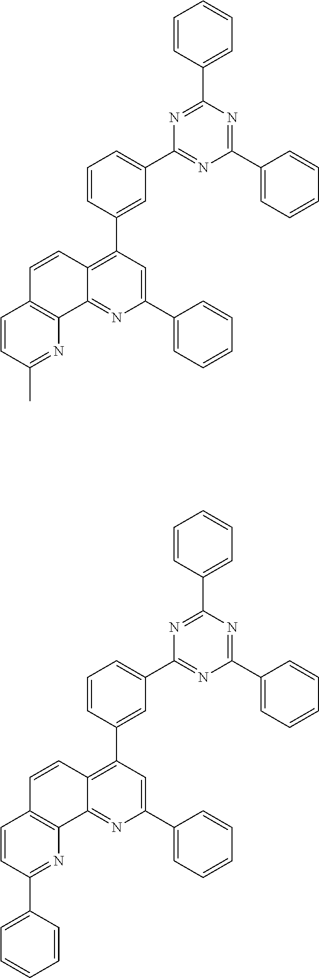 [SMILES: Cc1ccc2ccc3c(-c4cccc(-c5nc(-c6ccccc6)nc(-c6ccccc6)n5)c4)cc(-c4ccccc4)nc3c2n1 ; c1ccc(-c2ccc3ccc4c(-c5cccc(-c6nc(-c7ccccc7)nc(-c7ccccc7)n6)c5)cc(-c5ccccc5)nc4c3n2)cc1]

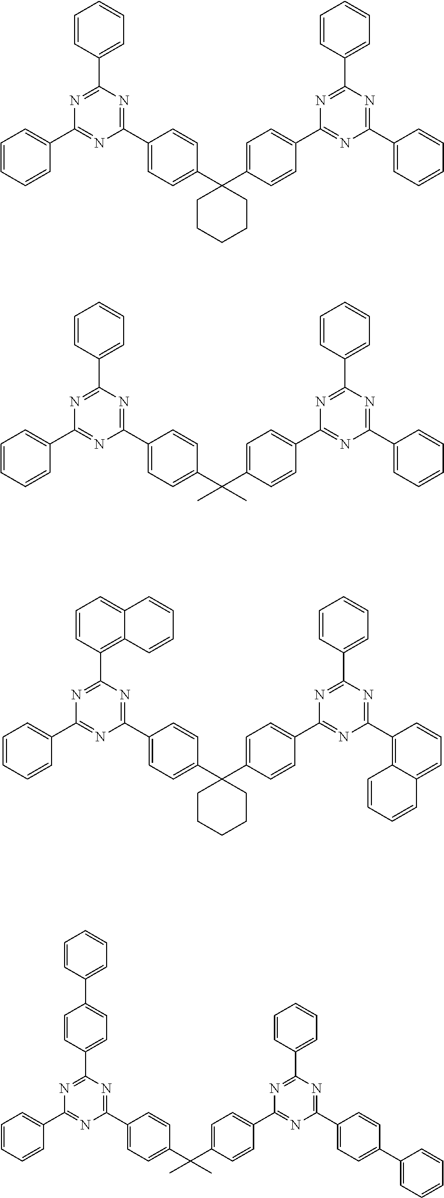 [SMILES: c1ccc(-c2nc(-c3ccccc3)nc(-c3ccc(C4(c5ccc(-c6nc(-c7ccccc7)nc(-c7ccccc7)n6)cc5)CCCCC4)cc3)n2)cc1 ; CC(C)(c1ccc(-c2nc(-c3ccccc3)nc(-c3ccccc3)n2)cc1)c1ccc(-c2nc(-c3ccccc3)nc(-c3ccccc3)n2)cc1 ; c1ccc(-c2nc(-c3ccc(C4(c5ccc(-c6nc(-c7ccccc7)nc(-c7cccc8ccccc78)n6)cc5)CCCCC4)cc3)nc(-c3cccc4ccccc34)n2)cc1 ; CC(C)(c1ccc(-c2nc(-c3ccccc3)nc(-c3ccc(-c4ccccc4)cc3)n2)cc1)c1ccc(-c2nc(-c3ccccc3)nc(-c3ccc(-c4ccccc4)cc3)n2)cc1]

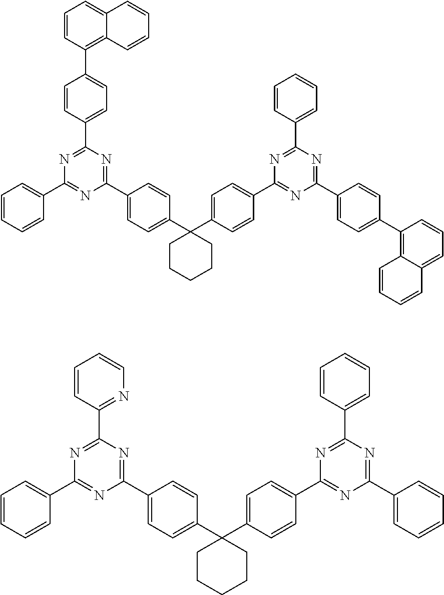 [SMILES: c1ccc(-c2nc(-c3ccc(-c4cccc5ccccc45)cc3)nc(-c3ccc(C4(c5ccc(-c6nc(-c7ccccc7)nc(-c7ccc(-c8cccc9ccccc89)cc7)n6)cc5)CCCCC4)cc3)n2)cc1 ; c1ccc(-c2nc(-c3ccccc3)nc(-c3ccc(C4(c5ccc(-c6nc(-c7ccccc7)nc(-c7ccccn7)n6)cc5)CCCCC4)cc3)n2)cc1]

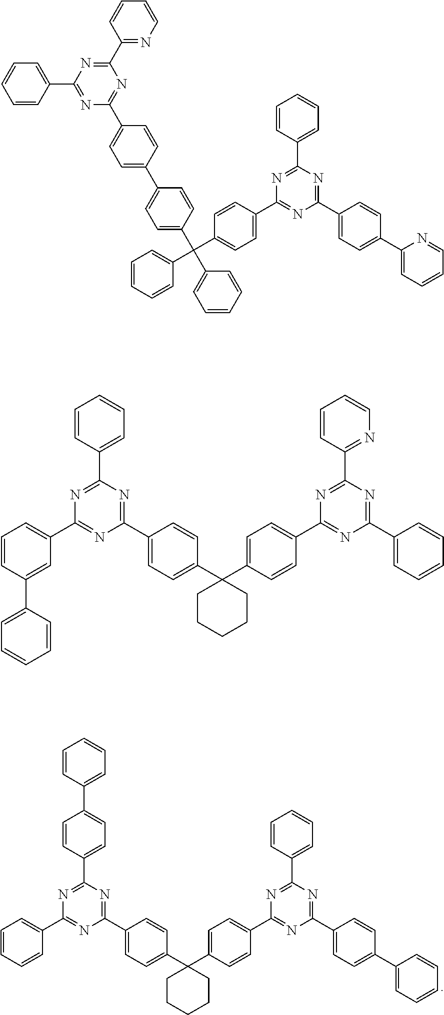 [SMILES: c1ccc(-c2nc(-c3ccc(-c4ccccn4)cc3)nc(-c3ccc(C(c4ccccc4)(c4ccccc4)c4ccc(-c5ccc(-c6nc(-c7ccccc7)nc(-c7ccccn7)n6)cc5)cc4)cc3)n2)cc1 ; c1ccc(-c2cccc(-c3nc(-c4ccccc4)nc(-c4ccc(C5(c6ccc(-c7nc(-c8ccccc8)nc(-c8ccccn8)n7)cc6)CCCCC5)cc4)n3)c2)cc1 ; c1ccc(-c2ccc(-c3nc(-c4ccccc4)nc(-c4ccc(C5(c6ccc(-c7nc(-c8ccccc8)nc(-c8ccc(-c9ccccc9)cc8)n7)cc6)CCCCC5)cc4)n3)cc2)cc1]

19. An electronic apparatus comprising the light-emitting device of claim 1.

20. The electronic apparatus of claim 19, wherein the m emitting units comprise one to seven blue emitting units.
